(19) United States
(12) Patent Application Publication
(10) Pub. No.: US 2025/0359481 A1
(43) Pub. Date: Nov. 20, 2025

(54) LIGHT-EMITTING DEVICE AND ELECTRONIC APPARATUS INCLUDING THE SAME

(71) Applicant: Samsung Display Co., Ltd., Yongin-si (KR)

(72) Inventors: Dongjun Kim, Yongin-si (KR); Chaeyeong Kim, Yongin-si (KR); Hwasook Ryu, Yongin-si (KR); Hankyu Pak, Yongin-si (KR); Sanghyun Han, Yongin-si (KR)

(21) Appl. No.: 18/967,326

(22) Filed: Dec. 3, 2024

(30) Foreign Application Priority Data
May 14, 2024 (KR) 10-2024-0063415

(51) Int. Cl. H10K 85/60; C09K 11/02; H10K 50/12; H10K 50/16; H10K 101/00

(52) U.S. Cl. CPC H10K 85/658; C09K 11/02; H10K 50/12; H10K 50/16; H10K 85/615; H10K 85/654; H10K 85/656; H10K 2101/90

(57) ABSTRACT

A light-emitting device includes a first electrode, a second electrode facing the first electrode, and an interlayer arranged between the first electrode and the second electrode and including an emission layer, wherein the interlayer includes a compound represented by Formula 1.

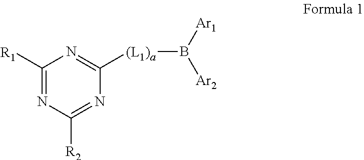

### CROSS-REFERENCE TO RELATED APPLICATION

The present application claims priority to and the benefit of Korean Patent Application No. 10-2024-0063415, filed on May 14, 2024, in the Korean Intellectual Property Office, the disclosure of which is incorporated by reference herein in its entirety.

### BACKGROUND

### 1. Field

One or more embodiments of the present disclosure relate to a light-emitting device and an electronic apparatus including the same.

### 2. Description of the Related Art

Among light-emitting devices, self-emissive devices (e.g., organic light-emitting devices) have relatively wide viewing angles, high contrast ratios, short response times, and excellent or suitable characteristics in terms of luminance, driving voltage, and response speed. That is, self-emissive devices, such as organic light-emitting devices, stand out among light-emitting devices due to their wide viewing angles, high contrast ratios, quick response times, and excellent characteristics in luminance, driving voltage, and response speed.

In a light-emitting device, a first electrode is arranged on a substrate, and a hole transport region, an emission layer, an electron transport region, and a second electrode are sequentially arranged on the first electrode in the stated order. Holes provided from the first electrode move toward the emission layer through the hole transport region, and electrons provided from the second electrode move toward the emission layer through the electron transport region. Carriers, such as the holes and the electrons, recombine in the emission layer to produce excitons. These excitons may transition and decay from an excited state to a ground state, thereby generating light (e.g., to display an image).

### SUMMARY

One or more aspects of embodiments of the present disclosure are directed toward a light-emitting device that surpasses (e.g., is superior to) comparable light-emitting devices.

Additional aspects will be set forth in part in the description which follows and, in part, will be apparent from the description, or may be learned by practice of the presented embodiments of the disclosure.

According to one or more embodiments of the present disclosure, a light-emitting device includes:
a first electrode;
a second electrode opposite to (e.g., facing) the first electrode; and
an interlayer between the first electrode and the second electrode and including an emission layer,
wherein the interlayer includes a compound represented by Formula 1:

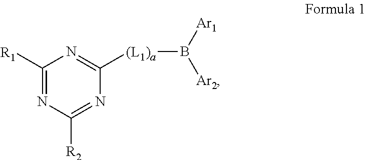

wherein, in Formula 1,
R₁ and R₂ may each independently be a C₁-C₆₀ alkyl group unsubstituted or substituted with at least one R₁₀ₐ, a C₃-C₁₀ cycloalkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₁-C₆₀ alkylthio group unsubstituted or substituted with at least one R₁₀ₐ, a C₆-C₆₀ aryl group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₁-C₆₀ heteroaryl group unsubstituted or substituted with at least one R₁₀ₐ, a C₈-C₆₀ non-aromatic condensed polycyclic group unsubstituted or substituted with at least one R₁₀ₐ, a C₁-C₆₀ non-aromatic condensed heteropolycyclic group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
in one or more embodiments, R₁ and/or R₂ may be a C₁-C₆₀ alkyl group unsubstituted or substituted with at least one R₁₀ₐ or a C₃-C₁₀ cycloalkyl group unsubstituted or substituted with at least one R₁₀ₐ,
provided that an adamantyl group is excluded from the cycloalkyl group,
Ar₁ and Ar₂ may each independently be hydrogen, deuterium, —F, —Cl, —Br, —I, a hydroxyl group, a cyano group, a nitro group, a C₆-C₆₀ aryl group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₁-C₆₀ heteroaryl group unsubstituted or substituted with at least one R₁₀ₐ, a C₈-C₆₀ non-aromatic condensed polycyclic group unsubstituted or substituted with at least one R₁₀ₐ, or a C₁-C₆₀ non-aromatic condensed heteropolycyclic group unsubstituted or substituted with at least one R₁₀ₐ,
a may be an integer from 1 to 5,
L₁ may be a C₃-C₃₀ carbocyclic group unsubstituted or substituted with at least one R₁₀ₐ or a C₁-C₃₀ heterocyclic group unsubstituted or substituted with at least one R₁₀ₐ,
provided that if (e.g., when) L₁ directly bonded to a triazine moiety is phenylene, the substitution position (e.g., the other substitution position) of the phenylene is not meta,
if (e.g., when) a is 2 or more, each L₁ may be identical to or different from the others,
in one or more embodiments, adjacent substituents among the substituents bonded to B may be linked to each other via a direct bond, —O—, —C(Q₁)(Q₂)-, —Si(Q₁)(Q₂)-, —N(Q₁)-, —C(═O)—, —S(═O)₂—, or —P(═O)—, to form a ring,
R₁₀ₐ may be:
hydrogen, deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₅-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof,
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof, or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

According to one or more embodiments of the present disclosure, an electronic apparatus includes the light-emitting device.

According to one or more embodiments of the present disclosure, a compound represented by Formula 1 is provided.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects, features, and advantages of certain embodiments of the disclosure will be more apparent from the following description taken in conjunction with the accompanying drawings, in which:

FIGS. 1-3 are each a schematic view of a light-emitting device according to one or more embodiments of the present disclosure;

FIG. 4 is a cross-sectional view of an electronic apparatus according to one or more embodiments of the present disclosure; and

FIG. 5 is a cross-sectional view of an electronic apparatus according to one or more embodiments of the present disclosure.

### DETAILED DESCRIPTION

Reference will now be made in more detail to one or more embodiments, examples of which are illustrated in the accompanying drawings, wherein like reference numerals refer to like elements throughout, and duplicative descriptions thereof may not be provided for conciseness. In this regard, the presented embodiments may have different forms and should not be construed as being limited to the descriptions set forth herein. Accordingly, embodiments of the present disclosure are merely described, by referring to the drawings, to explain aspects of the present disclosure. As used herein, the term “and/or” or “or” may include any and all combinations of one or more of the associated listed items. Throughout the disclosure, the expressions such as “at least one of,” “one of,” and “selected from,” when preceding a list of elements, modify the entire list of elements and do not modify the individual elements of the list. For example, “at least one of a, b, or c,” “at least one selected from a, b, and c,” “at least one selected from among a to c,” etc., may indicate only a, only b, only c, both (e.g., simultaneously) a and b, both (e.g., simultaneously) a and c, both (e.g., simultaneously) b and c, all of a, b, and c, or variations thereof.

Although it has been widely reported that commonly utilized electron transport materials have the characteristics of suitable and high efficiency and long lifespan, so far, in the commercialization of mobile devices and large-sized televisions using organic light-emitting devices, further improvements in luminescence efficiency and lifespan are desired or required to achieve a fine pitch and low power consumption.

According to one or more embodiments of the present disclosure, a light-emitting device may include:
a first electrode;
a second electrode opposite to (e.g., facing) the first electrode; and
an interlayer between the first electrode and the second electrode and including an emission layer,
wherein the interlayer may include a compound represented by Formula 1:

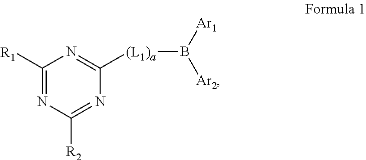

wherein, in Formula 1,
R₁ and R₂ may each independently be a C₁-C₆₀ alkyl group unsubstituted or substituted with at least one R₁₀ₐ, a C₃-C₁₀ cycloalkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₁-C₆₀ alkylthio group unsubstituted or substituted with at least one R₁₀ₐ, a C₆-C₆₀ aryl group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₁-C₆₀ heteroaryl group unsubstituted or substituted with at least one R₁₀ₐ, a C₈-C₆₀ non-aromatic condensed polycyclic group unsubstituted or substituted with at least one R₁₀ₐ, a C₁-C₆₀ non-aromatic condensed heteropolycyclic group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
in one or more embodiments, R₁ and/or R₂ may be a C₁-C₆₀ alkyl group unsubstituted or substituted with at least one R₁₀ₐ or a C₃-C₁₀ cycloalkyl group unsubstituted or substituted with at least one R₁₀ₐ,
provided that an adamantyl group is excluded from the cycloalkyl group (i.e., the C₃-C₁₀ cycloalkyl group),
Ar₁ and Ar₂ may each independently be hydrogen, deuterium, —F, —Cl, —Br, —I, a hydroxyl group, a cyano group, a nitro group, a C₆-C₆₀ aryl group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₁-C₆₀ heteroaryl group unsubstituted or substituted with at least one R₁₀ₐ, a C₈-C₆₀ non-aromatic condensed polycyclic group unsubstituted or substituted with at least one R₁₀ₐ, or a C₁-C₆₀ non-aromatic condensed heteropolycyclic group unsubstituted or substituted with at least one R₁₀ₐ,
a may be an integer from 1 to 5,
L₁ may be a C₃-C₃₀ carbocyclic group unsubstituted or substituted with at least one R₁₀ₐ or a C₁-C₃₀ heterocyclic group unsubstituted or substituted with at least one R₁₀ₐ,
provided that if (e.g., when) L₁ directly bonded to a triazine moiety is phenylene, the substitution position (e.g., the other substitution position) of the phenylene is not meta, for example, the substitution position of the phenylene bonded to another L₁ or the boron (B) is not meta with respect to the substitution position of the phenylene bonded to the triazine moiety,
if (e.g., when) a is 2 or more, each L₁ may be identical to or different from the others,
in one or more embodiments, adjacent substituents among the substituents bonded to B may be linked to each other via a direct bond, —O—, —C(Q₁)(Q₂)-, —Si(Q₁)(Q₂)-, —N(Q₁)-, —C(═O)—, —S(═O)₂—, or —P(═O)—, to form a ring (i.e., optionally, in one or more embodiments, adjacent substituents bonded to B may be linked to each other via a direct bond, or through a bond by —O—, —C(Q₁)(Q₂)-, —Si(Q₁)(Q₂)-, —N(Q₁)-, —C(═O)—, —S(═O)₂—, or —P(═O)—, to form a ring),
R₁₀ₐ may be:
hydrogen, deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₅-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

The compound of Formula 1 may have electrical stability and excellent or suitable charge transport ability by including a triazine moiety directly substituted with an alkyl group or a cycloalkyl group. A light-emitting device including the compound of Formula 1 may have excellent or suitable driving voltage, efficiency, and lifespan.

According to one or more embodiments, the first electrode may be an anode, the second electrode may be a cathode, and the interlayer may further include a hole transport region between the first electrode and the emission layer and including a hole injection layer, a hole transport layer, an electron blocking layer, an emission auxiliary layer, or any combination thereof.

According to one or more embodiments, the first electrode may be an anode, the second electrode may be a cathode, and the interlayer may further include an electron transport region between the second electrode and the emission layer and including a hole blocking layer, an electron transport layer, an electron injection layer, or any combination thereof.

According to one or more embodiments, the electron transport region may include a compound represented by Formula 1. For example, in one or more embodiments, the hole blocking layer may include a compound represented by Formula 1. For example, in one or more embodiments, the electron transport layer may include a compound represented by Formula 1. For example, in one or more embodiments, the electron injection layer may include a compound represented by Formula 1.

According to one or more embodiments, the emission layer may include a first host, a second host, a first dopant, and a second dopant, the first dopant is a compound including a metal and a ligand including an imidazole moiety, and the second dopant may be a compound including boron.

According to one or more embodiments, the first host may be a hole-transporting host.

According to one or more embodiments, the second host may be an electron-transporting host.

The hole-transporting host may be a compound having strong hole properties. The expression “a compound having strong hole properties” refers to a compound that is easy to accept holes and transport the holes with suitable carrier mobility, and such properties may be obtained by including a hole-receiving moiety (also, referred to as a hole transporting (HT) moiety).

Such a hole-receiving moiety may include, for example, a π electron-rich heteroaromatic compound (for example, a carbazole derivative or an indole derivative), or an aromatic amine compound.

The electron-transporting host may be a compound having strong electron properties. The expression “a compound having strong electron properties” refers to a compound that is easy to accept electrons and transport the electrons with suitable carrier mobility, and such properties may be obtained by including an electron-receiving moiety (also, referred to as an electron transporting (ET) moiety).

Such an electron-receiving moiety may include, for example, a π electron-deficient heteroaromatic compound. For example, the electron-receiving moiety may include a nitrogen-containing heteroaromatic compound.

When a compound includes only a HT moiety or only an ET moiety, it is clear whether the nature of the compound has HT properties or ET properties.

In one or more embodiments, a compound may include both (e.g., simultaneously) a HT moiety and an ET moiety. In this case, a simple comparison between the total number of the HT moieties and the total number of the ET moieties in the compound may be a criterion for predicting whether the compound is a HT compound or an ET compound, but may not be an absolute criterion. One of the reasons why such a simple comparison cannot be an absolute criterion is that one HT moiety and one ET moiety do not respectively have exactly the same ability to attract holes and electrons.

Therefore, a relatively reliable way to determine whether a compound having a certain structure is a HT compound or an ET compound is to directly implement the compound in a device.

In one or more embodiments, a weight ratio of the first host to the second host may be in a range of about 9:1 to about 1:9. For example, in one or more embodiments, the weight ratio of the first host to the second host may be in a range of about 6:4 to about 4:6. When the weight ratio of the first host to the second host is within the ranges above, the balance of injected charges may be appropriate or suitable.

According to one or more embodiments, the metal of the first dopant may include a transition metal.

For example, in one or more embodiments, the first dopant may include a compound represented by Formula 401:

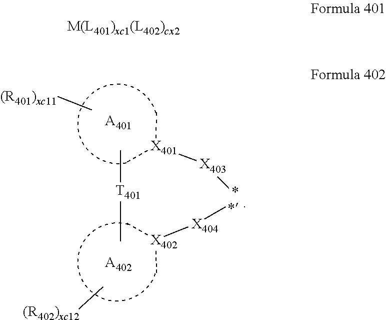

wherein, in Formulae 401 and 402,
M may be titanium (Ti), cobalt (Co), copper (Cu), zinc (Zn), zirconium (Zr), ruthenium (Ru), rhodium (Rh), palladium (Pd), rhenium (Re), platinum (Pt), gold (Au), osmium (Os), iridium (Ir), or rhenium (Re),
L₄₀₁ may be a ligand represented by Formula 402, and xc1 may be 1, 2, or 3, wherein, if (e.g., when) xc1 is 2 or more, two or more of L₄₀₁(s) may be identical to or different from each other,
L₄₀₂ may be an organic ligand, and xc2 may be 0, 1, 2, 3, or 4, and if (e.g., when) xc2 is 2 or more, two or more of L₄₀₂(s) may be identical to or different from each other,
X₄₀₁ and X₄₀₂ may each independently be nitrogen or carbon,
ring A₄₀₁ and ring A₄₀₂ may each independently be a C₅-C₆₀ carbocyclic group or a C₁-C₆₀ heterocyclic group,
T₄₀₁ may be a single bond, —O—, —S—, —C(═O)—, —N(Q₄₁₁)-, —C(Q₄₁₁)(Q₄₁₂)-, —C(Q₄₁₁)=C(Q₄₁₂)-, —C(Q₄₁₁)=, or ═C═,
X₄₀₃ and X₄₀₄ may each independently be a chemical bond, O, S, N(Q₄₁₃), B(Q₄₁₃), P(Q₄₁₃), C(Q₄₁₃)(Q₄₁₄), or Si(Q₄₁₃)(Q₄₁₄),
R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
in one or more embodiments, adjacent groups selected from among R₄₀₁(s) and R₄₀₂(s) may be linked to form a ring (i.e., optionally, in one or more embodiments, adjacent groups selected from R₄₀₁(s) and R₄₀₂(s) may be linked to form a ring),
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₅-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁₁ to Q₁₃, Q₂₁ to Q₂₃, Q₃₁ to Q₃₃, Q₄₁₁ to Q₄₁₄, and Q₄₀₁ to Q₄₀₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group unsubstituted or substituted with deuterium, —F, a cyano group, a C₁-C₆₀ alkyl group, a C₁-C₆₀ alkoxy group, a phenyl group, a biphenyl group, or any combination thereof; a C₁-C₆₀ heterocyclic group; a C₇-C₆₀ arylalkyl group; or a C₂-C₆₀ heteroarylalkyl group,
xc11 and xc12 may each independently be an integer from 0 to 10,
* and *′ in Formula 402 each indicates a binding site to M in Formula 401, and
any one of ring A₄₀₁ or ring A₄₀₂ may include an imidazole moiety. In one or more embodiments, in Formula 401, if (e.g., when) xc1 is 2 or more, two ring A₄₀₁(s) in two or more of L₄₀₁(s) may be optionally linked to each other via T₄₀₂, which is a linking group, and/or two ring A₄₀₂(s) may be optionally linked to each other via T₄₀₃, which is a linking group. T₄₀₂ and T₄₀₃ may each independently be the same as described herein with respect to T₄₀₁.

According to one or more embodiments, the second dopant may include a compound represented by Formula 2:

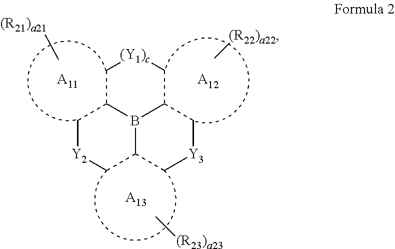

wherein, in Formula 2, Y₁ to Y₃ may each independently be S, N(R₂₄), B(R₂₄), C(R₂₄)(R₂₅), or Si(R₂₄)(R₂₅),
c may be 0 or 1,
A₁₁ to A₁₃ may each independently be selected from among a C₅-C₃₀ carbocyclic group and a C₁-C₃₀ heterocyclic group,
R₂₁ and R₂₅ may each independently be hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₁₀ cycloalkyl group unsubstituted or substituted with at least one R₁₀ₐ, a C₁-C₁₀ heterocycloalkyl group unsubstituted or substituted with at least one R₁₀ₐ, a C₃-C₁₀ cycloalkenyl group unsubstituted or substituted with at least one R₁₀ₐ, a C₁-C₁₀ heterocycloalkenyl group unsubstituted or substituted with at least one R₁₀ₐ, a C₆-C₆₀ aryl group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₁-C₆₀ heteroaryl group unsubstituted or substituted with at least one R₁₀ₐ, a monovalent non-aromatic condensed polycyclic group unsubstituted or substituted with at least one R₁₀ₐ, a monovalent non-aromatic condensed heteropolycyclic group unsubstituted or substituted with at least one R₁₀ₐ, —Si(Q₁)(Q₂)(Q₃), —N(Q₁)(Q₂), —B(Q₁)(Q₂), —P(Q₁)(Q₂), —C(═O)(Q₁), —S(═O)₂(Q₁), and —P(═O)(Q₁)(Q₂),
R₂₁ to R₂₅ may optionally independently be linked to each other to form a substituted or unsubstituted C₅-C₃₀ carbocyclic group and a substituted or unsubstituted C₁-C₃₀ heterocyclic group,
a21 to a23 may each independently be an integer from 0 to 10,
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₅-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₅-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group unsubstituted or substituted with deuterium, —F, a cyano group, a C₁-C₆₀ alkyl group, a C₁-C₆₀ alkoxy group, a phenyl group, a biphenyl group, or any combination thereof; a C₁-C₆₀ heterocyclic group; a C₇-C₆₀ arylalkyl group; or a C₂-C₆₀ heteroarylalkyl group.

According to one or more embodiments, the emission layer may be a fluorescent emission layer.

According to one or more embodiments, the emission layer may be a blue emission layer.

According to one or more embodiments, the emission layer may include m emission layers,
the interlayer may further include m−1 charge generation layers each respectively arranged between two adjacent emission layers among the m emission layers, for example, for each two adjacent emission layers, a charge generation layer is arranged therebetween, and
m may be an integer of 2 or more.

Referring to FIG. 2, the interlayer 130 may include m emission layers 145(1), . . . , up to 145(m), and (m−1) charge generation layers, for example, up to 144(m−1), each arranged between the adjacent emission layers.

For example, in one or more embodiments, if (e.g., when) m is 2, a first electrode, a first emission layer, a first charge generation layer, and a second emission layer may be sequentially arranged in the stated order. In these embodiments, the first emission layer may be to emit a first color light, the second emission layer may be to emit a second color light, and the maximum emission wavelength of the first color light and the maximum emission wavelength of the second color light may be substantially identical to or different from each other.

In one or more embodiments, if (e.g., when) m is 3, a first electrode, a first emission layer, a first charge generation layer, a second emission layer, a second charge generation layer, and a third emission layer may be sequentially arranged in the stated order. In these embodiments, the first emission layer may be to emit a first color light, the second emission layer may be to emit a second color light, the third emission layer may be to emit a third color light, and the maximum emission wavelengths of the first color light, the second color light, and the third color light may be substantially identical to or different from one another.

In one or more embodiments, if (e.g., when) m is 4, a first electrode, a first emission layer, a first charge generation layer, a second emission layer, a second charge generation layer, a third emission layer, a third charge generation layer, and a fourth emission layer may be sequentially arranged in the stated order. In these embodiments, the first emission layer may be to emit a first color light, the second emission layer may be to emit a second color light, the third emission layer may be to emit a third color light, the fourth emission layer may be to emit a fourth color light, and the maximum emission wavelengths of the first color light, the second color light, the third color light, and the fourth color light may be substantially identical to or different from one another.

The same applies if (e.g., when) m is 5 to 7.

According to one or more embodiments, the interlayer may include a red emission layer, a blue emission layer, and a green emission layer. For example, in one or more embodiments, the interlayer may include the red emission layer, the blue emission layer, and the green emission layer which are arranged in series, or in parallel on the same plane.

According to one or more embodiments, the first electrode may include a 1-1 pixel electrode, a 1-2 pixel electrode, and a 1-3 pixel electrode,
the light-emitting device may include
m first light-emitting units each including the 1-1 pixel electrode, a counter electrode opposite to (e.g., facing) the 1-1 pixel electrode, and an emission layer arranged between the 1-1 pixel electrode and the counter electrode, and m−1 charge generation layers each respectively arranged between two adjacent first light-emitting units among the m first light-emitting units, for example, for each two adjacent first light-emitting units, a charge generation layer is arranged therebetween,
m second light-emitting units each including the 1-2 pixel electrode, the counter electrode opposite to (e.g., facing) the 1-2 pixel electrode, and an emission layer arranged between the 1-2 pixel electrode and the counter electrode, and m−1 charge generation layers each respectively arranged between two adjacent second light-emitting units among the m second light-emitting units, for example, for each two adjacent second light-emitting units, a charge generation layer is arranged therebetween, and
m third light-emitting units each including the 1-3 pixel electrode, the counter electrode opposite to (e.g., facing) the 1-3 pixel electrode, and an emission layer arranged between the 1-3 pixel electrode and the counter electrode, and m−1 charge generation layers each respectively arranged between two adjacent third light-emitting units among the m third light-emitting units, for example, for each two adjacent third light-emitting units, a charge generation layer is arranged therebetween,
wherein m may be an integer of 2 or more,
the m first light-emitting units may each be to emit a first color light, the m second light-emitting units may each be to emit a second color light, and the m third light-emitting units may each be to emit a third color light, wherein and the first to third color lights may have different colors, and
the m−1 charge generation layers and the counter electrode may be formed in common.

According to one or more embodiments, any light-emitting unit selected from among the m first light-emitting units, any light-emitting unit selected from among the m second light-emitting units, or any light-emitting unit selected from among the m third light-emitting units may further include a hole transport region and/or an electron transport region.

According to one or more embodiments, the electron transport region may include an electron transport layer, and the electron transport layer may include the compound represented by Formula 1.

FIG. 3 shows a light-emitting device according to one or more embodiments in which m=2 in FIG. 2, and a red emission layer, a blue emission layer, and a green emission layer are arranged in parallel on the same plane.

Referring to FIG. 3, according to one or more embodiments, the light-emitting device may include
a first light-emitting unit 1 including a 1-1 pixel electrode, a cathode opposite to (e.g., facing) the 1-1 pixel electrode, and a red emission layer 1 (Red EML (1)) arranged between the 1-1 pixel electrode and the cathode, a first light-emitting unit 2 including a red emission layer 2 (Red EML (2)), and a charge generation layer arranged between the two first light-emitting units (e.g., between the first light-emitting unit 1 and the first light-emitting unit 2),
a second light-emitting unit 1 including a 1-2 pixel electrode, a cathode opposite to (e.g., facing) the 1-2 pixel electrode, and a green emission layer 1 (Green EML (1)) arranged between the 1-2 pixel electrode and the cathode, a second light-emitting unit 2 including a green emission layer 2 (Green EML (2)), and a charge generation layer arranged between the two second light-emitting units (e.g., between the second light-emitting unit 1 and the second light-emitting unit 2), and
a third light-emitting unit 1 including a 1-3 pixel electrode, a cathode opposite to (e.g., facing) the 1-3 pixel electrode, and a blue emission layer 1 (Blue EML (1)) arranged between the 1-3 pixel electrode and the cathode, a third light-emitting unit 2 including a blue emission layer 2 (Blue EML (2)), and a charge generation layer arranged between the two third light-emitting units (e.g., between the third light-emitting unit 1 and the third light-emitting unit 2) (the charge generation layer may include an n-charge generation layer (n-CGL) and a p-charge generation layer (p-CGL)).

The two first light-emitting units may be to emit a red light as the first color light, the two second light-emitting units may be to emit a green light as the second color light, and the two third light-emitting units may be to emit a blue light as the third color light.

The descriptions of a capping layer (CPL), a cathode, an electron transport layer (ETL), and a hole transport layer (HTL) in FIG. 3 may be referred to the descriptions of a capping layer, a second electrode 170, an electron transport layer (ETL), and a hole transport layer (HTL) herein, respectively.

According to one or more embodiments, provided is an electronic apparatus including the light-emitting device as described above. The electronic apparatus may further include a thin-film transistor. For example, in one or more embodiments, the electronic apparatus may further include a thin-film transistor including a source electrode and a drain electrode, wherein the first electrode of the light-emitting device may be electrically connected to the source electrode or the drain electrode of the thin-film transistor.

In one or more embodiments, the electronic apparatus may further include a color filter, a color conversion layer, a touch screen layer, a polarizing layer, or any combination thereof. More details on the electronic apparatus may be the same as described herein.

The term “interlayer” as used herein refers to a single layer and/or all of multiple layers arranged between the first electrode and the second electrode of the light-emitting device.

According to one or more embodiments, provided is a compound represented by Formula 1:

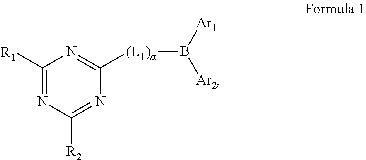

wherein, in Formula 1,
R₁ and R₂ may each independently be a C₁-C₆₀ alkyl group unsubstituted or substituted with at least one R₁₀ₐ, a C₅-C₁₀ cycloalkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₁-C₆₀ alkylthio group unsubstituted or substituted with at least one R₁₀ₐ, a C₆-C₆₀ aryl group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₁-C₆₀ heteroaryl group unsubstituted or substituted with at least one R₁₀ₐ, a C₈-C₆₀ non-aromatic condensed polycyclic group unsubstituted or substituted with at least one R₁₀ₐ, a C₁-C₆₀ non-aromatic condensed heteropolycyclic group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
in one or more embodiments, R₁ and/or R₂ may be a C₁-C₆₀ alkyl group unsubstituted or substituted with at least one R₁₀ₐ or a C₃-C₁₀ cycloalkyl group unsubstituted or substituted with at least one R₁₀ₐ,
provided that an adamantyl group is excluded from the cycloalkyl group (i.e., the C₃-C₁₀ cycloalkyl group),
Ar₁ and Ar₂ may each independently be hydrogen, deuterium, —F, —Cl, —Br, —I, a hydroxyl group, a cyano group, a nitro group, a C₆-C₆₀ aryl group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₁-C₆₀ heteroaryl group unsubstituted or substituted with at least one R₁₀ₐ, a C₈-C₆₀ non-aromatic condensed polycyclic group unsubstituted or substituted with at least one R₁₀ₐ, or a C₁-C₆₀ non-aromatic condensed heteropolycyclic group unsubstituted or substituted with at least one R₁₀ₐ,
a may be an integer from 1 to 5,
L₁ may be a C₃-C₃₀ carbocyclic group unsubstituted or substituted with at least one R₁₀ₐ or a C₁-C₃₀ heterocyclic group unsubstituted or substituted with at least one R₁₀ₐ,
provided that if (e.g., when) L₁ directly bonded to a triazine moiety is phenylene, the substitution position (e.g., the other substitution position) of the phenylene is not meta, for example, the substitution position of the phenylene bonded to another L₁ or the boron (B) is not meta with respect to the substitution position of the phenylene bonded to the triazine moiety,
if (e.g., when) a is 2 or more, each L₁ may be substantially identical to or different from the others,
in one or more embodiments, adjacent substituents among the substituents bonded to B may be linked to each other via a direct bond, —O—, —C(Q₁)(Q₂)-, —Si(Q₁)(Q₂)-, —N(Q₁)-, —C(═O)—, —S(═O)₂—, or —P(═O)—, to form a ring (i.e., optionally, in one or more embodiments, adjacent substituents bonded to B may be linked to each other via a direct bond, or through a bond by —O—, —C(Q₁)(Q₂)-, —Si(Q₁)(Q₂)-, —N(Q₁)-, —C(═O)—, —S(═O)₂—, or —P(═O)—, to form a ring),
R₁₀ₐ may be:
hydrogen, deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₅-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

According to one or more embodiments, in Formula 1, L₁ and Ar₁ may be linked to each other via a direct bond, —O—, —C(Q₁)(Q₂)-, —Si(Q₁)(Q₂)-, —N(Q₁)-, —C(═O)—, —S(═O)₂—, or —P(═O)—, to form a ring.

According to one or more embodiments, in Formula 1, L₁ and Ar₂ may be linked to each other via a direct bond, —O—, —C(Q₁)(Q₂)-, —Si(Q₁)(Q₂)-, —N(Q₁)-, —C(═O)—, —S(═O)₂—, or —P(═O)—, to form a ring.

According to one or more embodiments, in Formula 1, Ar₁ and Ar₂ may be linked to each other via a direct bond, —O—, —C(Q₁)(Q₂)-, —Si(Q₁)(Q₂)-, —N(Q₁)-, —C(═O)—, —S(═O)₂—, or —P(═O)—, to form a ring.

For example, in one or more embodiments, in Formula 1, L₁ and Ar₁ may be linked to each other via —O—, and L₁ and Ar₂ may be linked to each other via —O—, to form a respective ring.

According to one or more embodiments, in Formula 1, if (e.g., when) L₁ directly bonded to the triazine moiety is phenylene, the substitution position of the phenylene may be para, for example, with respect to the substitution position of the phenylene bonded to another L₁ or the boron (B). For example, in one or more embodiments, in Formula 1, if (e.g., when) L₁ directly bonded to the triazine moiety is phenylene, the substitution position of the phenylene may not be ortho, for example, with respect to the substitution position of the phenylene bonded to another L₁ or the boron (B).

According to one or more embodiments, in Formula 1, R₁ and/or R₂ may be a C₁-C₂₀ alkyl group, a cyclopentyl group, a cyclohexyl group, a cycloheptyl group, a cyclooctyl group, or a norbornyl group.

According to one or more embodiments, in Formula 1, if (e.g., when) a is 2 or more, L₁ directly bonded to the boron atom may be phenylene.

According to one or more embodiments, the compound represented by Formula 1 may be any one of (e.g., selected from among) Compounds 1 to 262:

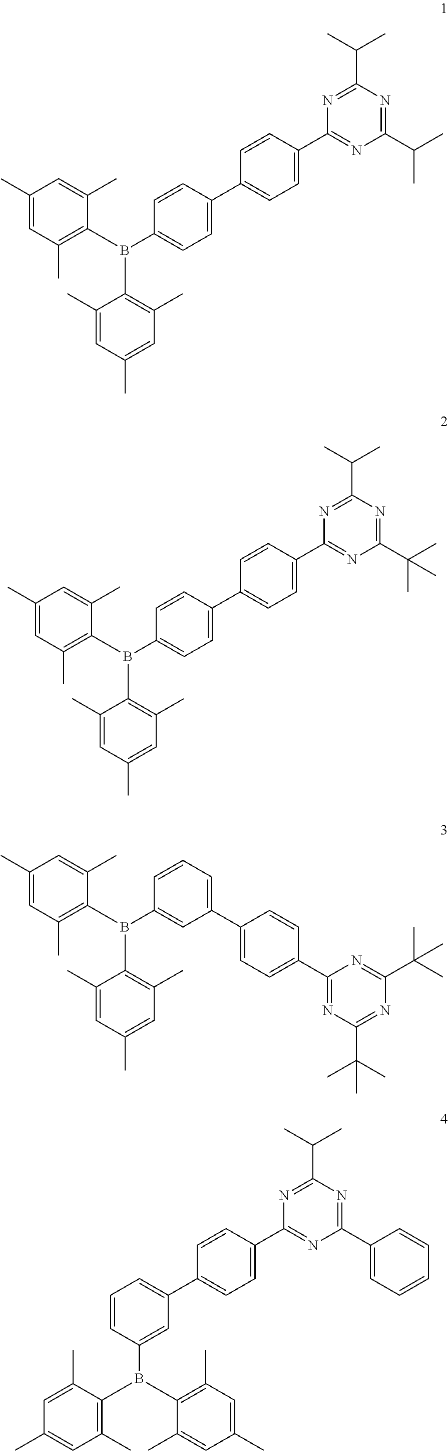

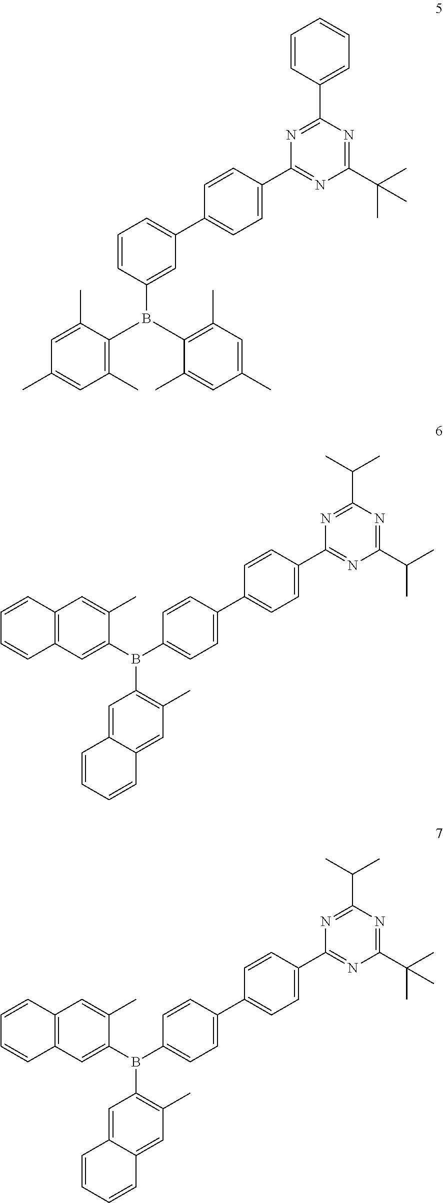 [SMILES: Cc1cc(C)c(B(c2cccc(-c3ccc(-c4nc(-c5ccccc5)nc(C(C)(C)C)n4)cc3)c2)c2c(C)cc(C)cc2C)c(C)c1 ; Cc1cc2ccccc2cc1B(c1ccc(-c2ccc(-c3nc(C(C)C)nc(C(C)C)n3)cc2)cc1)c1cc2ccccc2cc1C ; Cc1cc2ccccc2cc1B(c1ccc(-c2ccc(-c3nc(C(C)C)nc(C(C)(C)C)n3)cc2)cc1)c1cc2ccccc2cc1C]

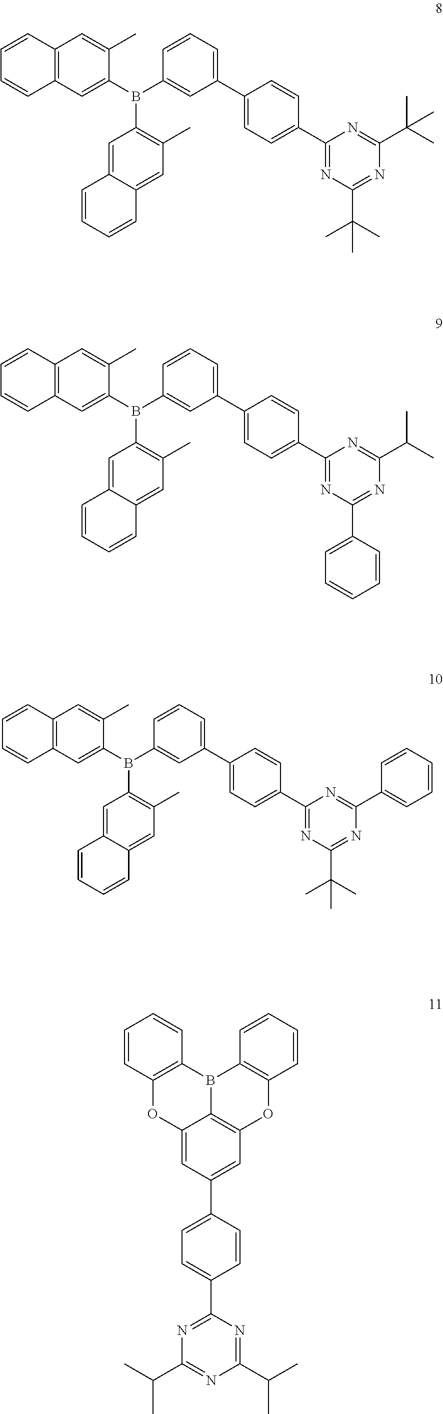

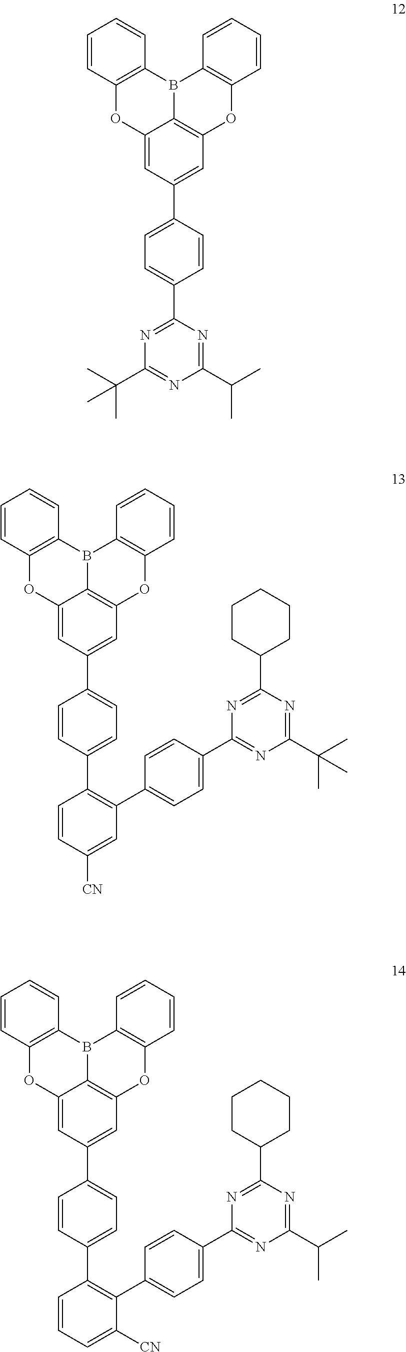 [SMILES: CC(C)c1nc(-c2ccc(-c3cc4c5c(c3)Oc3ccccc3B5c3ccccc3O4)cc2)nc(C(C)(C)C)n1 ; CC(C)(C)c1nc(-c2ccc(-c3cc(C#N)ccc3-c3ccc(-c4cc5c6c(c4)Oc4ccccc4B6c4ccccc4O5)cc3)cc2)nc(C2CCCCC2)n1 ; CC(C)c1nc(-c2ccc(-c3c(C#N)cccc3-c3ccc(-c4cc5c6c(c4)Oc4ccccc4B6c4ccccc4O5)cc3)cc2)nc(C2CCCCC2)n1]

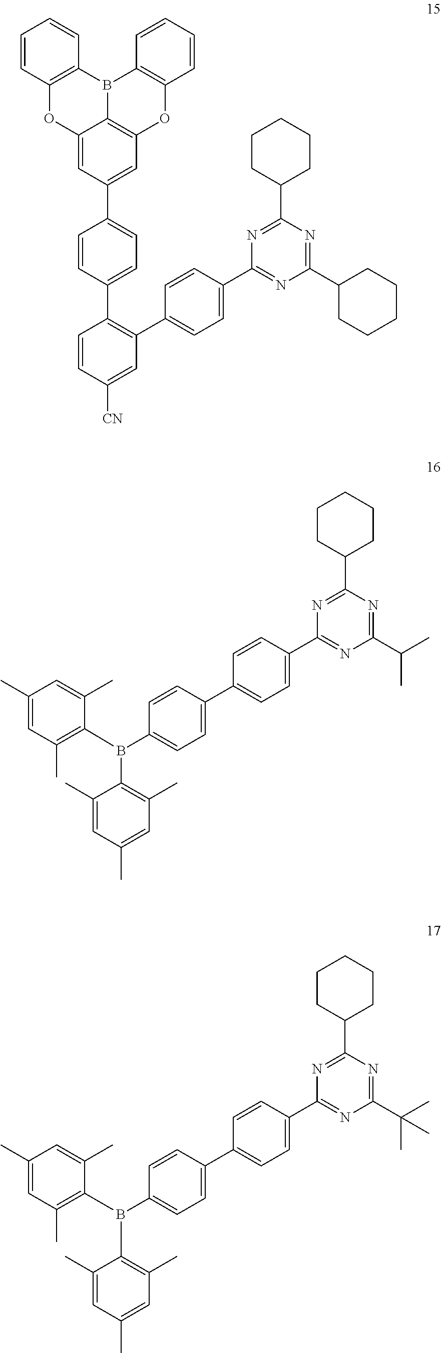

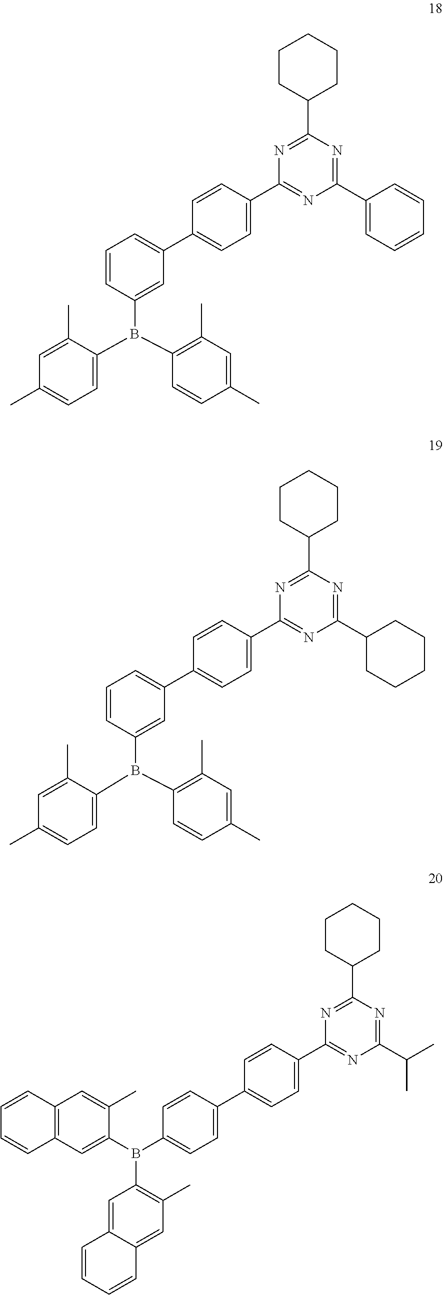 [SMILES: Cc1ccc(B(c2cccc(-c3ccc(-c4nc(-c5ccccc5)nc(C5CCCCC5)n4)cc3)c2)c2ccc(C)cc2C)c(C)c1 ; Cc1ccc(B(c2cccc(-c3ccc(-c4nc(C5CCCCC5)nc(C5CCCCC5)n4)cc3)c2)c2ccc(C)cc2C)c(C)c1 ; Cc1cc2ccccc2cc1B(c1ccc(-c2ccc(-c3nc(C(C)C)nc(C4CCCCC4)n3)cc2)cc1)c1cc2ccccc2cc1C]

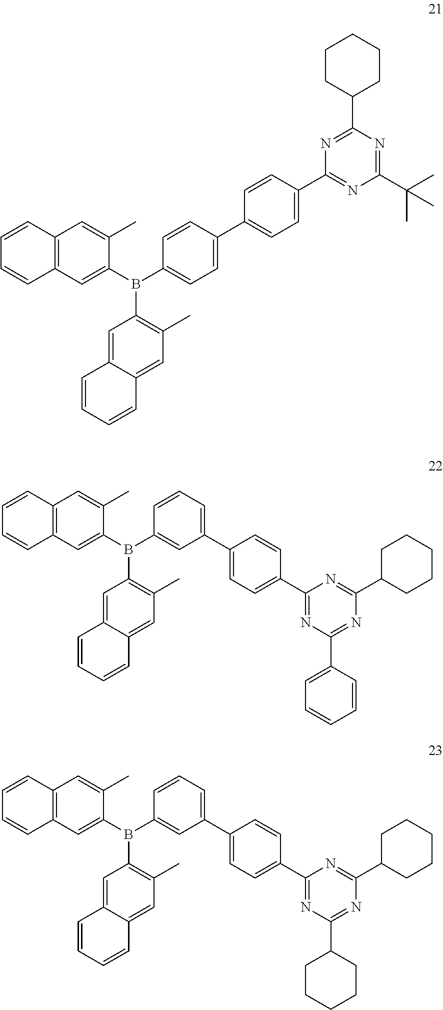 [SMILES: Cc1cc2ccccc2cc1B(c1ccc(-c2ccc(-c3nc(C4CCCCC4)nc(C(C)(C)C)n3)cc2)cc1)c1cc2ccccc2cc1C ; Cc1cc2ccccc2cc1B(c1cccc(-c2ccc(-c3nc(-c4ccccc4)nc(C4CCCCC4)n3)cc2)c1)c1cc2ccccc2cc1C ; Cc1cc2ccccc2cc1B(c1cccc(-c2ccc(-c3nc(C4CCCCC4)nc(C4CCCCC4)n3)cc2)c1)c1cc2ccccc2cc1C]

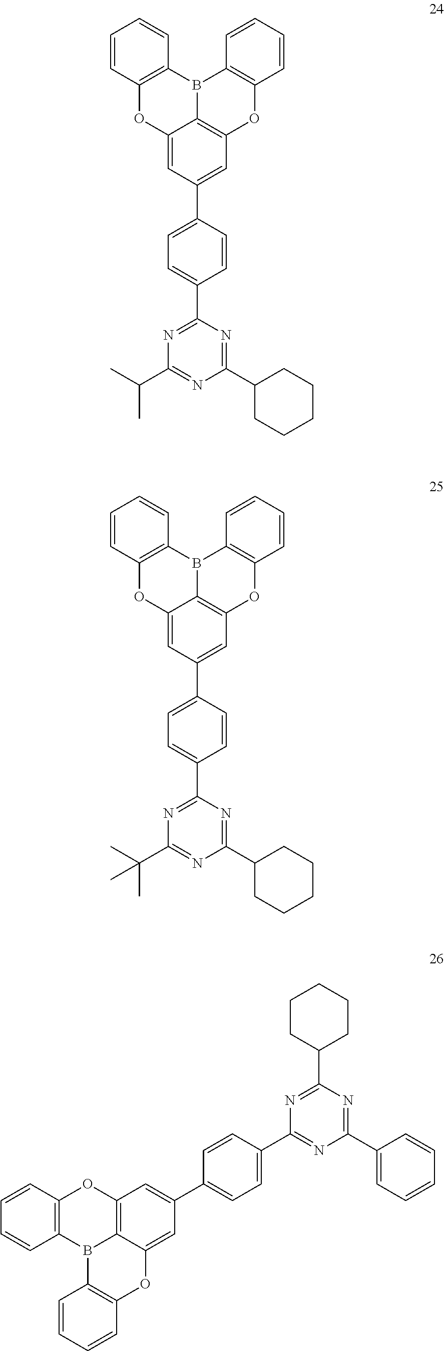 [SMILES: CC(C)c1nc(-c2ccc(-c3cc4c5c(c3)Oc3ccccc3B5c3ccccc3O4)cc2)nc(C2CCCCC2)n1 ; CC(C)(C)c1nc(-c2ccc(-c3cc4c5c(c3)Oc3ccccc3B5c3ccccc3O4)cc2)nc(C2CCCCC2)n1 ; c1ccc(-c2nc(-c3ccc(-c4cc5c6c(c4)Oc4ccccc4B6c4ccccc4O5)cc3)nc(C3CCCCC3)n2)cc1]

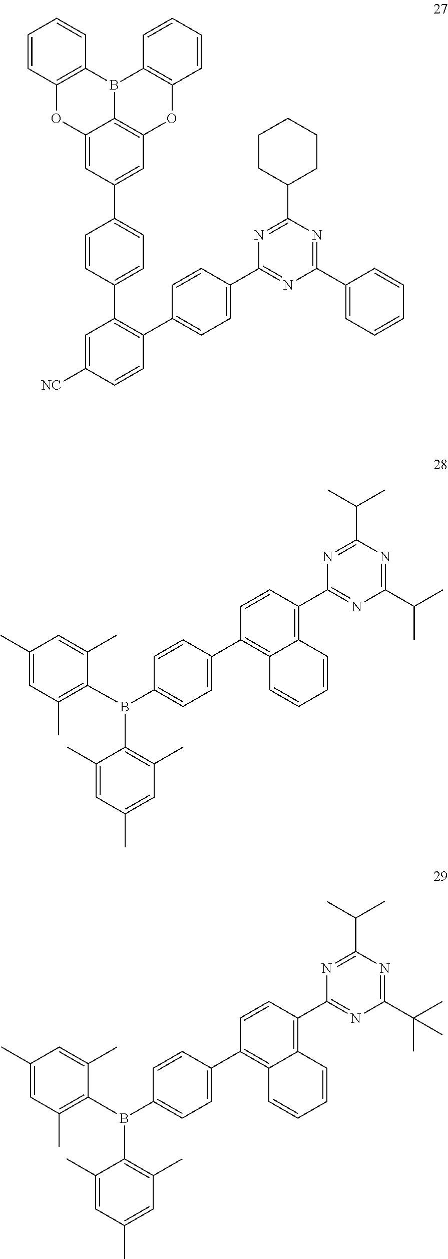

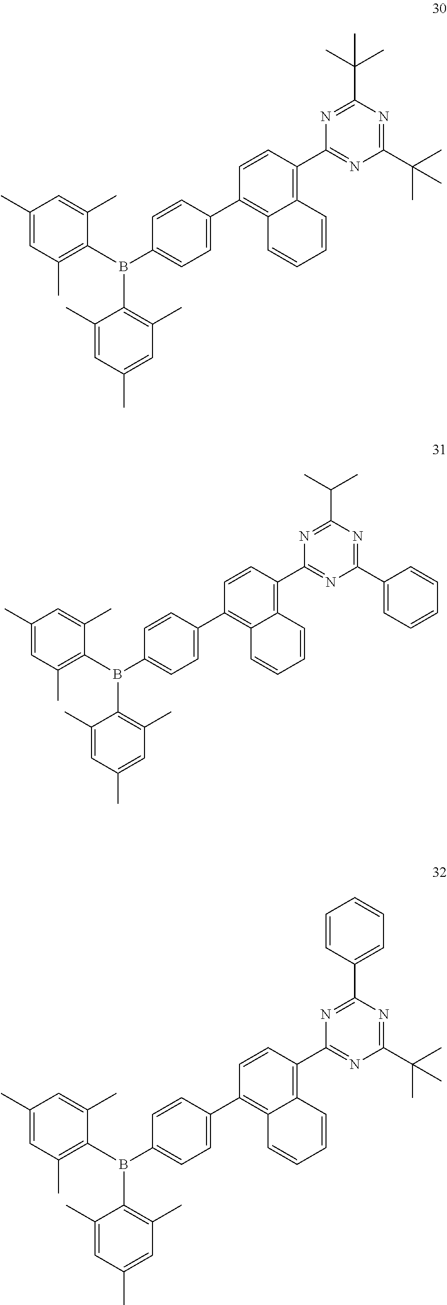

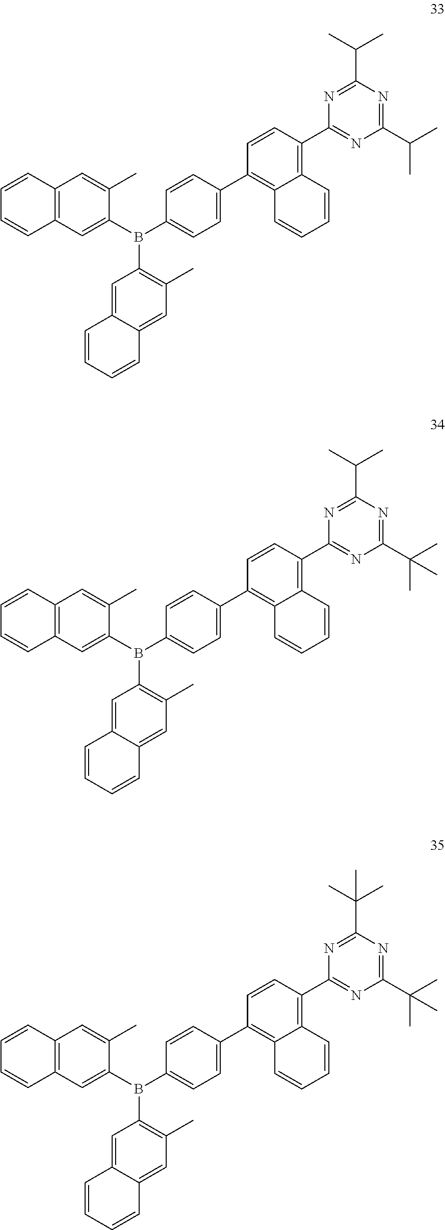 [SMILES: Cc1cc2ccccc2cc1B(c1ccc(-c2ccc(-c3nc(C(C)C)nc(C(C)C)n3)c3ccccc23)cc1)c1cc2ccccc2cc1C ; Cc1cc2ccccc2cc1B(c1ccc(-c2ccc(-c3nc(C(C)C)nc(C(C)(C)C)n3)c3ccccc23)cc1)c1cc2ccccc2cc1C ; Cc1cc2ccccc2cc1B(c1ccc(-c2ccc(-c3nc(C(C)(C)C)nc(C(C)(C)C)n3)c3ccccc23)cc1)c1cc2ccccc2cc1C]

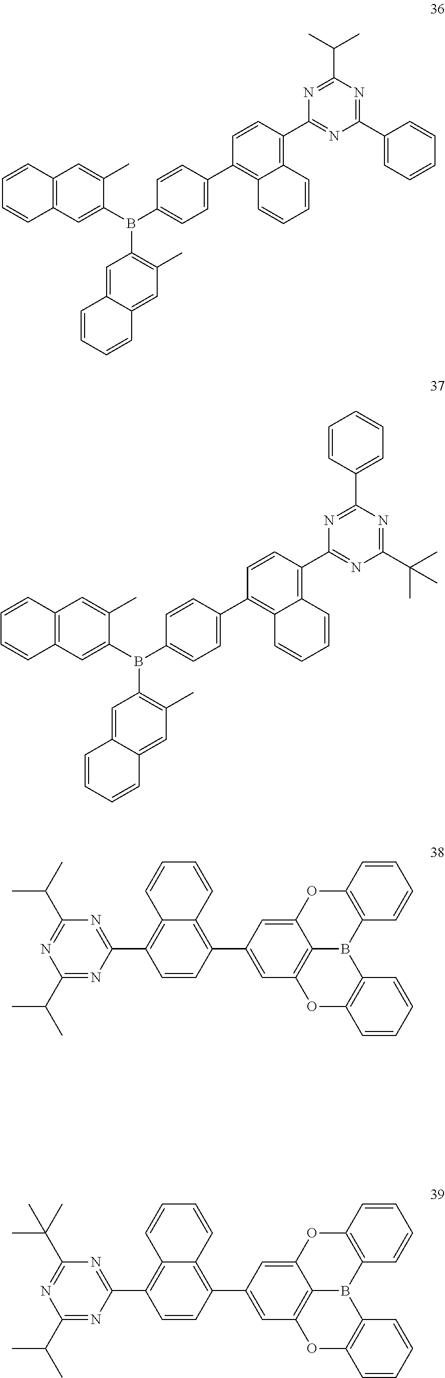

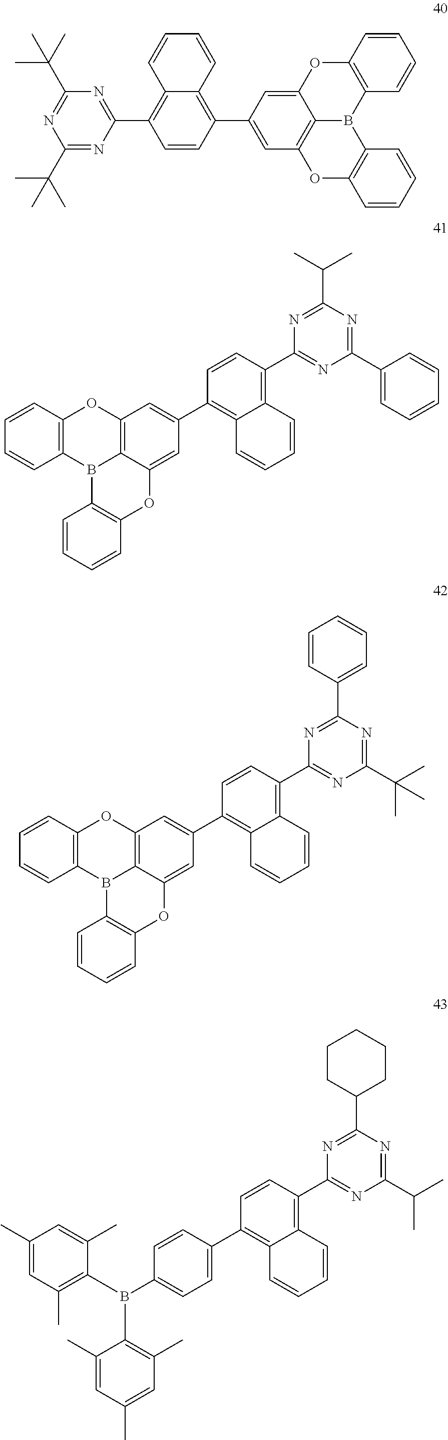

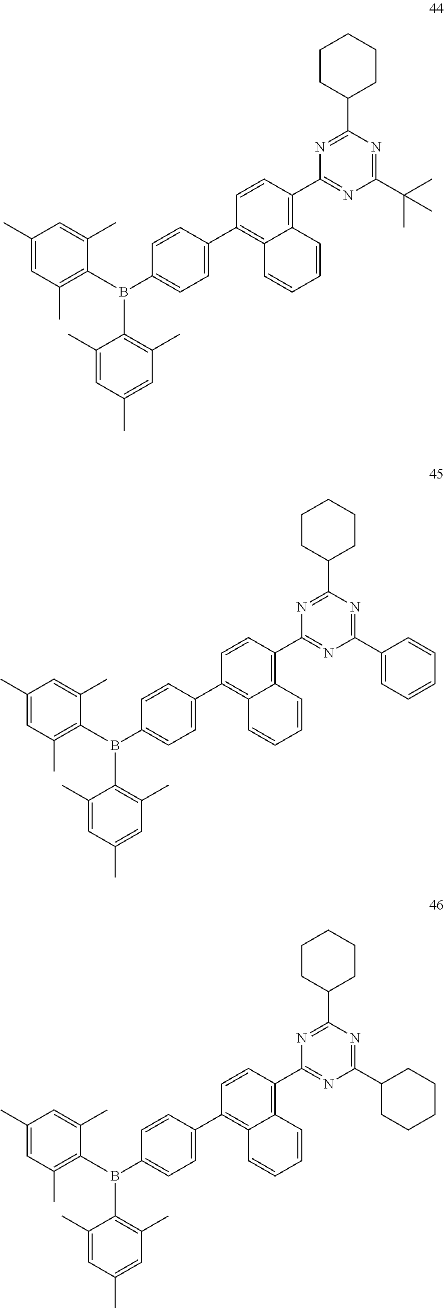

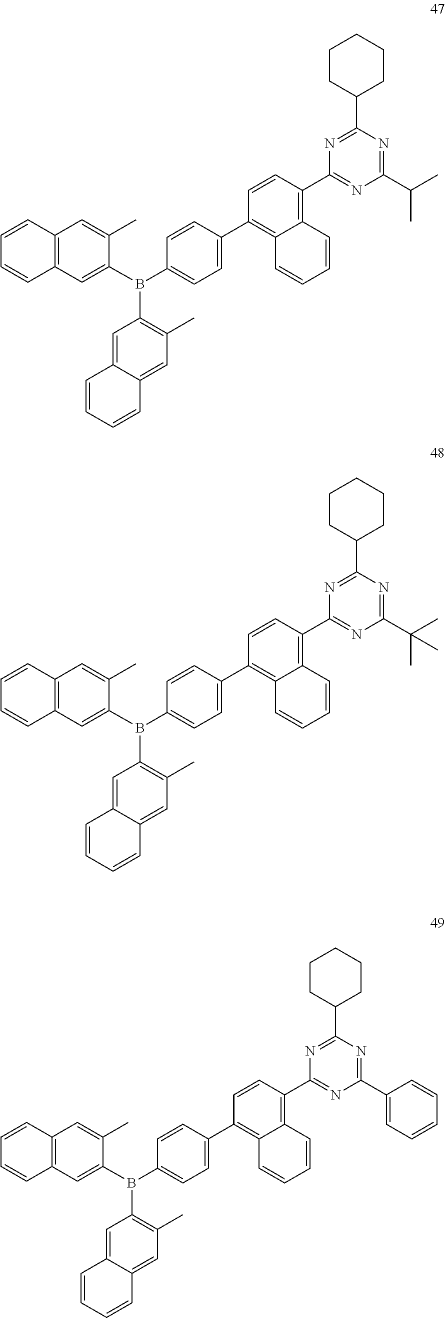 [SMILES: Cc1cc2ccccc2cc1B(c1ccc(-c2ccc(-c3nc(C(C)C)nc(C4CCCCC4)n3)c3ccccc23)cc1)c1cc2ccccc2cc1C ; Cc1cc2ccccc2cc1B(c1ccc(-c2ccc(-c3nc(C4CCCCC4)nc(C(C)(C)C)n3)c3ccccc23)cc1)c1cc2ccccc2cc1C ; Cc1cc2ccccc2cc1B(c1ccc(-c2ccc(-c3nc(-c4ccccc4)nc(C4CCCCC4)n3)c3ccccc23)cc1)c1cc2ccccc2cc1C]

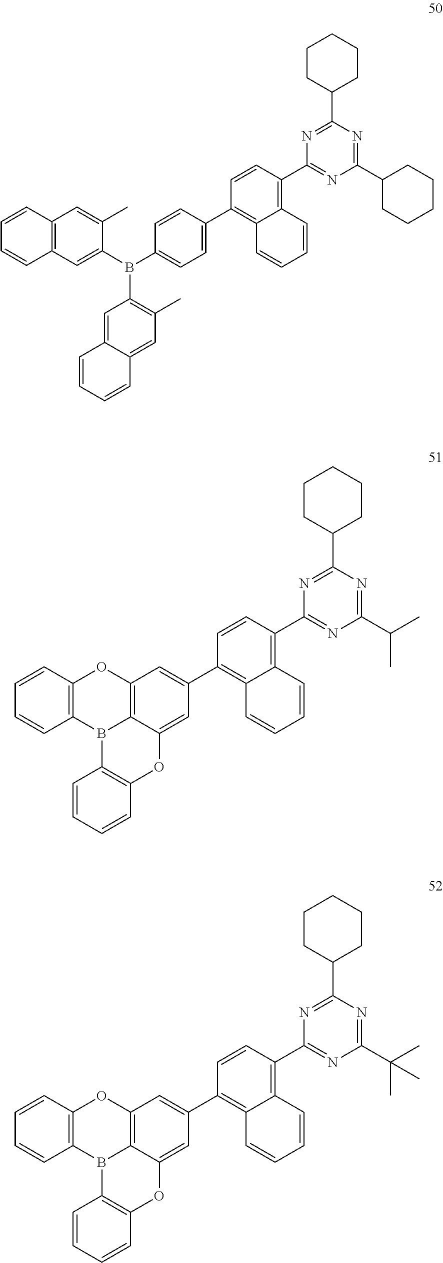 [SMILES: Cc1cc2ccccc2cc1B(c1ccc(-c2ccc(-c3nc(C4CCCCC4)nc(C4CCCCC4)n3)c3ccccc23)cc1)c1cc2ccccc2cc1C ; CC(C)c1nc(-c2ccc(-c3cc4c5c(c3)Oc3ccccc3B5c3ccccc3O4)c3ccccc23)nc(C2CCCCC2)n1 ; CC(C)(C)c1nc(-c2ccc(-c3cc4c5c(c3)Oc3ccccc3B5c3ccccc3O4)c3ccccc23)nc(C2CCCCC2)n1]

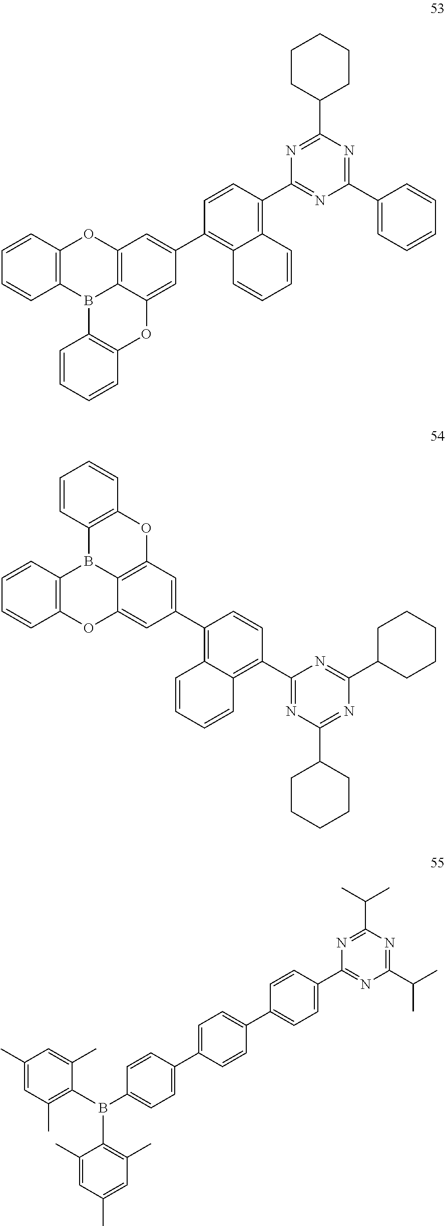 [SMILES: c1ccc(-c2nc(-c3ccc(-c4cc5c6c(c4)Oc4ccccc4B6c4ccccc4O5)c4ccccc34)nc(C3CCCCC3)n2)cc1 ; c1ccc2c(c1)Oc1cc(-c3ccc(-c4nc(C5CCCCC5)nc(C5CCCCC5)n4)c4ccccc34)cc3c1B2c1ccccc1O3 ; Cc1cc(C)c(B(c2ccc(-c3ccc(-c4ccc(-c5nc(C(C)C)nc(C(C)C)n5)cc4)cc3)cc2)c2c(C)cc(C)cc2C)c(C)c1]

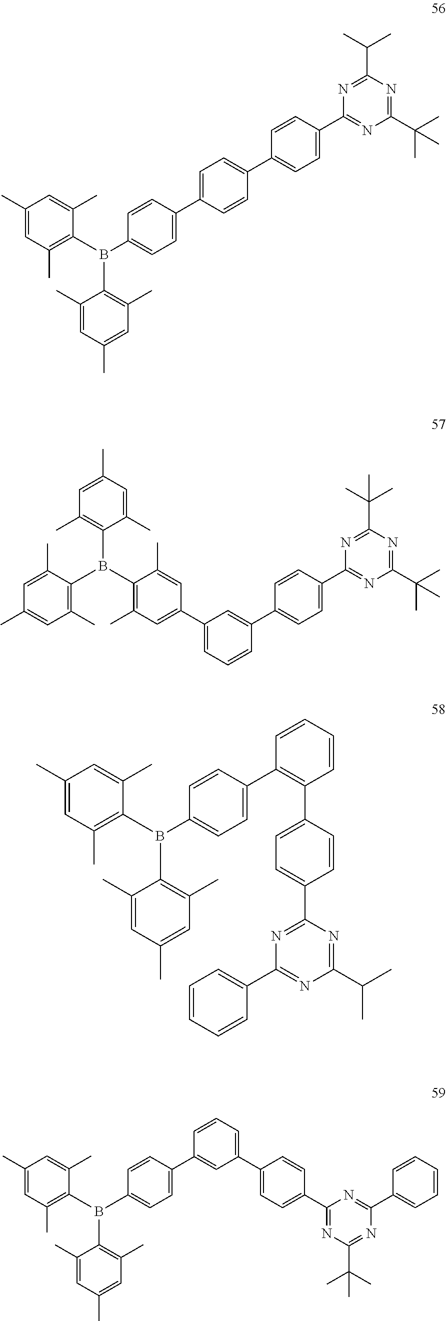

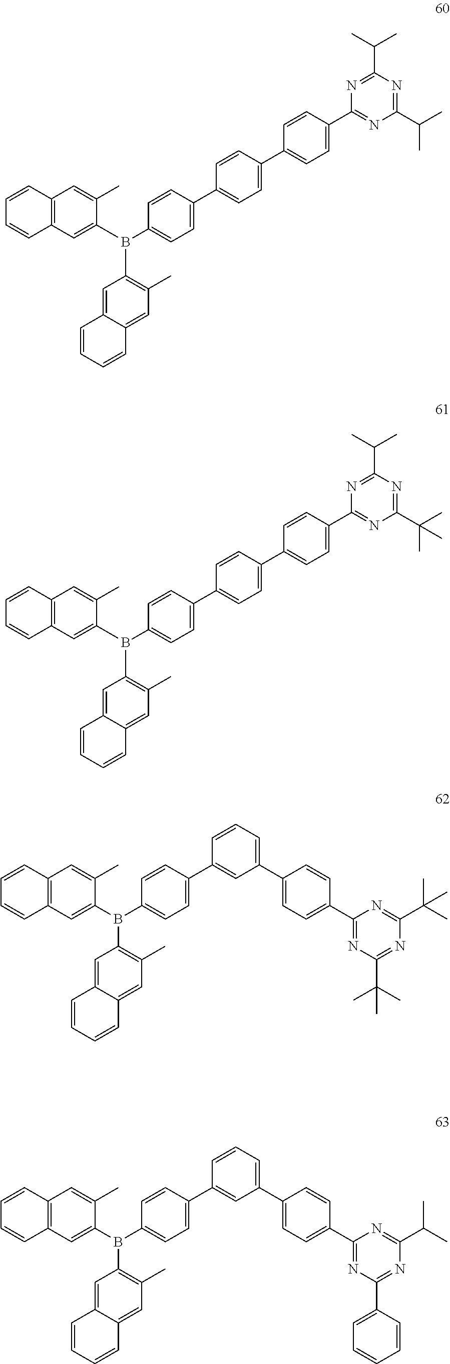 [SMILES: Cc1cc2ccccc2cc1B(c1ccc(-c2ccc(-c3ccc(-c4nc(C(C)C)nc(C(C)C)n4)cc3)cc2)cc1)c1cc2ccccc2cc1C ; Cc1cc2ccccc2cc1B(c1ccc(-c2ccc(-c3ccc(-c4nc(C(C)C)nc(C(C)(C)C)n4)cc3)cc2)cc1)c1cc2ccccc2cc1C ; Cc1cc2ccccc2cc1B(c1ccc(-c2cccc(-c3ccc(-c4nc(C(C)(C)C)nc(C(C)(C)C)n4)cc3)c2)cc1)c1cc2ccccc2cc1C ; Cc1cc2ccccc2cc1B(c1ccc(-c2cccc(-c3ccc(-c4nc(-c5ccccc5)nc(C(C)C)n4)cc3)c2)cc1)c1cc2ccccc2cc1C]

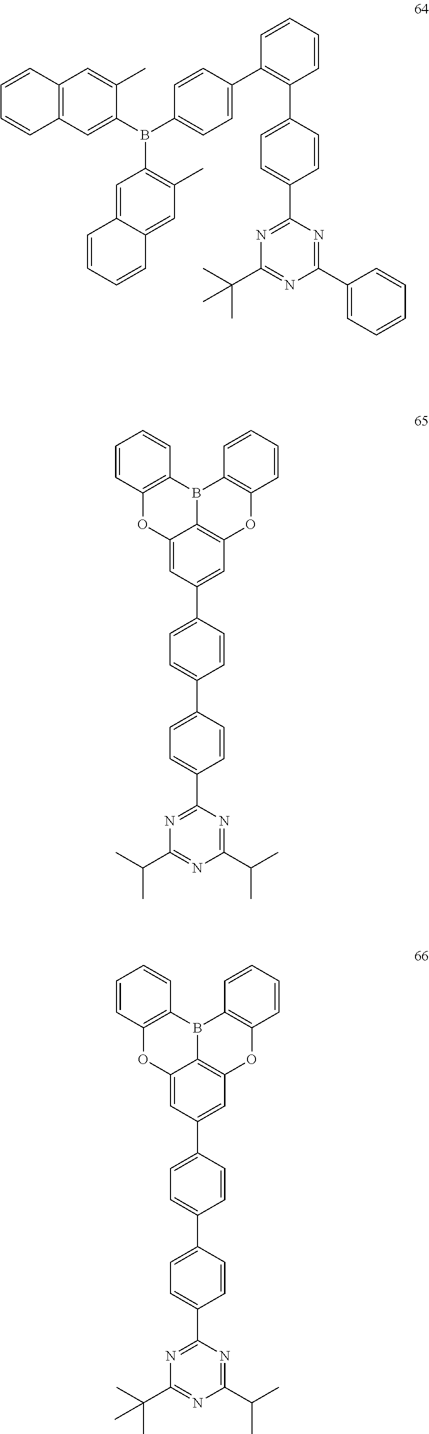 [SMILES: Cc1cc2ccccc2cc1B(c1ccc(-c2ccccc2-c2ccc(-c3nc(-c4ccccc4)nc(C(C)(C)C)n3)cc2)cc1)c1cc2ccccc2cc1C ; CC(C)c1nc(-c2ccc(-c3ccc(-c4cc5c6c(c4)Oc4ccccc4B6c4ccccc4O5)cc3)cc2)nc(C(C)C)n1 ; CC(C)c1nc(-c2ccc(-c3ccc(-c4cc5c6c(c4)Oc4ccccc4B6c4ccccc4O5)cc3)cc2)nc(C(C)(C)C)n1]

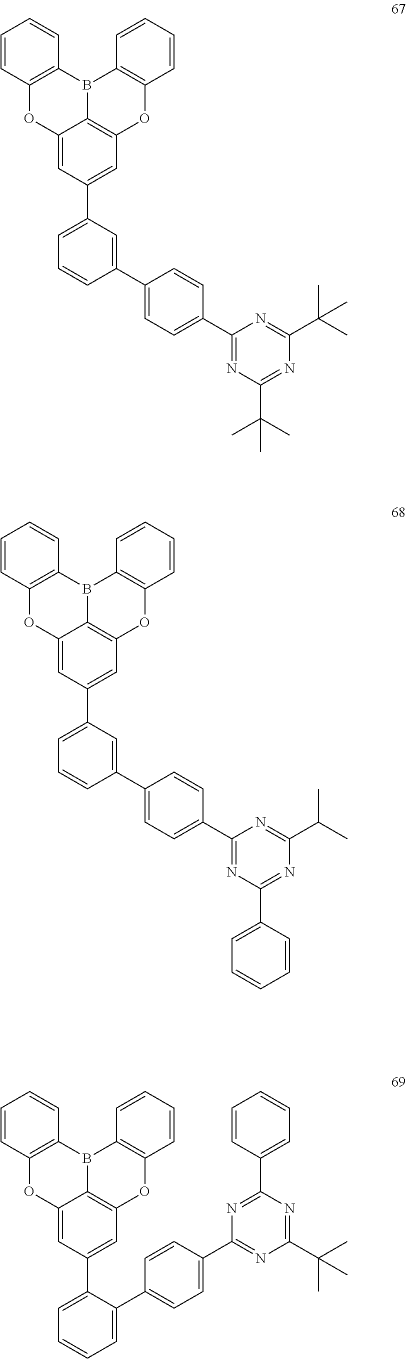 [SMILES: CC(C)(C)c1nc(-c2ccc(-c3cccc(-c4cc5c6c(c4)Oc4ccccc4B6c4ccccc4O5)c3)cc2)nc(C(C)(C)C)n1 ; CC(C)c1nc(-c2ccccc2)nc(-c2ccc(-c3cccc(-c4cc5c6c(c4)Oc4ccccc4B6c4ccccc4O5)c3)cc2)n1 ; CC(C)(C)c1nc(-c2ccccc2)nc(-c2ccc(-c3ccccc3-c3cc4c5c(c3)Oc3ccccc3B5c3ccccc3O4)cc2)n1]

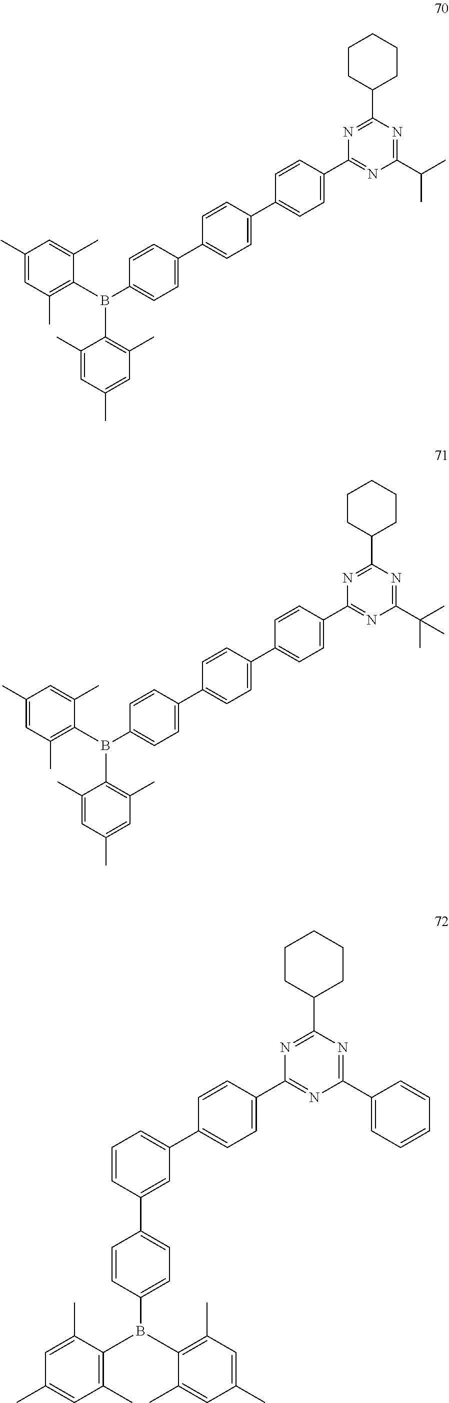

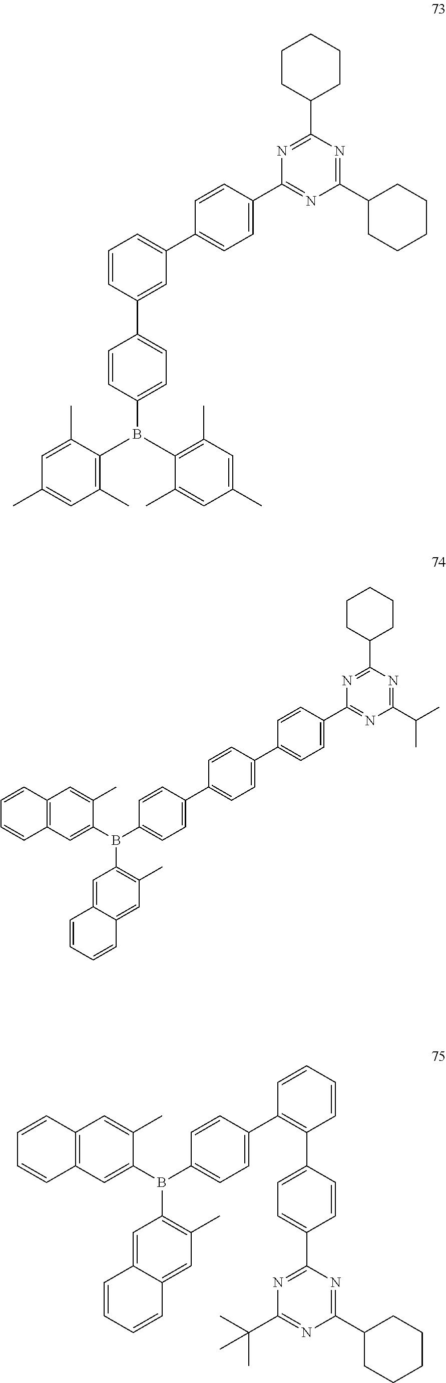 [SMILES: Cc1cc(C)c(B(c2ccc(-c3cccc(-c4ccc(-c5nc(C6CCCCC6)nc(C6CCCCC6)n5)cc4)c3)cc2)c2c(C)cc(C)cc2C)c(C)c1 ; Cc1cc2ccccc2cc1B(c1ccc(-c2ccc(-c3ccc(-c4nc(C(C)C)nc(C5CCCCC5)n4)cc3)cc2)cc1)c1cc2ccccc2cc1C ; Cc1cc2ccccc2cc1B(c1ccc(-c2ccccc2-c2ccc(-c3nc(C4CCCCC4)nc(C(C)(C)C)n3)cc2)cc1)c1cc2ccccc2cc1C]

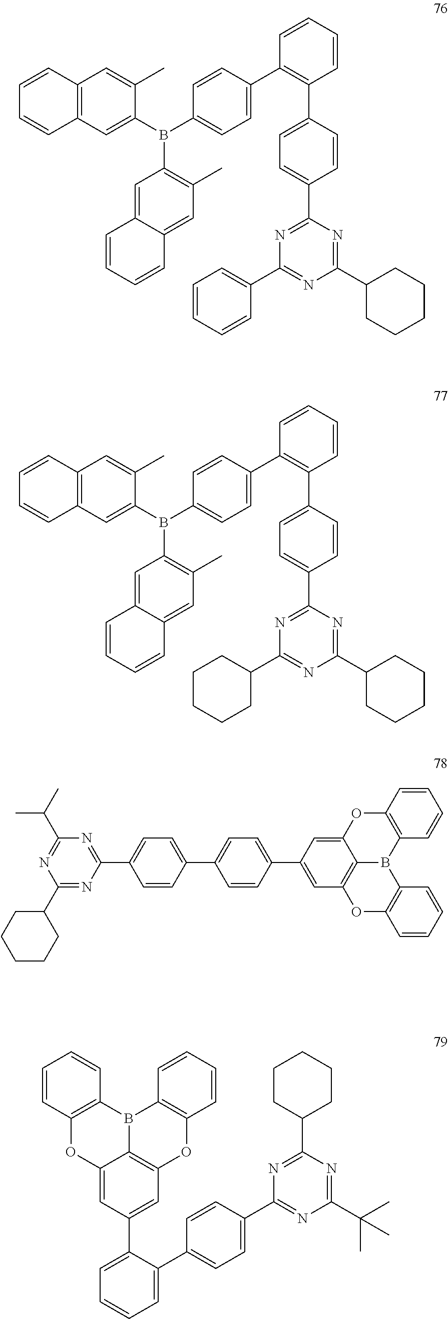 [SMILES: Cc1cc2ccccc2cc1B(c1ccc(-c2ccccc2-c2ccc(-c3nc(-c4ccccc4)nc(C4CCCCC4)n3)cc2)cc1)c1cc2ccccc2cc1C ; Cc1cc2ccccc2cc1B(c1ccc(-c2ccccc2-c2ccc(-c3nc(C4CCCCC4)nc(C4CCCCC4)n3)cc2)cc1)c1cc2ccccc2cc1C ; CC(C)c1nc(-c2ccc(-c3ccc(-c4cc5c6c(c4)Oc4ccccc4B6c4ccccc4O5)cc3)cc2)nc(C2CCCCC2)n1 ; CC(C)(C)c1nc(-c2ccc(-c3ccccc3-c3cc4c5c(c3)Oc3ccccc3B5c3ccccc3O4)cc2)nc(C2CCCCC2)n1]

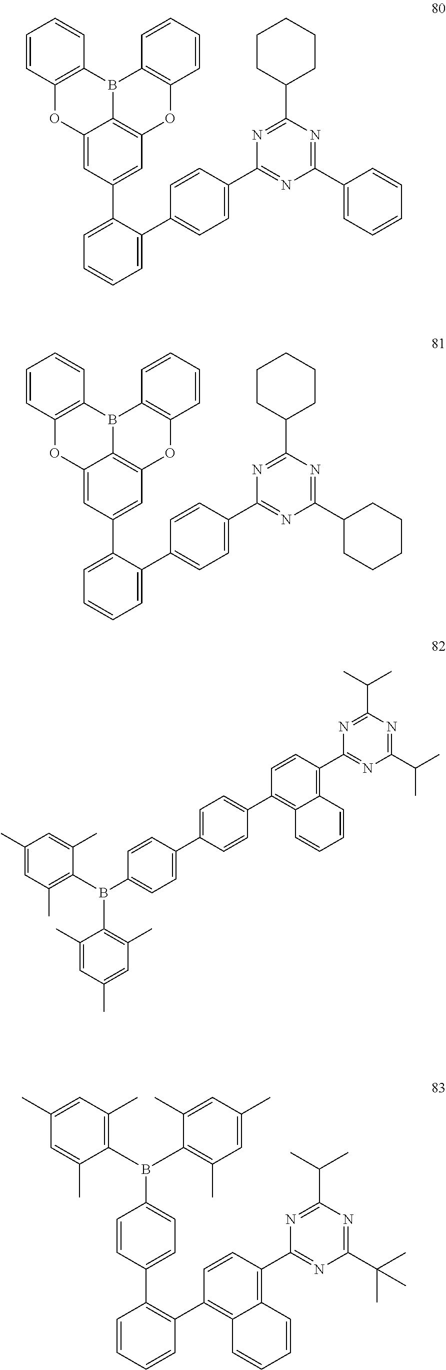

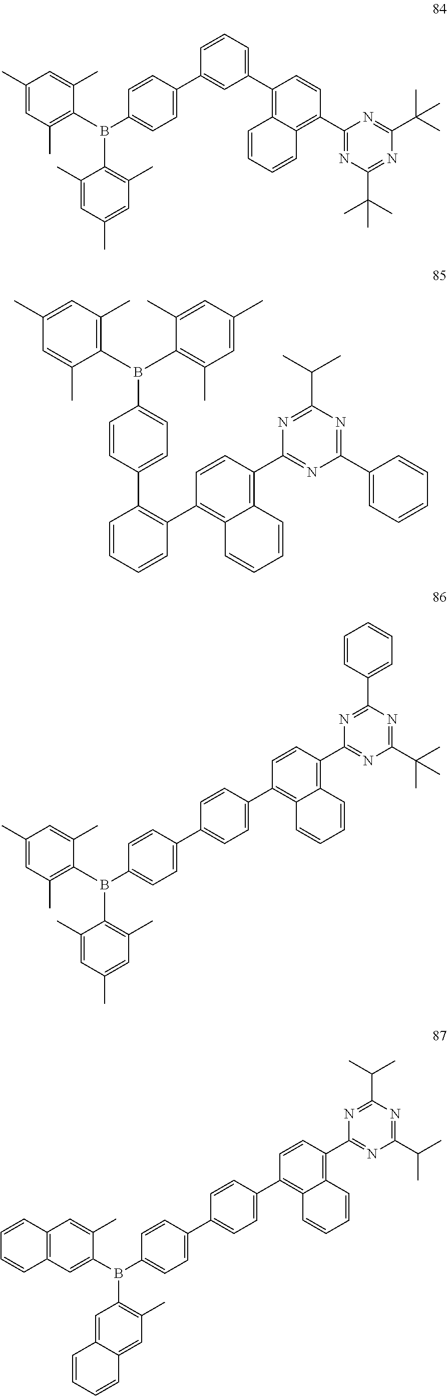

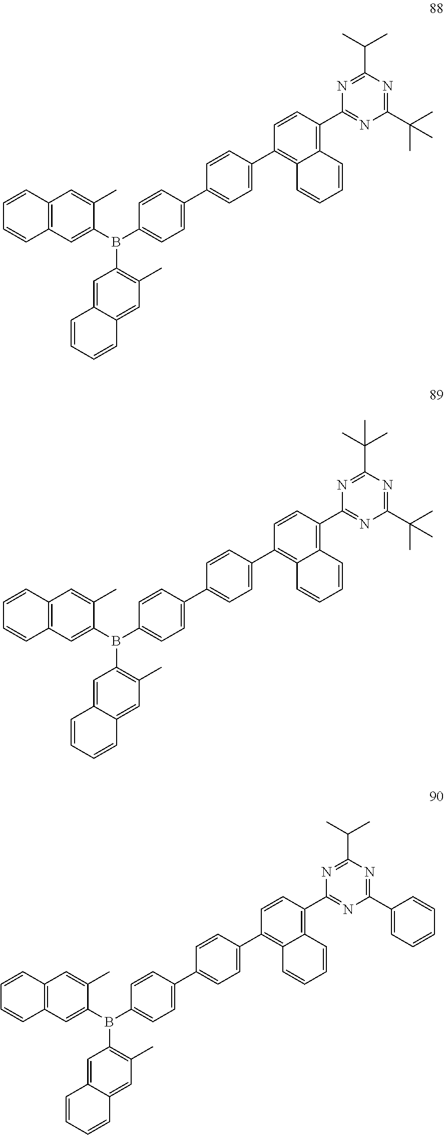 [SMILES: Cc1cc2ccccc2cc1B(c1ccc(-c2ccc(-c3ccc(-c4nc(C(C)C)nc(C(C)(C)C)n4)c4ccccc34)cc2)cc1)c1cc2ccccc2cc1C ; Cc1cc2ccccc2cc1B(c1ccc(-c2ccc(-c3ccc(-c4nc(C(C)(C)C)nc(C(C)(C)C)n4)c4ccccc34)cc2)cc1)c1cc2ccccc2cc1C ; Cc1cc2ccccc2cc1B(c1ccc(-c2ccc(-c3ccc(-c4nc(-c5ccccc5)nc(C(C)C)n4)c4ccccc34)cc2)cc1)c1cc2ccccc2cc1C]

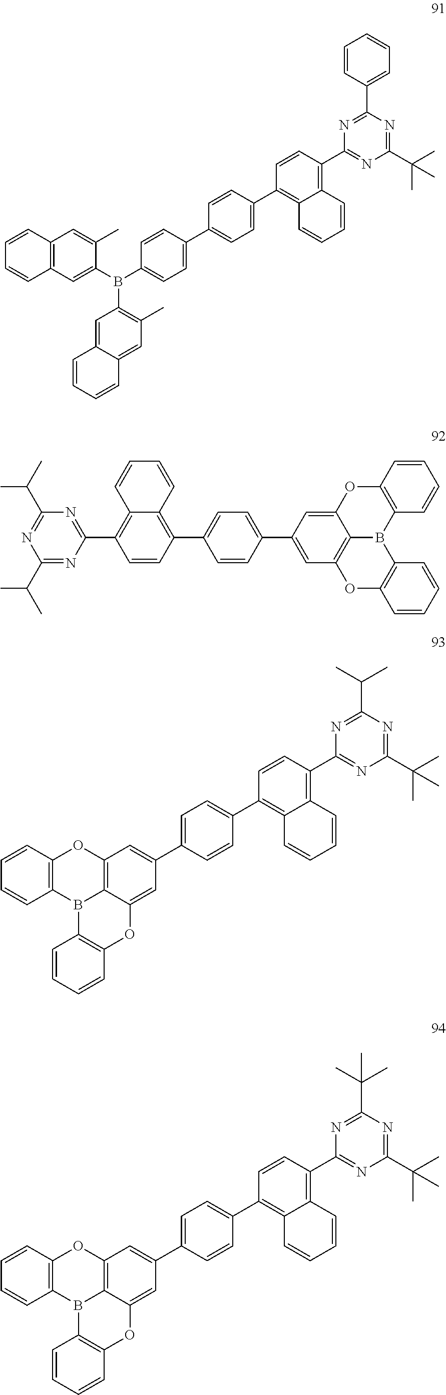

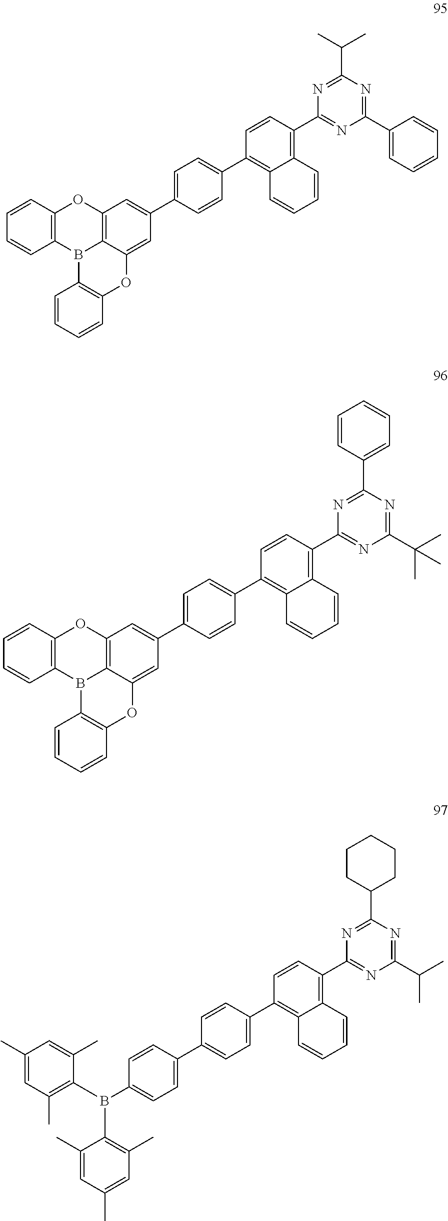

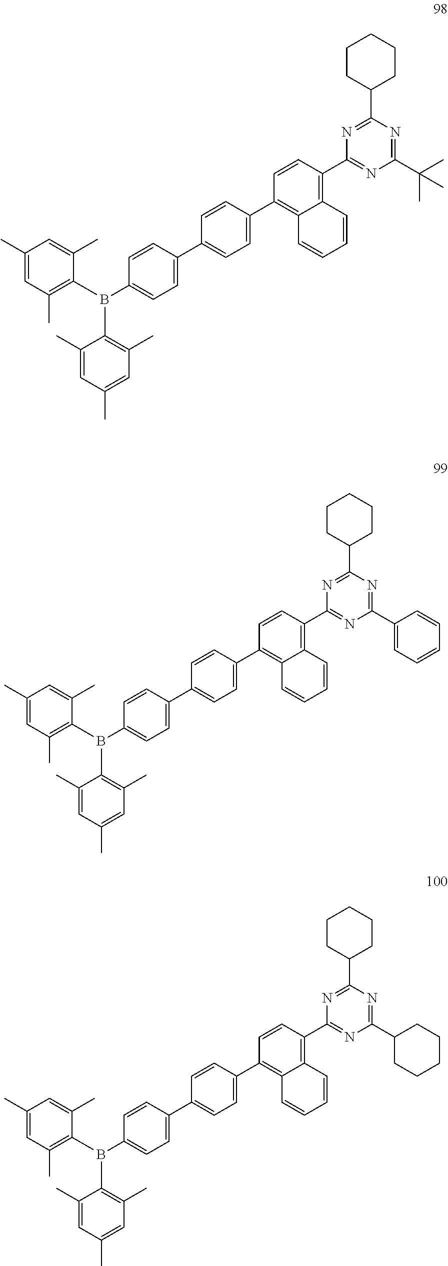

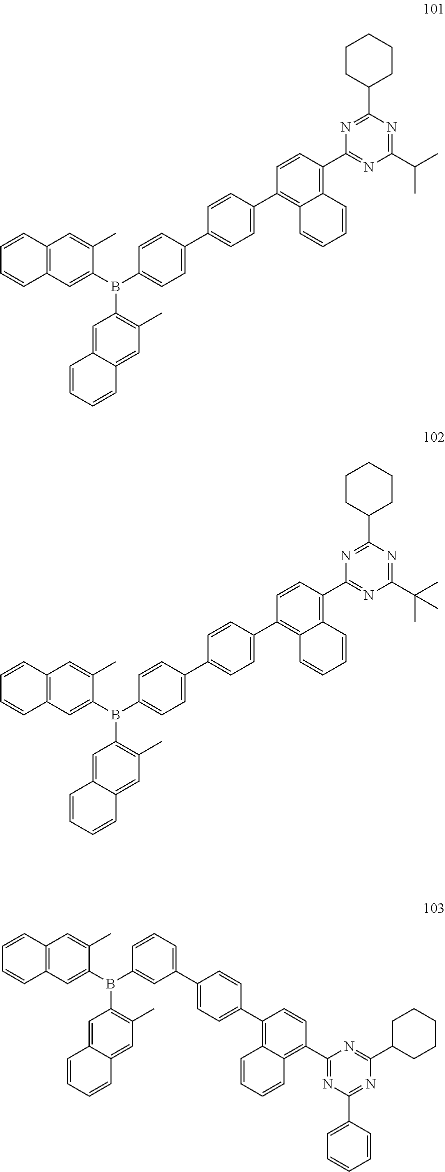 [SMILES: Cc1cc2ccccc2cc1B(c1ccc(-c2ccc(-c3ccc(-c4nc(C(C)C)nc(C5CCCCC5)n4)c4ccccc34)cc2)cc1)c1cc2ccccc2cc1C ; Cc1cc2ccccc2cc1B(c1ccc(-c2ccc(-c3ccc(-c4nc(C5CCCCC5)nc(C(C)(C)C)n4)c4ccccc34)cc2)cc1)c1cc2ccccc2cc1C ; Cc1cc2ccccc2cc1B(c1cccc(-c2ccc(-c3ccc(-c4nc(-c5ccccc5)nc(C5CCCCC5)n4)c4ccccc34)cc2)c1)c1cc2ccccc2cc1C]

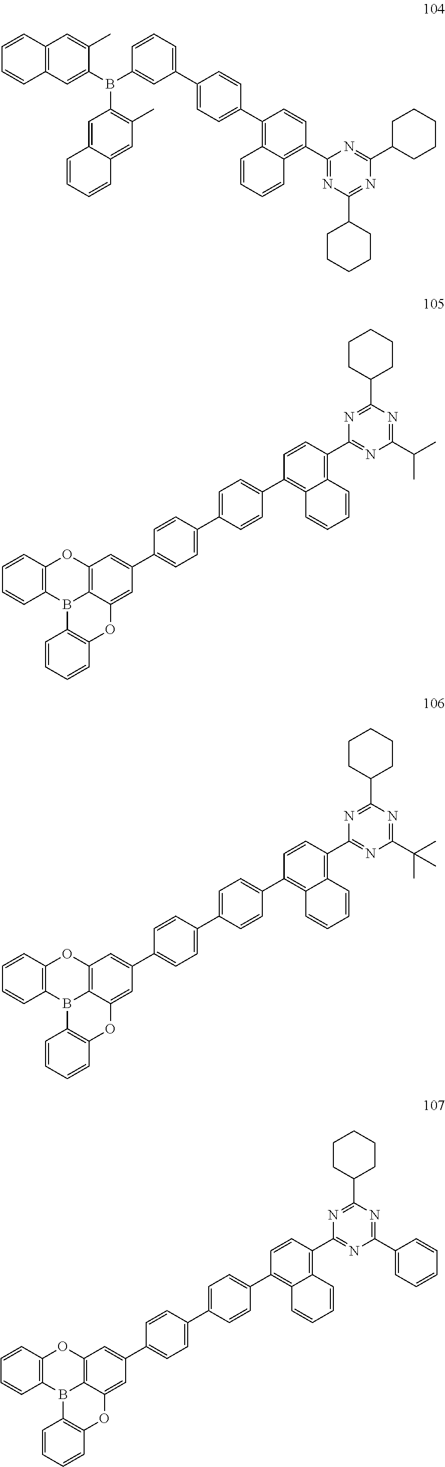 [SMILES: Cc1cc2ccccc2cc1B(c1cccc(-c2ccc(-c3ccc(-c4nc(C5CCCCC5)nc(C5CCCCC5)n4)c4ccccc34)cc2)c1)c1cc2ccccc2cc1C ; CC(C)c1nc(-c2ccc(-c3ccc(-c4ccc(-c5cc6c7c(c5)Oc5ccccc5B7c5ccccc5O6)cc4)cc3)c3ccccc23)nc(C2CCCCC2)n1 ; CC(C)(C)c1nc(-c2ccc(-c3ccc(-c4ccc(-c5cc6c7c(c5)Oc5ccccc5B7c5ccccc5O6)cc4)cc3)c3ccccc23)nc(C2CCCCC2)n1 ; c1ccc(-c2nc(-c3ccc(-c4ccc(-c5ccc(-c6cc7c8c(c6)Oc6ccccc6B8c6ccccc6O7)cc5)cc4)c4ccccc34)nc(C3CCCCC3)n2)cc1]

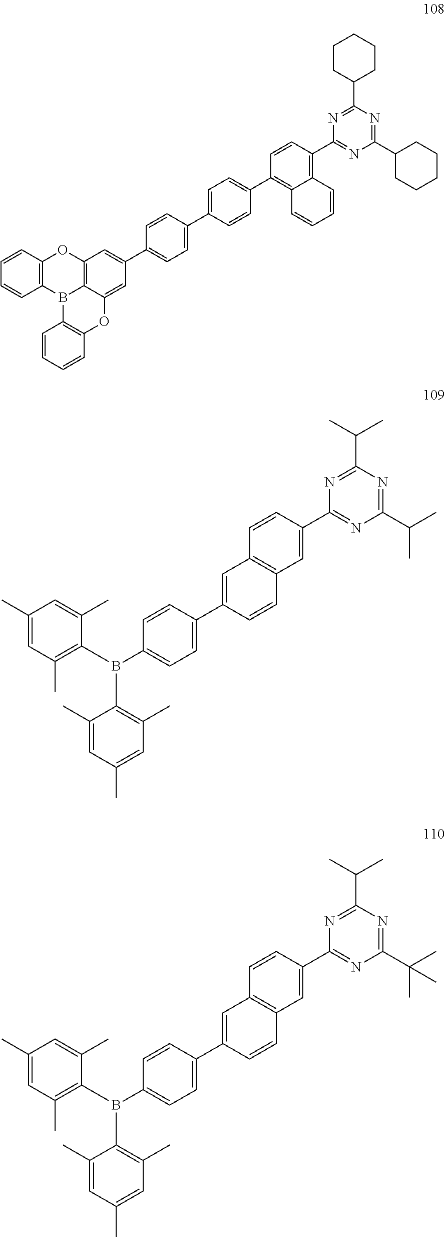

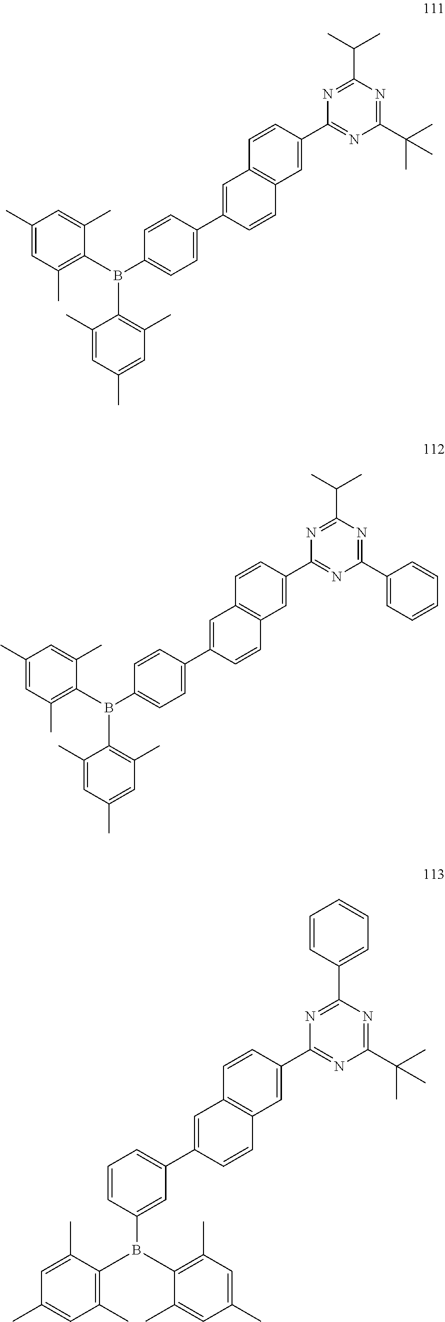

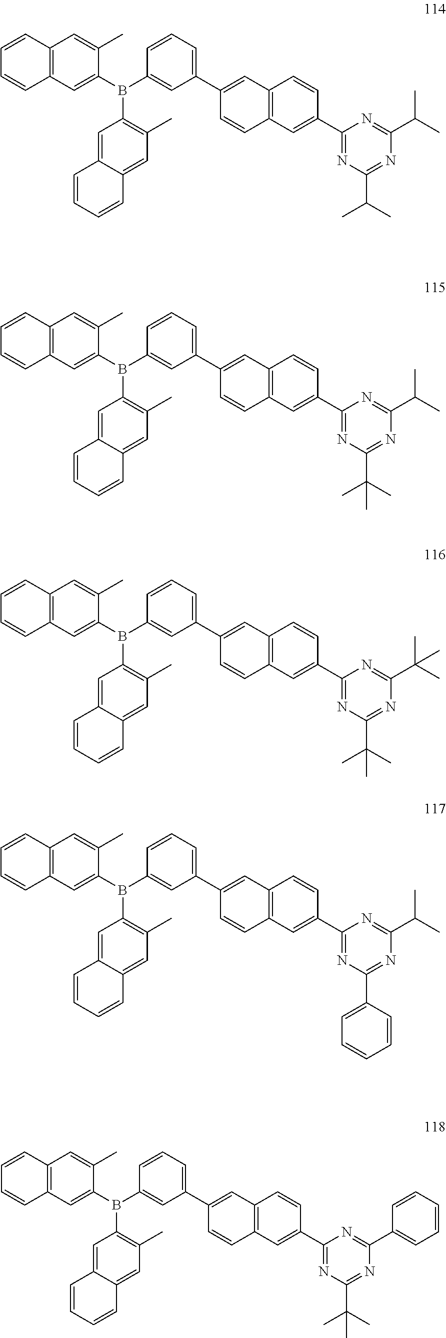 [SMILES: Cc1cc2ccccc2cc1B(c1cccc(-c2ccc3cc(-c4nc(C(C)C)nc(C(C)C)n4)ccc3c2)c1)c1cc2ccccc2cc1C ; Cc1cc2ccccc2cc1B(c1cccc(-c2ccc3cc(-c4nc(C(C)C)nc(C(C)(C)C)n4)ccc3c2)c1)c1cc2ccccc2cc1C ; Cc1cc2ccccc2cc1B(c1cccc(-c2ccc3cc(-c4nc(C(C)(C)C)nc(C(C)(C)C)n4)ccc3c2)c1)c1cc2ccccc2cc1C ; Cc1cc2ccccc2cc1B(c1cccc(-c2ccc3cc(-c4nc(-c5ccccc5)nc(C(C)C)n4)ccc3c2)c1)c1cc2ccccc2cc1C ; Cc1cc2ccccc2cc1B(c1cccc(-c2ccc3cc(-c4nc(-c5ccccc5)nc(C(C)(C)C)n4)ccc3c2)c1)c1cc2ccccc2cc1C]

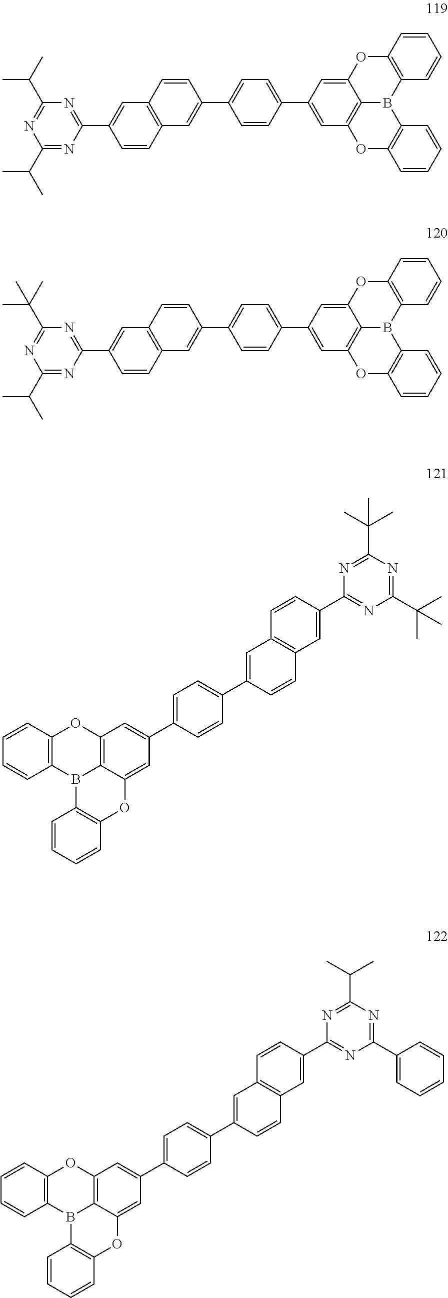 [SMILES: CC(C)c1nc(-c2ccc3cc(-c4ccc(-c5cc6c7c(c5)Oc5ccccc5B7c5ccccc5O6)cc4)ccc3c2)nc(C(C)C)n1 ; CC(C)c1nc(-c2ccc3cc(-c4ccc(-c5cc6c7c(c5)Oc5ccccc5B7c5ccccc5O6)cc4)ccc3c2)nc(C(C)(C)C)n1 ; CC(C)(C)c1nc(-c2ccc3cc(-c4ccc(-c5cc6c7c(c5)Oc5ccccc5B7c5ccccc5O6)cc4)ccc3c2)nc(C(C)(C)C)n1 ; CC(C)c1nc(-c2ccccc2)nc(-c2ccc3cc(-c4ccc(-c5cc6c7c(c5)Oc5ccccc5B7c5ccccc5O6)cc4)ccc3c2)n1]

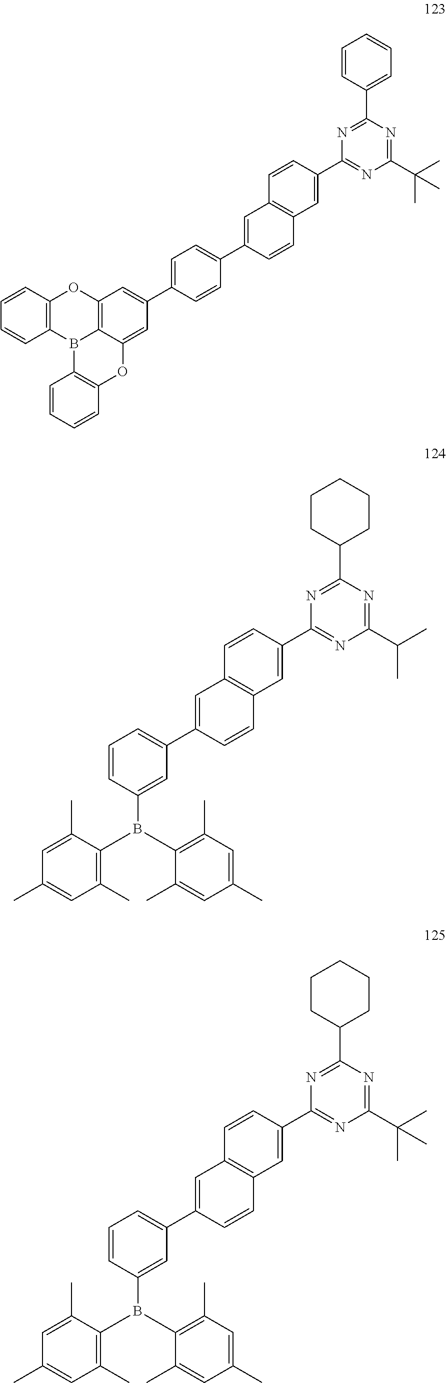

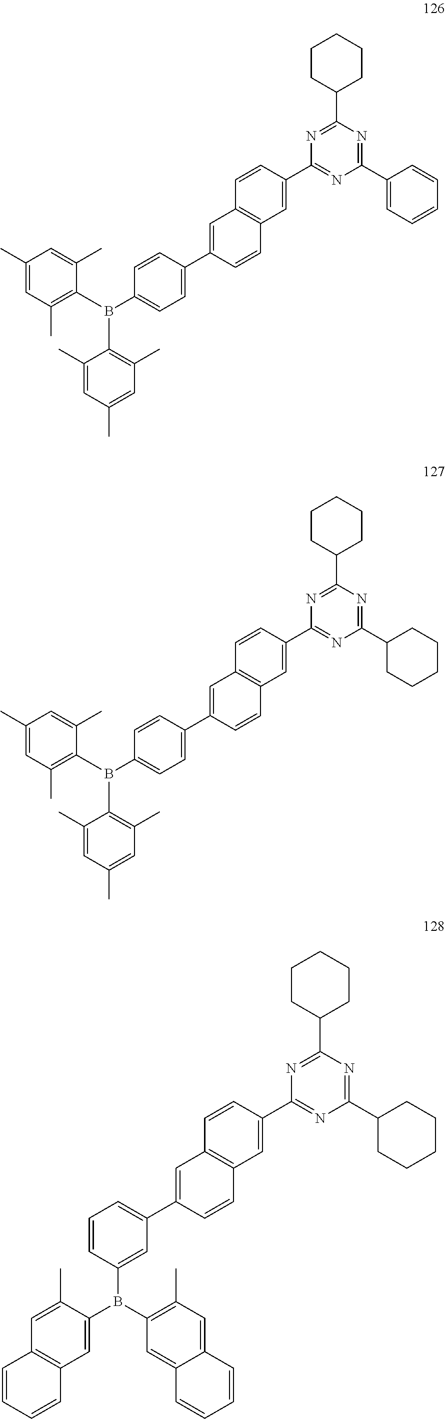 [SMILES: Cc1cc(C)c(B(c2ccc(-c3ccc4cc(-c5nc(-c6ccccc6)nc(C6CCCCC6)n5)ccc4c3)cc2)c2c(C)cc(C)cc2C)c(C)c1 ; Cc1cc(C)c(B(c2ccc(-c3ccc4cc(-c5nc(C6CCCCC6)nc(C6CCCCC6)n5)ccc4c3)cc2)c2c(C)cc(C)cc2C)c(C)c1 ; Cc1cc2ccccc2cc1B(c1cccc(-c2ccc3cc(-c4nc(C5CCCCC5)nc(C5CCCCC5)n4)ccc3c2)c1)c1cc2ccccc2cc1C]

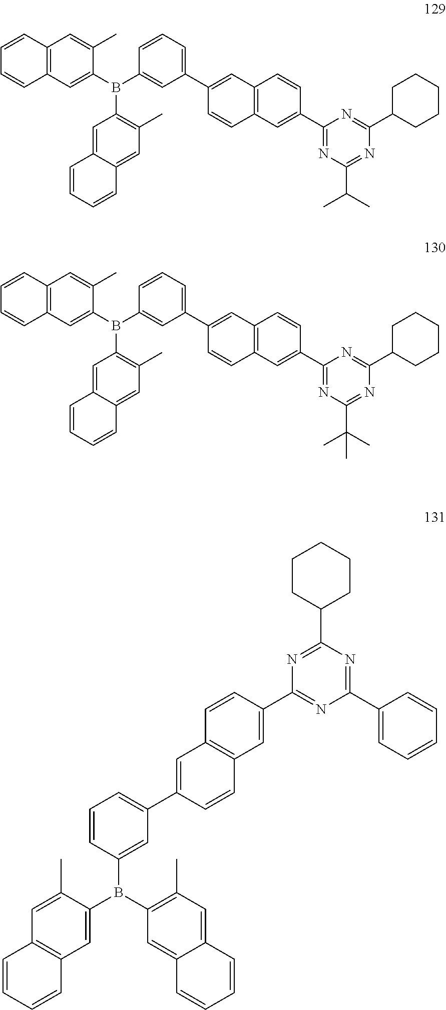 [SMILES: Cc1cc2ccccc2cc1B(c1cccc(-c2ccc3cc(-c4nc(C(C)C)nc(C5CCCCC5)n4)ccc3c2)c1)c1cc2ccccc2cc1C ; Cc1cc2ccccc2cc1B(c1cccc(-c2ccc3cc(-c4nc(C5CCCCC5)nc(C(C)(C)C)n4)ccc3c2)c1)c1cc2ccccc2cc1C ; Cc1cc2ccccc2cc1B(c1cccc(-c2ccc3cc(-c4nc(-c5ccccc5)nc(C5CCCCC5)n4)ccc3c2)c1)c1cc2ccccc2cc1C]

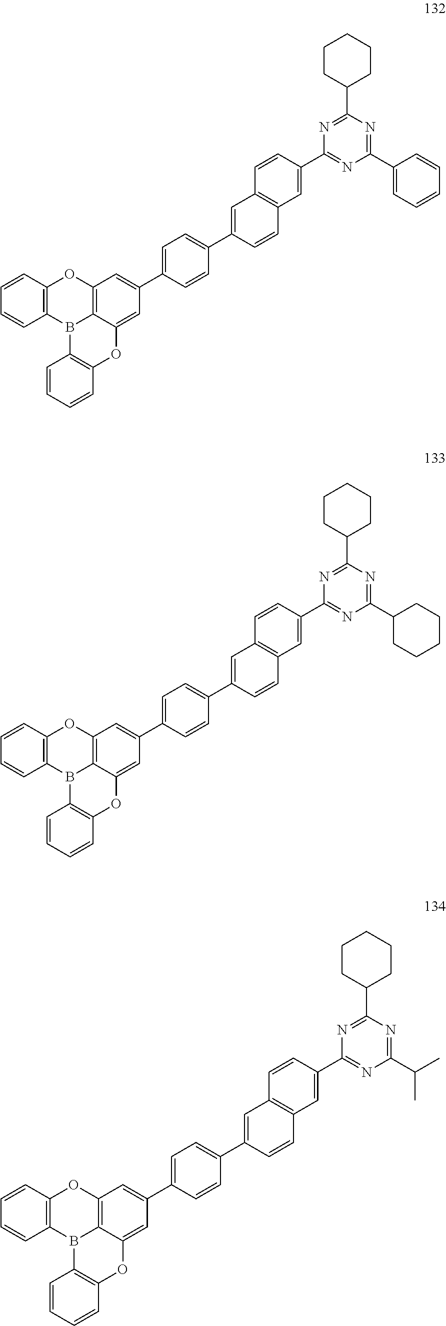 [SMILES: c1ccc(-c2nc(-c3ccc4cc(-c5ccc(-c6cc7c8c(c6)Oc6ccccc6B8c6ccccc6O7)cc5)ccc4c3)nc(C3CCCCC3)n2)cc1 ; c1ccc2c(c1)Oc1cc(-c3ccc(-c4ccc5cc(-c6nc(C7CCCCC7)nc(C7CCCCC7)n6)ccc5c4)cc3)cc3c1B2c1ccccc1O3 ; CC(C)c1nc(-c2ccc3cc(-c4ccc(-c5cc6c7c(c5)Oc5ccccc5B7c5ccccc5O6)cc4)ccc3c2)nc(C2CCCCC2)n1]

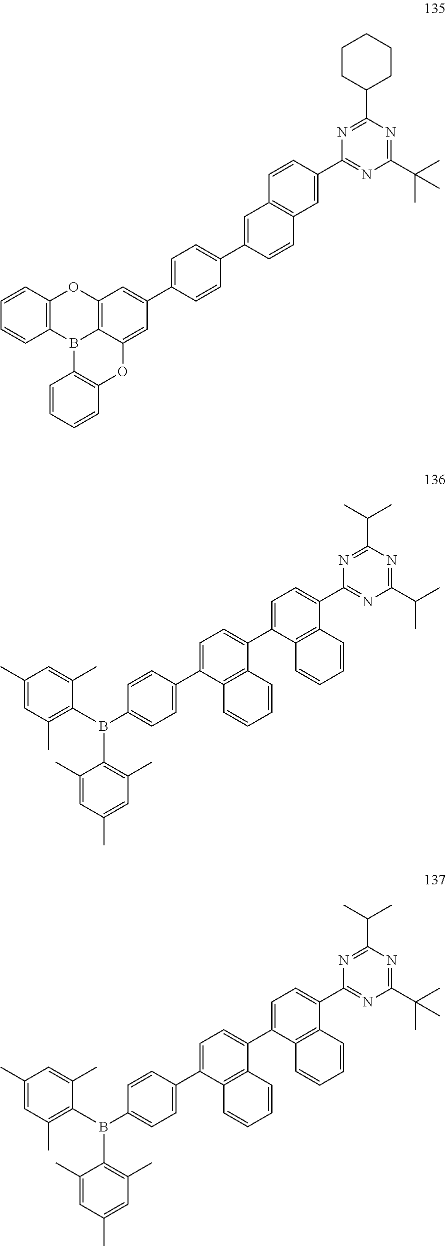

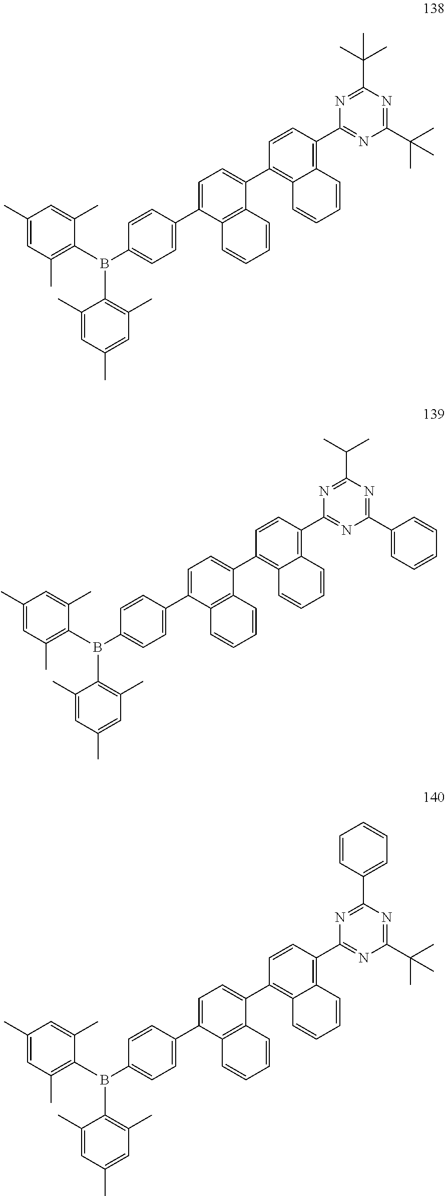

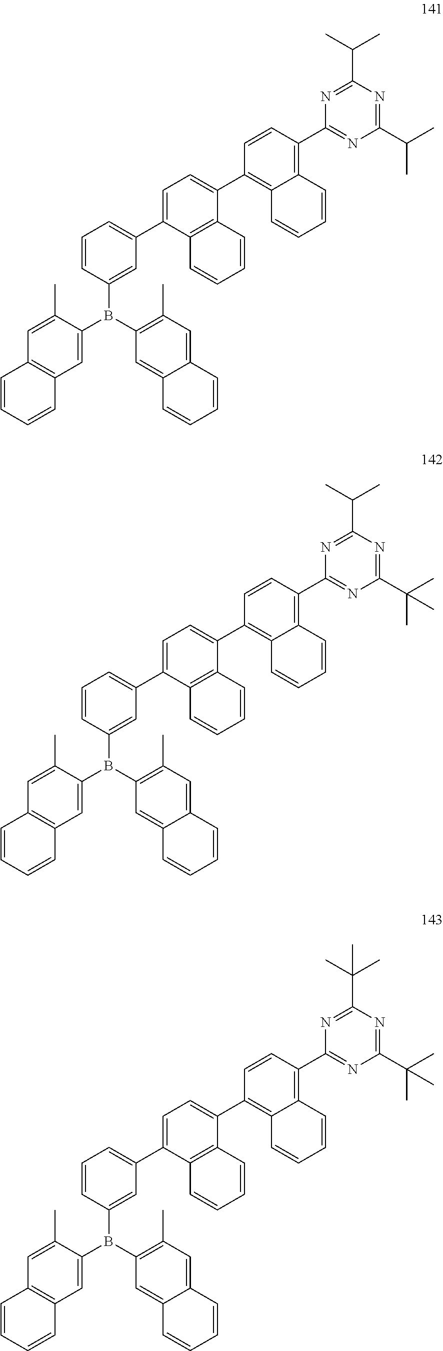 [SMILES: Cc1cc2ccccc2cc1B(c1cccc(-c2ccc(-c3ccc(-c4nc(C(C)C)nc(C(C)C)n4)c4ccccc34)c3ccccc23)c1)c1cc2ccccc2cc1C ; Cc1cc2ccccc2cc1B(c1cccc(-c2ccc(-c3ccc(-c4nc(C(C)C)nc(C(C)(C)C)n4)c4ccccc34)c3ccccc23)c1)c1cc2ccccc2cc1C ; Cc1cc2ccccc2cc1B(c1cccc(-c2ccc(-c3ccc(-c4nc(C(C)(C)C)nc(C(C)(C)C)n4)c4ccccc34)c3ccccc23)c1)c1cc2ccccc2cc1C]

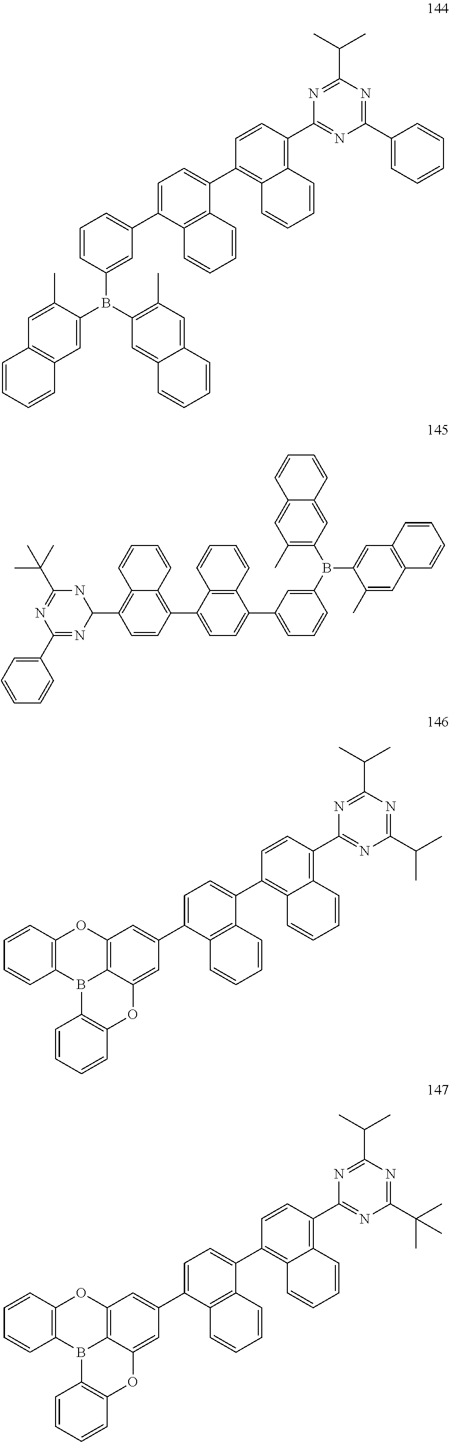

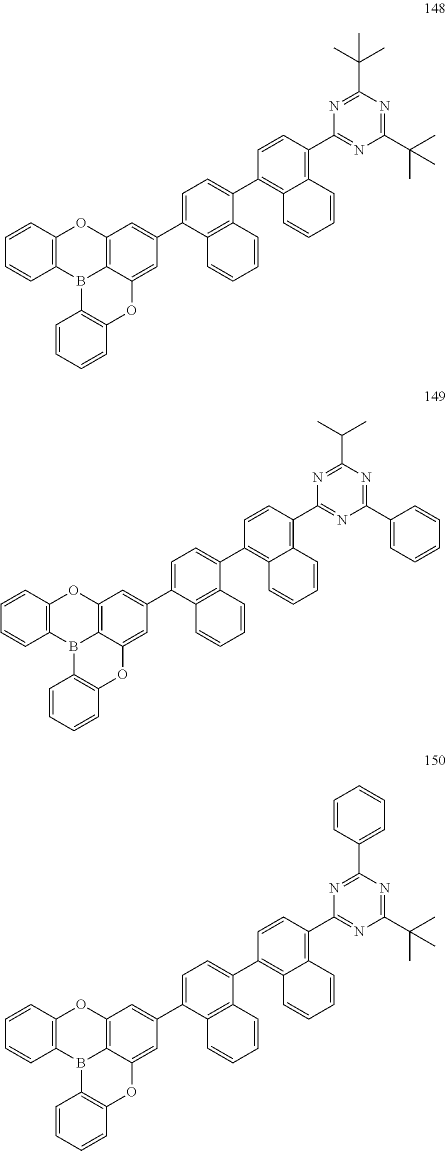 [SMILES: CC(C)(C)c1nc(-c2ccc(-c3ccc(-c4cc5c6c(c4)Oc4ccccc4B6c4ccccc4O5)c4ccccc34)c3ccccc23)nc(C(C)(C)C)n1 ; CC(C)c1nc(-c2ccccc2)nc(-c2ccc(-c3ccc(-c4cc5c6c(c4)Oc4ccccc4B6c4ccccc4O5)c4ccccc34)c3ccccc23)n1 ; CC(C)(C)c1nc(-c2ccccc2)nc(-c2ccc(-c3ccc(-c4cc5c6c(c4)Oc4ccccc4B6c4ccccc4O5)c4ccccc34)c3ccccc23)n1]

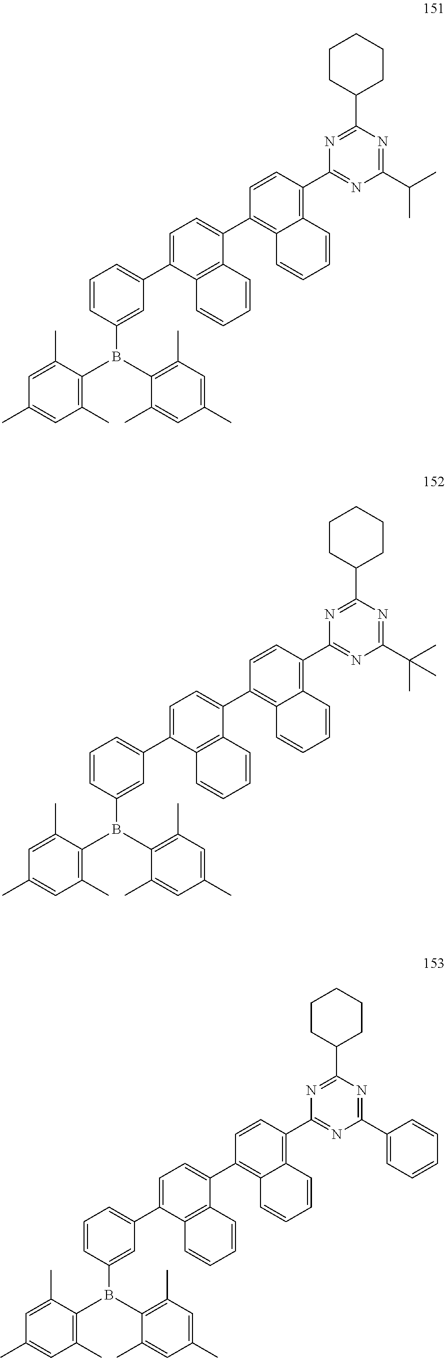

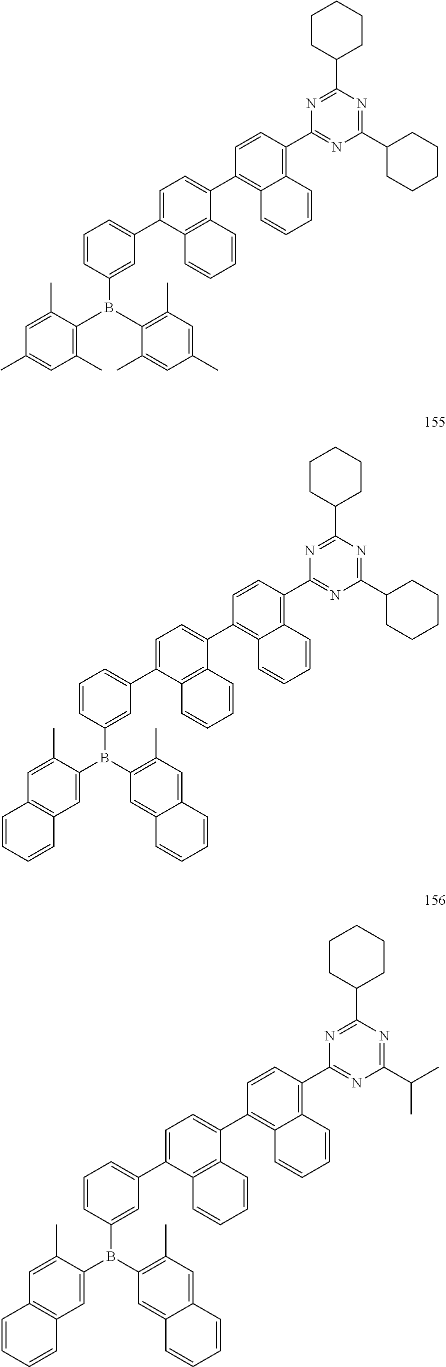 [SMILES: Cc1cc(C)c(B(c2cccc(-c3ccc(-c4ccc(-c5nc(C6CCCCC6)nc(C6CCCCC6)n5)c5ccccc45)c4ccccc34)c2)c2c(C)cc(C)cc2C)c(C)c1 ; Cc1cc2ccccc2cc1B(c1cccc(-c2ccc(-c3ccc(-c4nc(C5CCCCC5)nc(C5CCCCC5)n4)c4ccccc34)c3ccccc23)c1)c1cc2ccccc2cc1C ; Cc1cc2ccccc2cc1B(c1cccc(-c2ccc(-c3ccc(-c4nc(C(C)C)nc(C5CCCCC5)n4)c4ccccc34)c3ccccc23)c1)c1cc2ccccc2cc1C]

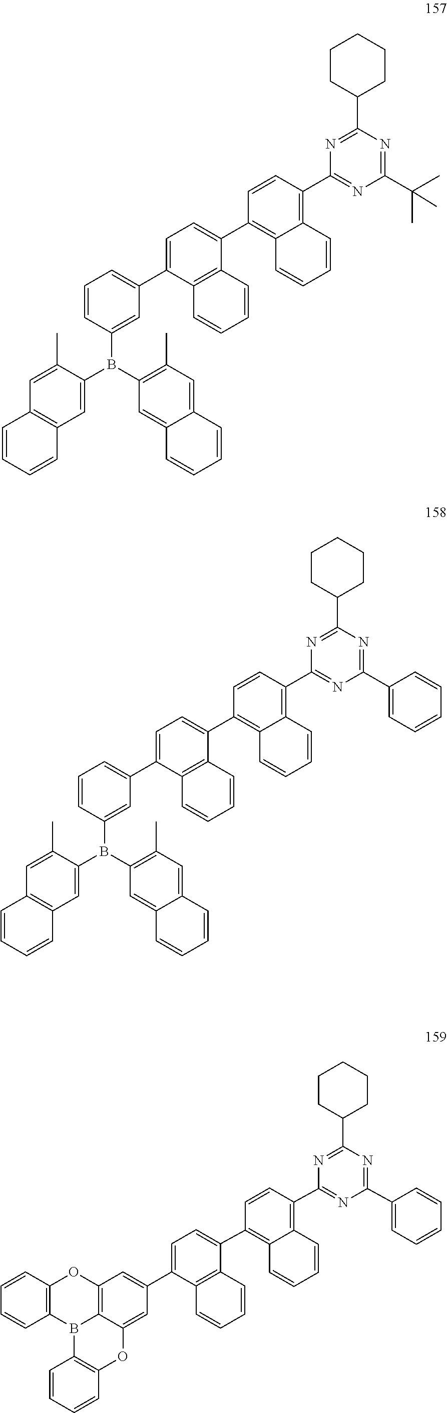 [SMILES: Cc1cc2ccccc2cc1B(c1cccc(-c2ccc(-c3ccc(-c4nc(C5CCCCC5)nc(C(C)(C)C)n4)c4ccccc34)c3ccccc23)c1)c1cc2ccccc2cc1C ; Cc1cc2ccccc2cc1B(c1cccc(-c2ccc(-c3ccc(-c4nc(-c5ccccc5)nc(C5CCCCC5)n4)c4ccccc34)c3ccccc23)c1)c1cc2ccccc2cc1C ; c1ccc(-c2nc(-c3ccc(-c4ccc(-c5cc6c7c(c5)Oc5ccccc5B7c5ccccc5O6)c5ccccc45)c4ccccc34)nc(C3CCCCC3)n2)cc1]

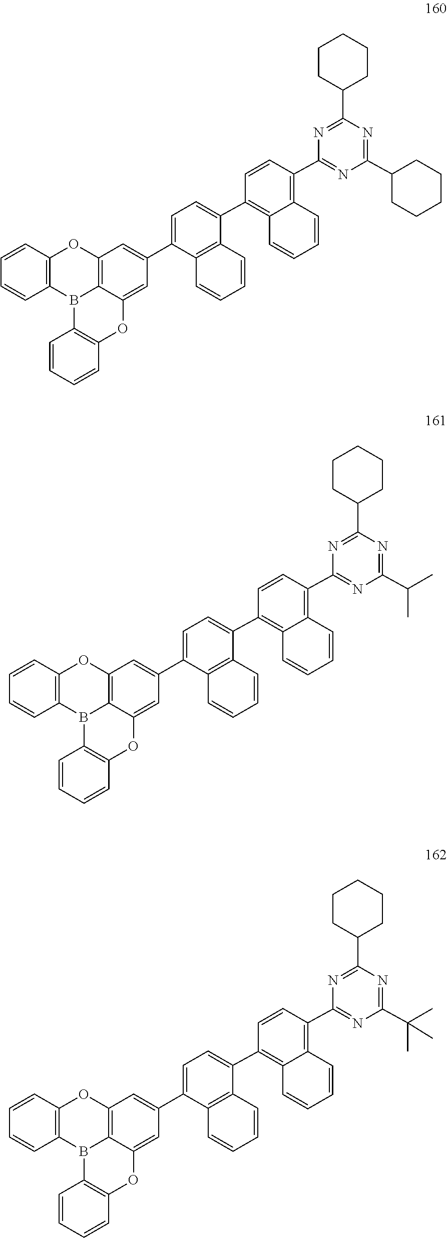 [SMILES: c1ccc2c(c1)Oc1cc(-c3ccc(-c4ccc(-c5nc(C6CCCCC6)nc(C6CCCCC6)n5)c5ccccc45)c4ccccc34)cc3c1B2c1ccccc1O3 ; CC(C)c1nc(-c2ccc(-c3ccc(-c4cc5c6c(c4)Oc4ccccc4B6c4ccccc4O5)c4ccccc34)c3ccccc23)nc(C2CCCCC2)n1 ; CC(C)(C)c1nc(-c2ccc(-c3ccc(-c4cc5c6c(c4)Oc4ccccc4B6c4ccccc4O5)c4ccccc34)c3ccccc23)nc(C2CCCCC2)n1]

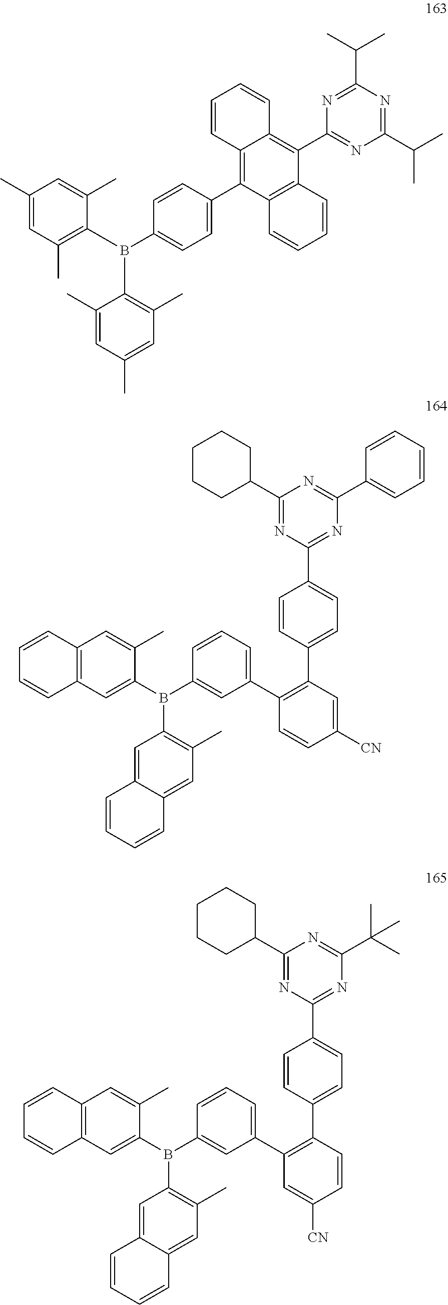 [SMILES: Cc1cc(C)c(B(c2ccc(-c3c4ccccc4c(-c4nc(C(C)C)nc(C(C)C)n4)c4ccccc34)cc2)c2c(C)cc(C)cc2C)c(C)c1 ; Cc1cc2ccccc2cc1B(c1cccc(-c2ccc(C#N)cc2-c2ccc(-c3nc(-c4ccccc4)nc(C4CCCCC4)n3)cc2)c1)c1cc2ccccc2cc1C ; Cc1cc2ccccc2cc1B(c1cccc(-c2cc(C#N)ccc2-c2ccc(-c3nc(C4CCCCC4)nc(C(C)(C)C)n3)cc2)c1)c1cc2ccccc2cc1C]

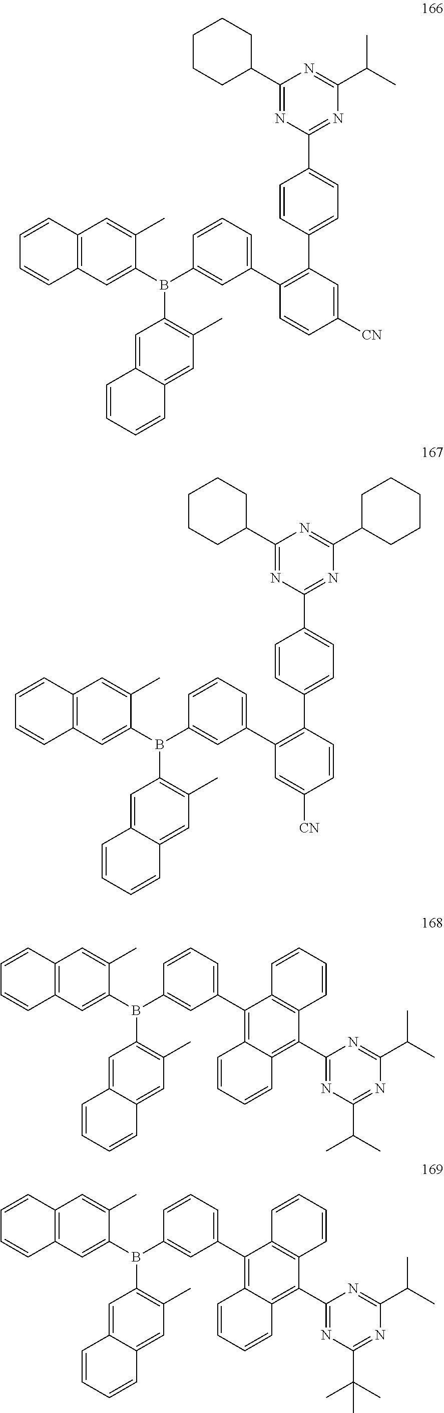 [SMILES: Cc1cc2ccccc2cc1B(c1cccc(-c2ccc(C#N)cc2-c2ccc(-c3nc(C(C)C)nc(C4CCCCC4)n3)cc2)c1)c1cc2ccccc2cc1C ; Cc1cc2ccccc2cc1B(c1cccc(-c2cc(C#N)ccc2-c2ccc(-c3nc(C4CCCCC4)nc(C4CCCCC4)n3)cc2)c1)c1cc2ccccc2cc1C ; Cc1cc2ccccc2cc1B(c1cccc(-c2c3ccccc3c(-c3nc(C(C)C)nc(C(C)C)n3)c3ccccc23)c1)c1cc2ccccc2cc1C ; Cc1cc2ccccc2cc1B(c1cccc(-c2c3ccccc3c(-c3nc(C(C)C)nc(C(C)(C)C)n3)c3ccccc23)c1)c1cc2ccccc2cc1C]

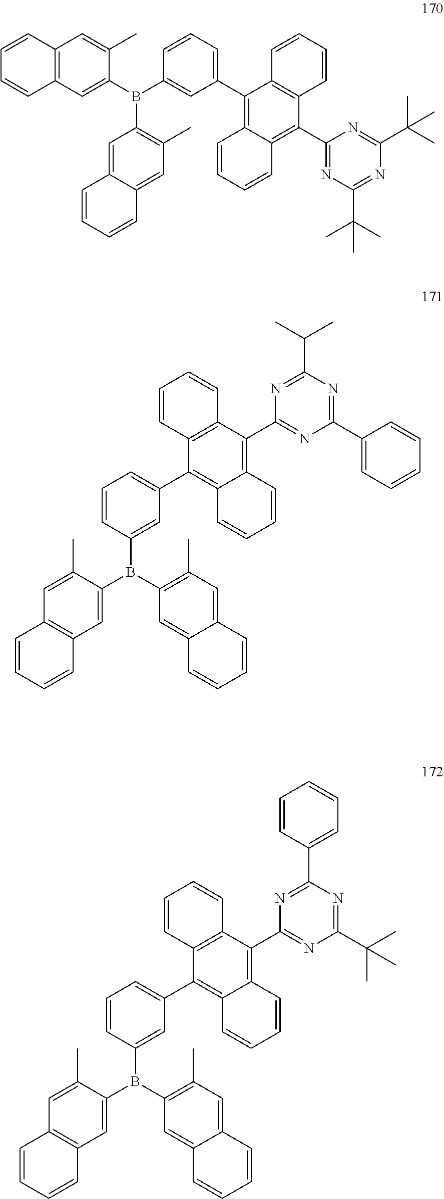 [SMILES: Cc1cc2ccccc2cc1B(c1cccc(-c2c3ccccc3c(-c3nc(C(C)(C)C)nc(C(C)(C)C)n3)c3ccccc23)c1)c1cc2ccccc2cc1C ; Cc1cc2ccccc2cc1B(c1cccc(-c2c3ccccc3c(-c3nc(-c4ccccc4)nc(C(C)C)n3)c3ccccc23)c1)c1cc2ccccc2cc1C ; Cc1cc2ccccc2cc1B(c1cccc(-c2c3ccccc3c(-c3nc(-c4ccccc4)nc(C(C)(C)C)n3)c3ccccc23)c1)c1cc2ccccc2cc1C]

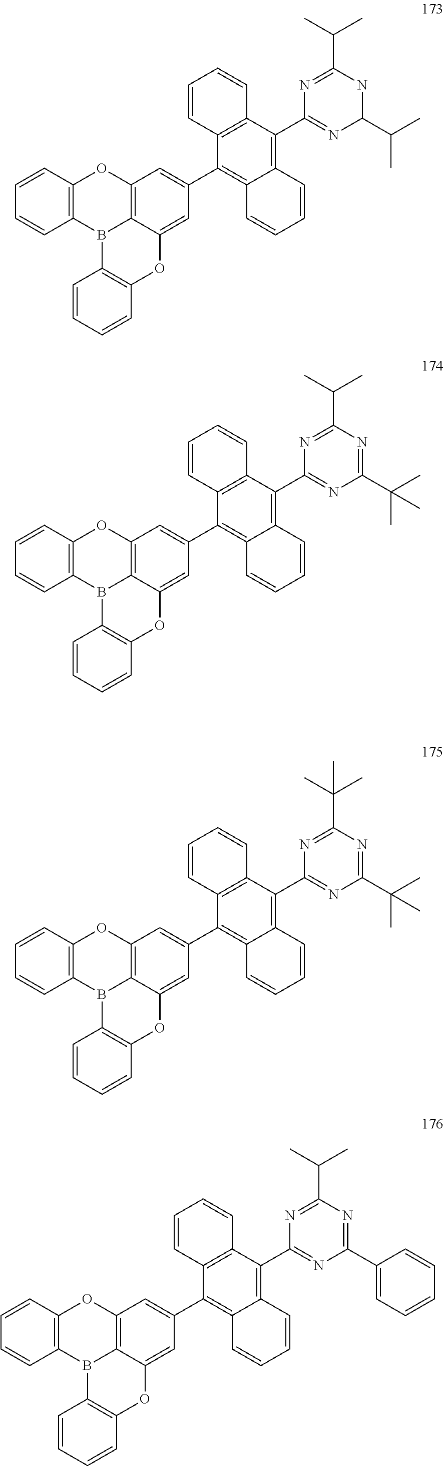

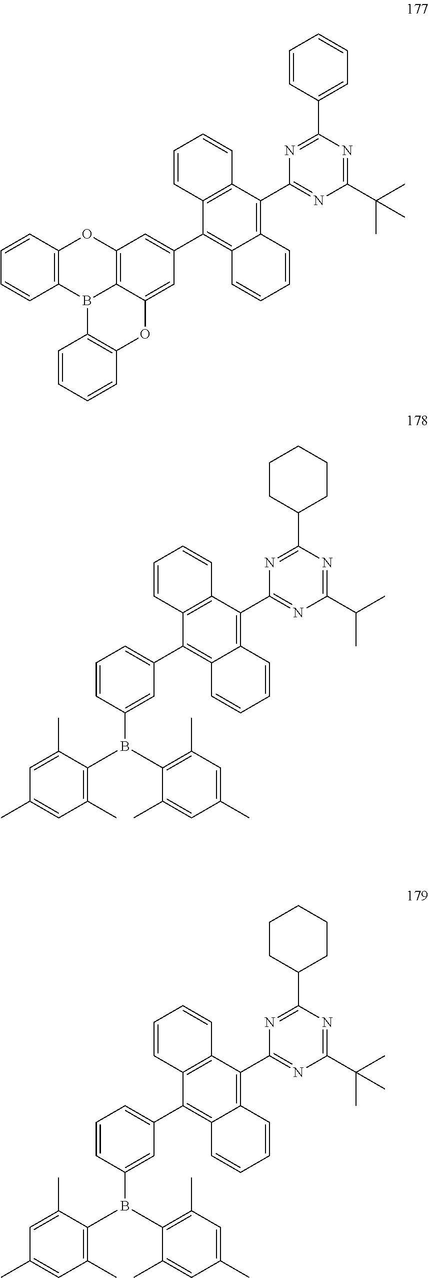

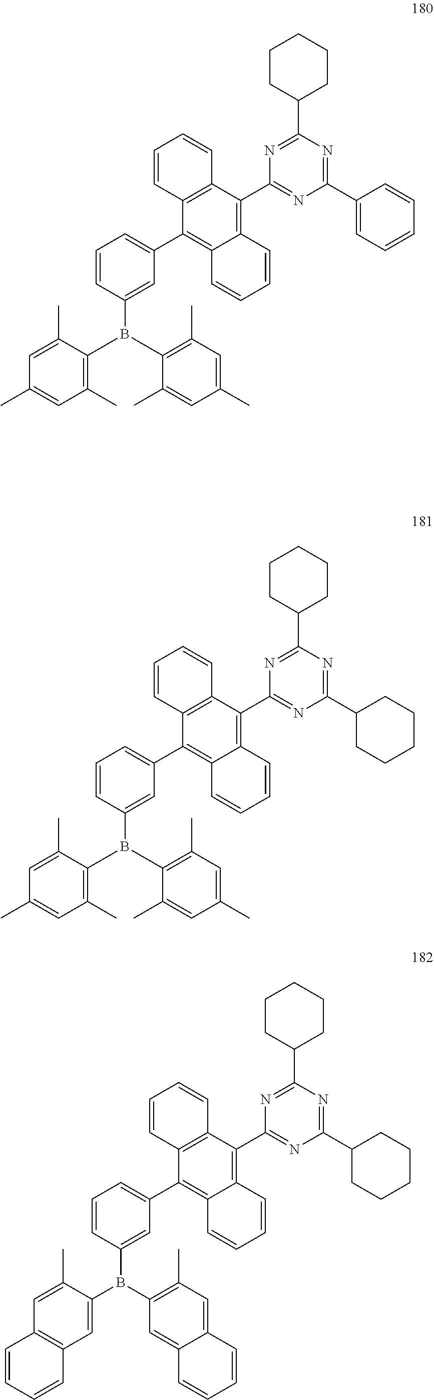 [SMILES: Cc1cc(C)c(B(c2cccc(-c3c4ccccc4c(-c4nc(-c5ccccc5)nc(C5CCCCC5)n4)c4ccccc34)c2)c2c(C)cc(C)cc2C)c(C)c1 ; Cc1cc(C)c(B(c2cccc(-c3c4ccccc4c(-c4nc(C5CCCCC5)nc(C5CCCCC5)n4)c4ccccc34)c2)c2c(C)cc(C)cc2C)c(C)c1 ; Cc1cc2ccccc2cc1B(c1cccc(-c2c3ccccc3c(-c3nc(C4CCCCC4)nc(C4CCCCC4)n3)c3ccccc23)c1)c1cc2ccccc2cc1C]

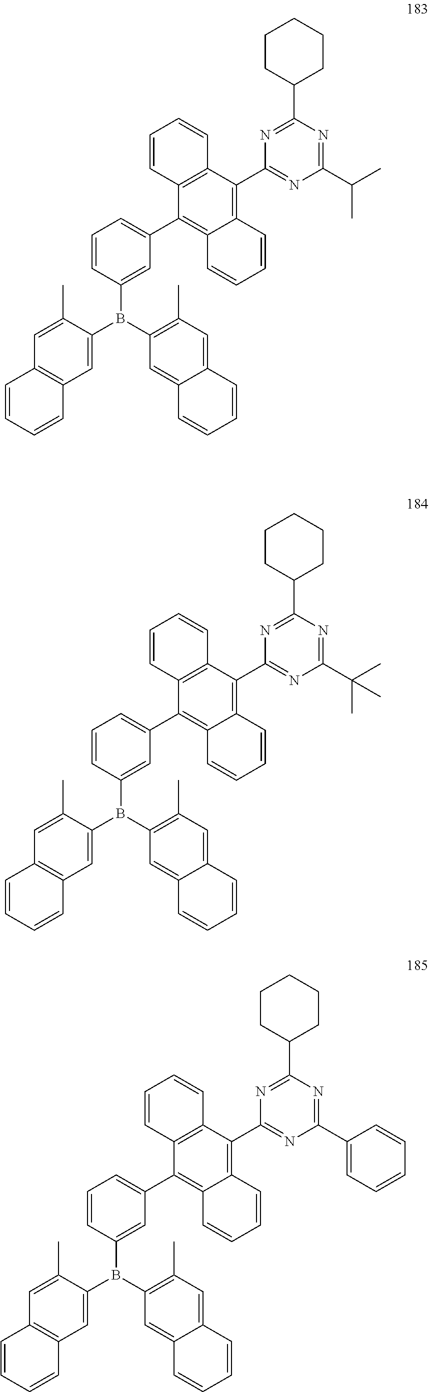 [SMILES: Cc1cc2ccccc2cc1B(c1cccc(-c2c3ccccc3c(-c3nc(C(C)C)nc(C4CCCCC4)n3)c3ccccc23)c1)c1cc2ccccc2cc1C ; Cc1cc2ccccc2cc1B(c1cccc(-c2c3ccccc3c(-c3nc(C4CCCCC4)nc(C(C)(C)C)n3)c3ccccc23)c1)c1cc2ccccc2cc1C ; Cc1cc2ccccc2cc1B(c1cccc(-c2c3ccccc3c(-c3nc(-c4ccccc4)nc(C4CCCCC4)n3)c3ccccc23)c1)c1cc2ccccc2cc1C]

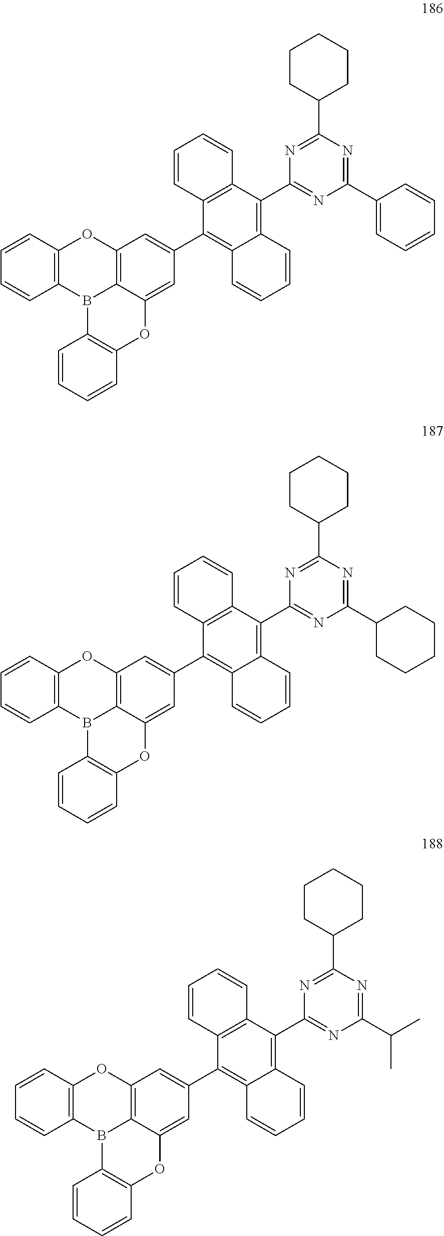 [SMILES: c1ccc(-c2nc(-c3c4ccccc4c(-c4cc5c6c(c4)Oc4ccccc4B6c4ccccc4O5)c4ccccc34)nc(C3CCCCC3)n2)cc1 ; c1ccc2c(c1)Oc1cc(-c3c4ccccc4c(-c4nc(C5CCCCC5)nc(C5CCCCC5)n4)c4ccccc34)cc3c1B2c1ccccc1O3 ; CC(C)c1nc(-c2c3ccccc3c(-c3cc4c5c(c3)Oc3ccccc3B5c3ccccc3O4)c3ccccc23)nc(C2CCCCC2)n1]

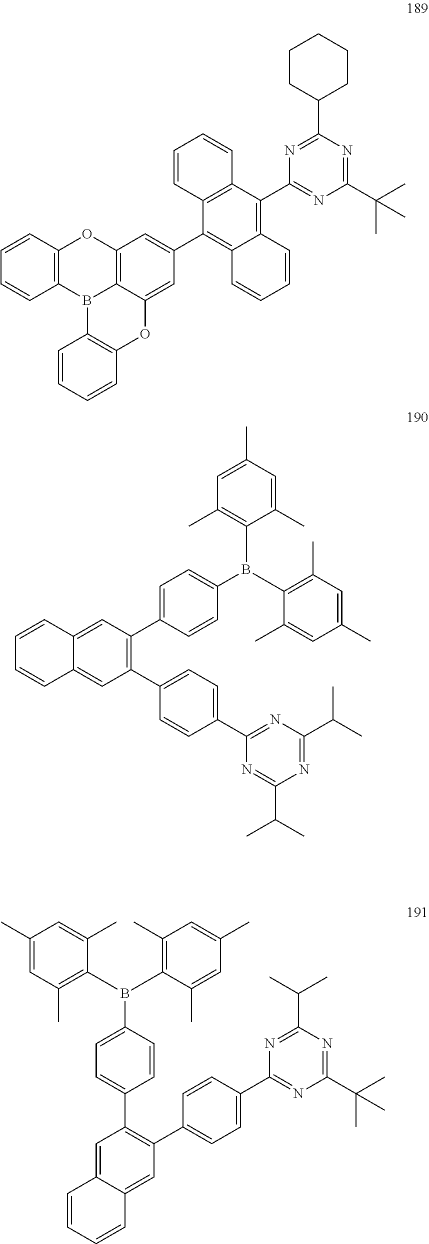

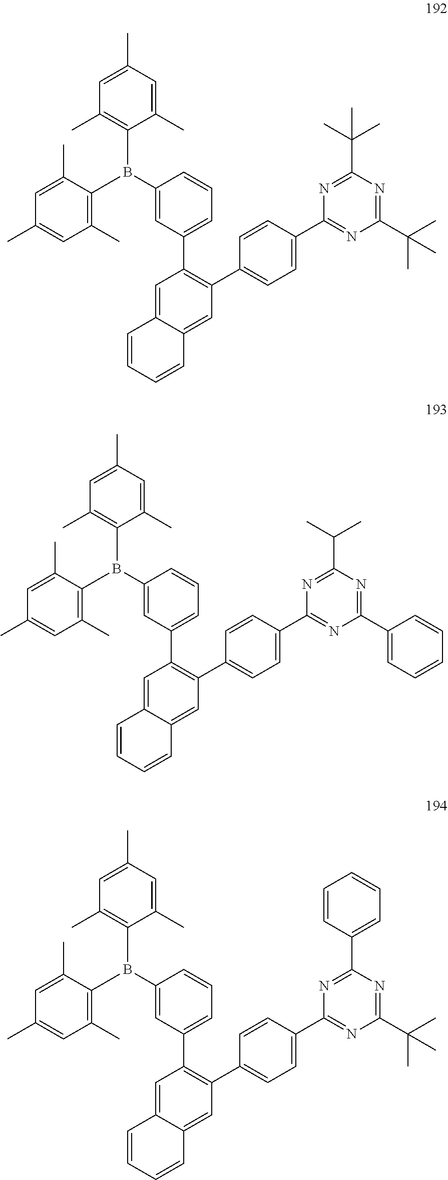

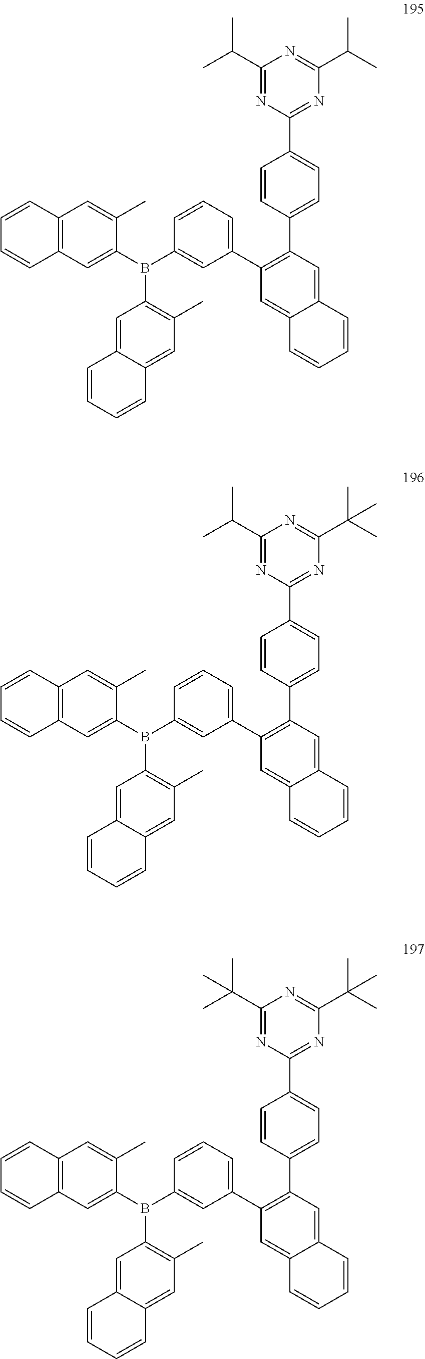 [SMILES: Cc1cc2ccccc2cc1B(c1cccc(-c2cc3ccccc3cc2-c2ccc(-c3nc(C(C)C)nc(C(C)C)n3)cc2)c1)c1cc2ccccc2cc1C ; Cc1cc2ccccc2cc1B(c1cccc(-c2cc3ccccc3cc2-c2ccc(-c3nc(C(C)C)nc(C(C)(C)C)n3)cc2)c1)c1cc2ccccc2cc1C ; Cc1cc2ccccc2cc1B(c1cccc(-c2cc3ccccc3cc2-c2ccc(-c3nc(C(C)(C)C)nc(C(C)(C)C)n3)cc2)c1)c1cc2ccccc2cc1C]

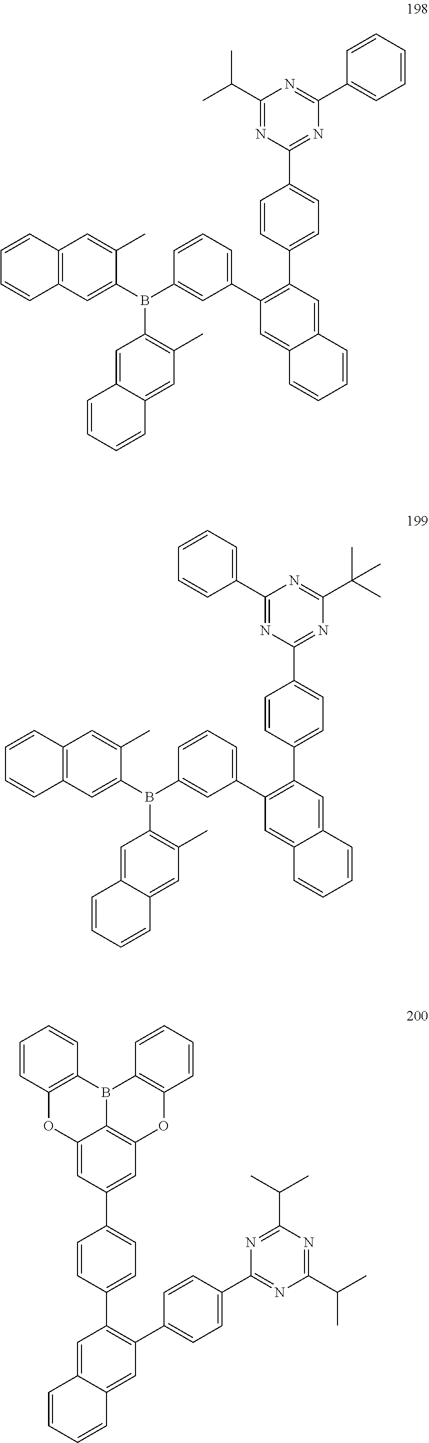 [SMILES: Cc1cc2ccccc2cc1B(c1cccc(-c2cc3ccccc3cc2-c2ccc(-c3nc(-c4ccccc4)nc(C(C)C)n3)cc2)c1)c1cc2ccccc2cc1C ; Cc1cc2ccccc2cc1B(c1cccc(-c2cc3ccccc3cc2-c2ccc(-c3nc(-c4ccccc4)nc(C(C)(C)C)n3)cc2)c1)c1cc2ccccc2cc1C ; CC(C)c1nc(-c2ccc(-c3cc4ccccc4cc3-c3ccc(-c4cc5c6c(c4)Oc4ccccc4B6c4ccccc4O5)cc3)cc2)nc(C(C)C)n1]

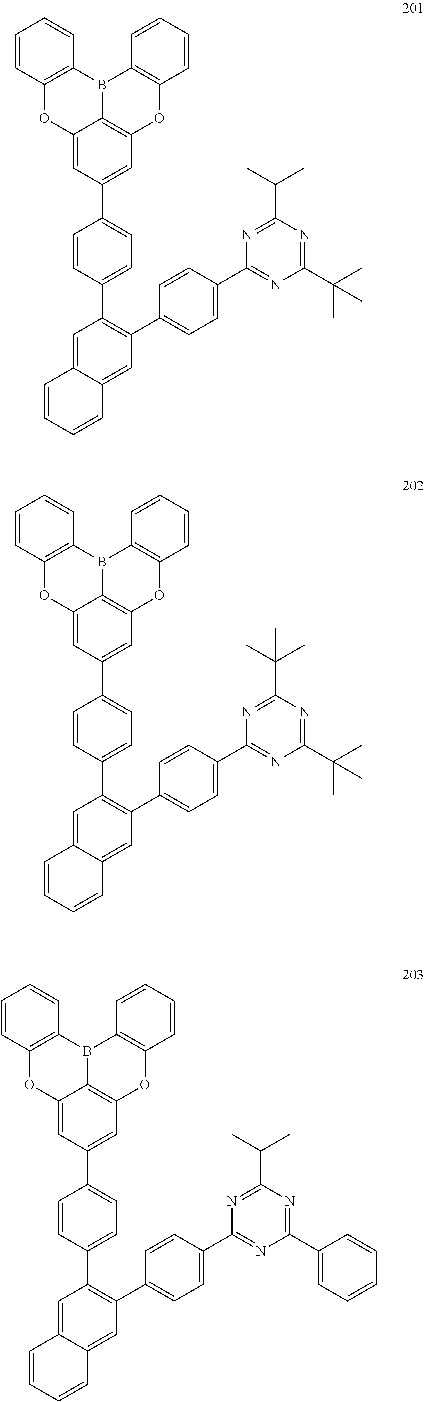 [SMILES: CC(C)c1nc(-c2ccc(-c3cc4ccccc4cc3-c3ccc(-c4cc5c6c(c4)Oc4ccccc4B6c4ccccc4O5)cc3)cc2)nc(C(C)(C)C)n1 ; CC(C)(C)c1nc(-c2ccc(-c3cc4ccccc4cc3-c3ccc(-c4cc5c6c(c4)Oc4ccccc4B6c4ccccc4O5)cc3)cc2)nc(C(C)(C)C)n1 ; CC(C)c1nc(-c2ccccc2)nc(-c2ccc(-c3cc4ccccc4cc3-c3ccc(-c4cc5c6c(c4)Oc4ccccc4B6c4ccccc4O5)cc3)cc2)n1]

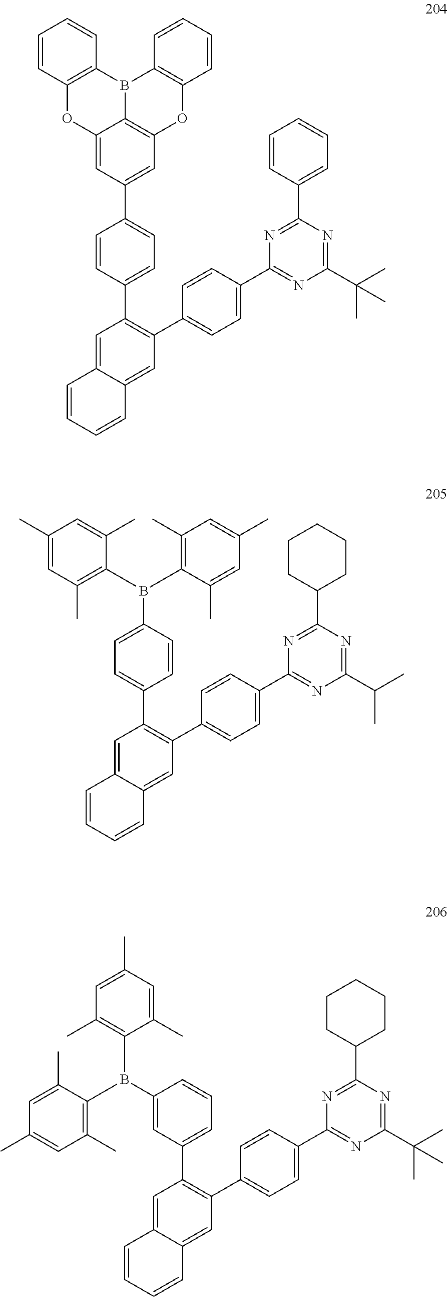

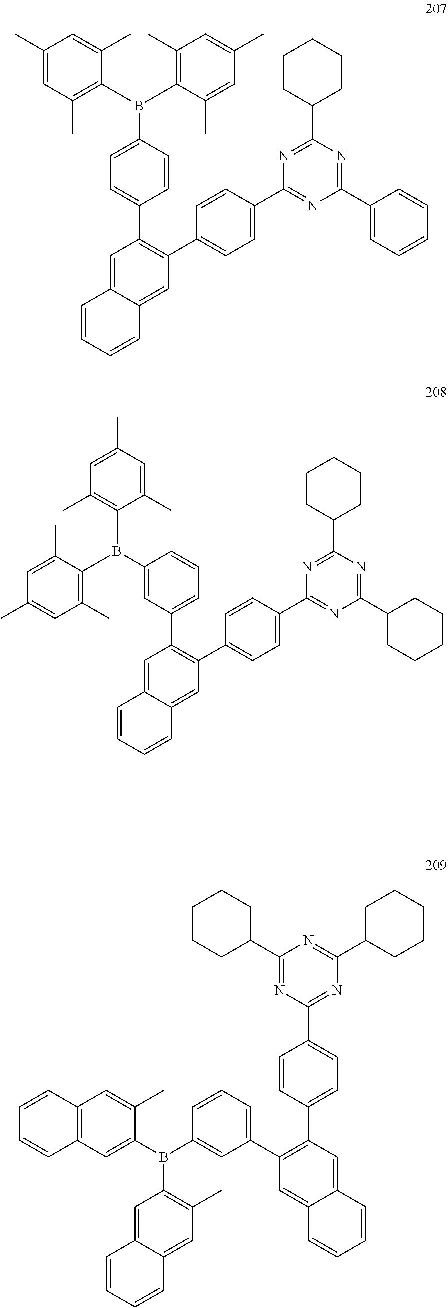 [SMILES: Cc1cc(C)c(B(c2ccc(-c3cc4ccccc4cc3-c3ccc(-c4nc(-c5ccccc5)nc(C5CCCCC5)n4)cc3)cc2)c2c(C)cc(C)cc2C)c(C)c1 ; Cc1cc(C)c(B(c2cccc(-c3cc4ccccc4cc3-c3ccc(-c4nc(C5CCCCC5)nc(C5CCCCC5)n4)cc3)c2)c2c(C)cc(C)cc2C)c(C)c1 ; Cc1cc2ccccc2cc1B(c1cccc(-c2cc3ccccc3cc2-c2ccc(-c3nc(C4CCCCC4)nc(C4CCCCC4)n3)cc2)c1)c1cc2ccccc2cc1C]

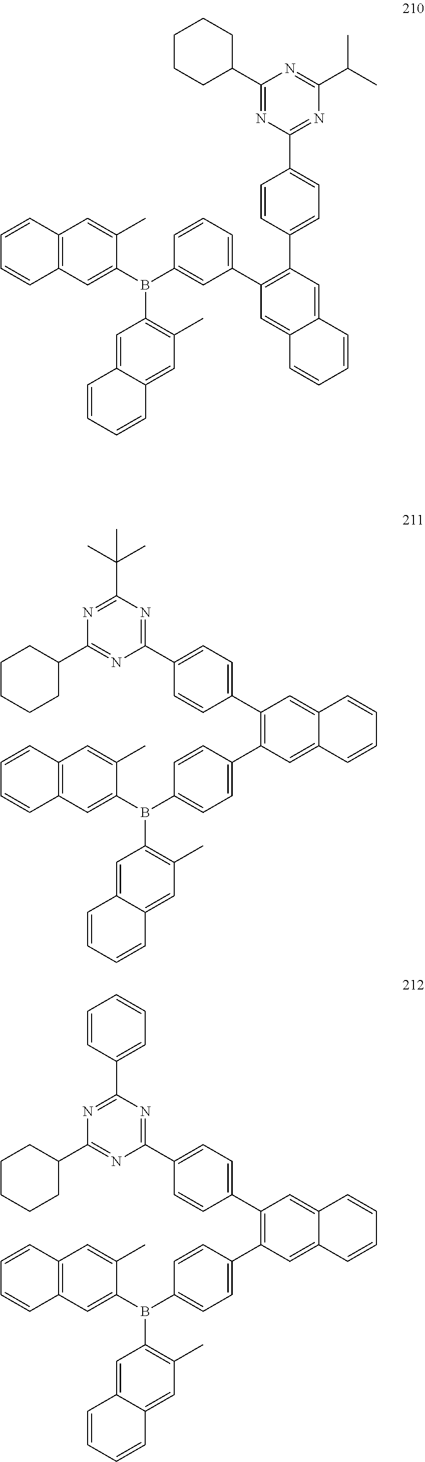

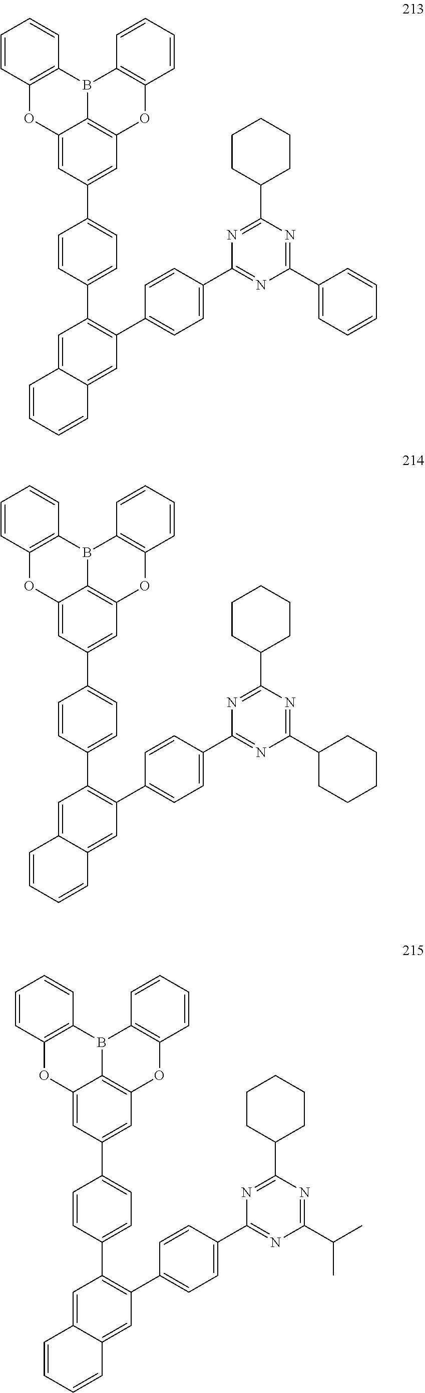 [SMILES: c1ccc(-c2nc(-c3ccc(-c4cc5ccccc5cc4-c4ccc(-c5cc6c7c(c5)Oc5ccccc5B7c5ccccc5O6)cc4)cc3)nc(C3CCCCC3)n2)cc1 ; c1ccc2c(c1)Oc1cc(-c3ccc(-c4cc5ccccc5cc4-c4ccc(-c5nc(C6CCCCC6)nc(C6CCCCC6)n5)cc4)cc3)cc3c1B2c1ccccc1O3 ; CC(C)c1nc(-c2ccc(-c3cc4ccccc4cc3-c3ccc(-c4cc5c6c(c4)Oc4ccccc4B6c4ccccc4O5)cc3)cc2)nc(C2CCCCC2)n1]

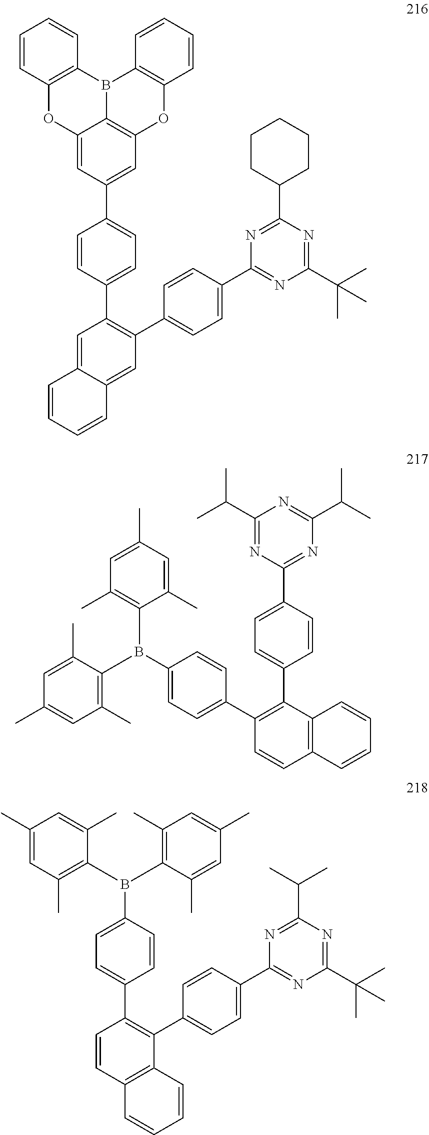

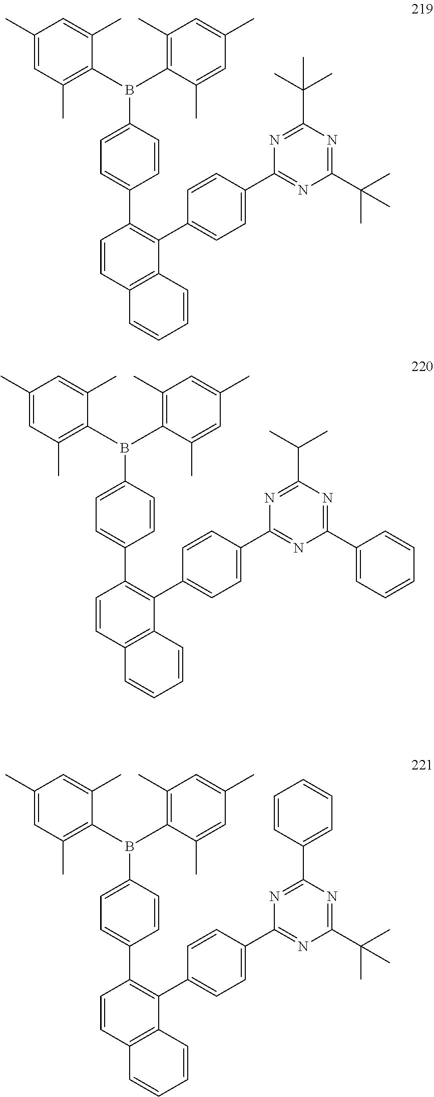

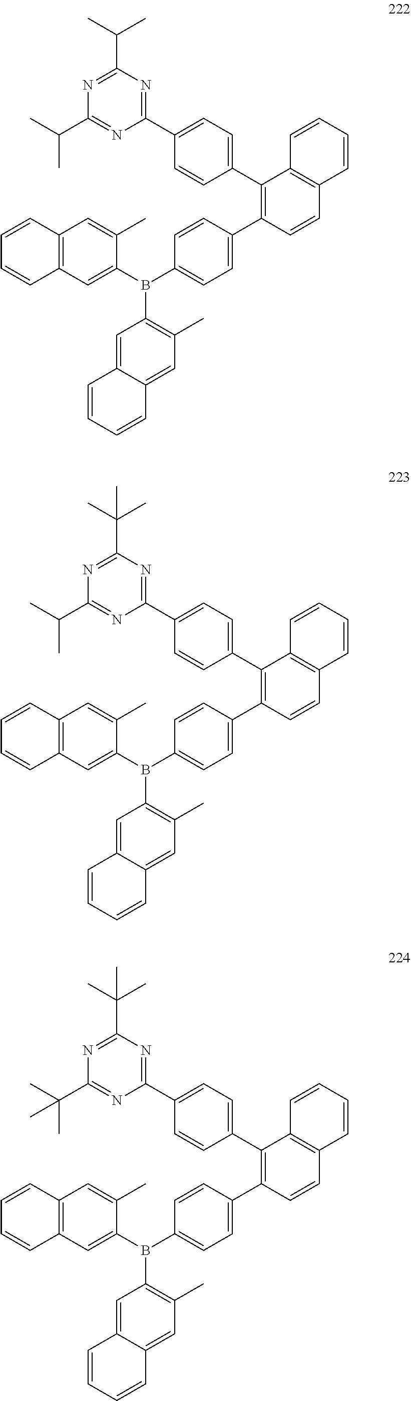 [SMILES: Cc1cc2ccccc2cc1B(c1ccc(-c2ccc3ccccc3c2-c2ccc(-c3nc(C(C)C)nc(C(C)C)n3)cc2)cc1)c1cc2ccccc2cc1C ; Cc1cc2ccccc2cc1B(c1ccc(-c2ccc3ccccc3c2-c2ccc(-c3nc(C(C)C)nc(C(C)(C)C)n3)cc2)cc1)c1cc2ccccc2cc1C ; Cc1cc2ccccc2cc1B(c1ccc(-c2ccc3ccccc3c2-c2ccc(-c3nc(C(C)(C)C)nc(C(C)(C)C)n3)cc2)cc1)c1cc2ccccc2cc1C]

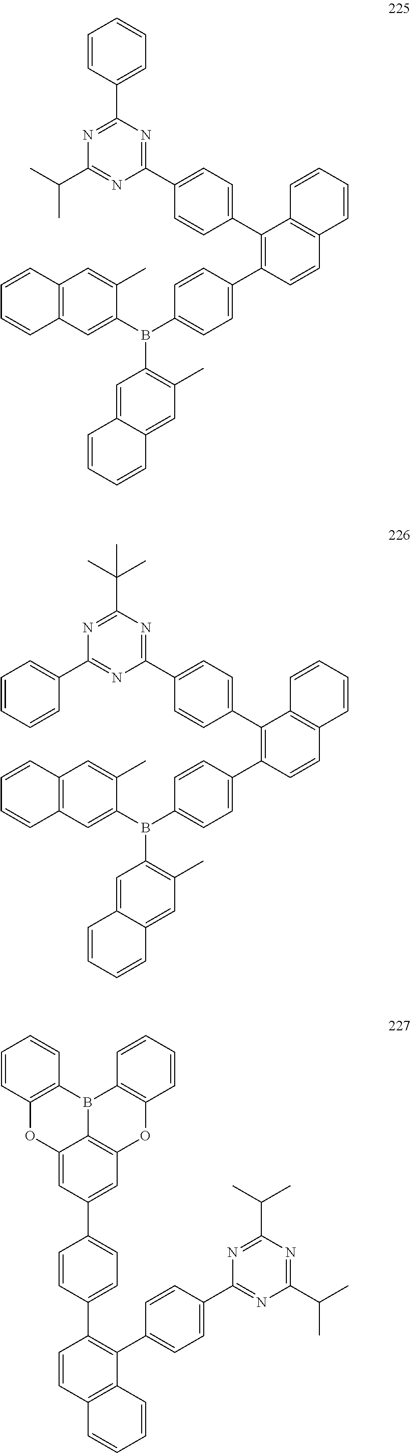 [SMILES: Cc1cc2ccccc2cc1B(c1ccc(-c2ccc3ccccc3c2-c2ccc(-c3nc(-c4ccccc4)nc(C(C)C)n3)cc2)cc1)c1cc2ccccc2cc1C ; Cc1cc2ccccc2cc1B(c1ccc(-c2ccc3ccccc3c2-c2ccc(-c3nc(-c4ccccc4)nc(C(C)(C)C)n3)cc2)cc1)c1cc2ccccc2cc1C ; CC(C)c1nc(-c2ccc(-c3c(-c4ccc(-c5cc6c7c(c5)Oc5ccccc5B7c5ccccc5O6)cc4)ccc4ccccc34)cc2)nc(C(C)C)n1]

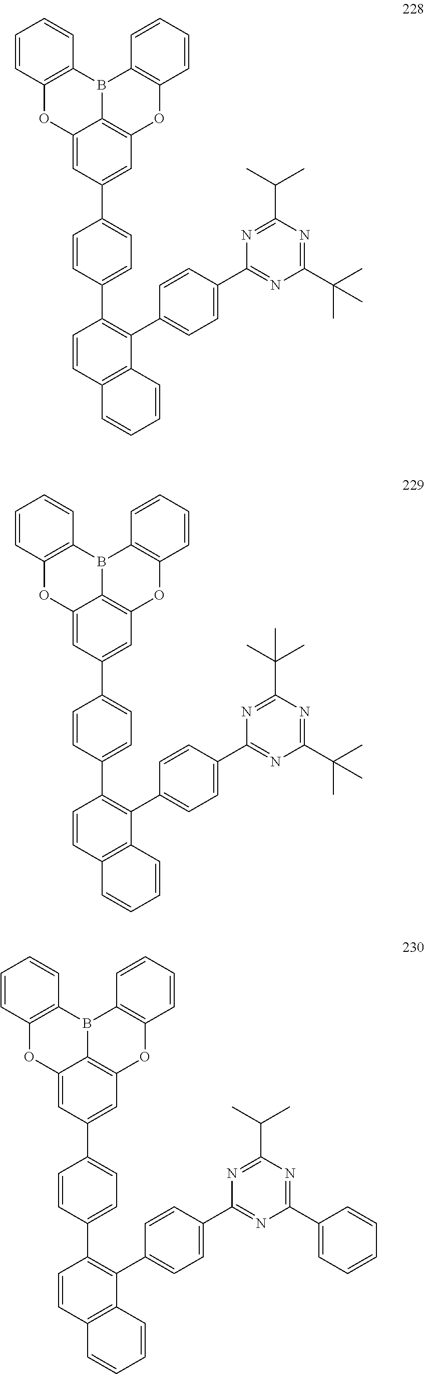 [SMILES: CC(C)c1nc(-c2ccc(-c3c(-c4ccc(-c5cc6c7c(c5)Oc5ccccc5B7c5ccccc5O6)cc4)ccc4ccccc34)cc2)nc(C(C)(C)C)n1 ; CC(C)(C)c1nc(-c2ccc(-c3c(-c4ccc(-c5cc6c7c(c5)Oc5ccccc5B7c5ccccc5O6)cc4)ccc4ccccc34)cc2)nc(C(C)(C)C)n1 ; CC(C)c1nc(-c2ccccc2)nc(-c2ccc(-c3c(-c4ccc(-c5cc6c7c(c5)Oc5ccccc5B7c5ccccc5O6)cc4)ccc4ccccc34)cc2)n1]

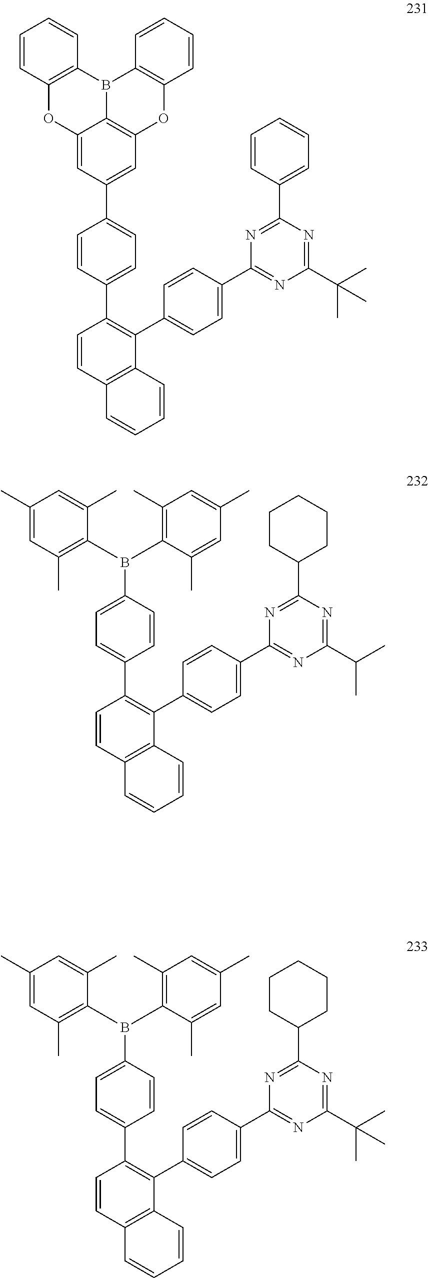

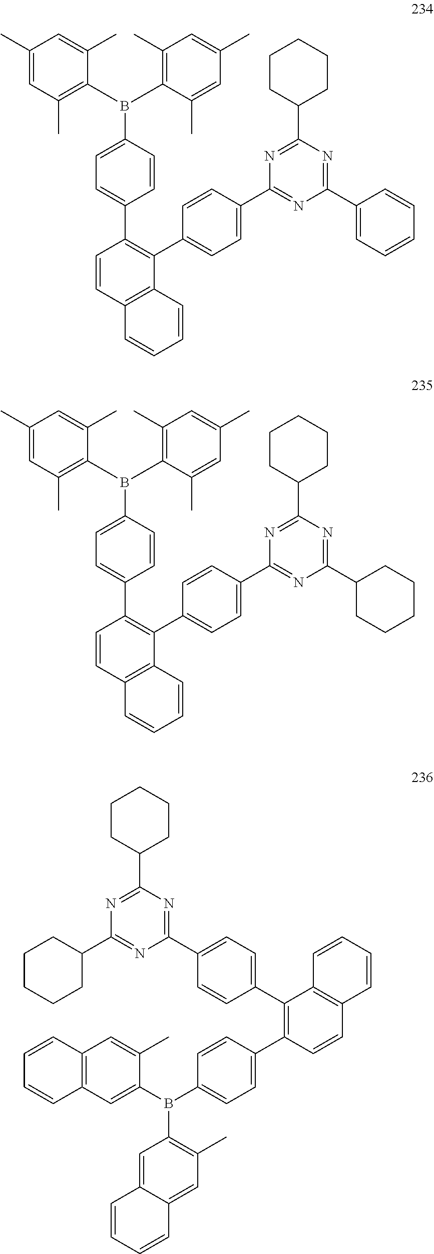 [SMILES: Cc1cc(C)c(B(c2ccc(-c3ccc4ccccc4c3-c3ccc(-c4nc(-c5ccccc5)nc(C5CCCCC5)n4)cc3)cc2)c2c(C)cc(C)cc2C)c(C)c1 ; Cc1cc(C)c(B(c2ccc(-c3ccc4ccccc4c3-c3ccc(-c4nc(C5CCCCC5)nc(C5CCCCC5)n4)cc3)cc2)c2c(C)cc(C)cc2C)c(C)c1 ; Cc1cc2ccccc2cc1B(c1ccc(-c2ccc3ccccc3c2-c2ccc(-c3nc(C4CCCCC4)nc(C4CCCCC4)n3)cc2)cc1)c1cc2ccccc2cc1C]

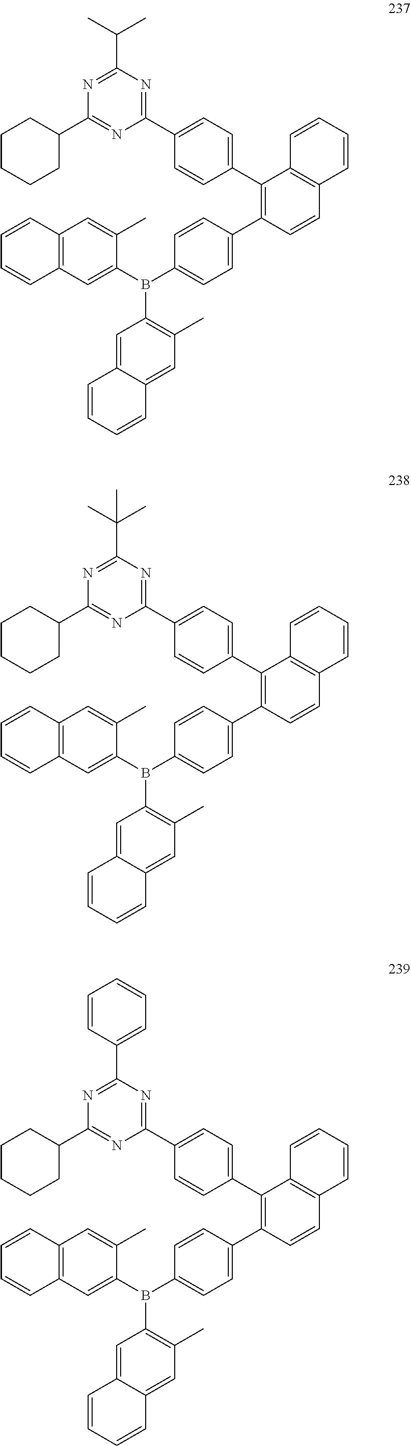 [SMILES: Cc1cc2ccccc2cc1B(c1ccc(-c2ccc3ccccc3c2-c2ccc(-c3nc(C(C)C)nc(C4CCCCC4)n3)cc2)cc1)c1cc2ccccc2cc1C ; Cc1cc2ccccc2cc1B(c1ccc(-c2ccc3ccccc3c2-c2ccc(-c3nc(C4CCCCC4)nc(C(C)(C)C)n3)cc2)cc1)c1cc2ccccc2cc1C ; Cc1cc2ccccc2cc1B(c1ccc(-c2ccc3ccccc3c2-c2ccc(-c3nc(-c4ccccc4)nc(C4CCCCC4)n3)cc2)cc1)c1cc2ccccc2cc1C]

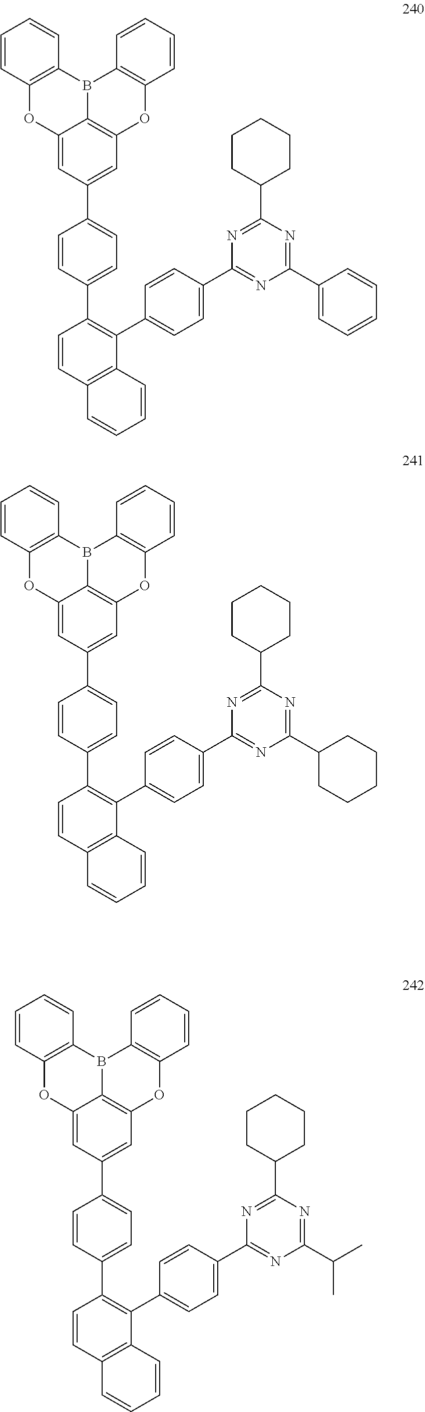 [SMILES: c1ccc(-c2nc(-c3ccc(-c4c(-c5ccc(-c6cc7c8c(c6)Oc6ccccc6B8c6ccccc6O7)cc5)ccc5ccccc45)cc3)nc(C3CCCCC3)n2)cc1 ; c1ccc2c(c1)Oc1cc(-c3ccc(-c4ccc5ccccc5c4-c4ccc(-c5nc(C6CCCCC6)nc(C6CCCCC6)n5)cc4)cc3)cc3c1B2c1ccccc1O3 ; CC(C)c1nc(-c2ccc(-c3c(-c4ccc(-c5cc6c7c(c5)Oc5ccccc5B7c5ccccc5O6)cc4)ccc4ccccc34)cc2)nc(C2CCCCC2)n1]

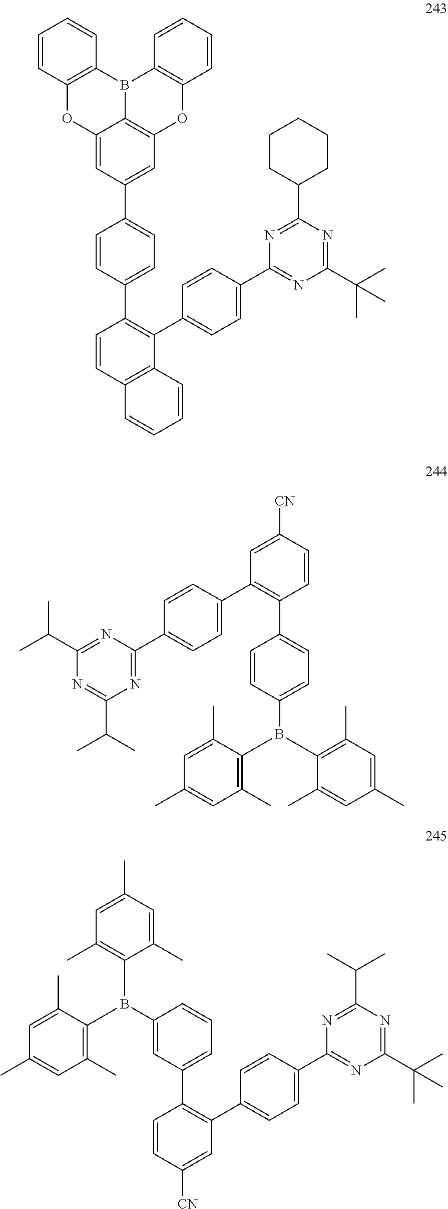

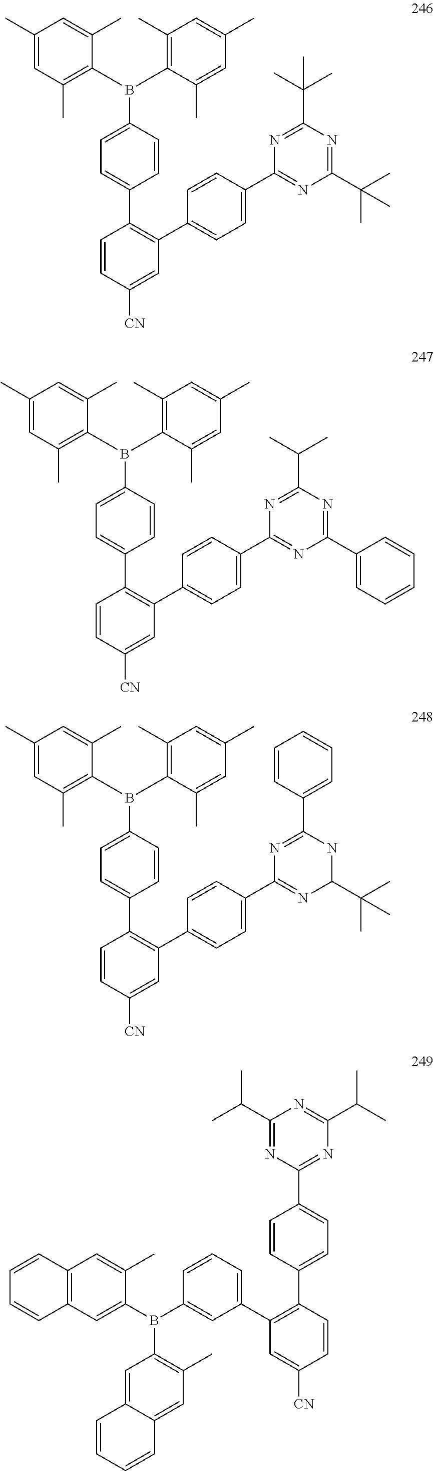

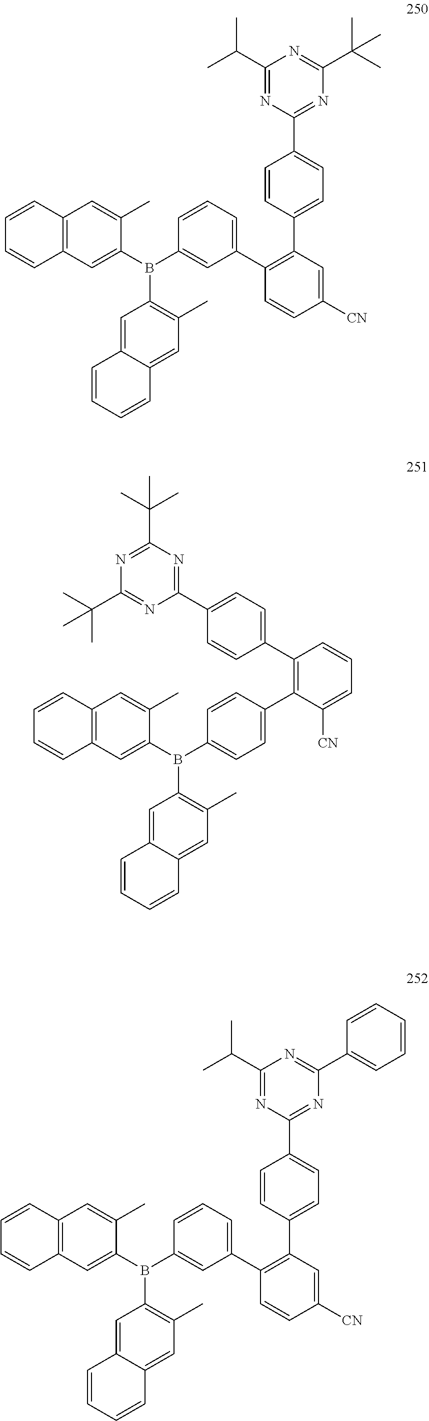 [SMILES: Cc1cc2ccccc2cc1B(c1cccc(-c2ccc(C#N)cc2-c2ccc(-c3nc(C(C)C)nc(C(C)(C)C)n3)cc2)c1)c1cc2ccccc2cc1C ; Cc1cc2ccccc2cc1B(c1ccc(-c2c(C#N)cccc2-c2ccc(-c3nc(C(C)(C)C)nc(C(C)(C)C)n3)cc2)cc1)c1cc2ccccc2cc1C ; Cc1cc2ccccc2cc1B(c1cccc(-c2ccc(C#N)cc2-c2ccc(-c3nc(-c4ccccc4)nc(C(C)C)n3)cc2)c1)c1cc2ccccc2cc1C]

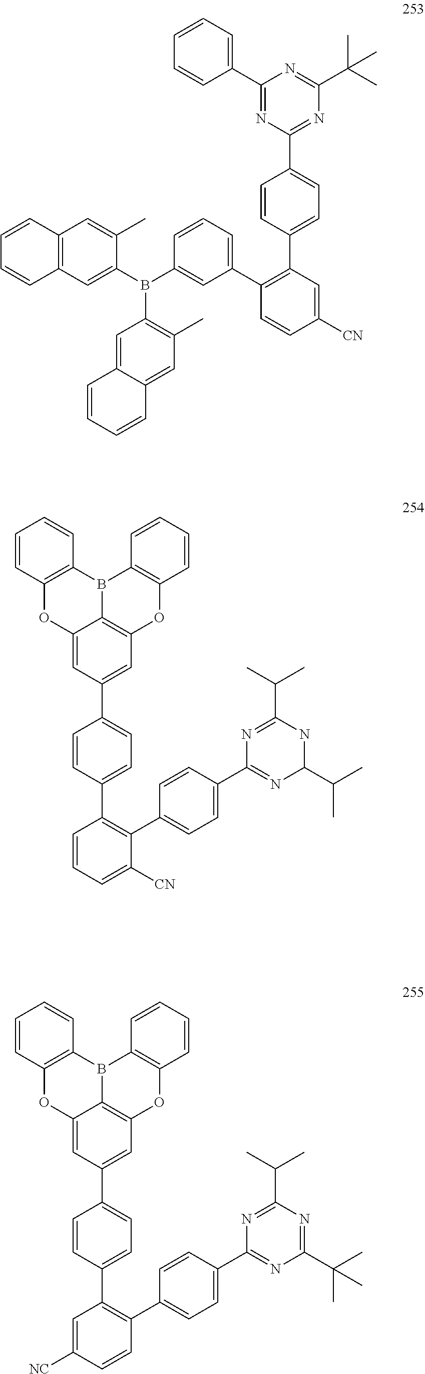

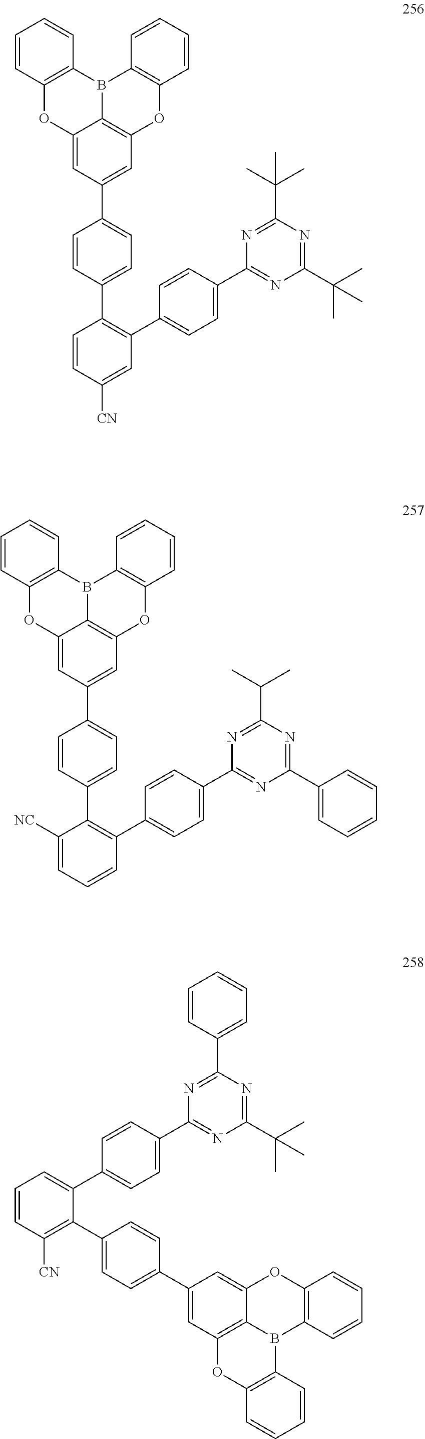 [SMILES: CC(C)(C)c1nc(-c2ccc(-c3cc(C#N)ccc3-c3ccc(-c4cc5c6c(c4)Oc4ccccc4B6c4ccccc4O5)cc3)cc2)nc(C(C)(C)C)n1 ; CC(C)c1nc(-c2ccccc2)nc(-c2ccc(-c3cccc(C#N)c3-c3ccc(-c4cc5c6c(c4)Oc4ccccc4B6c4ccccc4O5)cc3)cc2)n1 ; CC(C)(C)c1nc(-c2ccccc2)nc(-c2ccc(-c3cccc(C#N)c3-c3ccc(-c4cc5c6c(c4)Oc4ccccc4B6c4ccccc4O5)cc3)cc2)n1]

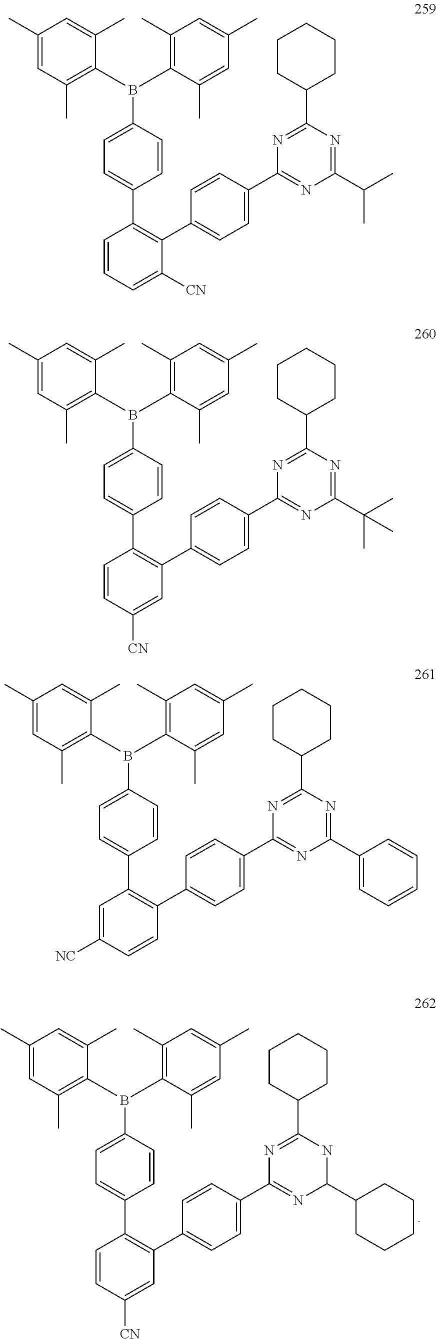

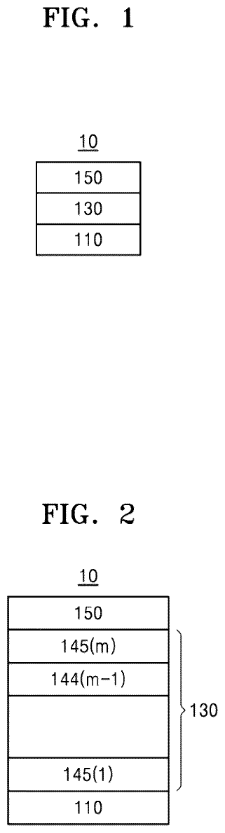

### Description of FIG. 1

FIG. 1 is a schematic cross-sectional view of a light-emitting device 10 according to one or more embodiments of the present disclosure. The light-emitting device 10 may include a first electrode 110, an interlayer 130, and a second electrode 150.

Hereinafter, the structure of the light-emitting device 10 according to one or more embodiments and a method of manufacturing the light-emitting device 10 will be described in more detail with reference to FIG. 1.

### First Electrode 110

In FIG. 1, in one or more embodiments, a substrate may be additionally provided and arranged under the first electrode 110 and/or on the second electrode 150. As the substrate, a glass substrate or a plastic substrate may be used. In one or more embodiments, the substrate may be a flexible substrate, and may include plastics with excellent or suitable heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, depositing or sputtering a material for forming the first electrode 110 on the substrate. When the first electrode 110 is an anode, a material for forming the first electrode 110 may be a high-work function material that facilitates injection of holes.

The first electrode 110 may be a reflective electrode, a transflective electrode, or a transmissive electrode. In one or more embodiments, if (e.g., when) the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In one or more embodiments, if (e.g., when) the first electrode 110 is a transflective electrode or a reflective electrode, a material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a single-layered structure including (e.g., consisting of) a single layer or a multi-layered structure including a plurality of layers. For example, in some embodiments, the first electrode 110 may have a three-layered structure of ITO/Ag/ITO.

### Interlayer 130

The interlayer 130 may be arranged on the first electrode 110. The interlayer 130 may include an emission layer.

In one or more embodiments, the interlayer 130 may further include a hole transport region between the first electrode 110 and the emission layer, and an electron transport region between the emission layer and the second electrode 150.

In one or more embodiments, the interlayer 130 may further include, in addition to one or more suitable organic materials, for example, the compound represented by Formula 1, a metal-containing compound such as an organometallic compound, an inorganic material such as quantum dots, and/or the like.

In one or more embodiments, the interlayer 130 may include i) two or more emitting units sequentially stacked between the first electrode 110 and the second electrode 150, and ii) a charge generation layer arranged between the two or more emitting units. When the interlayer 130 includes the two or more emitting units and the charge generation layer as described above, the light-emitting device 10 may be a tandem light-emitting device.

### Hole Transport Region in Interlayer 130

The hole transport region may have: i) a single-layered structure including (e.g., consisting of) a single layer including (e.g., consisting of) a single material, ii) a single-layered structure including (e.g., consisting of) a single layer including (e.g., consisting of) a plurality of different materials, or iii) a multi-layered structure including a plurality of layers including different materials.

The hole transport region may include a hole injection layer, a hole transport layer, an emission auxiliary layer, an electron blocking layer, or any combination thereof.

For example, in one or more embodiments, the hole transport region may have a multi-layered structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, the constituent layers of each structure being stacked sequentially from the first electrode 110 in the stated order.

For example, in one or more embodiments, the hole transport region may have a multi-layered structure of hole transport layer/emission auxiliary layer, or hole transport layer/electron blocking layer, which are sequentially stacked in this stated order from the first electrode 110.

In one or more embodiments, the hole transport region may include a compound represented by Formula 201, a compound represented by Formula 202, or any combination thereof:

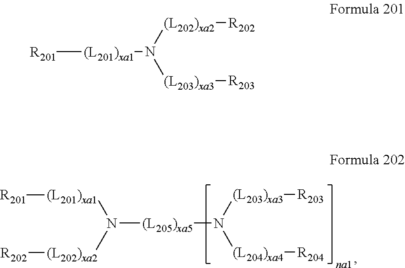

wherein, in Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—**, *—S—**, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group (for example, a carbazole group and/or the like) unsubstituted or substituted with at least one R₁₀ₐ (for example, see Compound HT16 and/or the like),
R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer from 1 to 4.

In one or more embodiments, each of Formulae 201 and 202 may include at least one selected from among groups represented by Formulae CY201 to CY217:

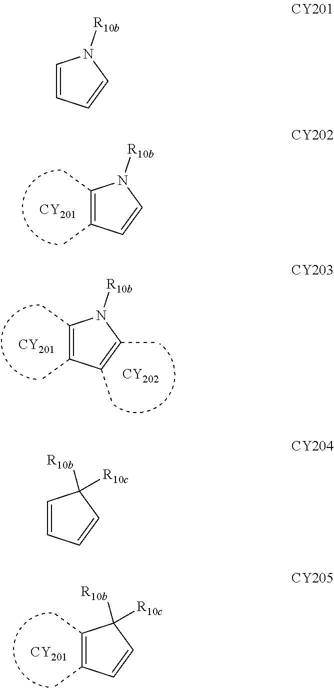

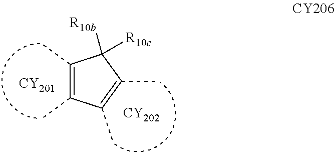

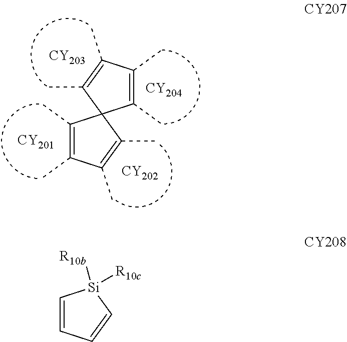

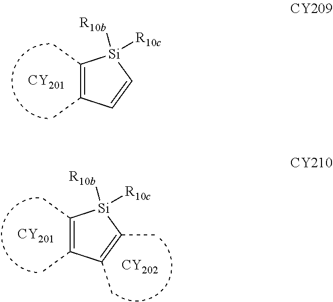

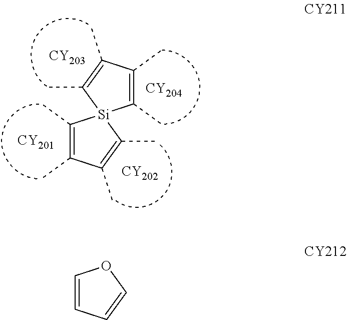

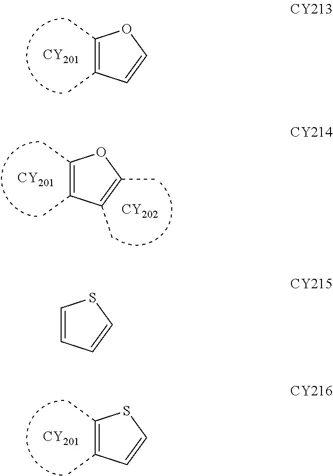

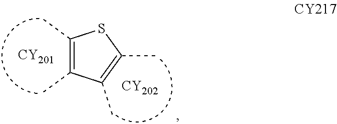

wherein, in Formulae CY201 to CY217, R_{10b} and R_{10c} may each be the same as described herein with respect to R₁₀ₐ, ring CY201 to ring CY204 may each independently be a C₅-C₂₀ carbocyclic group or a C₁-C₂₀ heterocyclic group, and at least one hydrogen in Formulae CY201 to CY217 may be unsubstituted or substituted with R₁₀ₐ as described herein.

According to one or more embodiments, ring CY201 to ring CY204 in Formulae CY201 to CY217 may each independently be a benzene group, a naphthalene group, a phenanthrene group, or an anthracene group.

According to one or more embodiments, each of Formulae 201 and 202 may include at least one selected from among groups represented by Formulae CY201 to CY203.

According to one or more embodiments, Formula 201 may include at least one selected from among the groups represented by Formulae CY201 to CY203 and at least one selected from among the groups represented by Formulae CY204 to CY217.

According to one or more embodiments, in Formula 201, xa1 may be 1, R₂₀₁ may be a group represented by any one selected from among Formulae CY201 to CY203, xa2 may be 0, and R₂₀₂ may be a group represented by any one selected from among Formulae CY204 to CY207.

According to one or more embodiments, each of Formulae 201 and 202 may not include (e.g., may exclude any of) groups represented by Formulae CY201 to CY203.

According to one or more embodiments, each of Formulae 201 and 202 may not include (e.g., may exclude any of) groups represented by Formulae CY201 to CY203, and may include at least one selected from among groups represented by Formulae CY204 to CY217.

In one or more embodiments, each of Formulae 201 and 202 may not include (e.g., may exclude any of) groups represented by Formulae CY201 to CY217.

For example, in one or more embodiments, the hole transport region may include one of (e.g., selected from among) Compounds HT1 to HT46, 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N-(2-naphthyl)-N-phenylamino]-triphenylamine (2-TNATA), N,N′-di(naphthalen-1-yl)-N,N′-diphenyl-benzidine (NPB(NPD)), β-NPB, N,N′-bis(3-methylphenyl)-N,N′-diphenyl-[1,1′-biphenyl]-4,4′-diamine (TPD), Spiro-TPD, Spiro-NPB, methylated NPB, 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or any combination thereof:

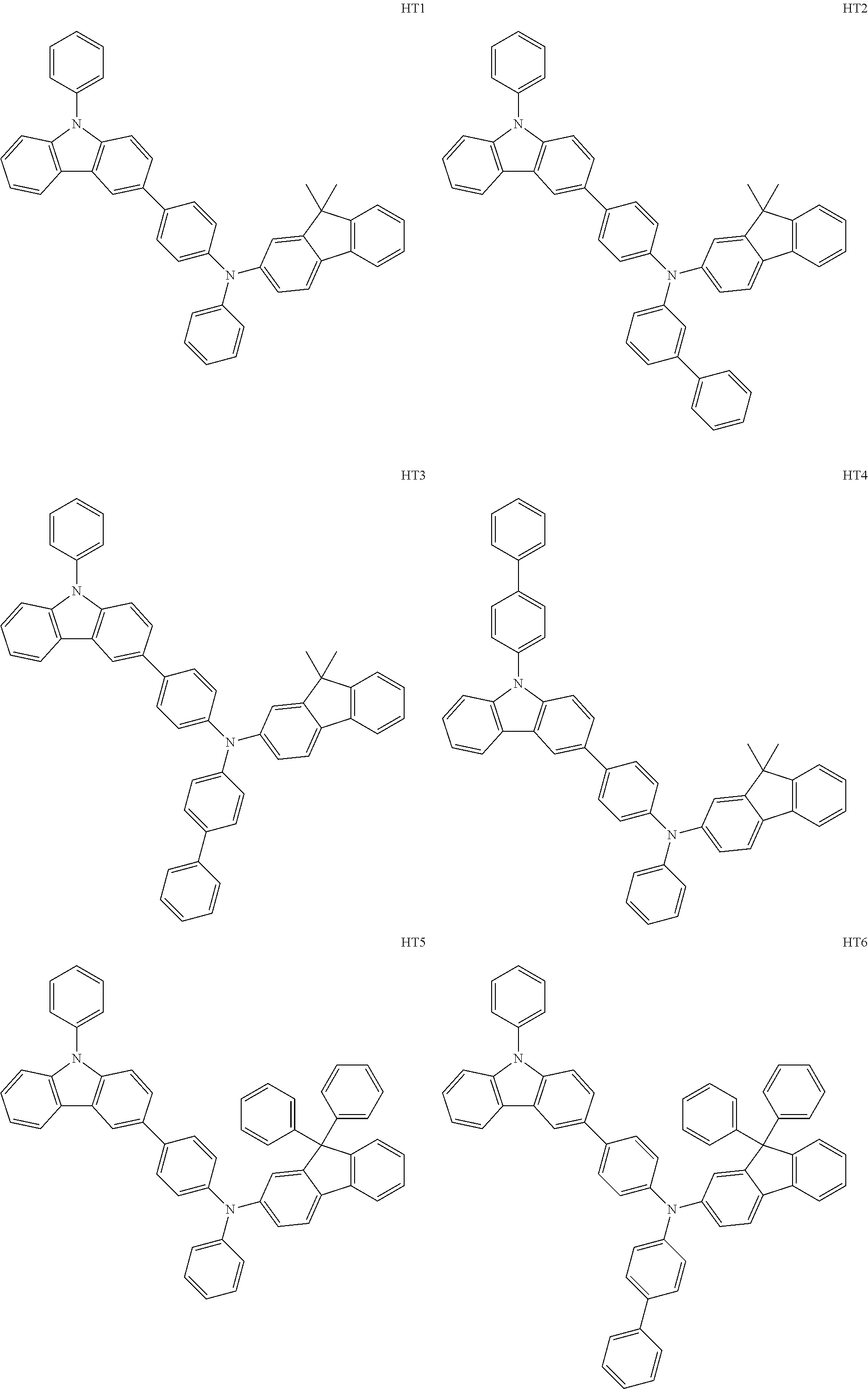

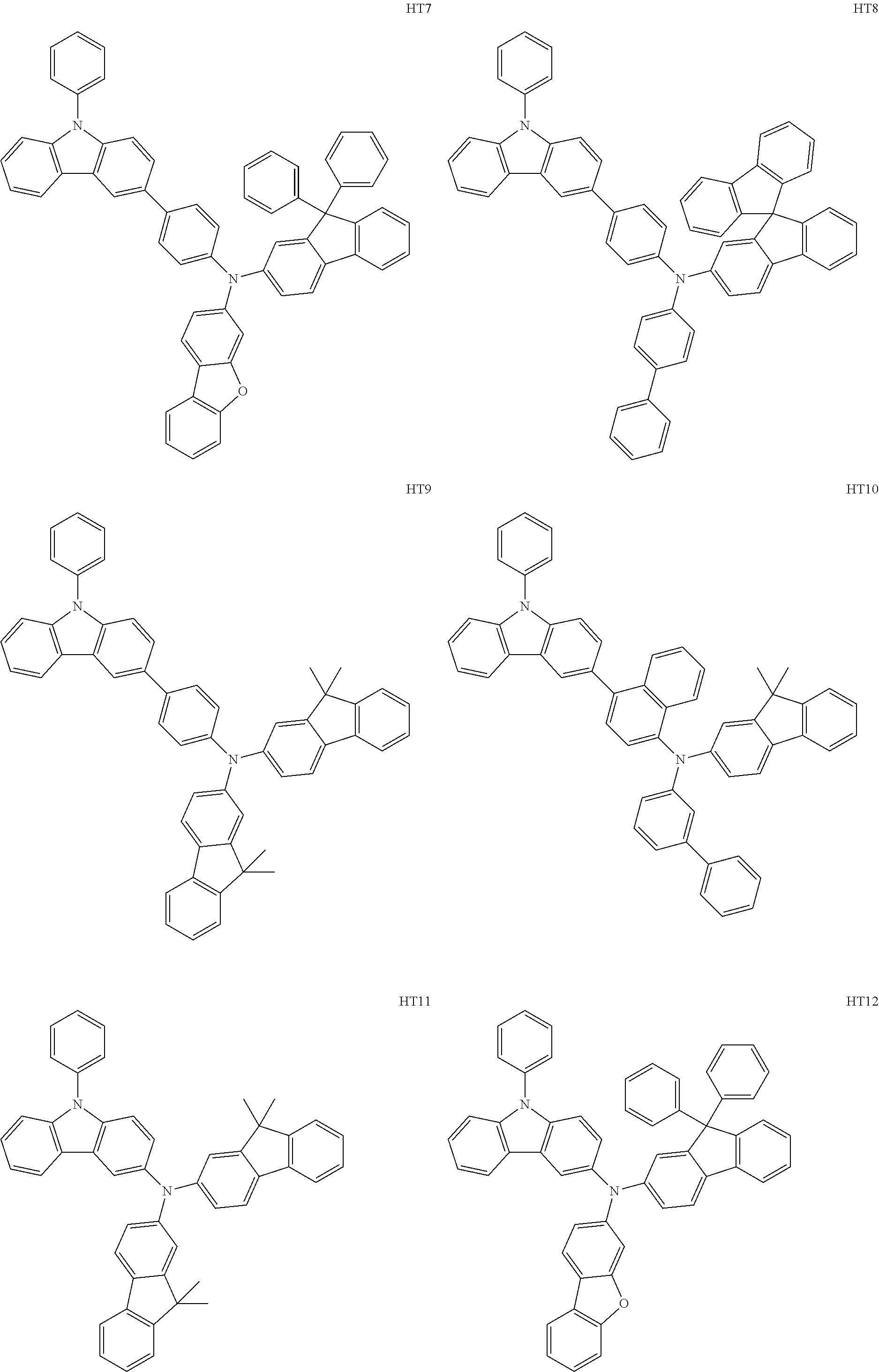

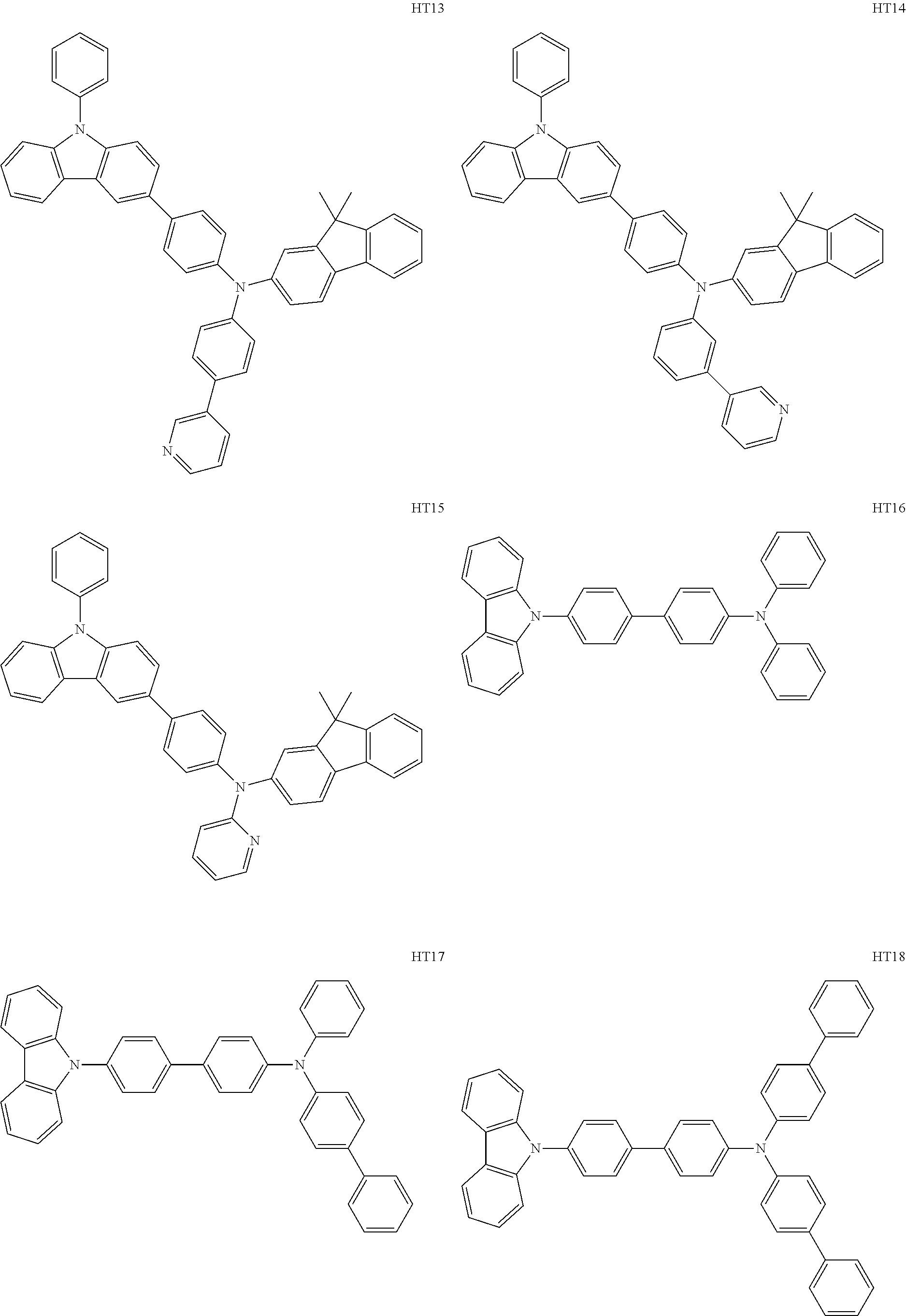 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

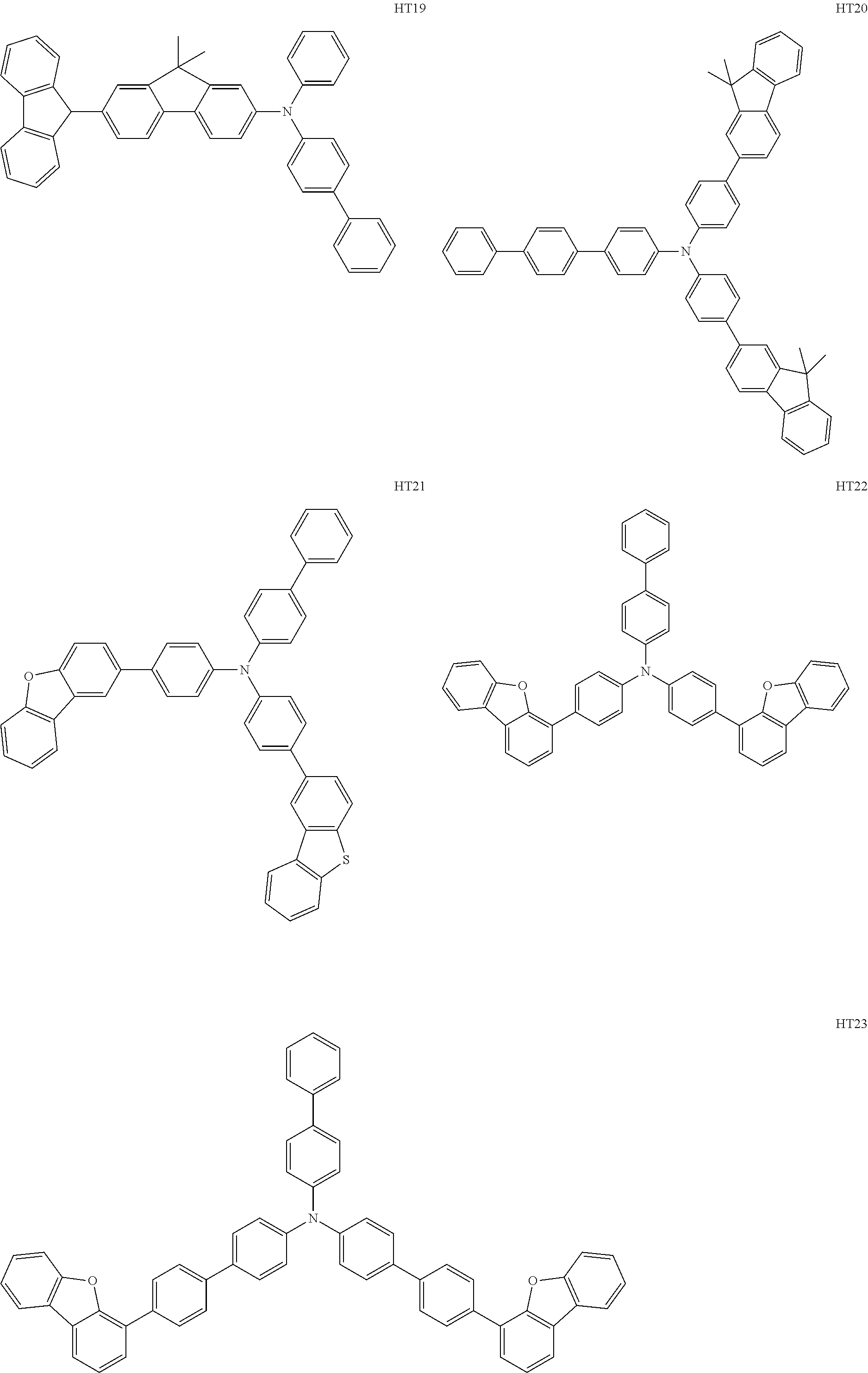 [SMILES: CC1(C)c2cc(C3c4ccccc4-c4ccccc43)ccc2-c2ccc(N(c3ccccc3)c3ccc(-c4ccccc4)cc3)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

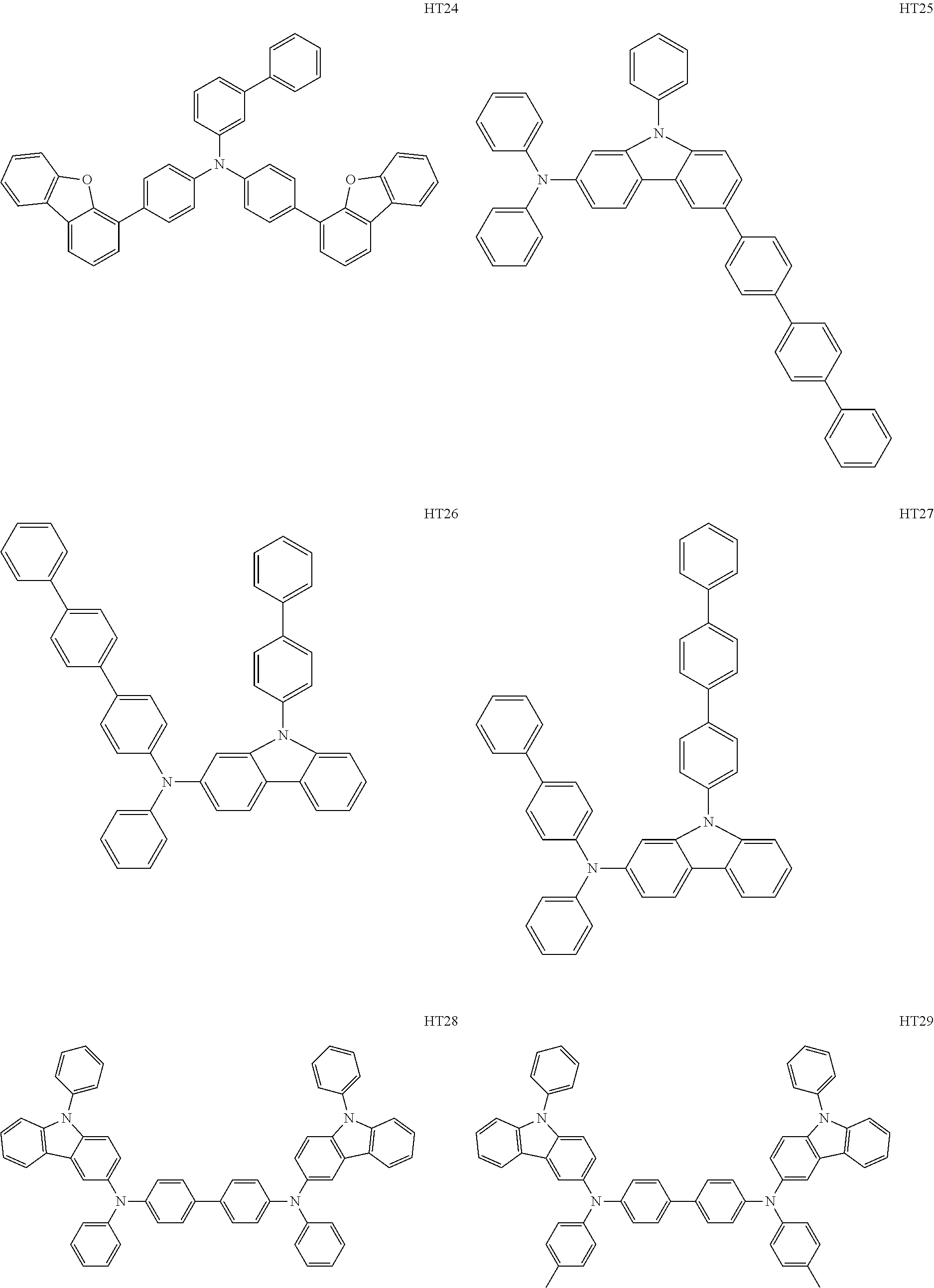

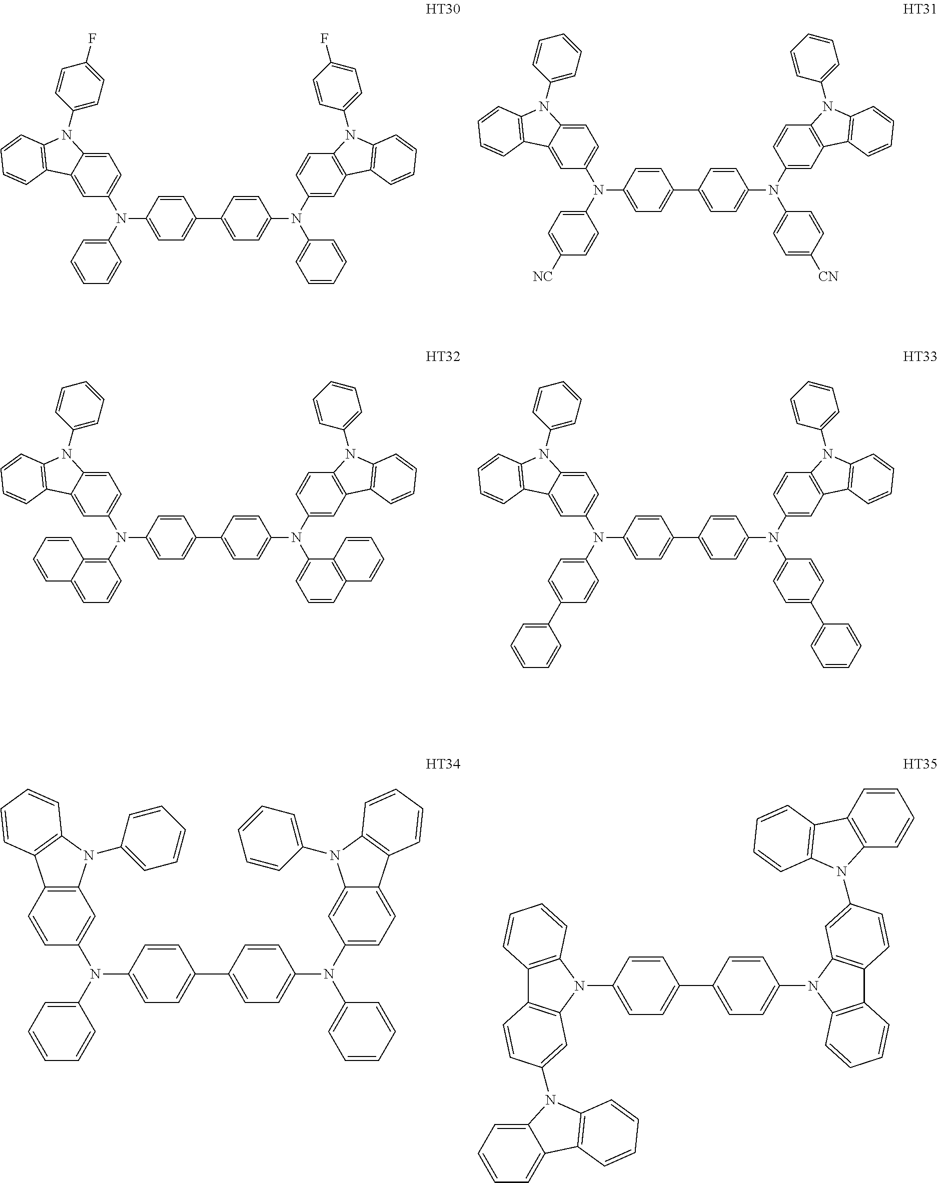

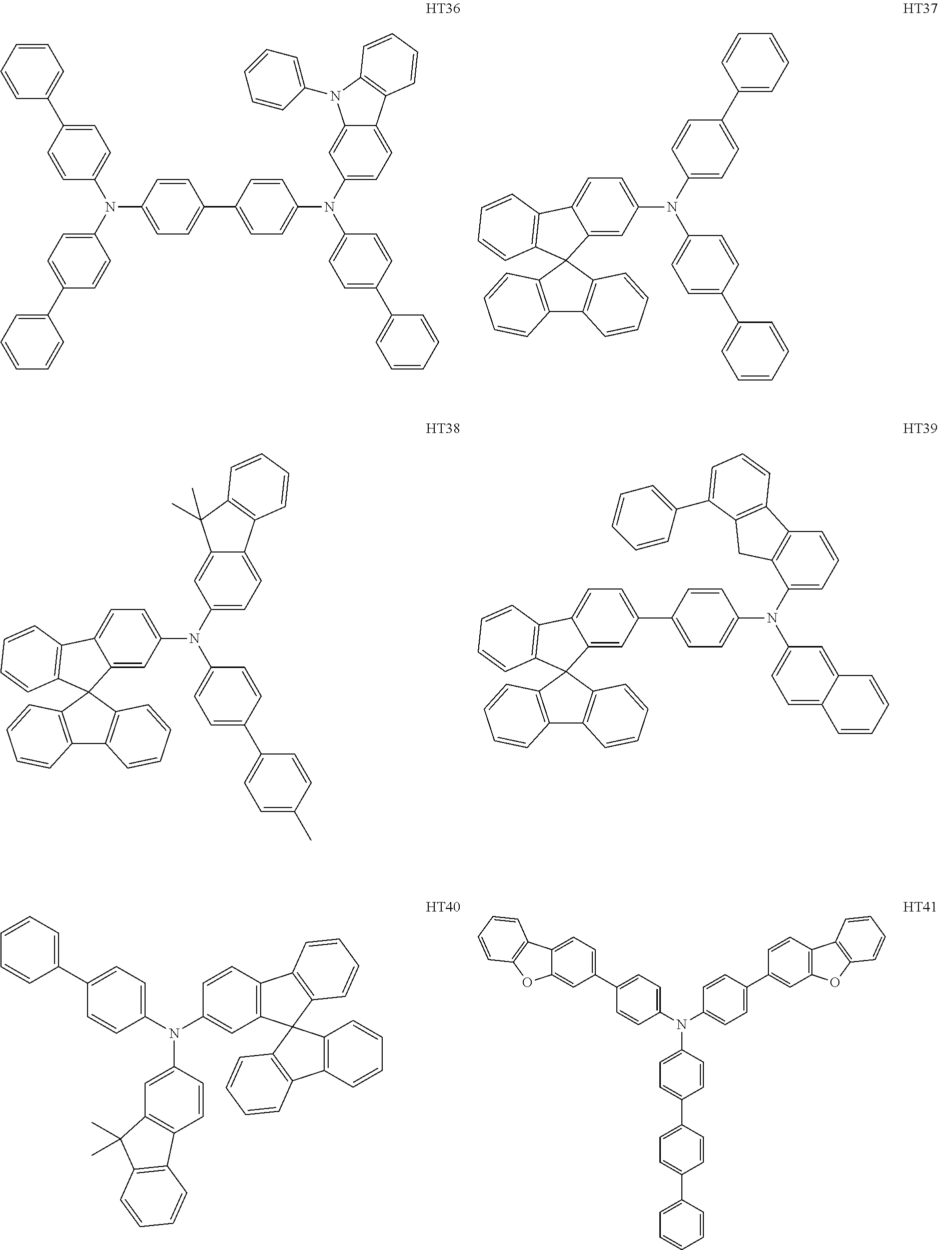

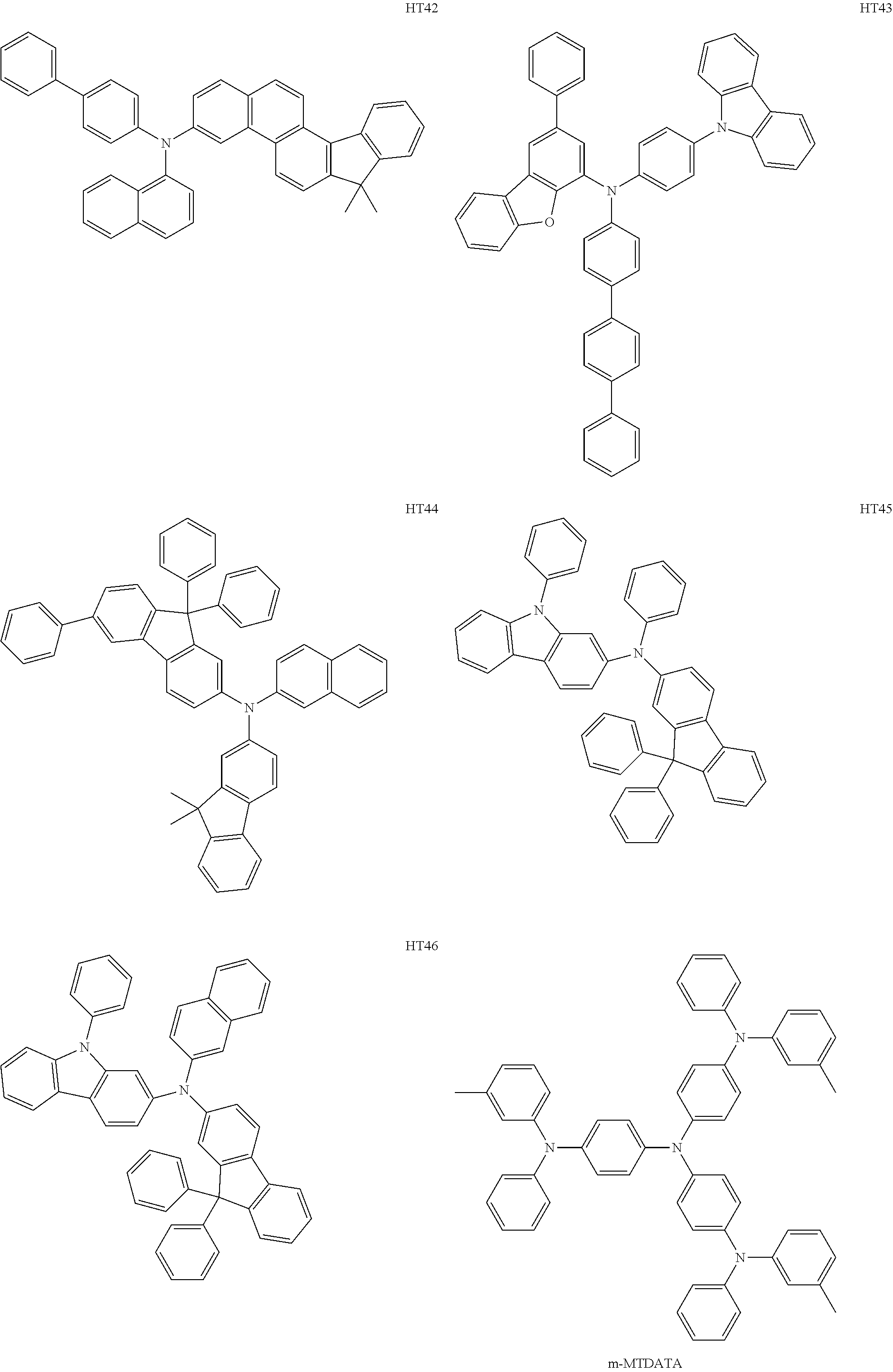

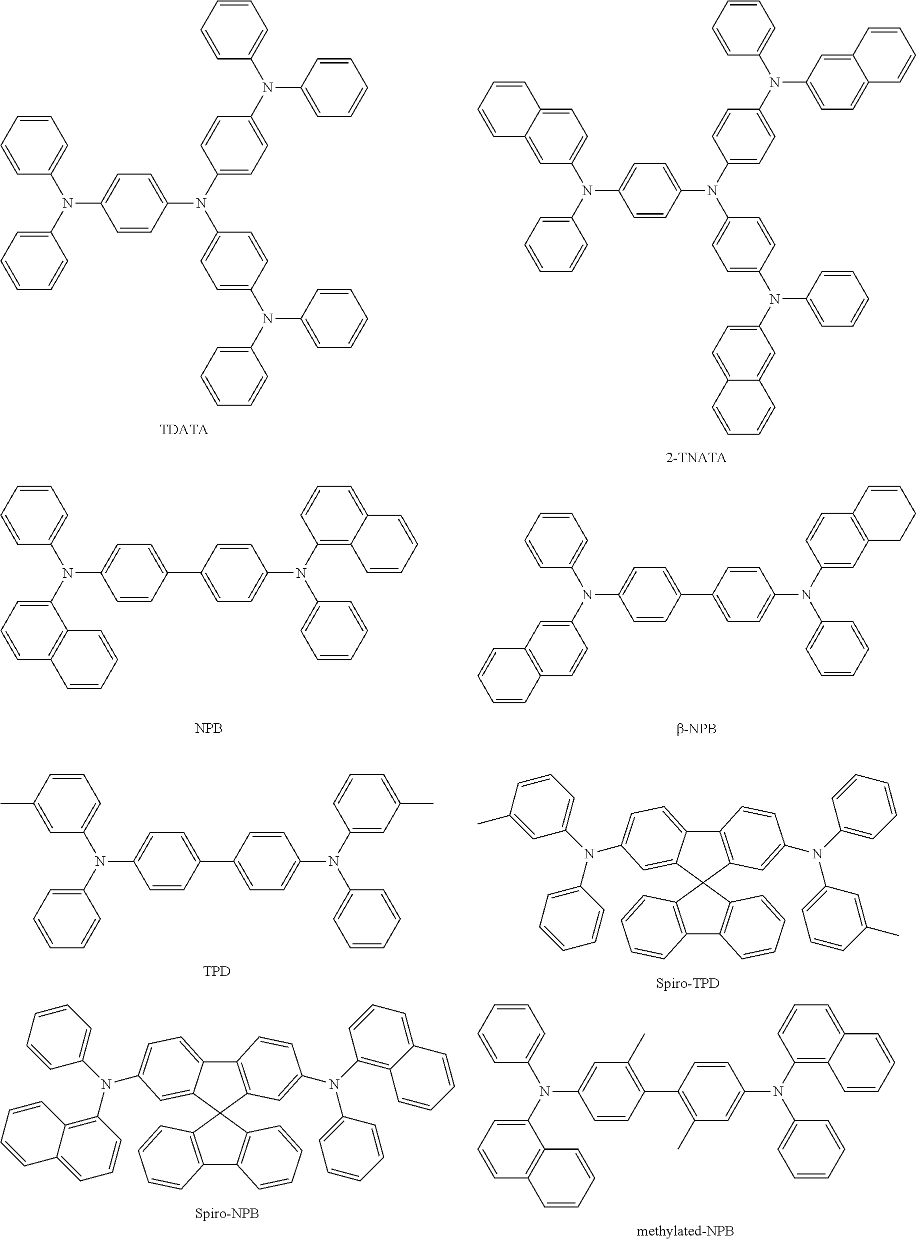

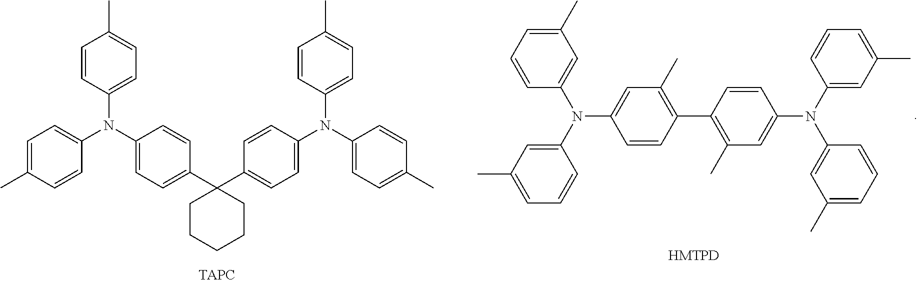

A thickness of the hole transport region may be in a range of about 50 Angstroms (Å) to about 10,000 Å, for example, about 100 Å to about 4,000 Å. When the hole transport region includes a hole transport layer, an electron blocking layer, or any combination thereof, a thickness of the hole transport layer may be about 50 Å to about 2,000 Å, for example, about 100 Å to about 1,500 Å. When the thicknesses of the hole transport region and the hole transport layer are within the ranges described above, satisfactory hole transportation characteristics may be obtained without a substantial increase in driving voltage.

The emission auxiliary layer may increase light-emission efficiency by compensating for an optical resonance distance according to the wavelength of light emitted from the emission layer, and the electron blocking layer may block the leakage of electrons from the emission layer to the hole transport region. Materials that may be included in the hole transport region may be included in the emission auxiliary layer and the electron blocking layer.

p-dopant

In one or more embodiments, the hole transport region may further include, in addition to one or more of the materials described above, a charge-generation material for the improvement of conductive properties. The charge-generation material may be uniformly (e.g., substantially uniformly) or non-uniformly dispersed in the hole transport region (for example, in the form of a single layer including (e.g., consisting of) a charge-generation material).

The charge-generation material may be, for example, a p-dopant.

For example, the lowest unoccupied molecular orbital (LUMO) energy level of the p-dopant may be −3.5 eV or less.

According to one or more embodiments, the p-dopant may include a quinone derivative, a cyano group-containing compound, a compound including element EL1 and element EL2, or any combination thereof.

Non-limiting examples of the quinone derivative may include tetracyanoquinodimethane (TCNQ), 2,3,5,6-tetrafluoro-7,7,8,8-tetracyanoquinodimethane (F₄-TCNQ), and/or the like.

Non-limiting examples of the cyano group-containing compound may include dipyrazino[2,3-f: 2′,3′-h] quinoxaline-2,3,6,7,10,11-hexacarbonitrile (HAT-CN), a compound represented by Formula 221, and/or the like:

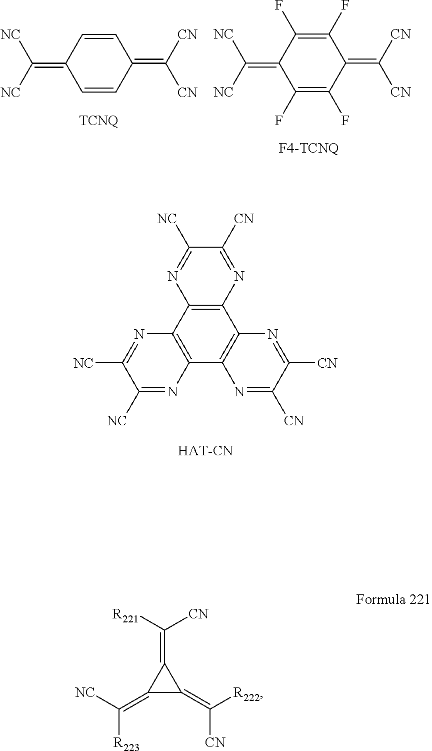

wherein, in Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one selected from among R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group that is substituted with a cyano group, —F, —Cl, —Br, —I, or any combination thereof; or any combination thereof.

In the compound including element EL1 and element EL2, element EL1 may be a metal, a metalloid, or any combination thereof, and element EL2 may be a non-metal, a metalloid, or any combination thereof.

Non-limiting examples of the metal may include: an alkali metal (for example, lithium (Li), sodium (Na), potassium (K), rubidium (Rb), cesium (Cs), and/or the like); an alkaline earth metal (for example, beryllium (Be), magnesium (Mg), calcium (Ca), strontium (Sr), barium (Ba), and/or the like); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), and/or the like); a post-transition metal (for example, zinc (Zn), indium (In), tin (Sn), and/or the like); a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and/or the like); and/or the like.

Non-limiting examples of the metalloid may include silicon (Si), antimony (Sb), tellurium (Te), and/or the like.

Non-limiting examples of the non-metal may include oxygen (O), a halogen (for example, F, Cl, Br, I, and/or the like), and/or the like.

The compound including element EL1 and element EL2 may include metal oxides, metal halides (for example, metal fluorides, metal chlorides, metal bromides, metal iodides, and/or the like), metalloid halides (for example, metalloid fluorides, metalloid chlorides, metalloid bromides, metalloid iodides, and/or the like), metal tellurides, or any combination thereof.

Non-limiting examples of the metal oxide may include tungsten oxides (for example, WO, W₂O₃, WO₂, WO₃, W₂O₅, and/or the like), vanadium oxides (for example, VO, V₂O₃, VO₂, V₂O₅, and/or the like), molybdenum oxides (MoO, Mo₂O₃, MoO₂, MoO₃, Mo₂O₅, and/or the like), rhenium oxides (for example, ReO₃, and/or the like), and/or the like.

Non-limiting examples of the metal halide may include alkali metal halides, alkaline earth metal halides, transition metal halides, post-transition metal halides, lanthanide metal halides, and/or the like.

Non-limiting examples of the alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, CsI, and/or the like.

Non-limiting examples of the alkaline earth metal halide may include BeF₂, MgF₂, CaF₂, SrF₂, BaF₂, BeCl₂, MgCl₂, CaCl₂, SrCl₂, BaCl₂, BeBr₂, MgBr₂, CaBr₂, SrBr₂, BaBr₂, BeI₂, MgI₂, CaI₂, SrI₂, BaI₂, and/or the like.

Non-limiting examples of the transition metal halide may include titanium halides (for example, TiF₄, TiCl₄, TiBr₄, TiI₄, and/or the like), zirconium halides (for example, ZrF₄, ZrCl₄, ZrBr₄, ZrI₄, and/or the like), hafnium halides (for example, HfF₄, HfCl₄, HfBr₄, HfI₄, and/or the like), vanadium halides (for example, VF₃, VCl₃, VBr₃, VI₃, and/or the like), niobium halides (for example, NbF₃, NbCl₃, NbBr₃, NbI₃, and/or the like), tantalum halides (for example, TaF₃, TaCl₃, TaBr₃, TaI₃, and/or the like), chromium halides (for example, CrF₃, CrCl₃, CrBr₃, CrI₃, and/or the like), molybdenum halides (for example, MoF₃, MoCl₃, MoBr₃, MoI₃, and/or the like), tungsten halides (for example, WF₃, WCl₃, WBr₃, WI₃, and/or the like), manganese halides (for example, MnF₂, MnCl₂, MnBr₂, MnI₂, and/or the like), technetium halides (for example, TcF₂, TcCl₂, TcBr₂, TcI₂, and/or the like), rhenium halides (for example, ReF₂, ReCl₂, ReBr₂, ReI₂, and/or the like), iron (II) halides (for example, FeF₂, FeCl₂, FeBr₂, FeI₂, and/or the like), ruthenium halides (for example, RuF₂, RuCl₂, RuBr₂, RuI₂, and/or the like), osmium halides (for example, OsF₂, OsCl₂, OsBr₂, OsI₂, and/or the like), cobalt halides (for example, CoF₂, CoCl₂, CoBr₂, CoI₂, and/or the like), rhodium halides (for example, RhF₂, RhCl₂, RhBr₂, RhI₂, and/or the like), iridium halides (for example, IrF₂, IrCl₂, IrBr₂, IrI₂, and/or the like), nickel halides (for example, NiF₂, NiCl₂, NiBr₂, NiI₂, and/or the like), palladium halides (for example, PdF₂, PdCl₂, PdBr₂, PdI₂, and/or the like), platinum halides (for example, PtF₂, PtCl₂, PtBr₂, PtI₂, and/or the like), copper (I) halides (for example, CuF, CuCl, CuBr, CuI, and/or the like), silver halides (for example, AgF, AgCl, AgBr, AgI, and/or the like), gold halides (for example, AuF, AuCl, AuBr, AuI, and/or the like), and/or the like.

Non-limiting examples of the post-transition metal halide may include zinc halides (for example, ZnF₂, ZnCl₂, ZnBr₂, ZnI₂, and/or the like), indium halides (for example, InI₃, and/or the like), tin halides (for example, SnI₂, and/or the like), and/or the like.

Non-limiting examples of the lanthanide metal halide may include YbF, YbF₂, YbF₃, SmF₃, YbCl, YbCl₂, YbCl₃, SmCl₃, YbBr, YbBr₂, YbBr₃, SmBr₃, YbI, YbI₂, YbI₃, SmI₃, and/or the like.

Non-limiting examples of the metalloid halide may include antimony halides (for example, SbCl₅, and/or the like) and/or the like.

Non-limiting examples of the metal telluride may include alkali metal tellurides (for example, Li₂Te, Na₂Te, K₂Te, Rb₂Te, Cs₂Te, and/or the like), alkaline earth metal tellurides (for example, BeTe, MgTe, CaTe, SrTe, BaTe, and/or the like), transition metal tellurides (for example, TiTe₂, ZrTe₂, HfTe₂, V₂Te₃, Nb₂Te₃, Ta₂Te₃, Cr₂Te₃, Mo₂Te₃, W₂Te₃, MnTe, ToTe, ReTe, FeTe, RuTe, OsTe, CoTe, RhTe, IrTe, NiTe, PdTe, PtTe, Cu₂Te, CuTe, Ag₂Te, AgTe, Au₂Te, and/or the like), post-transition metal tellurides (for example, ZnTe, and/or the like), lanthanide metal tellurides (for example, LaTe, CeTe, PrTe, NdTe, PmTe, EuTe, GdTe, TbTe, DyTe, HoTe, ErTe, TmTe, YbTe, LuTe, and/or the like), and/or the like.

### Emission Layer in Interlayer 130

When the light-emitting device 10 is a full-color light-emitting device, the emission layer may be patterned into a red emission layer, a green emission layer, and/or a blue emission layer, according to a subpixel. In one or more embodiments, the emission layer may have a stacked structure of two or more layers selected from among a red emission layer, a green emission layer, and a blue emission layer, in which the two or more layers contact each other or are separated from each other, to emit white light (e.g., combined white light). In one or more embodiments, the emission layer may include two or more materials selected from among a red light-emitting material, a green light-emitting material, and a blue light-emitting material, in which the two or more materials are mixed with each other in a single layer, to emit white light (e.g., combined white light).

The emission layer may include a host and a dopant. The host may include the first host and the second host described above. The dopant may include the first dopant and the second dopant described above. For example, the first dopant may include a phosphorescent dopant, and the second dopant may include a delayed fluorescence dopant.

A content (e.g., amount) of total dopants in the emission layer may be about 0.01 parts by weight to about 15 parts by weight based on 100 parts by weight of the total hosts.

In one or more embodiments, the emission layer may include a delayed fluorescence material. The delayed fluorescence material may act as a host or a dopant in the emission layer.

A thickness of the emission layer may be in a range of about 100 Å to about 1,000 Å, for example, about 200 Å to about 600 Å. For example, if (e.g., when) the interlayer includes m emission layers, and m is an integer of 2 or more, the thickness of each emission layer may be about 50 Å to about 500 Å. When the thickness of the emission layer is within the ranges described above, excellent or suitable luminescence characteristics may be obtained without a substantial increase in driving voltage.

### Host in Emission Layer

In one or more embodiments, the host may include the first host and the second host described above.

In one or more embodiments, the first host and/or the second host may each independently include a compound represented by Formula 301:

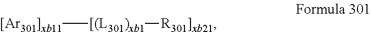

wherein, in Formula 301,
Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to Q₃₀₃ may each independently be the same as described herein with respect to Q₁.

In one or more embodiments, if (e.g., when)_{xb11} in Formula 301 is 2 or more, two or more of Ar₃₀₁(s) may be linked to each other via a single bond.

In one or more embodiments, the first host and/or the second host may each independently include a compound represented by Formula 301-1, a compound represented by Formula 301-2, or any combination thereof:

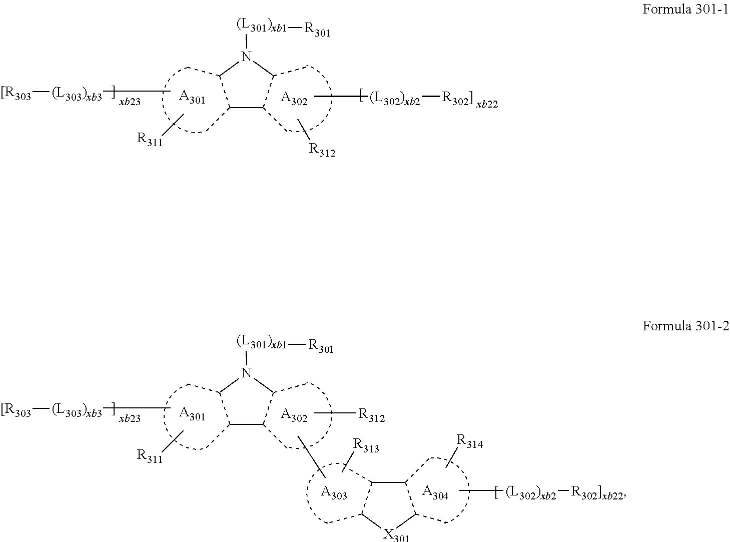

wherein, in Formulae 301-1 and 301-2,
ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ may each be the same as described herein,
L₃₀₂ to L₃₀₄ may each independently be the same as described herein with respect to with L₃₀₁,
xb2 to xb4 may each independently be the same as described herein with respect to xb1, and
R₃₀₂ to R₃₀₅ and R₃₁₁ to R₃₁₄ may each be the same as described herein with respect to R₃₀₁.

In one or more embodiments, the first host and/or the second host may each independently include an alkaline earth metal complex, a post-transition metal complex, or any combination thereof. For example, in some embodiments, the host may include a Be complex (for example, Compound H55), an Mg complex, a Zn complex, or any combination thereof.

In one or more embodiments, the first host and/or the second host may each independently include at least one of (e.g., selected from among) Compounds H1 to H128, HT-1 to HT-4, ET-1 to ET-3, 9,10-di(2-naphthyl)anthracene (AND), 2-methyl-9,10-bis(naphthalen-2-yl)anthracene (MADN), 9,10-di-(2-naphthyl)-2-t-butyl-anthracene (TBADN), 4,4′-bis(N-carbazolyl)-1,1′-biphenyl (CBP), 1,3-di(9H-carbazol-9-yl)benzene (mCP), 1,3,5-tri (carbazol-9-yl)benzene (TCP), or any combination thereof:

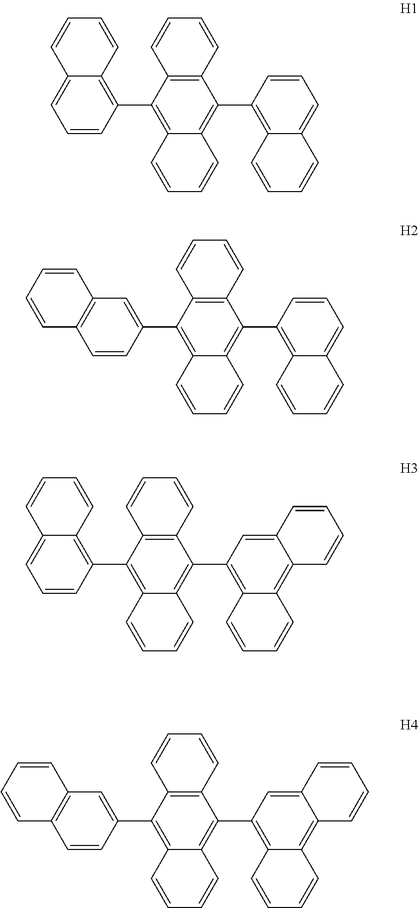

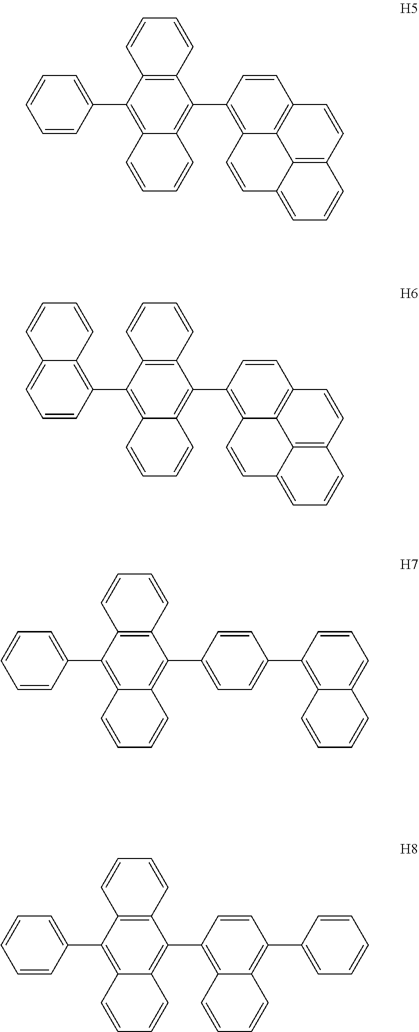

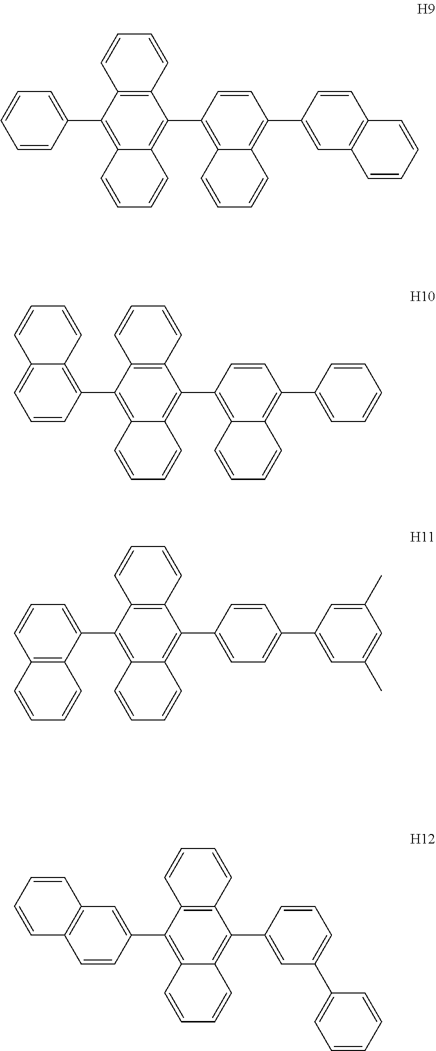

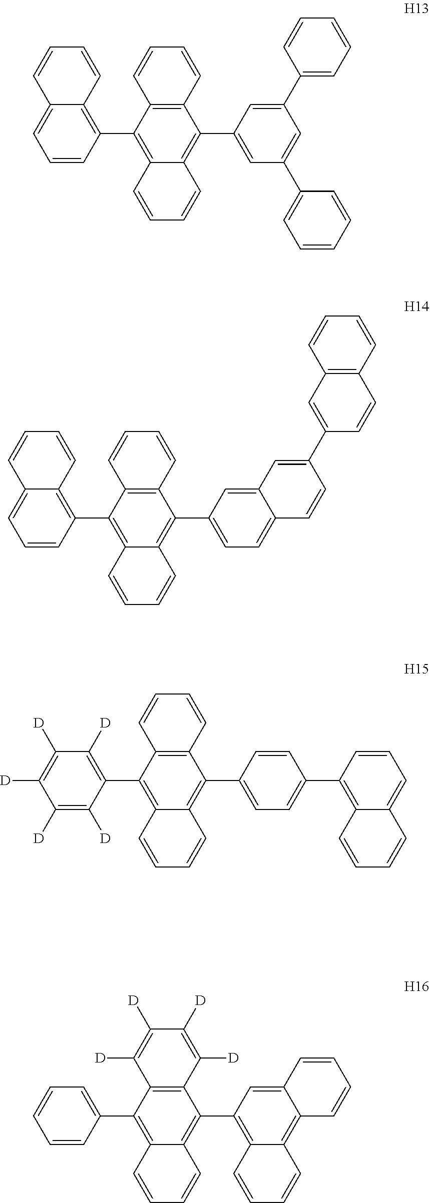

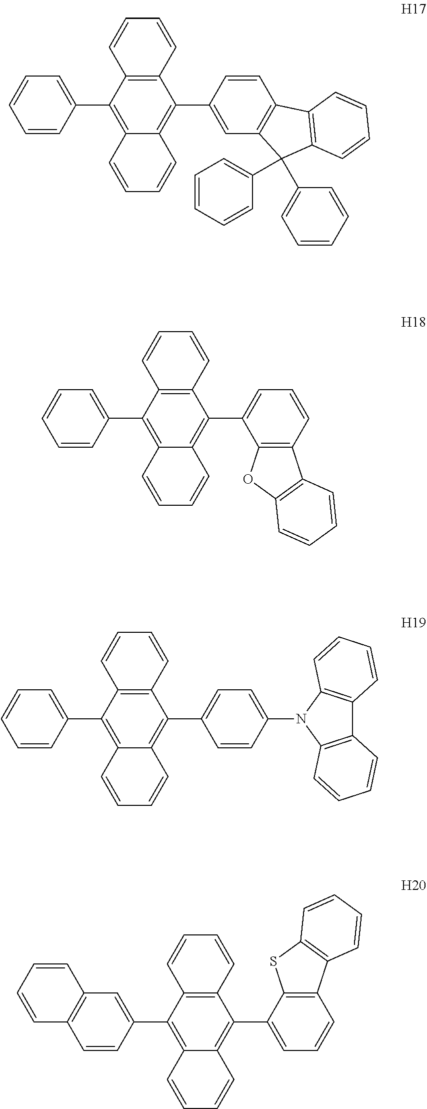

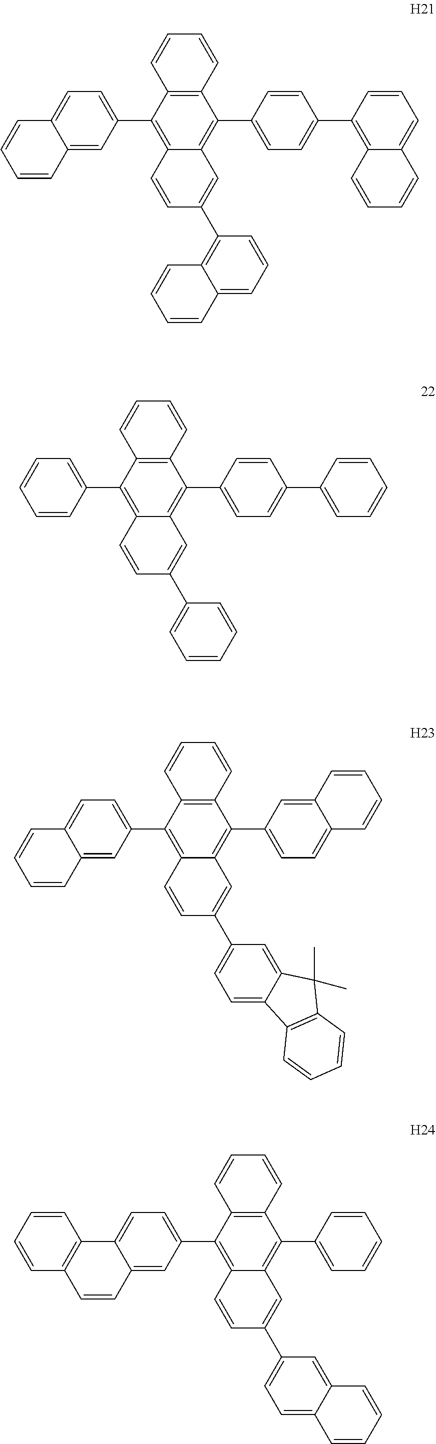

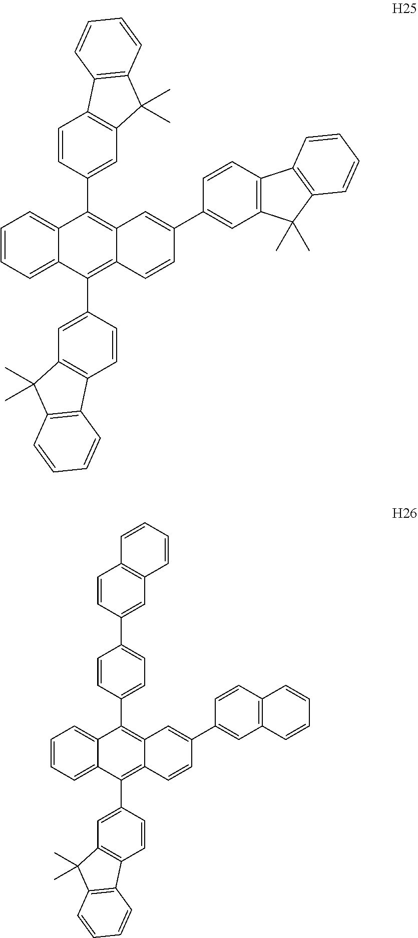

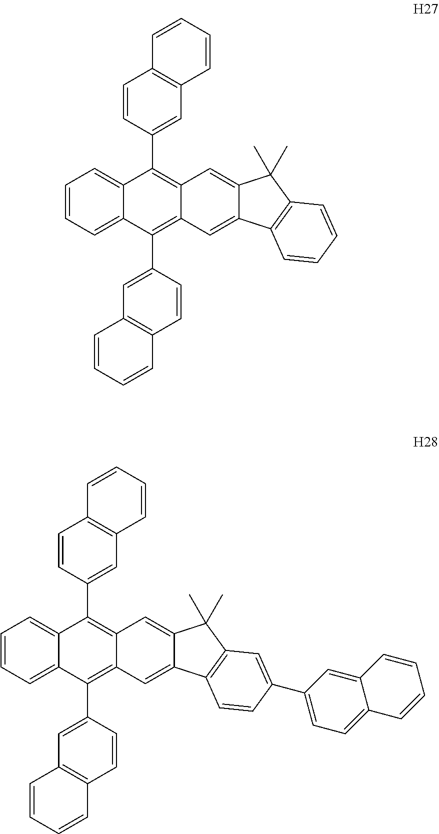

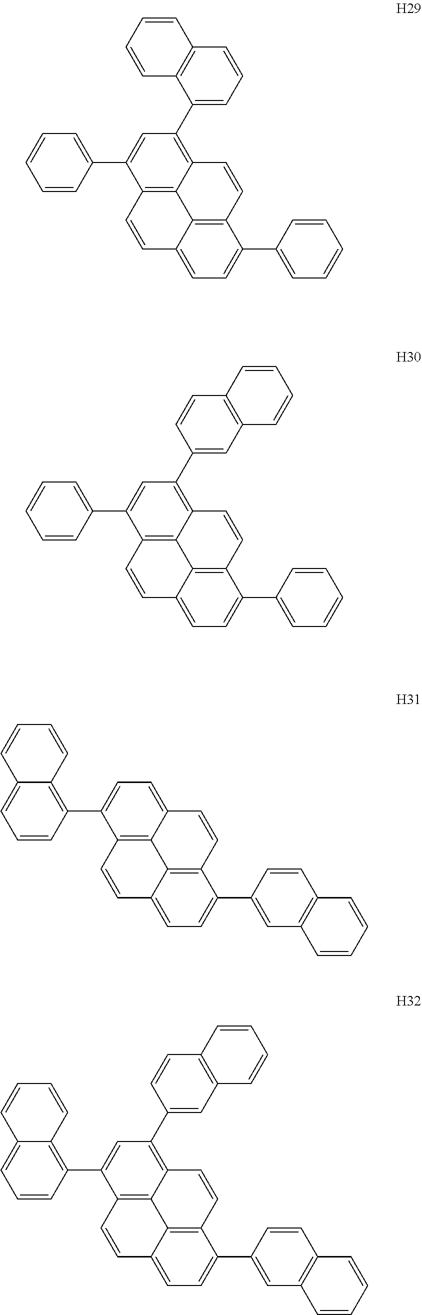

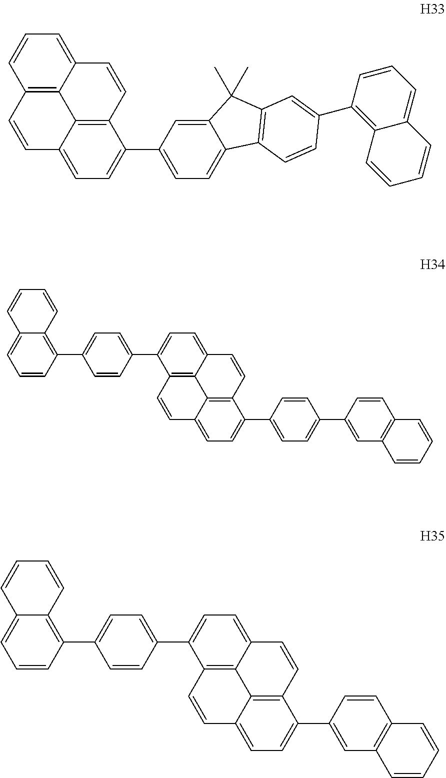

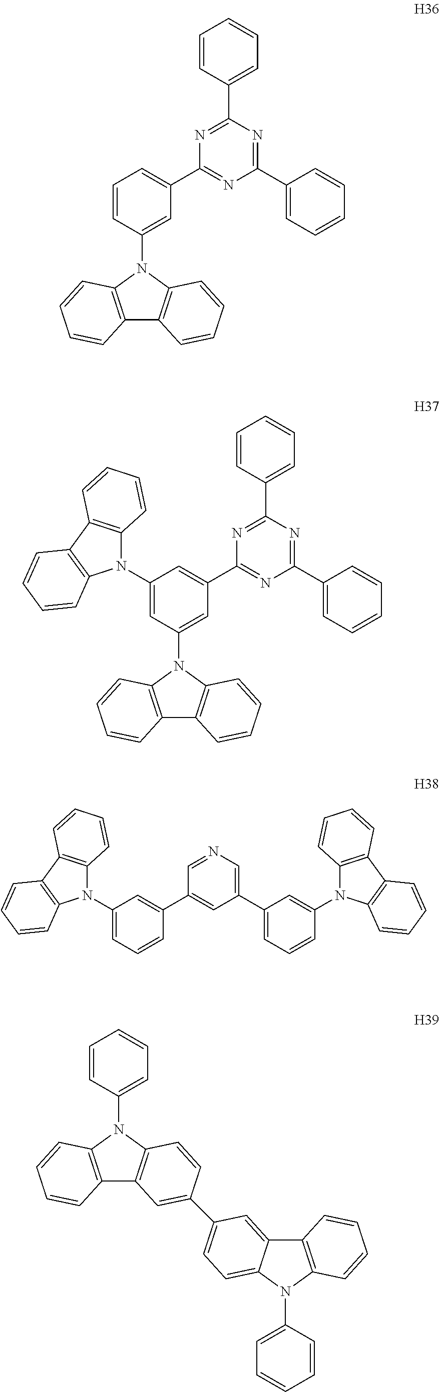 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1]

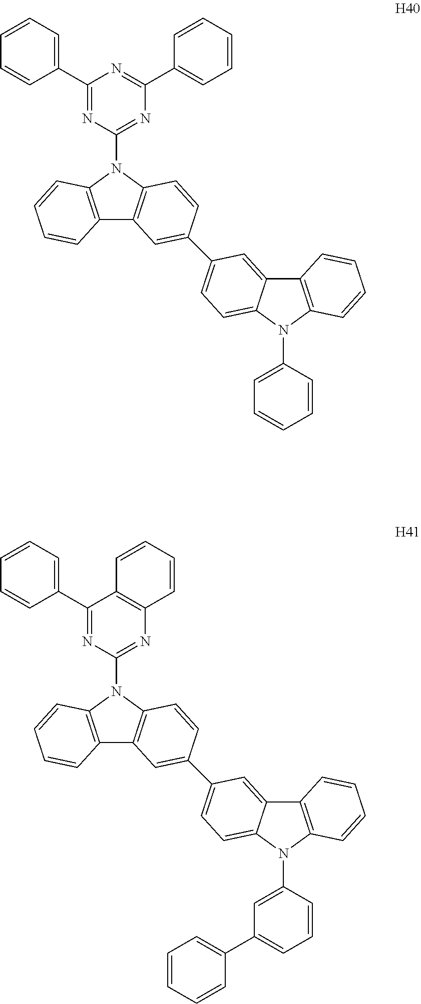 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-n3c4ccccc4c4cc(-c5ccc6c(c5)c5ccccc5n6-c5nc(-c6ccccc6)c6ccccc6n5)ccc43)c2)cc1]

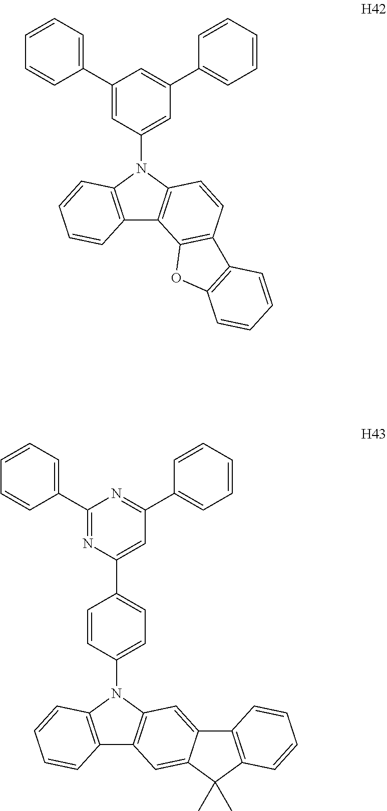 [SMILES: c1ccc(-c2cc(-c3ccccc3)cc(-n3c4ccccc4c4c5oc6ccccc6c5ccc43)c2)cc1 ; CC1(C)c2ccccc2-c2cc3c(cc21)c1ccccc1n3-c1ccc(-c2cc(-c3ccccc3)nc(-c3ccccc3)n2)cc1]

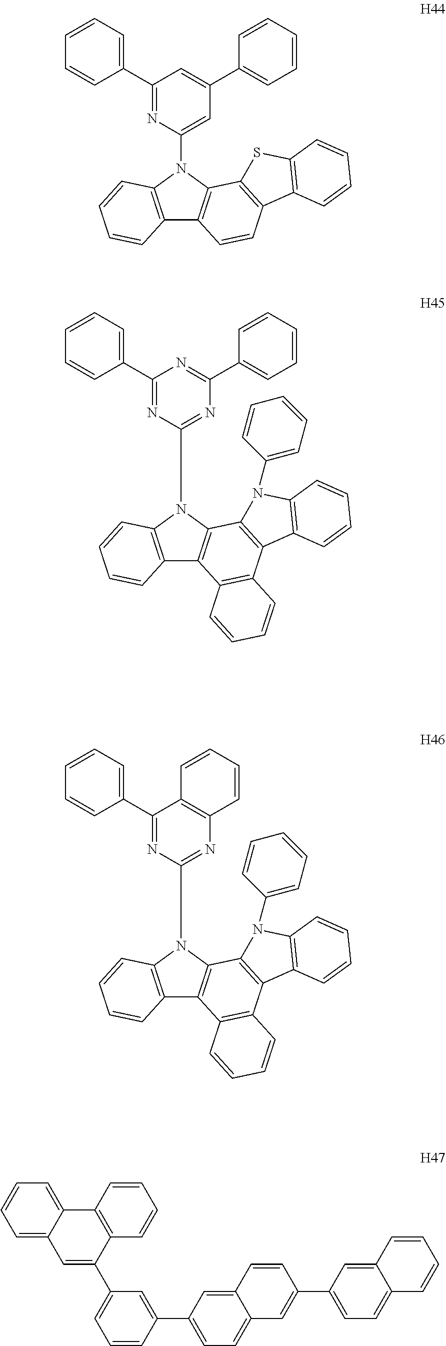

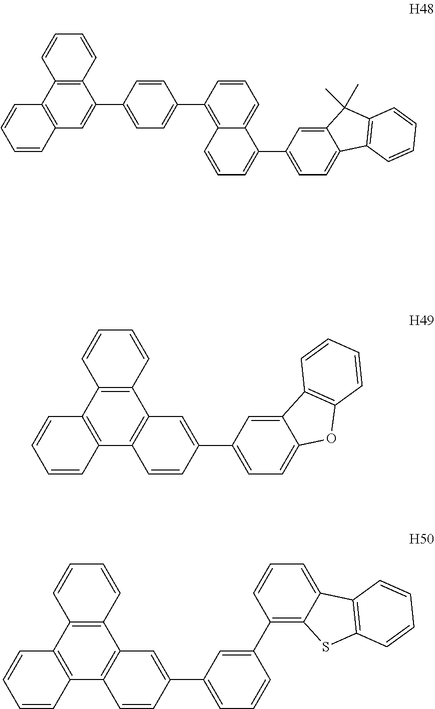

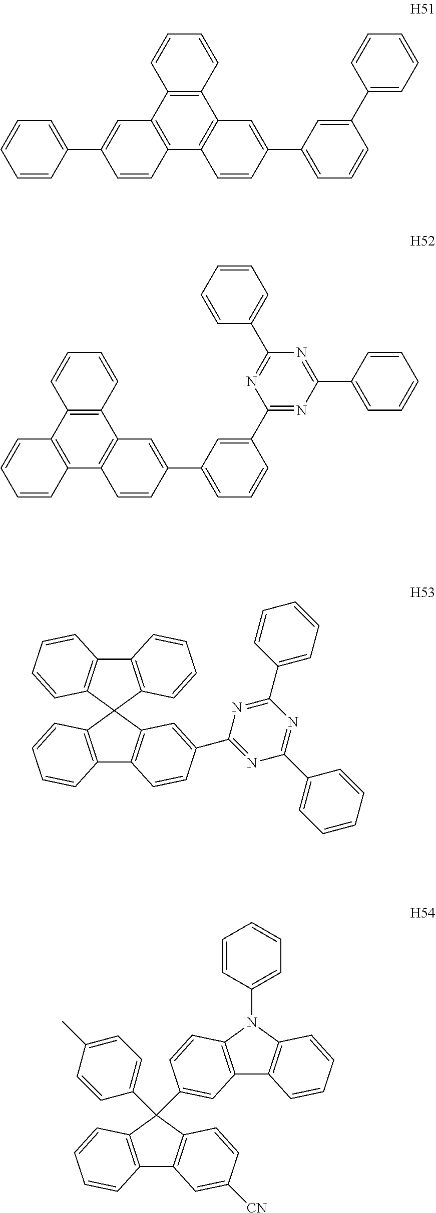

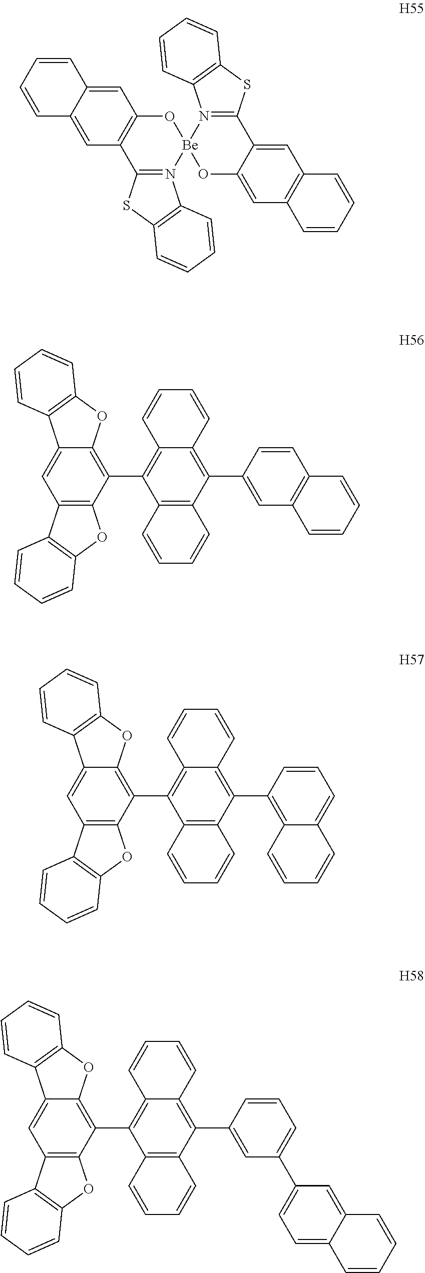

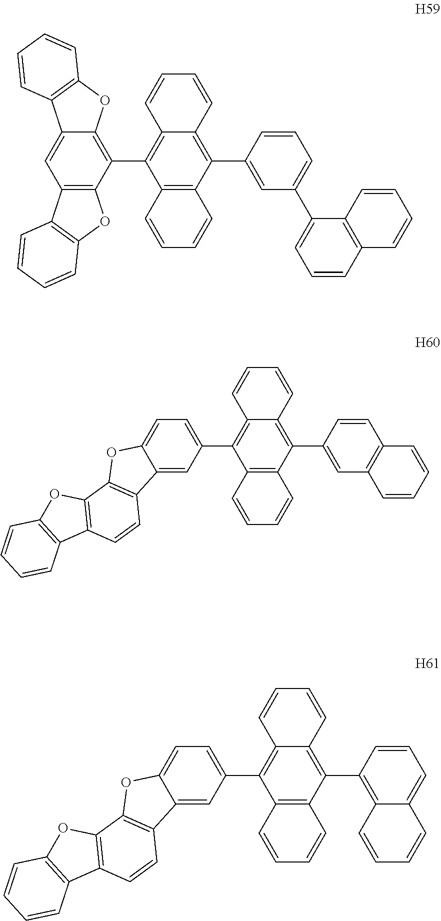 [SMILES: c1cc(-c2cccc3ccccc23)cc(-c2c3ccccc3c(-c3c4oc5ccccc5c4cc4c3oc3ccccc34)c3ccccc23)c1 ; c1ccc2cc(-c3c4ccccc4c(-c4ccc5oc6c(ccc7c8ccccc8oc76)c5c4)c4ccccc34)ccc2c1 ; c1ccc2c(-c3c4ccccc4c(-c4ccc5oc6c(ccc7c8ccccc8oc76)c5c4)c4ccccc34)cccc2c1]

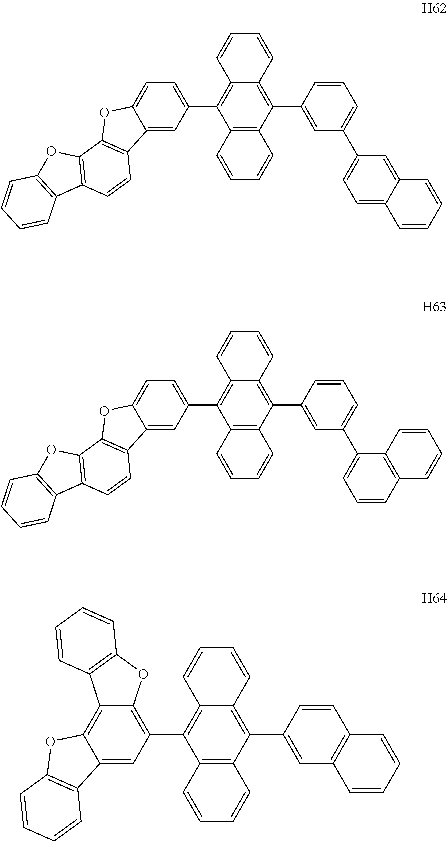 [SMILES: c1cc(-c2ccc3ccccc3c2)cc(-c2c3ccccc3c(-c3ccc4oc5c(ccc6c7ccccc7oc65)c4c3)c3ccccc23)c1 ; c1cc(-c2cccc3ccccc23)cc(-c2c3ccccc3c(-c3ccc4oc5c(ccc6c7ccccc7oc65)c4c3)c3ccccc23)c1 ; c1ccc2cc(-c3c4ccccc4c(-c4cc5c6ccccc6oc5c5c4oc4ccccc45)c4ccccc34)ccc2c1]

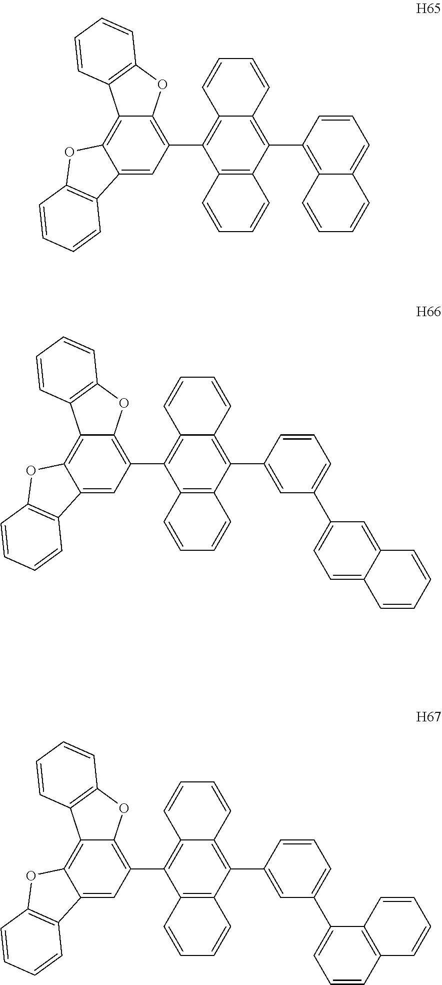 [SMILES: c1ccc2c(-c3c4ccccc4c(-c4cc5c6ccccc6oc5c5c4oc4ccccc45)c4ccccc34)cccc2c1 ; c1cc(-c2ccc3ccccc3c2)cc(-c2c3ccccc3c(-c3cc4c5ccccc5oc4c4c3oc3ccccc34)c3ccccc23)c1 ; c1cc(-c2cccc3ccccc23)cc(-c2c3ccccc3c(-c3cc4c5ccccc5oc4c4c3oc3ccccc34)c3ccccc23)c1]

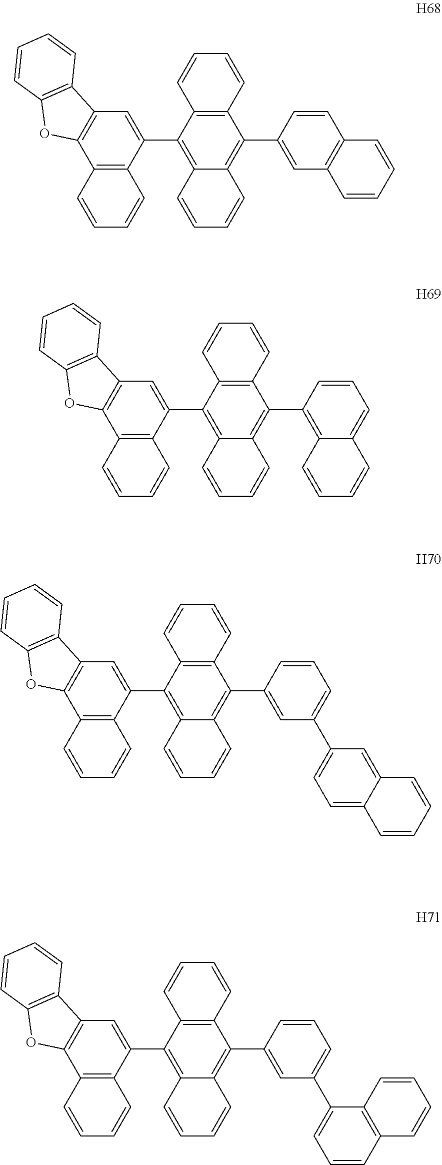 [SMILES: c1ccc2cc(-c3c4ccccc4c(-c4cc5c6ccccc6oc5c5ccccc45)c4ccccc34)ccc2c1 ; c1ccc2c(-c3c4ccccc4c(-c4cc5c6ccccc6oc5c5ccccc45)c4ccccc34)cccc2c1 ; c1cc(-c2ccc3ccccc3c2)cc(-c2c3ccccc3c(-c3cc4c5ccccc5oc4c4ccccc34)c3ccccc23)c1 ; c1cc(-c2cccc3ccccc23)cc(-c2c3ccccc3c(-c3cc4c5ccccc5oc4c4ccccc34)c3ccccc23)c1]

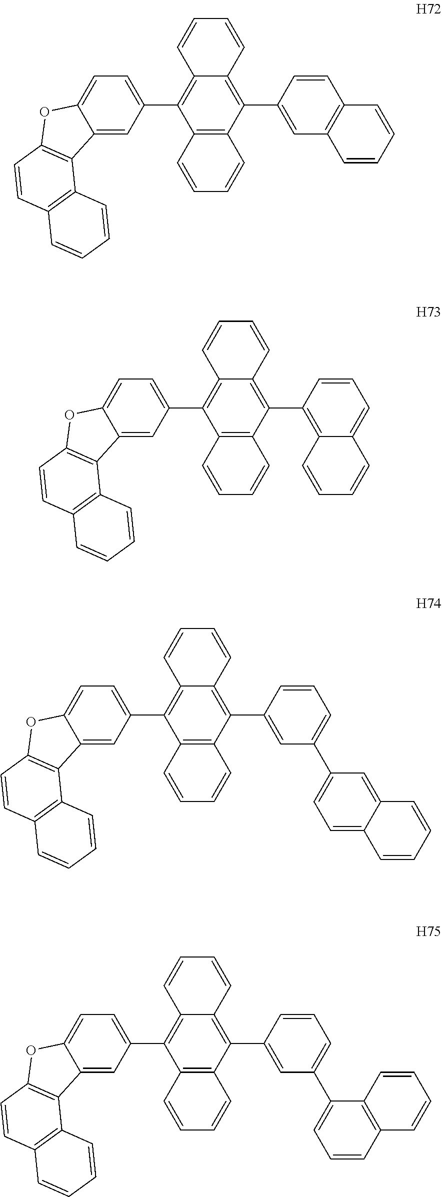 [SMILES: c1ccc2cc(-c3c4ccccc4c(-c4ccc5oc6ccc7ccccc7c6c5c4)c4ccccc34)ccc2c1 ; c1ccc2c(-c3c4ccccc4c(-c4ccc5oc6ccc7ccccc7c6c5c4)c4ccccc34)cccc2c1 ; c1cc(-c2ccc3ccccc3c2)cc(-c2c3ccccc3c(-c3ccc4oc5ccc6ccccc6c5c4c3)c3ccccc23)c1 ; c1cc(-c2cccc3ccccc23)cc(-c2c3ccccc3c(-c3ccc4oc5ccc6ccccc6c5c4c3)c3ccccc23)c1]

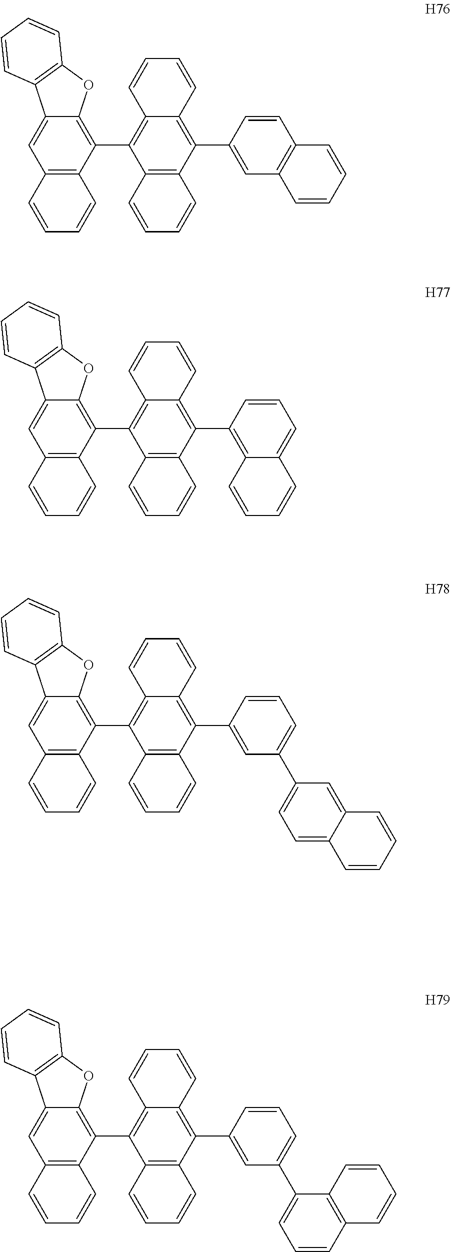 [SMILES: c1ccc2cc(-c3c4ccccc4c(-c4c5ccccc5cc5c4oc4ccccc45)c4ccccc34)ccc2c1 ; c1ccc2c(-c3c4ccccc4c(-c4c5ccccc5cc5c4oc4ccccc45)c4ccccc34)cccc2c1 ; c1cc(-c2ccc3ccccc3c2)cc(-c2c3ccccc3c(-c3c4ccccc4cc4c3oc3ccccc34)c3ccccc23)c1 ; c1cc(-c2cccc3ccccc23)cc(-c2c3ccccc3c(-c3c4ccccc4cc4c3oc3ccccc34)c3ccccc23)c1]

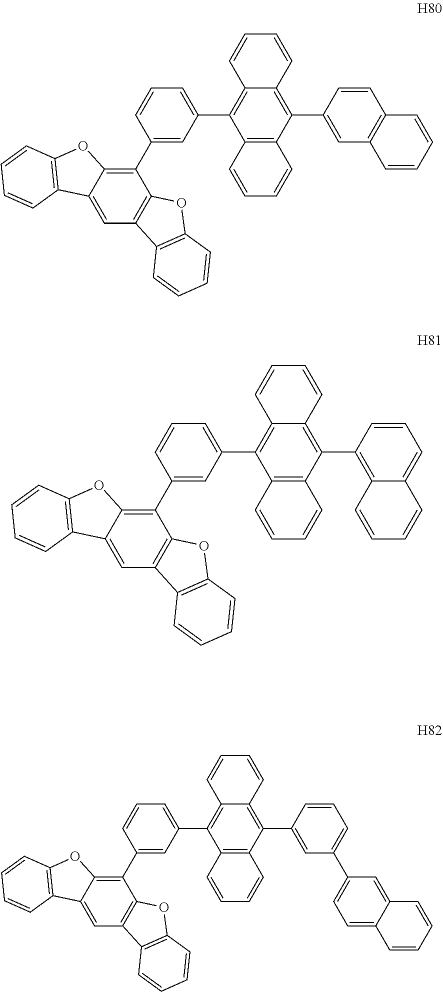 [SMILES: c1cc(-c2c3ccccc3c(-c3ccc4ccccc4c3)c3ccccc23)cc(-c2c3oc4ccccc4c3cc3c2oc2ccccc23)c1 ; c1cc(-c2c3ccccc3c(-c3cccc4ccccc34)c3ccccc23)cc(-c2c3oc4ccccc4c3cc3c2oc2ccccc23)c1 ; c1cc(-c2ccc3ccccc3c2)cc(-c2c3ccccc3c(-c3cccc(-c4c5oc6ccccc6c5cc5c4oc4ccccc45)c3)c3ccccc23)c1]

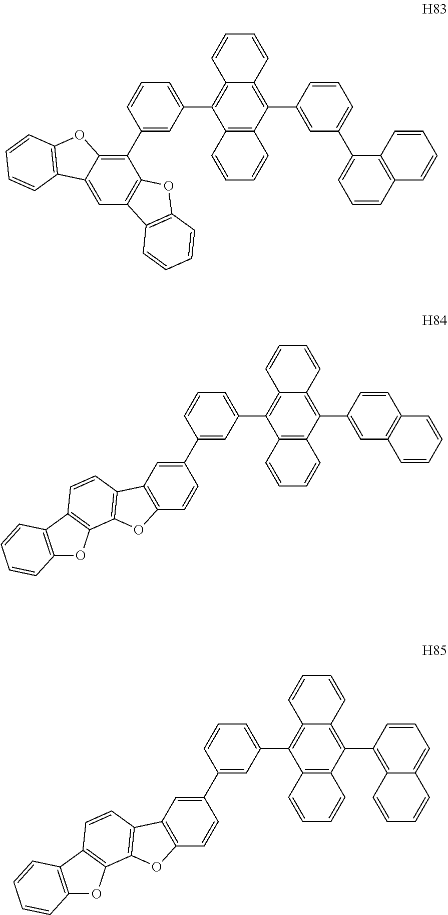 [SMILES: c1cc(-c2cccc3ccccc23)cc(-c2c3ccccc3c(-c3cccc(-c4c5oc6ccccc6c5cc5c4oc4ccccc45)c3)c3ccccc23)c1 ; c1cc(-c2ccc3oc4c(ccc5c6ccccc6oc54)c3c2)cc(-c2c3ccccc3c(-c3ccc4ccccc4c3)c3ccccc23)c1 ; c1cc(-c2ccc3oc4c(ccc5c6ccccc6oc54)c3c2)cc(-c2c3ccccc3c(-c3cccc4ccccc34)c3ccccc23)c1]

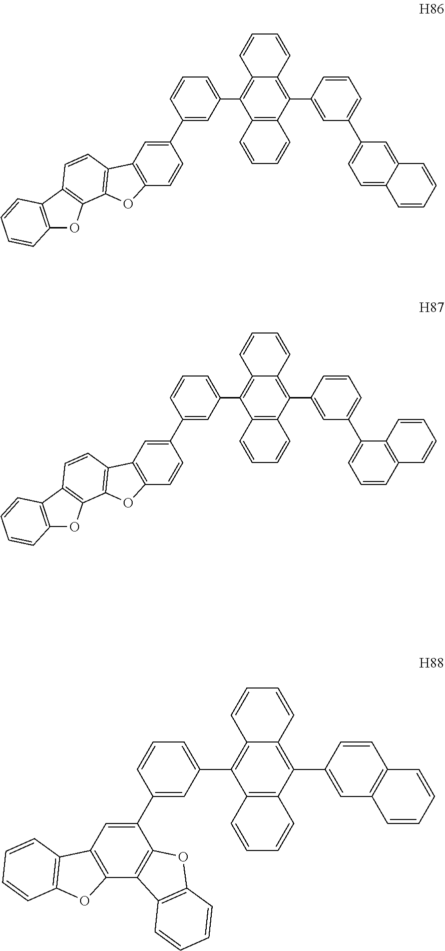 [SMILES: c1cc(-c2ccc3ccccc3c2)cc(-c2c3ccccc3c(-c3cccc(-c4ccc5oc6c(ccc7c8ccccc8oc76)c5c4)c3)c3ccccc23)c1 ; c1cc(-c2ccc3oc4c(ccc5c6ccccc6oc54)c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3c2oc2ccccc23)c1]

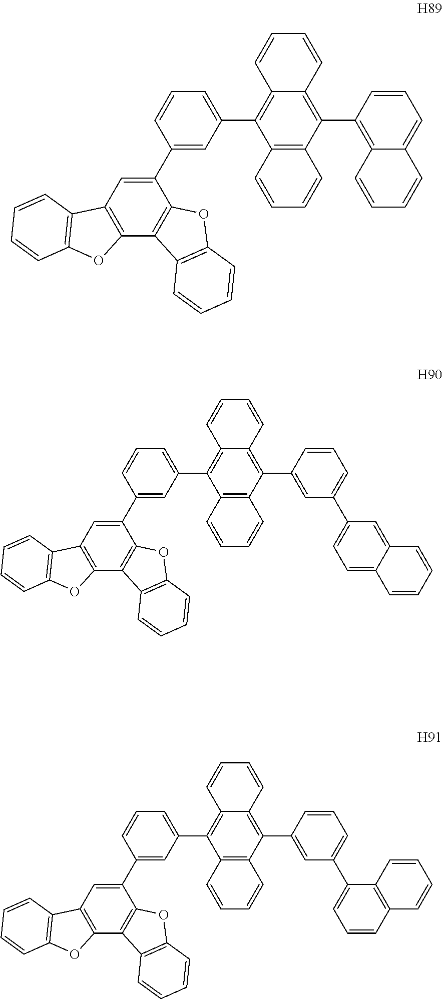 [SMILES: c1cc(-c2c3ccccc3c(-c3cccc4ccccc34)c3ccccc23)cc(-c2cc3c4ccccc4oc3c3c2oc2ccccc23)c1 ; c1cc(-c2ccc3ccccc3c2)cc(-c2c3ccccc3c(-c3cccc(-c4cc5c6ccccc6oc5c5c4oc4ccccc45)c3)c3ccccc23)c1 ; c1cc(-c2cccc3ccccc23)cc(-c2c3ccccc3c(-c3cccc(-c4cc5c6ccccc6oc5c5c4oc4ccccc45)c3)c3ccccc23)c1]

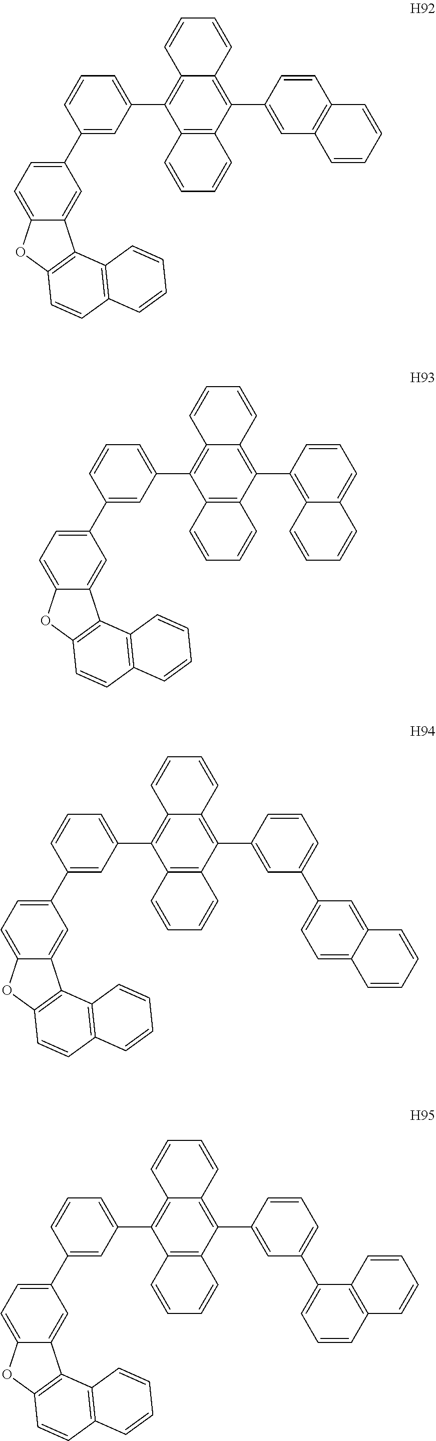 [SMILES: c1cc(-c2ccc3oc4ccc5ccccc5c4c3c2)cc(-c2c3ccccc3c(-c3ccc4ccccc4c3)c3ccccc23)c1 ; c1cc(-c2ccc3oc4ccc5ccccc5c4c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6ccc7ccccc7c6c5c4)c3)c3ccccc23)c1 ; c1cc(-c2ccc3oc4ccc5ccccc5c4c3c2)cc(-c2c3ccccc3c(-c3cccc(-c4cccc5ccccc45)c3)c3ccccc23)c1]

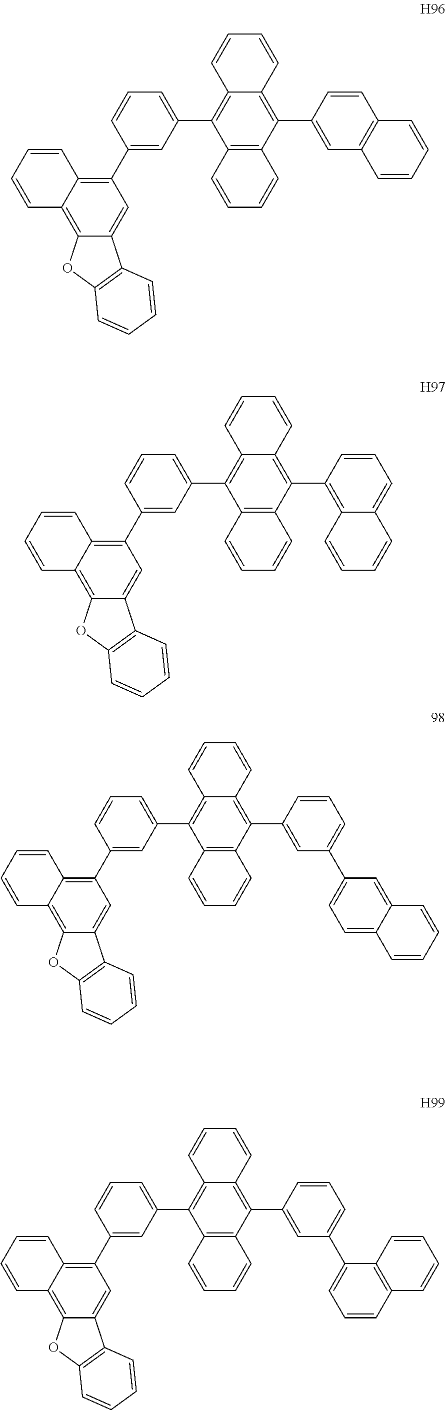 [SMILES: c1cc(-c2c3ccccc3c(-c3ccc4ccccc4c3)c3ccccc23)cc(-c2cc3c4ccccc4oc3c3ccccc23)c1 ; c1cc(-c2c3ccccc3c(-c3cccc4ccccc34)c3ccccc23)cc(-c2cc3c4ccccc4oc3c3ccccc23)c1 ; c1cc(-c2ccc3ccccc3c2)cc(-c2c3ccccc3c(-c3cccc(-c4cc5c6ccccc6oc5c5ccccc45)c3)c3ccccc23)c1 ; c1cc(-c2cccc3ccccc23)cc(-c2c3ccccc3c(-c3cccc(-c4cc5c6ccccc6oc5c5ccccc45)c3)c3ccccc23)c1]

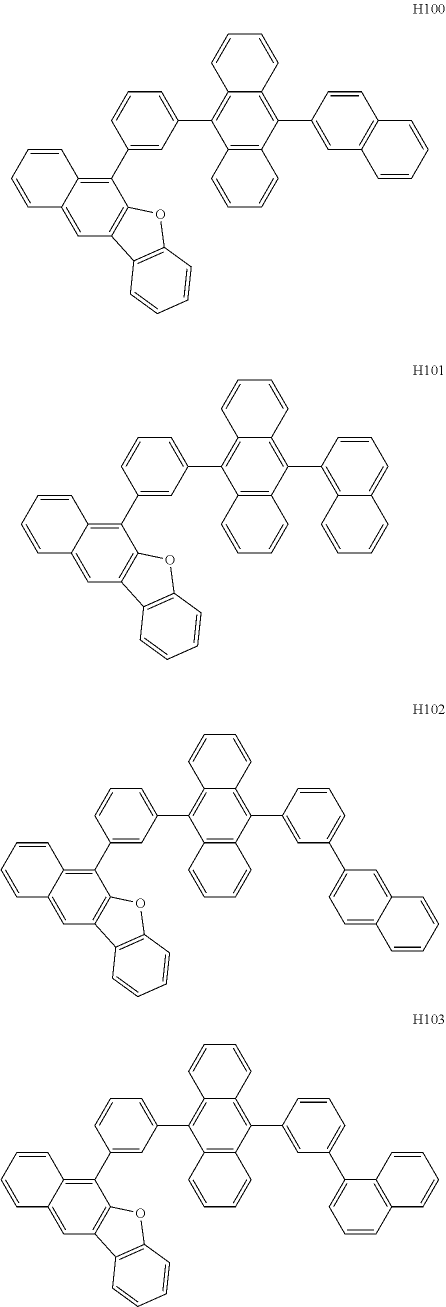 [SMILES: c1cc(-c2c3ccccc3c(-c3ccc4ccccc4c3)c3ccccc23)cc(-c2c3ccccc3cc3c2oc2ccccc23)c1 ; c1cc(-c2c3ccccc3c(-c3cccc4ccccc34)c3ccccc23)cc(-c2c3ccccc3cc3c2oc2ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1 ; c1cc(-c2cccc3ccccc23)cc(-c2c3ccccc3c(-c3cccc(-c4c5ccccc5cc5c4oc4ccccc45)c3)c3ccccc23)c1]

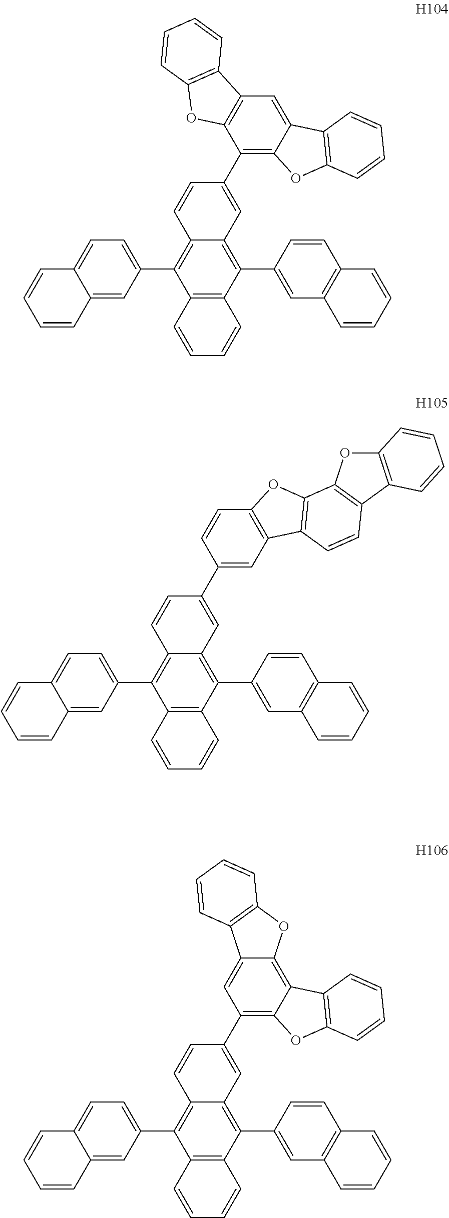 [SMILES: c1ccc2cc(-c3c4ccccc4c(-c4ccc5ccccc5c4)c4cc(-c5c6oc7ccccc7c6cc6c5oc5ccccc56)ccc34)ccc2c1 ; c1ccc2cc(-c3c4ccccc4c(-c4ccc5ccccc5c4)c4cc(-c5ccc6oc7c(ccc8c9ccccc9oc87)c6c5)ccc34)ccc2c1 ; c1ccc2cc(-c3c4ccccc4c(-c4ccc5ccccc5c4)c4cc(-c5cc6c7ccccc7oc6c6c5oc5ccccc56)ccc34)ccc2c1]

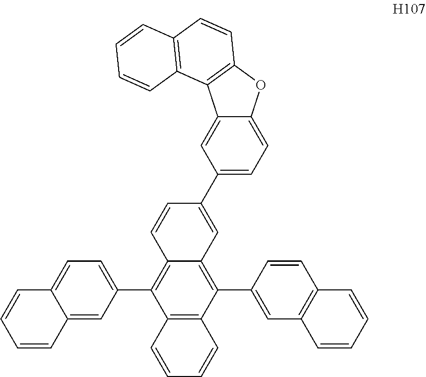 [SMILES: c1ccc2cc(-c3c4ccccc4c(-c4ccc5ccccc5c4)c4cc(-c5ccc6oc7ccc8ccccc8c7c6c5)ccc34)ccc2c1]

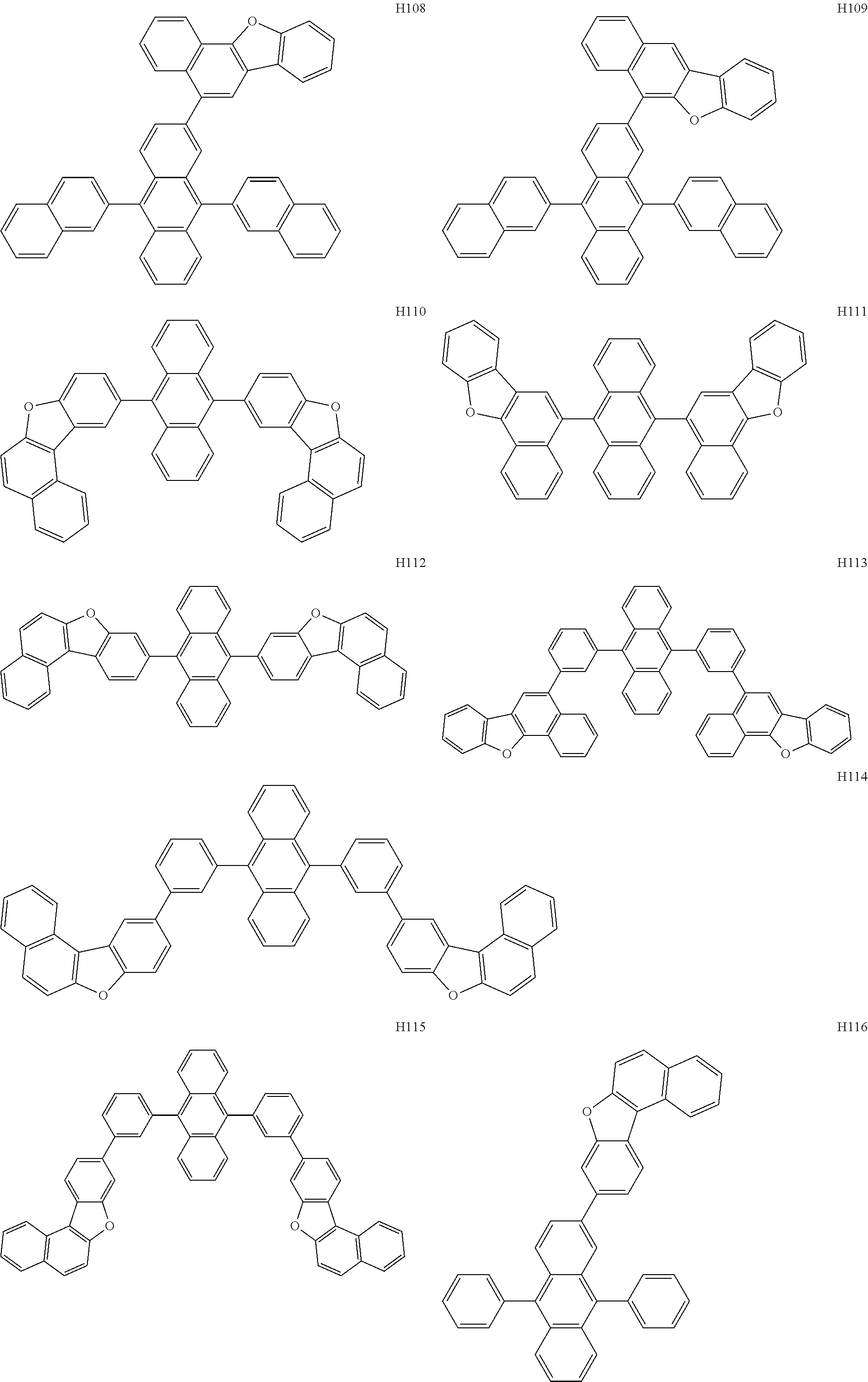

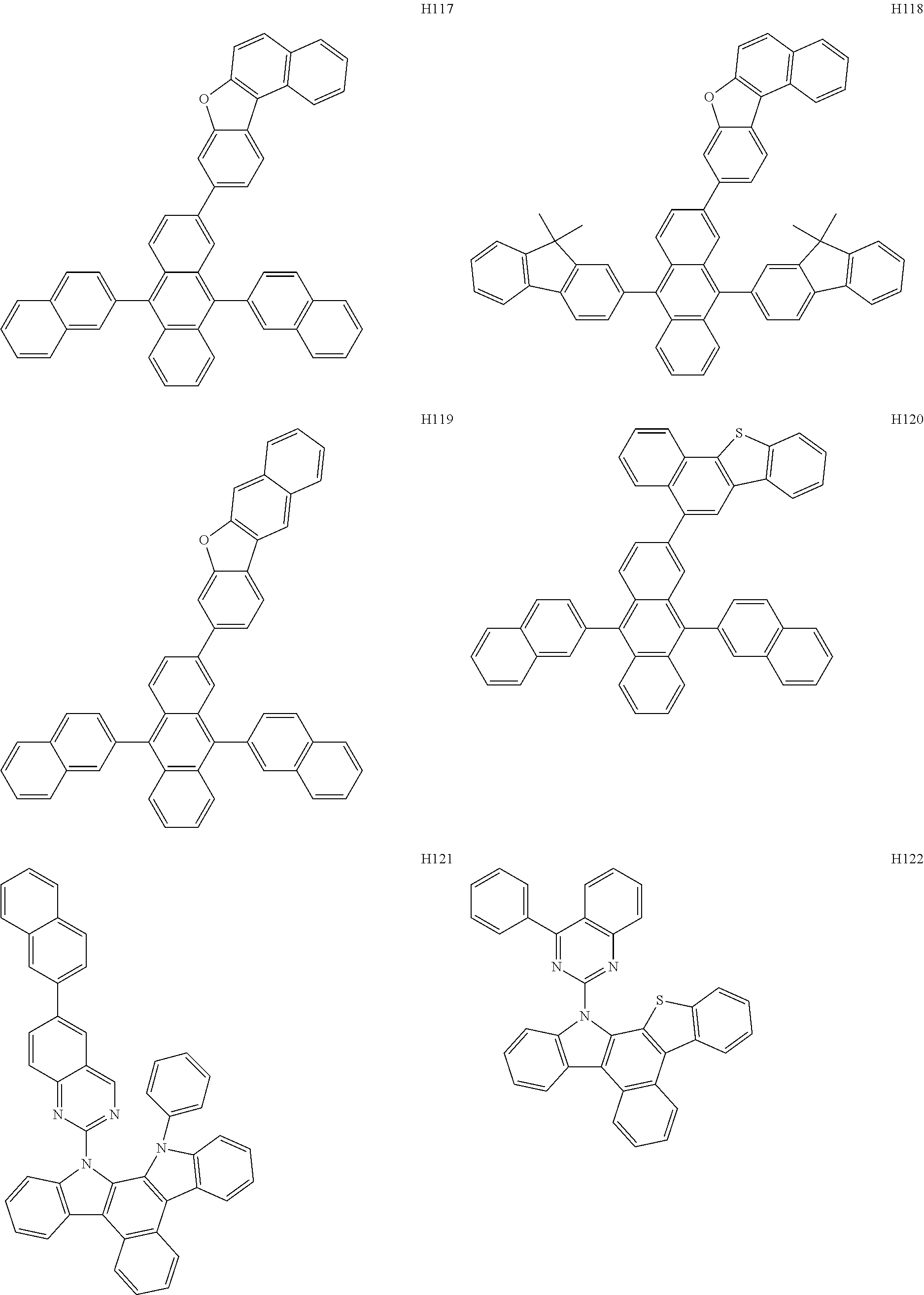

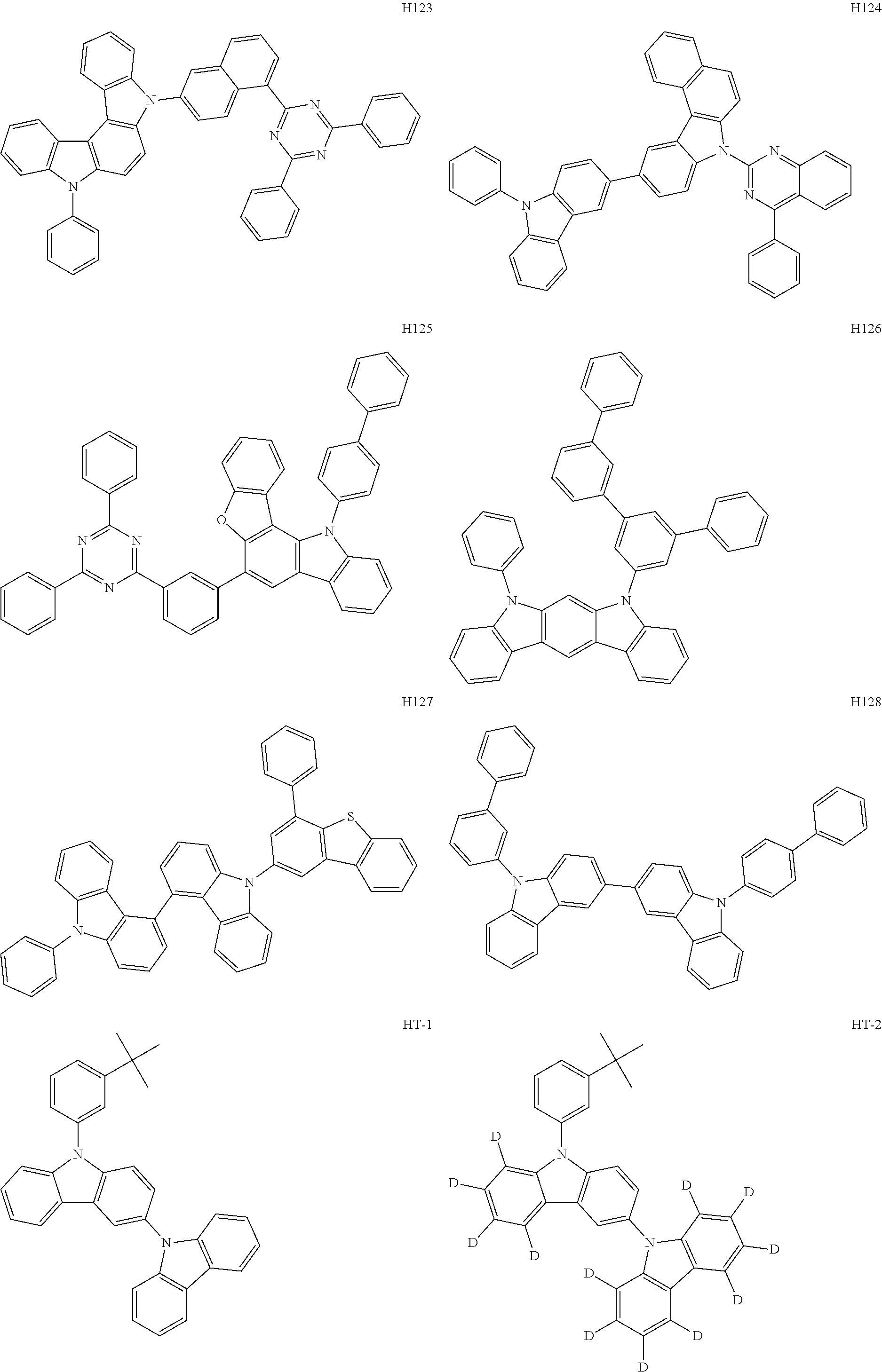

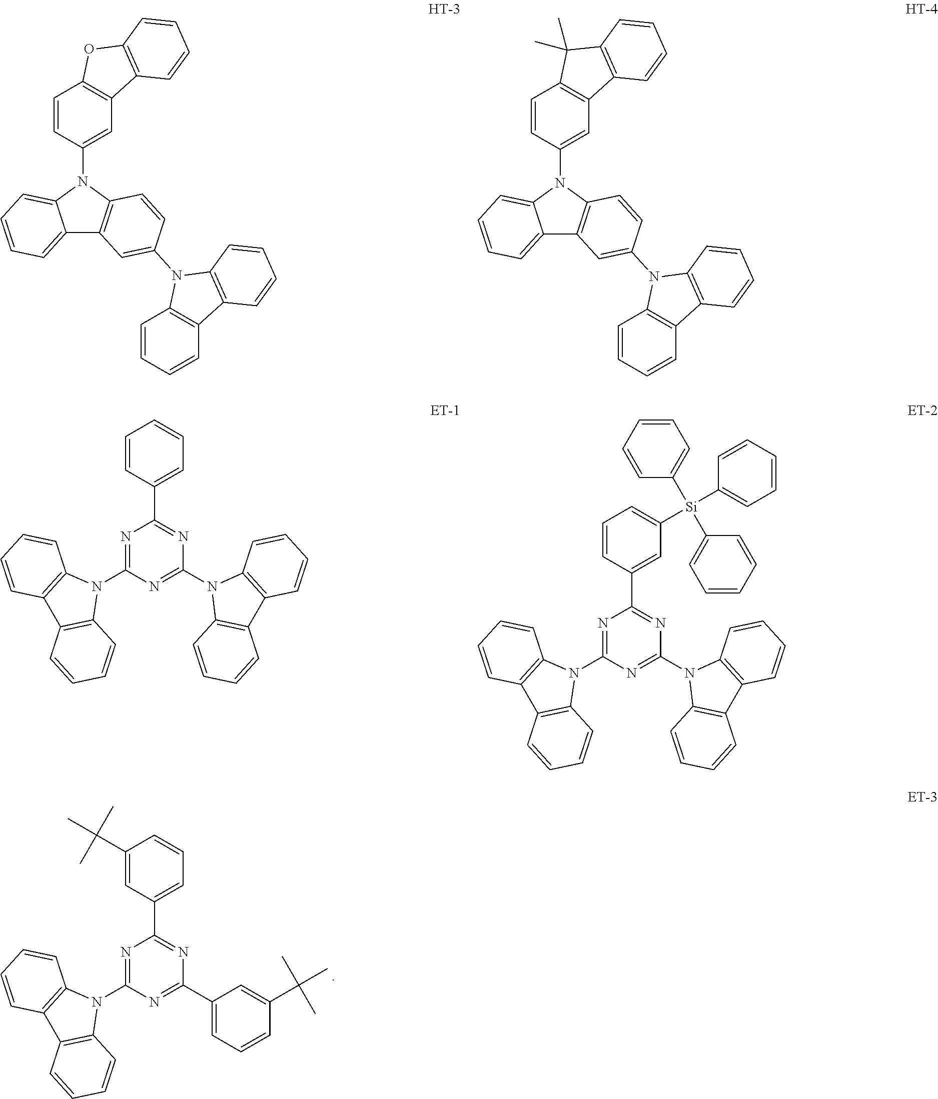

### Phosphorescent Dopant

The phosphorescent dopant may be same as described herein with respect to the first dopant.

According to one or more embodiments, an amount of the first dopant may be in a range of about 1.0 wt % to about 30 wt % (based on 100 parts by weight of the total hosts). When the amount of the first dopant is within the range above, the light-emitting device may have excellent or suitable efficiency and lifespan.

For example, in one or more embodiments, the first dopant may include at least one of (e.g., selected from among) Compounds PD26 to PD39, PS-1, and PS-2:

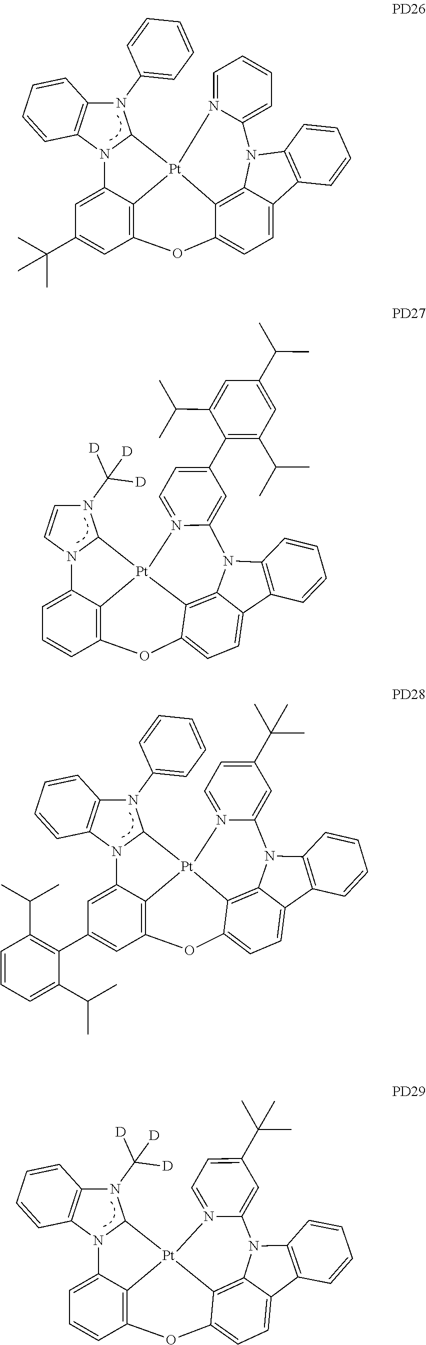

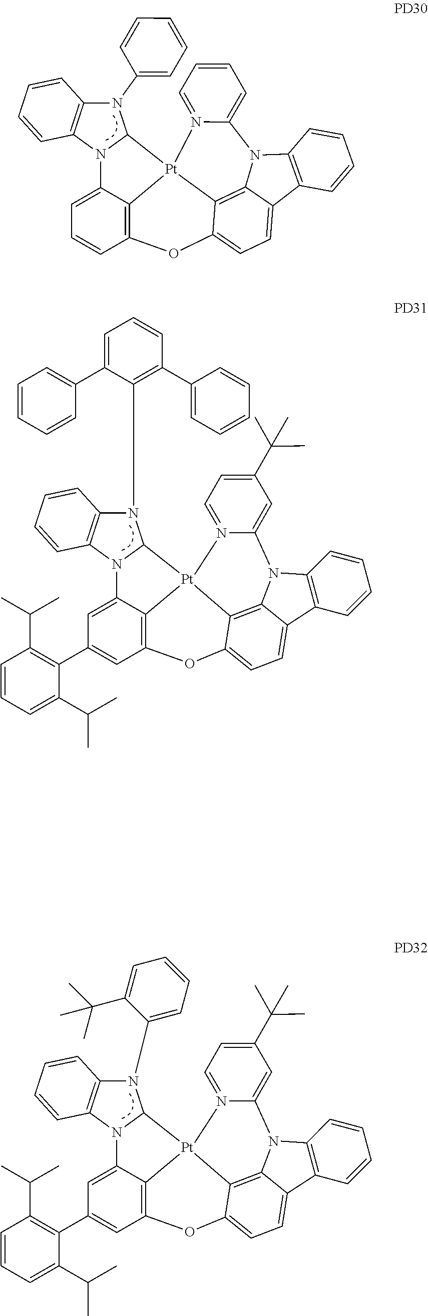

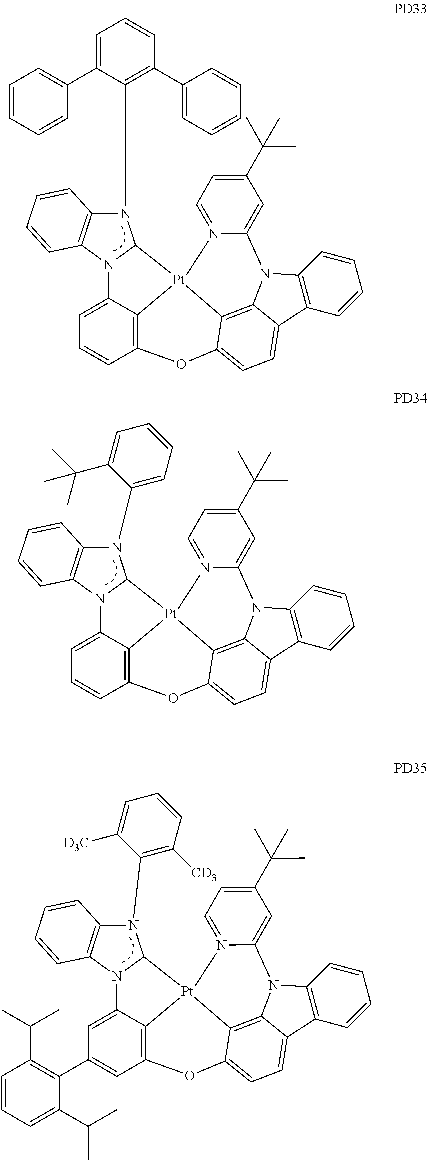

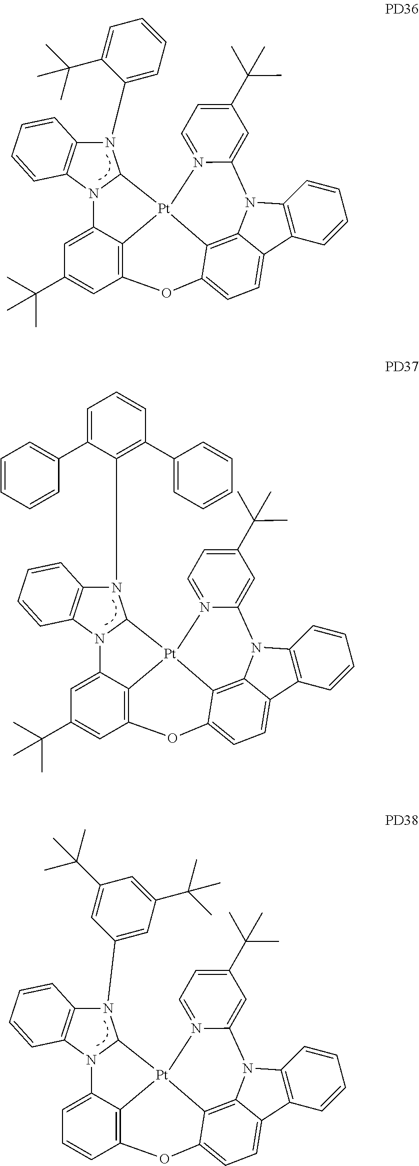

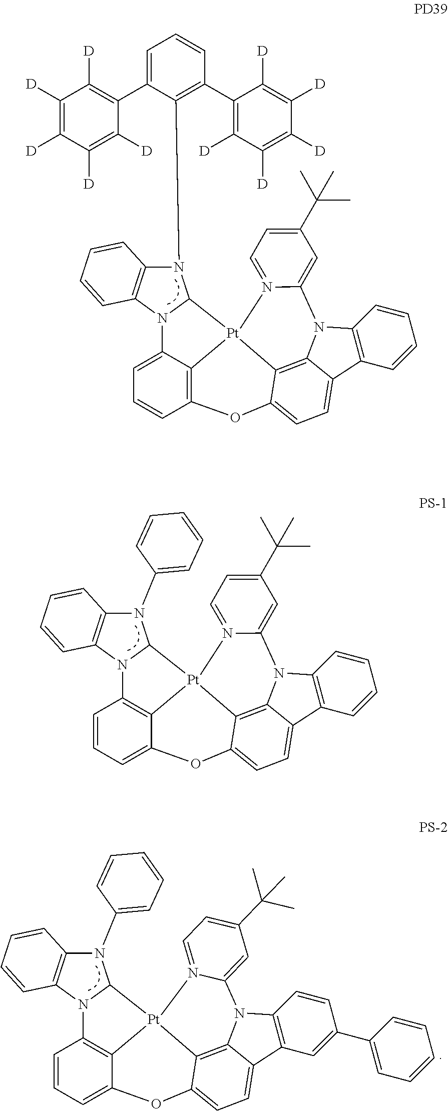

### Delayed Fluorescence Material

The delayed fluorescence material may be the same as described herein with respect to the second dopant.

According to one or more embodiments, an amount of the second dopant may be in a range of about 1.0 wt % to about 7.0 wt % (based on 100 parts by weight of the total hosts). When the amount of the second dopant is within the range above, the light-emitting device may have excellent or suitable efficiency and lifespan.

In one or more embodiments, the second dopant may include, for example, any one of (e.g., may be any one selected from among) the following Compounds:

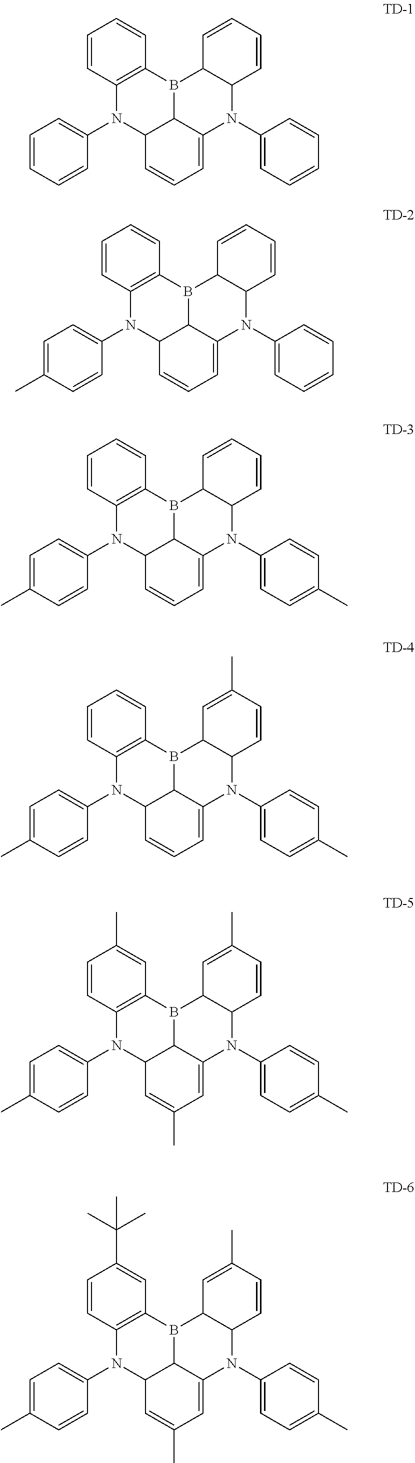

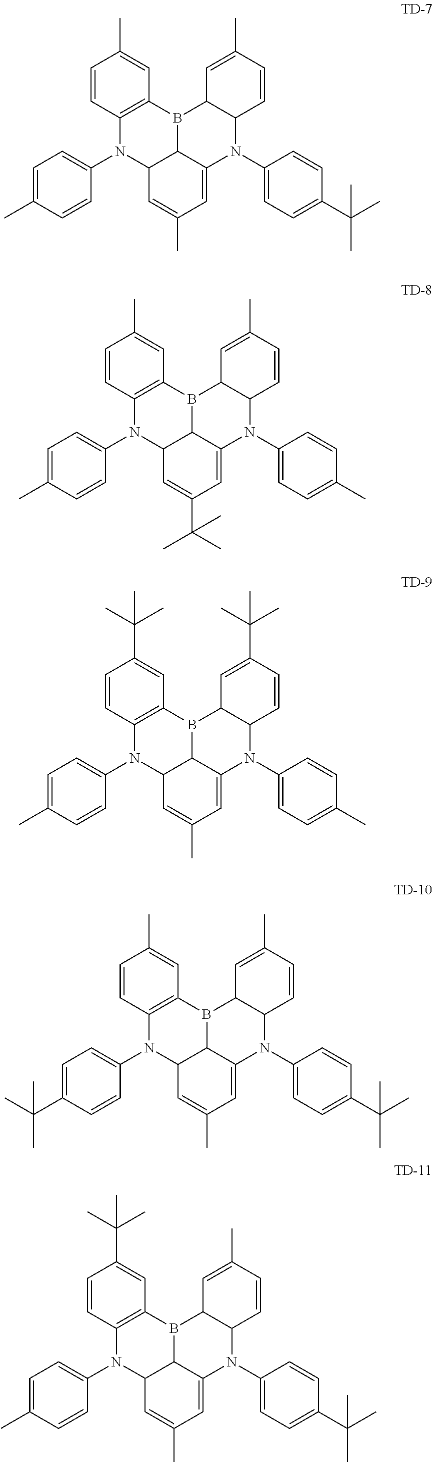

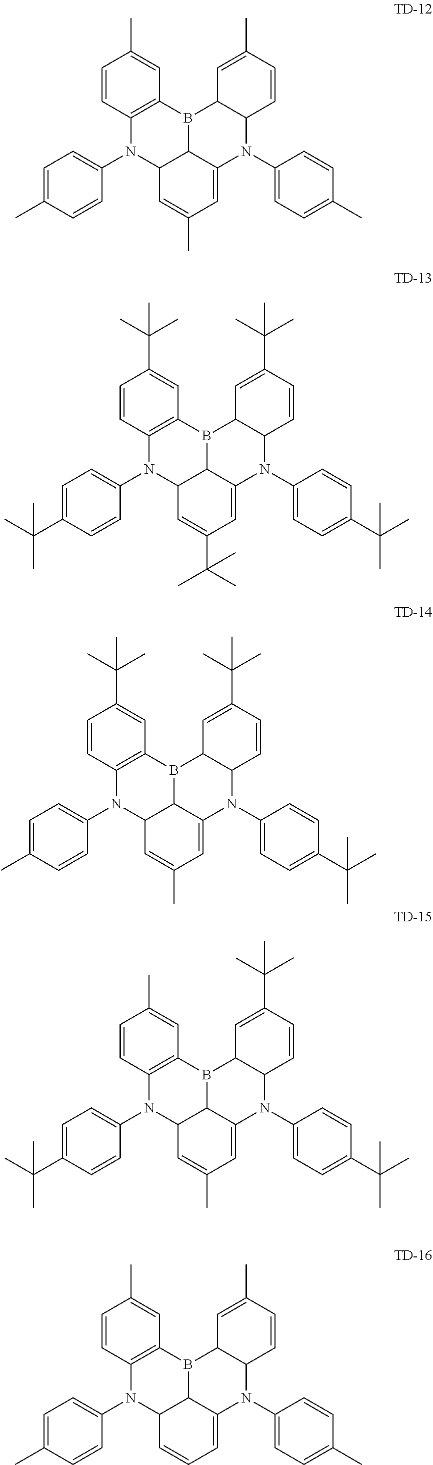

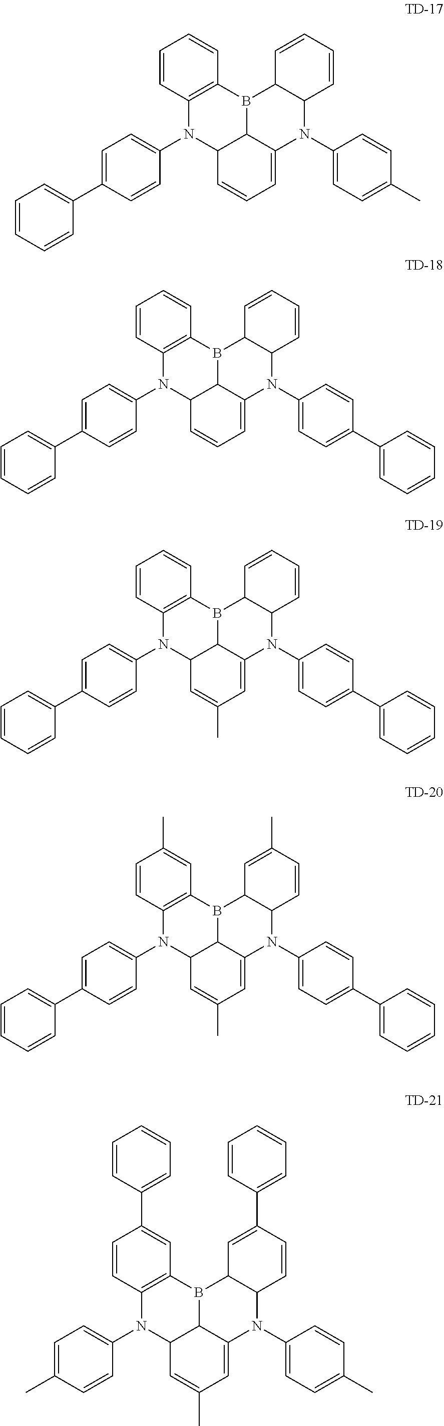

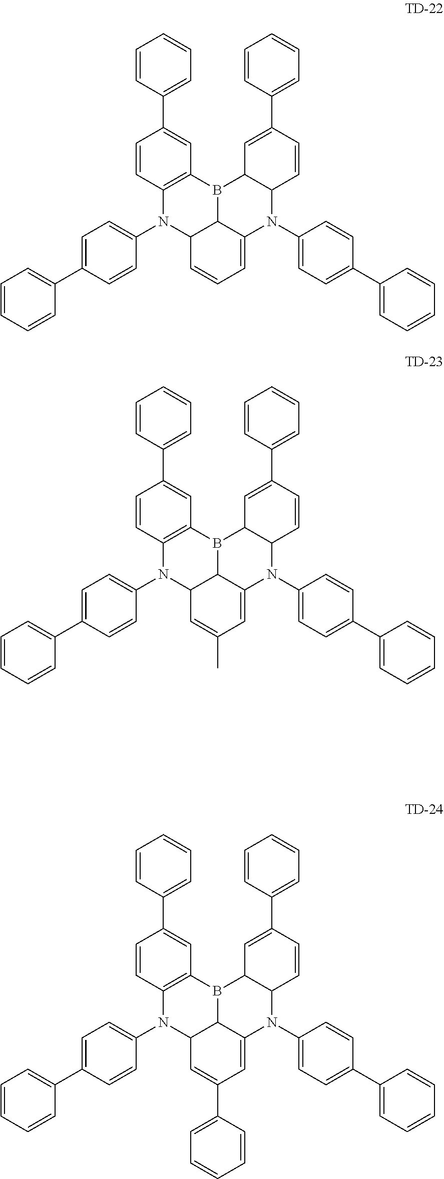 [SMILES: C1=CC2C3B(c4cc(-c5ccccc5)ccc4N2c2ccc(-c4ccccc4)cc2)C2C=C(c4ccccc4)C=CC2N(c2ccc(-c4ccccc4)cc2)C3=C1 ; CC1=CC2C3B(c4cc(-c5ccccc5)ccc4N2c2ccc(-c4ccccc4)cc2)C2C=C(c4ccccc4)C=CC2N(c2ccc(-c4ccccc4)cc2)C3=C1 ; C1=CC2C(C=C1c1ccccc1)B1c3cc(-c4ccccc4)ccc3N(c3ccc(-c4ccccc4)cc3)C3C=C(c4ccccc4)C=C(C13)N2c1ccc(-c2ccccc2)cc1]

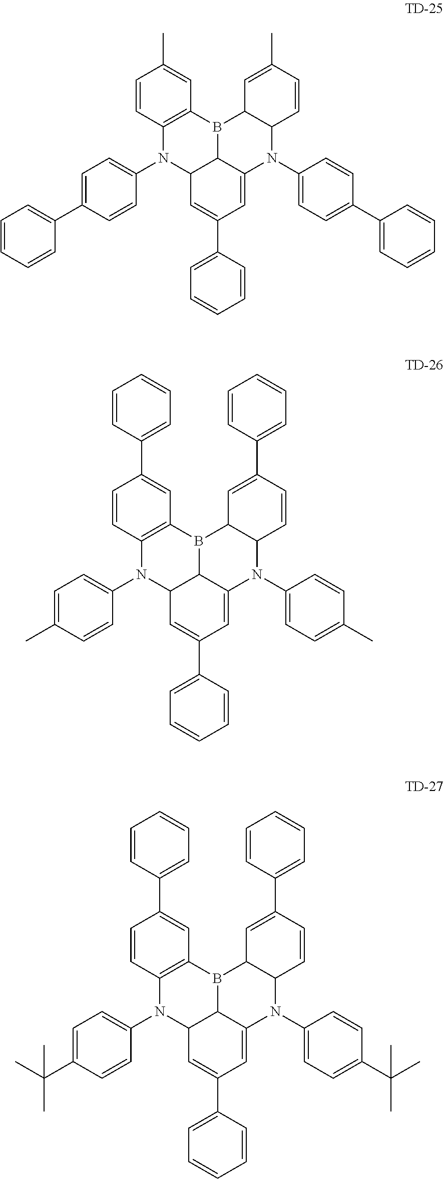

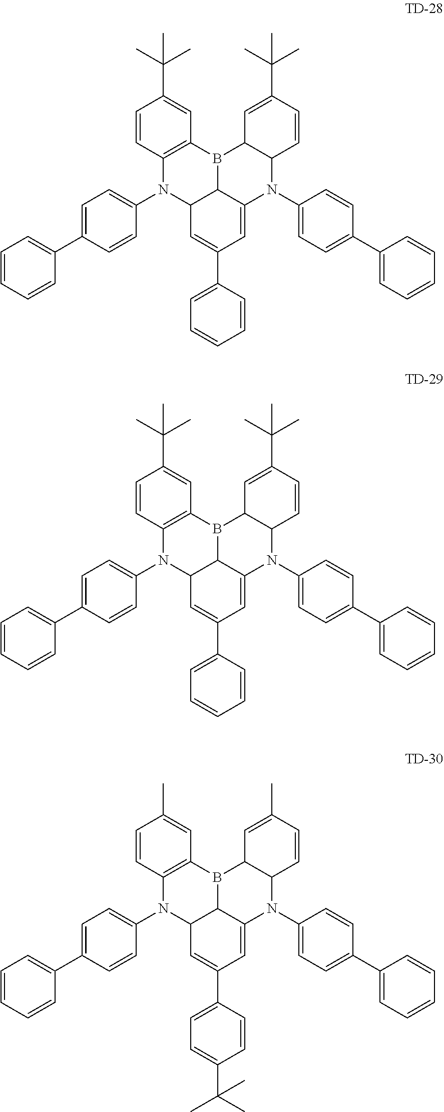 [SMILES: CC(C)(C)C1=CC2B3c4cc(C(C)(C)C)ccc4N(c4ccc(-c5ccccc5)cc4)C4C=C(c5ccccc5)C=C(C34)N(c3ccc(-c4ccccc4)cc3)C2C=C1 ; CC(C)(C)C1=CC2B3c4cc(C(C)(C)C)ccc4N(c4ccc(-c5ccccc5)cc4)C4C=C(c5ccccc5)C=C(C34)N(c3ccc(-c4ccccc4)cc3)C2C=C1 ; CC1=CC2B3c4cc(C)ccc4N(c4ccc(-c5ccccc5)cc4)C4C=C(c5ccc(C(C)(C)C)cc5)C=C(C34)N(c3ccc(-c4ccccc4)cc3)C2C=C1]

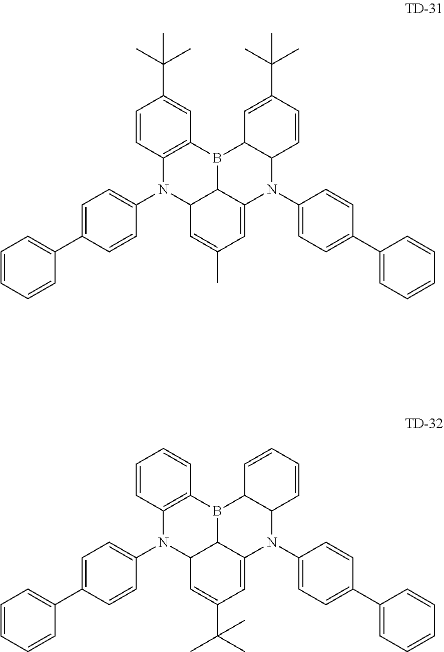 [SMILES: CC1=CC2C3B(c4cc(C(C)(C)C)ccc4N2c2ccc(-c4ccccc4)cc2)C2C=C(C(C)(C)C)C=CC2N(c2ccc(-c4ccccc4)cc2)C3=C1 ; CC(C)(C)C1=CC2C3B(c4ccccc4N2c2ccc(-c4ccccc4)cc2)C2C=CC=CC2N(c2ccc(-c4ccccc4)cc2)C3=C1]

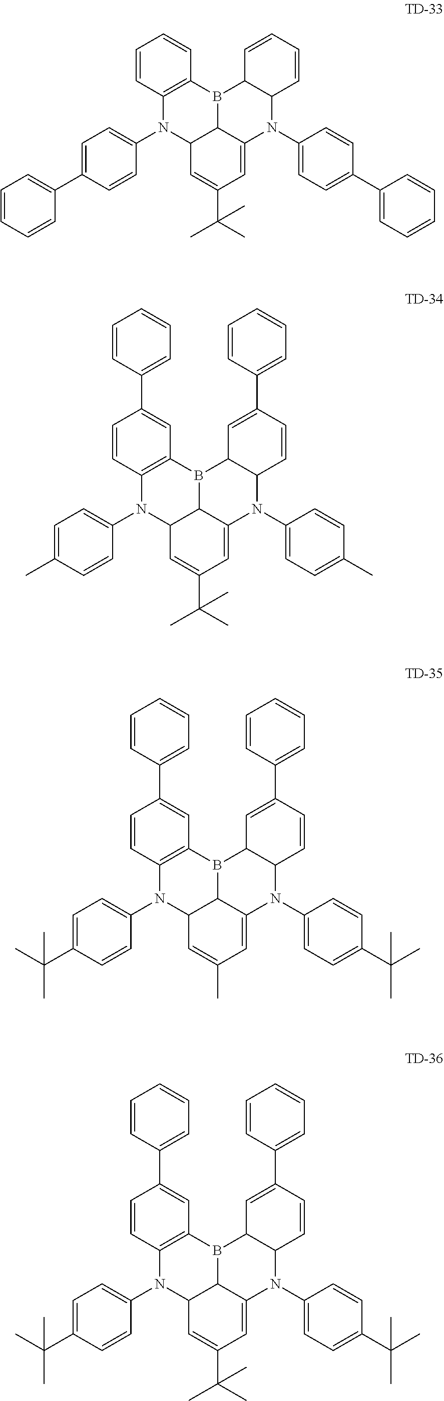

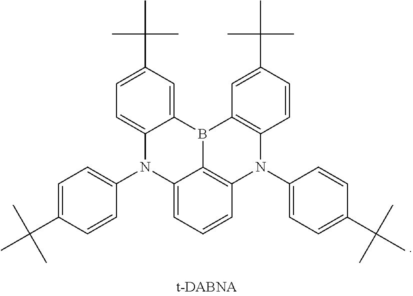 [SMILES: CC(C)(C)c1ccc(N2c3ccc(C(C)(C)C)cc3B3c4cc(C(C)(C)C)ccc4N(c4ccc(C(C)(C)C)cc4)c4cccc2c43)cc1]

### Quantum Dot

According to one or more embodiments of the present disclosure, the electronic apparatus may include quantum dots. For example, in one or more embodiments, the electronic apparatus may include a color filter, and the color filter may include quantum dots.

The term “quantum dot” as used herein refers to a crystal of a semiconductor compound, and may include any material capable of emitting light of one or more suitable emission wavelengths according to the size of the crystal. Quantum dots may also be to emit light of one or more suitable emission wavelengths by adjusting an element ratio in the quantum dot compound.

A diameter of the quantum dot may be, for example, in a range of about 1 nanometer (nm) to about 10 nm. In the present disclosure, when dot, dots, or dot particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The quantum dot may be synthesized by a wet chemical process, a metal organic chemical vapor deposition process, a molecular beam epitaxy process, or any process similar thereto.

The wet chemical process is a method including mixing a precursor material of a quantum dot with an organic solvent and then growing a quantum dot particle crystal. When the crystals grow, the organic solvent naturally acts as a dispersant coordinated on the surface of the quantum dot crystals and controls the growth of the crystals so that the growth of quantum dot particles may be controlled or selected through a process which costs lower and is easier than vapor deposition methods, such as metal organic chemical vapor deposition (MOCVD) or molecular beam epitaxy (MBE).

The quantum dot may include: a Group II-VI semiconductor compound; a Group III-V semiconductor compound; a Group III-VI semiconductor compound; a Group I-III-VI semiconductor compound; a Group IV-VI semiconductor compound; a Group IV element or compound; or any combination thereof.

Non-limiting examples of the Group II-VI semiconductor compound may include: a binary compound, such as CdS, CdSe, CdTe, ZnS, ZnSe, ZnTe, ZnO, HgS, HgSe, HgTe, MgSe, MgS, and/or the like; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or the like; a quaternary compound, such as CdZnSeS, CdZnSeTe, CdZnSTe, CdHgSeS, CdHgSeTe, CdHgSTe, HgZnSeS, HgZnSeTe, HgZnSTe, and/or the like; or any combination thereof.

Non-limiting examples of the Group III-V semiconductor compound may include: a binary compound, such as GaN, GaP, GaAs, GaSb, AlN, AlP, AlAs, AlSb, InN, InP, InAs, InSb, and/or the like; a ternary compound, such as GaNP, GaNAs, GaNSb, GaPAs, GaPSb, AlNP, AlNAs, AlNSb, AlPAS, AlPSb, InGaP, InNP, InAlP, InNAs, InNSb, InPAs, InPSb, and/or the like; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and/or the like; or any combination thereof. In one or more embodiments, the Group III-V semiconductor compound may further include a Group II element. Non-limiting examples of the Group III-V semiconductor compound further including a Group II element may include InZnP, InGaZnP, InAlZnP, and/or the like.

Non-limiting examples of the Group III-VI semiconductor compound may include: a binary compound, such as GaS, GaSe, GazSes, GaTe, InS, InSe, In₂Se₃, InTe, and/or the like; a ternary compound, such as InGaS₃, InGaSe₃, and/or the like; or any combination thereof.

Non-limiting examples of the Group I-III-VI semiconductor compound may include: a ternary compound, such as AgInS, AgInS₂, CuInS, CuInS₂, CuGaO₂, AgGaO₂, AgAlO₂, and/or the like; a quaternary compound, such as AgInGaS, AgInGaS₂, and/or the like; or any combination thereof.

Non-limiting examples of the Group IV-VI semiconductor compound may include: a binary compound, such as SnS, SnSe, SnTe, PbS, PbSe, PbTe, and/or the like; a ternary compound, such as SnSeS, SnSeTe, SnSTe, PbSeS, PbSeTe, PbSTe, SnPbS, SnPbSe, SnPbTe, and/or the like; a quaternary compound, such as SnPbSSe, SnPbSeTe, SnPbSTe, and/or the like; or any combination thereof.

The Group IV element or compound may include: a single element compound, such as Si, Ge, and/or the like; a binary compound, such as SiC, SiGe, and/or the like; or any combination thereof.

Each element included in a multi-element compound such as the binary compound, the ternary compound, and the quaternary compound may be present at a substantially uniform concentration or non-uniform concentration in a particle.

In one or more embodiments, the quantum dot may have a single structure in which the concentration of each element in the quantum dot is substantially uniform, or a core-shell dual structure. For example, a material included in the core and a material included in the shell may be different from each other.

The shell of the quantum dot may act as a protective layer that prevents chemical degeneration of the core to maintain semiconductor characteristics, and/or as a charging layer that imparts electrophoretic characteristics to the quantum dot. The shell may be a single layer or a multi-layer. The interface between the core and the shell may have a concentration gradient in which the concentration of an element existing in the shell decreases toward the center of the core.

Examples of the shell of the quantum dot may include an oxide of metal, metalloid, or non-metal, a semiconductor compound, or any combination thereof. Non-limiting examples of the oxide of metal, metalloid, or non-metal may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and/or the like; a ternary compound, such as MgAl₂O₄, CoFe₂O₄, NiFe₂O₄, CoMn₂O₄, and/or the like; or any combination thereof. Examples of the semiconductor compound may include: as described above, a Group II-VI semiconductor compound; a Group III-V semiconductor compound; a Group III-VI semiconductor compound; a Group I-III-VI semiconductor compound; a Group IV-VI semiconductor compound; or any combination thereof. For example, the semiconductor compound suitable as a shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

A full width at half maximum (FWHM) of the emission spectrum of the quantum dot may be about 45 nm or less, for example, about 40 nm or less, for example, about 30 nm or less, and within these ranges, color purity or color reproducibility of the quantum dot may be increased. In addition, because the light emitted through the quantum dot is emitted in all directions, the wide viewing angle may be improved.

In addition, the quantum dot may be in the form of a spherical particle, a pyramidal particle, a multi-arm particle, a cubic nanoparticle, a nanotube particle, a nanowire particle, a nanofiber particle, or a nanoplate particle.

Because an energy band gap of the quantum dot may be adjusted by controlling the size of the quantum dot, light having one or more suitable wavelength bands may be obtained from a quantum dot emission layer. Accordingly, by using quantum dots of different sizes, a light-emitting device that emits light of one or more suitable wavelengths may be implemented. In one or more embodiments, the size of quantum dots may be selected to enable the quantum dots to emit red light, green light, and/or blue light. In addition, the quantum dots with suitable sizes/diameters may be configured to emit white light by combination of light of one or more suitable colors.

### Electron Transport Region in Interlayer 130

The electron transport region may have i) a single-layered structure including (e.g., consisting of) a single layer including (e.g., consisting of) a single material, ii) a single-layered structure including (e.g., consisting of) a single layer including (e.g., consisting of) a plurality of different materials, or iii) a multi-layered structure including a plurality of layers including different materials.

The electron transport region may include: an electron injection layer; a hole blocking layer, an electron transport layer, or any combination thereof.

In one or more embodiments, an electron transport region may be arranged between the emission layer and the charge generation layer, and the electron transport region may include a hole blocking layer, an electron transport layer, an electron injection layer, or any combination thereof. For example, in one or more embodiments, the electron transport region may have a structure including an electron transport layer/electron injection layer structure or a hole blocking layer/electron transport layer/electron injection layer structure, wherein in each structure, constituting layers are sequentially stacked from the emission layer in the stated order.

In one or more embodiments, the electron transport region (for example, a hole blocking layer or an electron transport layer in the electron transport region) may include a metal-free compound including at least one π electron-deficient nitrogen-containing C₁-C₆₀ cyclic group.

For example, in one or more embodiments, the electron transport region may include a compound represented by Formula 601:

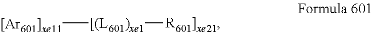

wherein, in Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each be the same as described herein with respect to Q₁,
xe21 may be 1, 2, 3, 4, or 5, and
at least one selected from among Ar₆₀₁, L₆₀₁, and R₆₀₁ may each independently be a π electron-deficient nitrogen-containing C₁-C₆₀ cyclic group unsubstituted or substituted with at least one R₁₀ₐ.

For example, in one or more embodiments, if (e.g., when) xe11 in Formula 601 is 2 or more, two or more of Ar₆₀₁(s) may be linked to each other via a single bond.

In one or more embodiments, Ar₆₀₁ in Formula 601 may be a substituted or unsubstituted anthracene group.

In one or more embodiments, the electron transport region may include a compound represented by Formula 601-1:

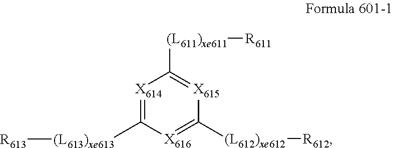

wherein, in Formula 601-1,
X₆₁₄ may be N or C(R₆₁₄), X₆₁₅ may be N or C(R₆₁₅), X₆₁₆ may be N or C(R₆₁₆), and at least one selected from among X₆₁₄ to X₆₁₆ may be N,
L₆₁₁ to L₆₁₃ may each independently be the same as described herein with respect to L₆₀₁,
xe611 to xe613 may each independently be the same as described herein with respect to xe1,
R₆₁₁ to R₆₁₃ may each independently be the same as described herein with respect to R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

For example, in one or more embodiments, xe1 and xe611 to xe613 in Formulae 601 and 601-1 may each independently be 0, 1, or 2.

In one or more embodiments, the electron transport region may include at least one of (e.g., selected from among) Compounds ET1 to ET45, 2,9-dimethyl-4,7-diphenyl-1,10-phenanthroline (BCP), 4,7-diphenyl-1,10-phenanthroline (Bphen), tris(8-hydroxyquinolinato)aluminum (Alq₃), bis(2-methyl-8-quinolinolato-N1,O8)-(1,1′-biphenyl-4-olato)aluminum (BAlq), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), or any combination thereof:

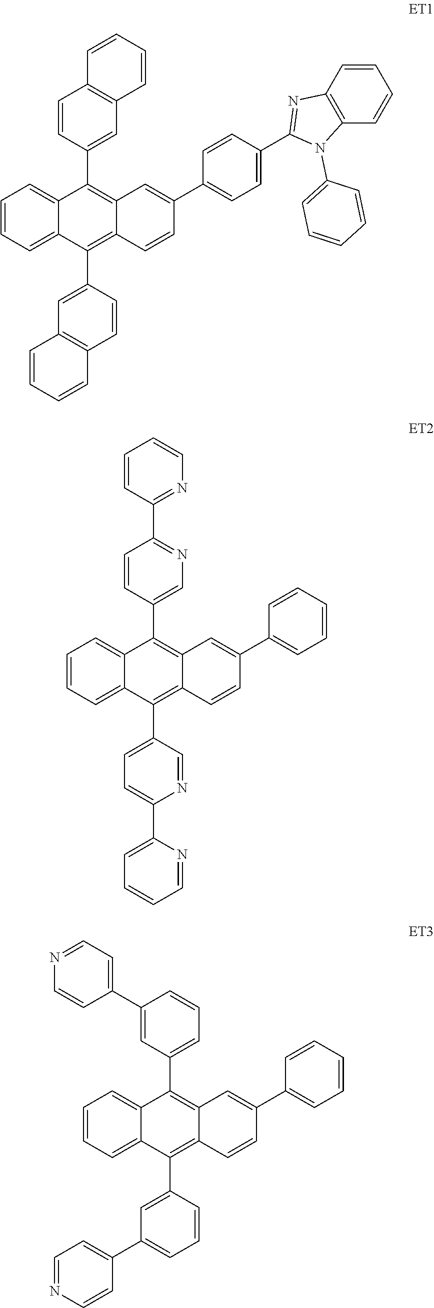 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

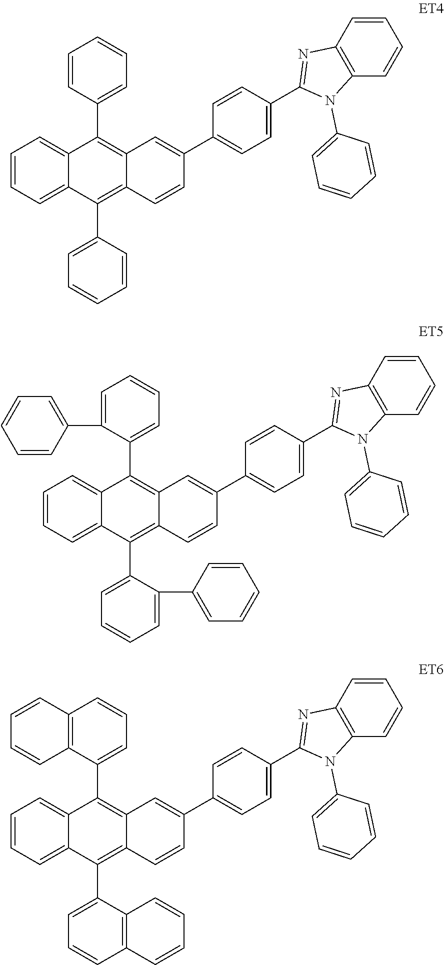 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

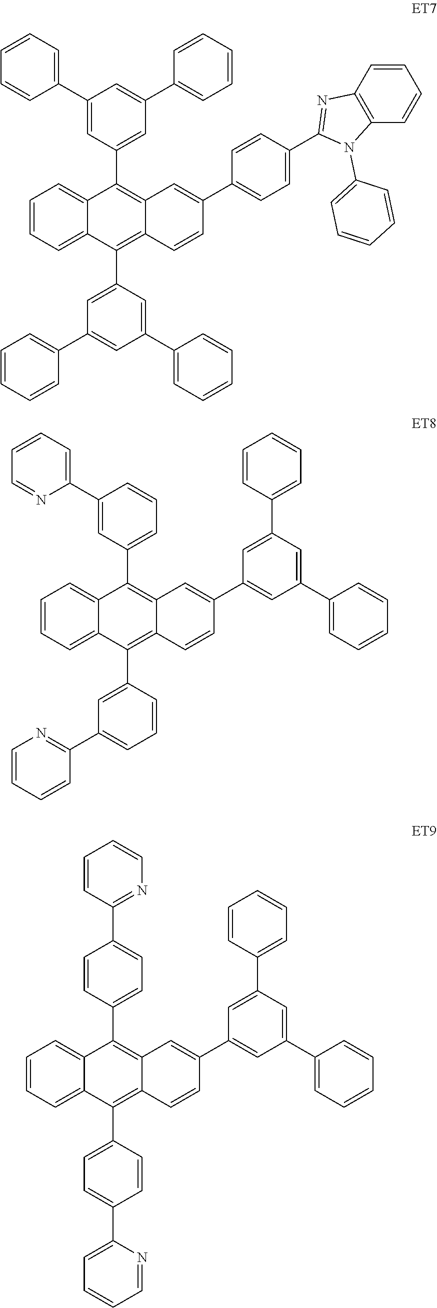

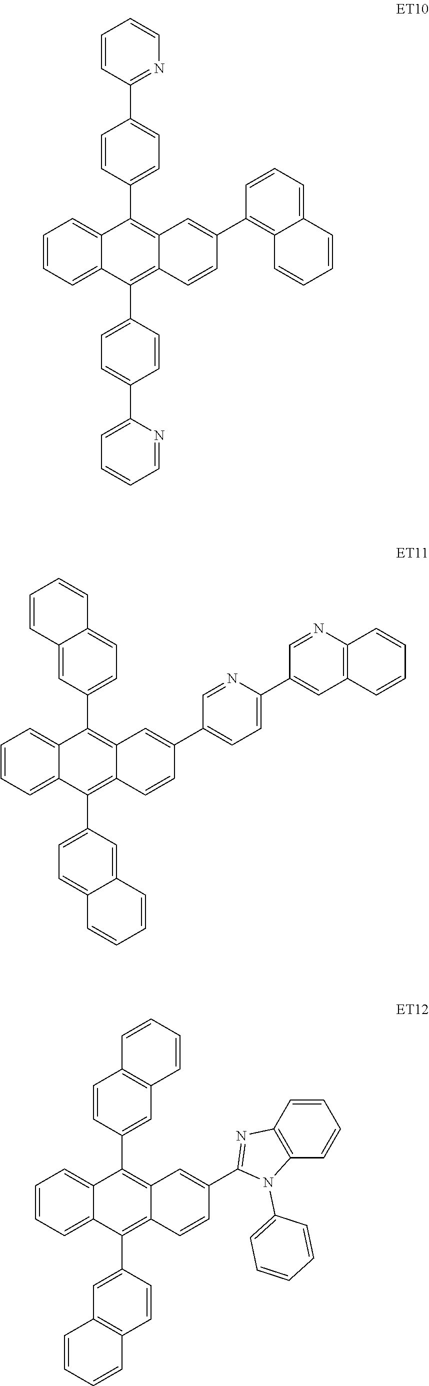 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

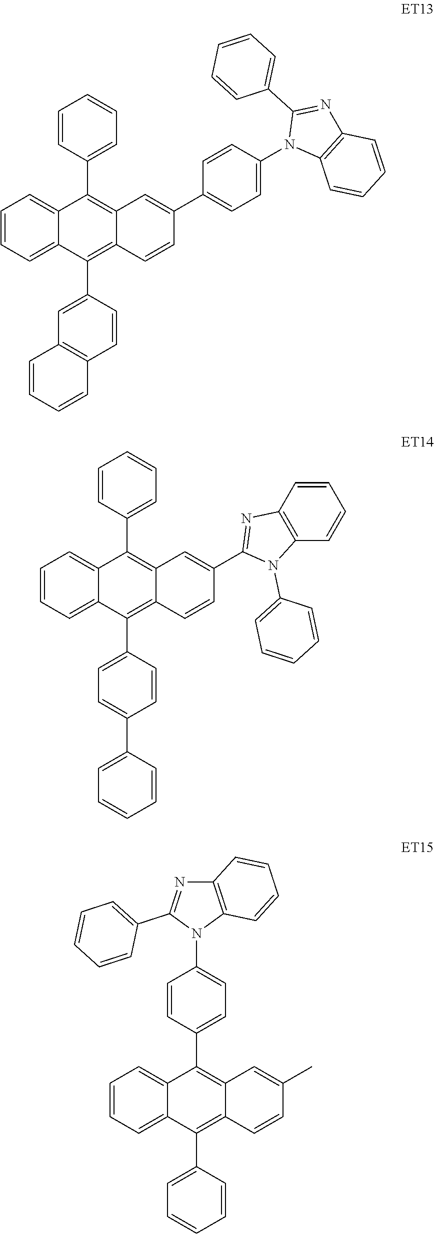 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

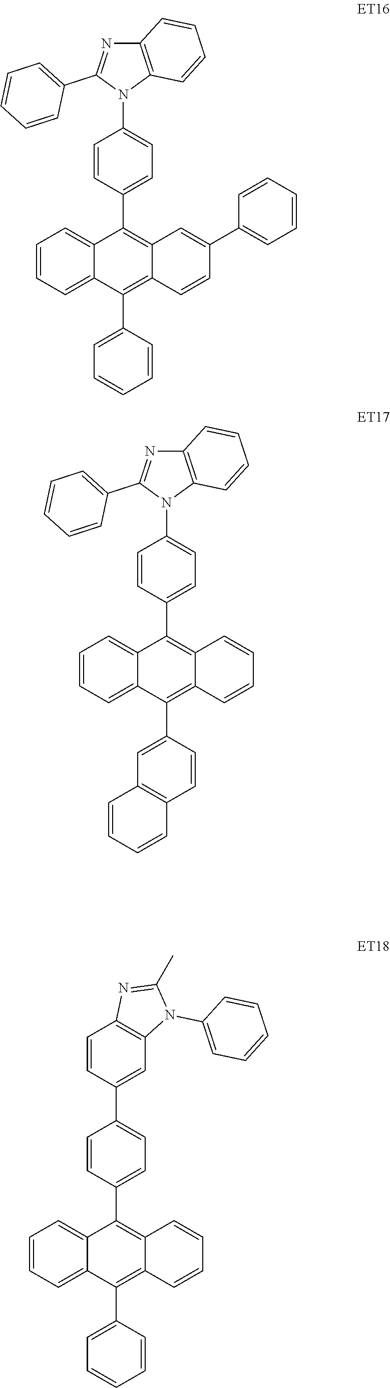 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

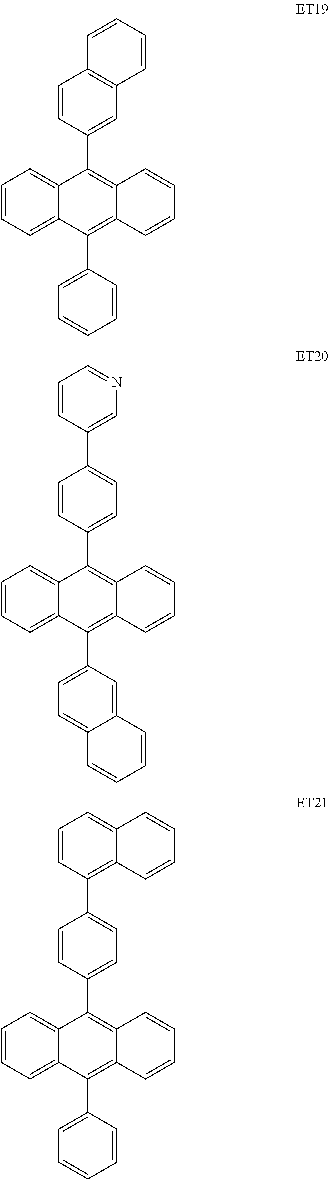

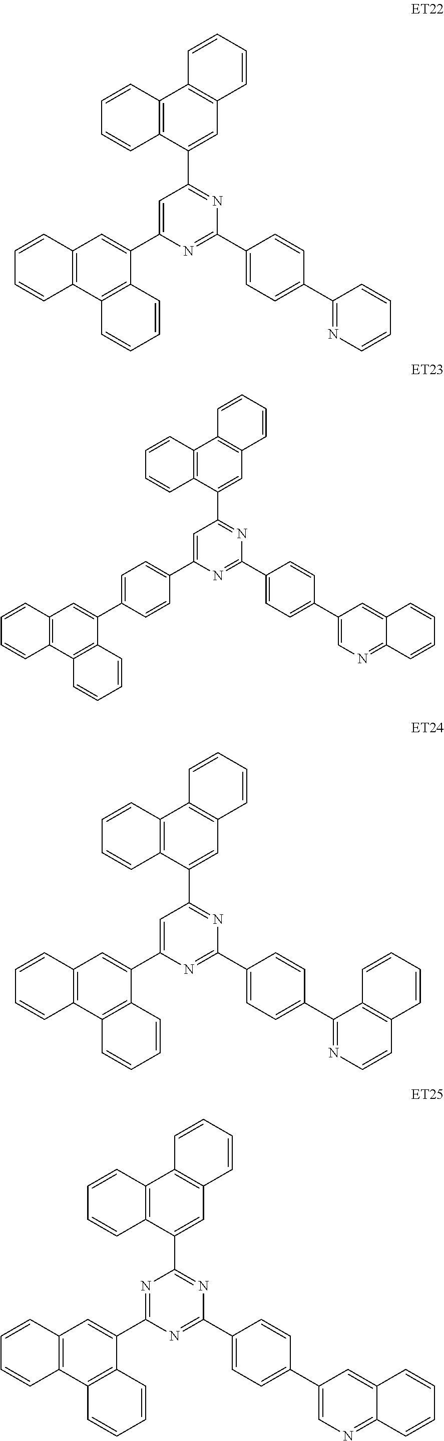 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

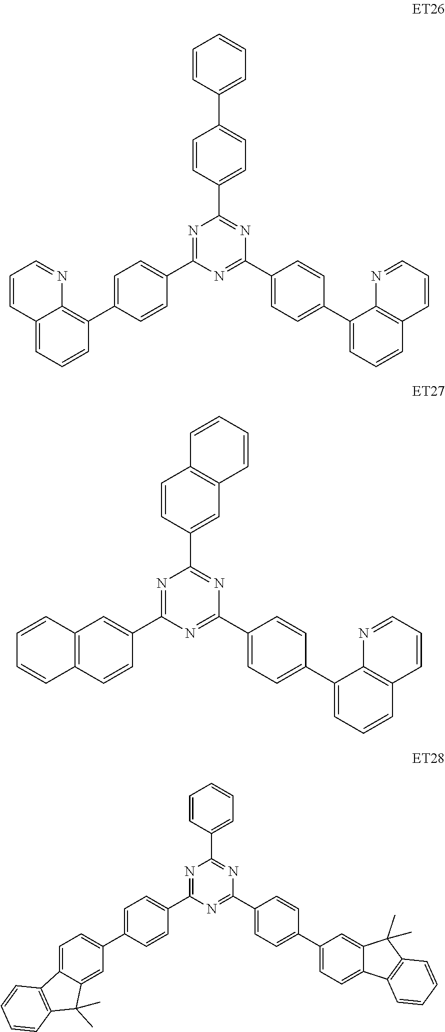 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

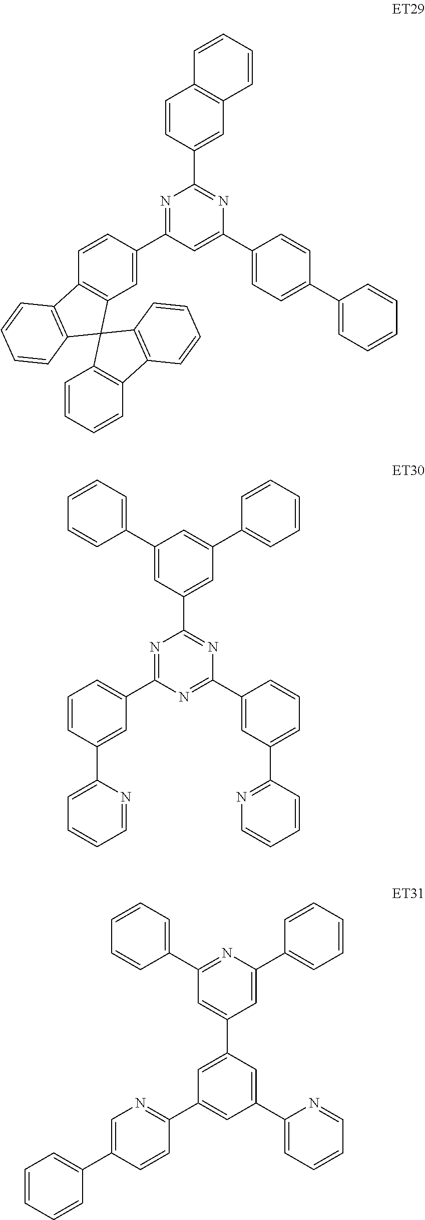 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

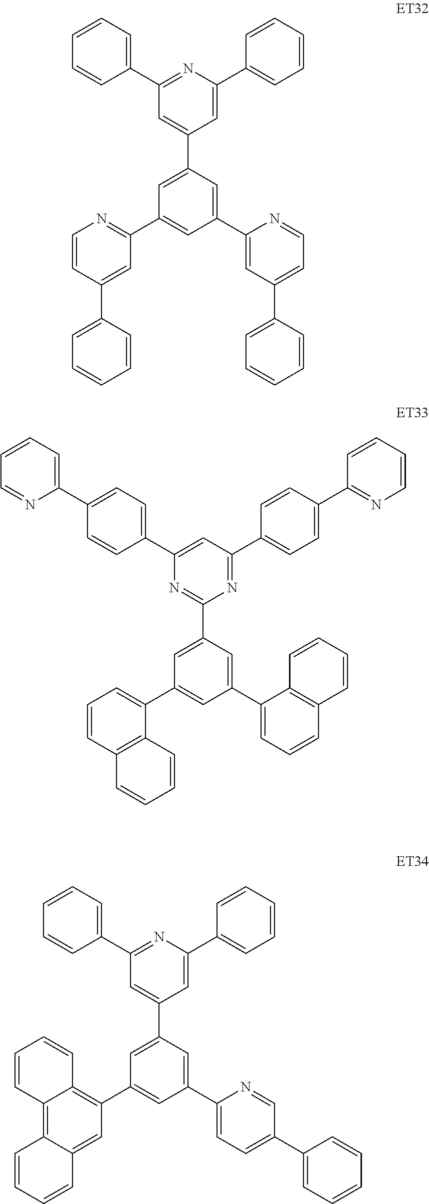 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

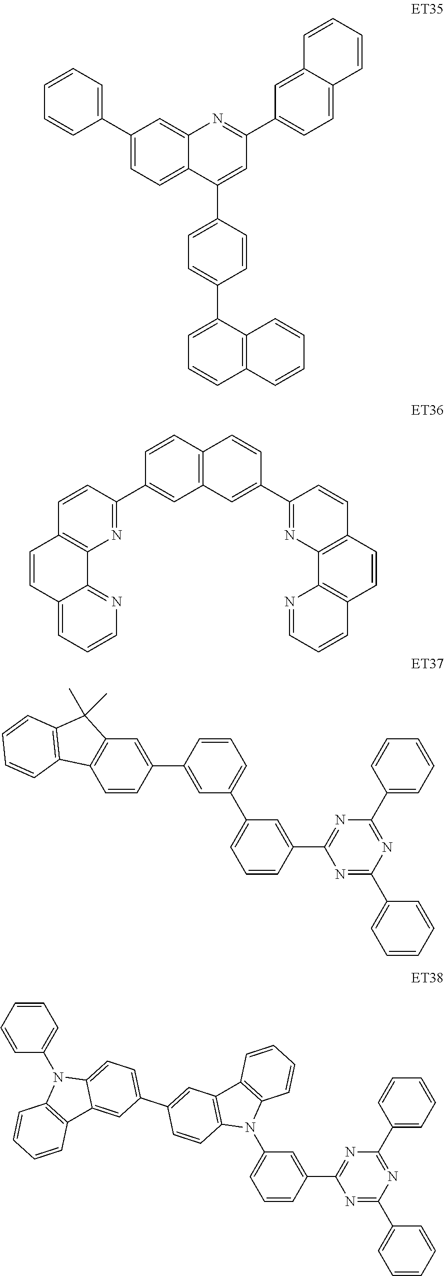

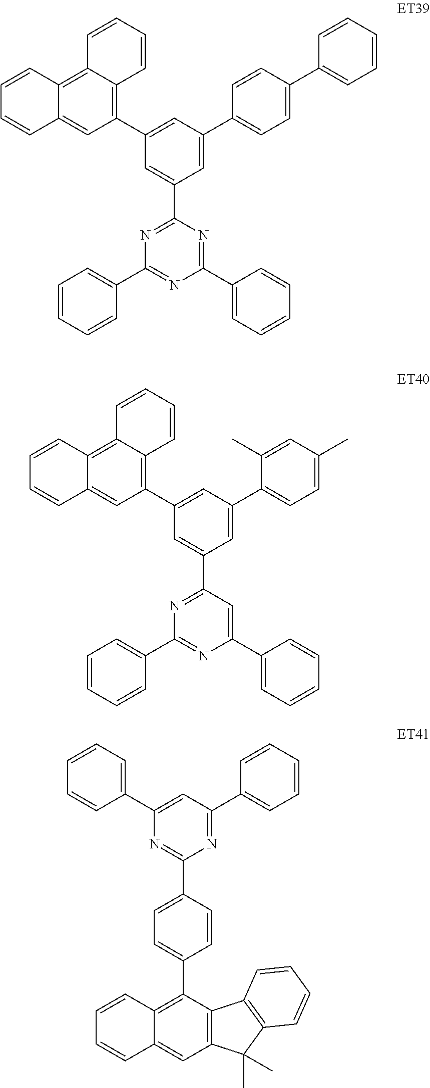

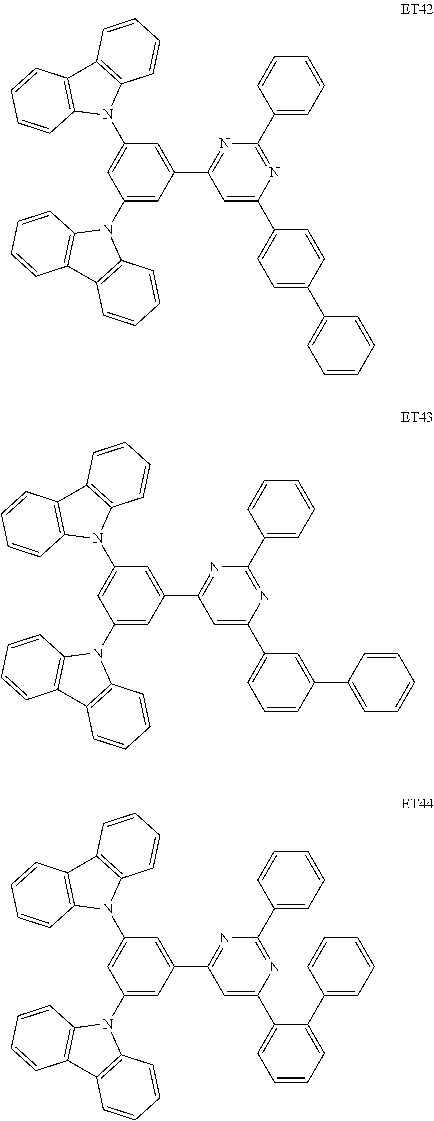 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2nc(-c3cc(-n4c5ccccc5c5ccccc54)cc(-n4c5ccccc5c5ccccc54)c3)cc(-c3ccccc3-c3ccccc3)n2)cc1]

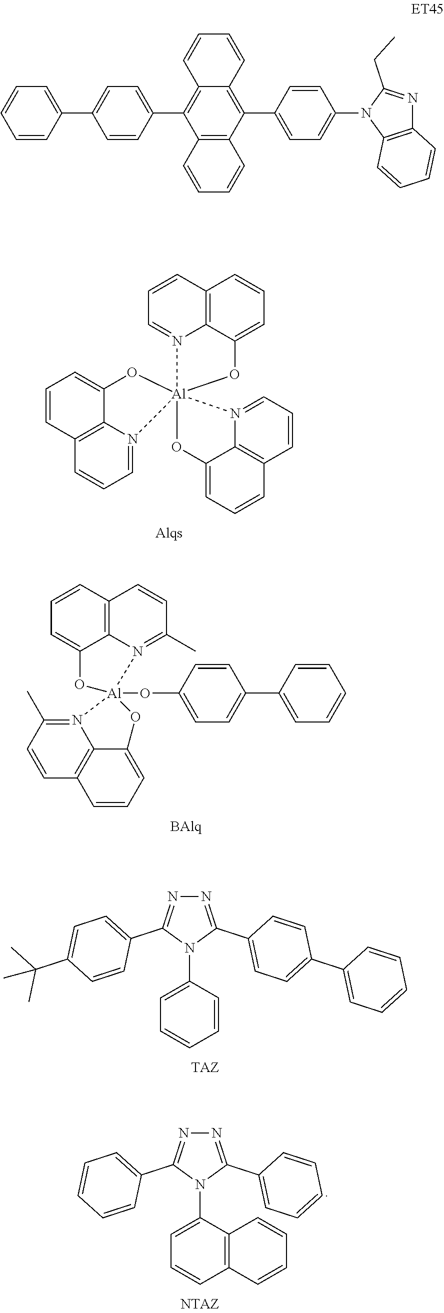

A thickness of the electron transport region may be from about 100 Å to about 5,000 Å, for example, about 160 Å to about 4,000 Å. When the electron transport region includes a hole blocking layer, an electron transport layer, or any combination thereof, a thickness of the hole blocking layer or the electron transport layer may each independently be about 20 Å to about 1,000 Å, for example, about 30 Å to about 300 Å, and, in some embodiments, the thickness of the electron transport layer may be about 100 Å to about 1,000 Å, for example, about 150 Å to about 500 Å. When the thicknesses of the hole blocking layer and/or the electron transport layer are within these ranges, satisfactory electron transporting characteristics may be obtained without a substantial increase in driving voltage.

In one or more embodiments, the electron transport region (for example, the electron transport layer in the electron transport region) may further include, in addition to one or more of the materials described above, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of the alkali metal complex or the metal ion of the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

For example, in one or more embodiments, the metal-containing material may include a Li complex. The Li complex may include, for example, Compound ET-D1 (Liq) or ET-D2:

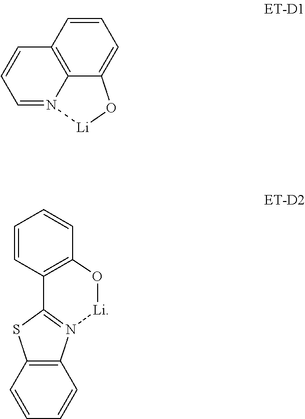

In one or more embodiments, the electron transport region may include an electron injection layer that facilitates the injection of electrons from the second electrode 150. The electron injection layer may directly contact the second electrode 150.

The electron injection layer may have: i) a single-layered structure including (e.g., consisting of) a single layer including (e.g., consisting of) a single material, ii) a single-layered structure including (e.g., consisting of) a single layer including (e.g., consisting of) a plurality of different materials, or iii) a multi-layered structure including a plurality of layers including a plurality of different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (for example, fluorides, chlorides, bromides, or iodides), or tellurides of the alkali metal, the alkaline earth metal, and the rare earth metal, respectively, or any combination thereof.

The alkali metal-containing compound may include: alkali metal oxides, such as Li₂O, Cs₂O, K₂O, and/or the like; alkali metal halides, such as LiF, NaF, CsF, KF, LiI, NaI, CsI, KI, and/or the like; or any combination thereof. The alkaline earth metal-containing compound may include an alkaline earth metal compound, such as BaO, SrO, CaO, BaₓSr₁₋ₓO (wherein x is a real number satisfying the condition of 0<x<1), BaₓCa₁₋ₓO (wherein x is a real number satisfying the condition of 0<x<1), and/or the like. The rare earth metal-containing compound may include YbF₃, ScF₃, SC₂O₃, Y₂O₃, Ce₂O₃, GdF₃, TbF₃, YbI₃, ScI₃, TbI₃, or any combination thereof. In one or more embodiments, the rare earth metal-containing compound may include a lanthanide metal telluride. Non-limiting examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, and/or the like.

The alkali metal complex, the alkaline earth-metal complex, and the rare earth metal complex may include i) one of metal ions of the alkali metal, one of metal ions of the alkaline earth metal, and one of metal ions of the rare earth metal, respectively, and ii) a ligand bonded to the metal ion (e.g., the respective metal ion), for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenylbenzimidazole, hydroxyphenylbenzothiazole, bipyridine, phenanthroline, cyclopentadiene, or any combination thereof.

In one or more embodiments, the electron injection layer may include (e.g., consist of) an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In one or more embodiments, the electron injection layer may further include an organic material (for example, a compound represented by Formula 601).

According to one or more embodiments, the electron injection layer may include (e.g., consist of): i) an alkali metal-containing compound (for example, an alkali metal halide); or ii) a) an alkali metal-containing compound (for example, an alkali metal halide), and b) an alkali metal, an alkaline earth metal, a rare earth metal, or any combination thereof. For example, in one or more embodiments, the electron injection layer may be a KI:Yb co-deposited layer, an RbI:Yb co-deposited layer, a LiF:Yb co-deposited layer, and/or the like.

When the electron injection layer further includes an organic material, an alkali metal, an alkaline earth metal, a rare earth metal, an alkali metal-containing compound, an alkaline earth metal-containing compound, a rare earth metal-containing compound, an alkali metal complex, an alkaline earth-metal complex, a rare earth metal complex, or any combination thereof may be uniformly (e.g., substantially uniformly) or non-uniformly dispersed in a matrix including the organic material.

A thickness of the electron injection layer may be in a range of about 1 Å to about 100 Å, for example, about 3 Å to about 90 Å. When the thickness of the electron injection layer is within the ranges described above, satisfactory electron injection characteristics may be obtained without a substantial increase in driving voltage.

### Second Electrode 150

The second electrode 150 may be arranged on the interlayer 130 having a structure as described above. The second electrode 150 may be a cathode, which is an electron injection electrode, and as a material for the second electrode 150, a metal, an alloy, an electrically conductive compound, or any combination thereof, each having a low-work function, may be used.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a transflective electrode, or a reflective electrode.

The second electrode 150 may have a single-layered structure or a multi-layered structure including a plurality of layers.

### Capping Layer

According to one or more embodiments, a first capping layer may be arranged outside (e.g., on) the first electrode 110, and/or a second capping layer may be arranged outside (e.g., on) the second electrode 150. For example, in one or more embodiments, the light-emitting device 10 may have a structure in which the first capping layer, the first electrode 110, the interlayer 130, and the second electrode 150 are sequentially stacked in the stated order, a structure in which the first electrode 110, the interlayer 130, the second electrode 150, and the second capping layer are sequentially stacked in the stated order, or a structure in which the first capping layer, the first electrode 110, the interlayer 130, the second electrode 150, and the second capping layer are sequentially stacked in the stated order.

In one or more embodiments, light generated in an emission layer of the interlayer 130 of the light-emitting device 10 may be extracted toward the outside through the first electrode 110 which is a transflective electrode or a transmissive electrode, and the first capping layer. In one or more embodiments, light generated in an emission layer of the interlayer 130 of the light-emitting device 10 may be extracted toward the outside through the second electrode 150 which is a transflective electrode or a transmissive electrode, and the second capping layer.

The first capping layer and the second capping layer may increase external emission efficiency according to the principle of constructive interference. Accordingly, the light extraction efficiency of the light-emitting device 10 is increased, so that the luminescence efficiency of the light-emitting device 10 may be improved.

Each of the first capping layer and the second capping layer may include a material having a refractive index of 1.6 or more (e.g., at 589 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer and/or the second capping layer may (e.g., the first capping layer and the second capping layer may each independently) include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may each optionally be substituted with a substituent including O, N, S, Se, Si, F, Cl, Br, I, or any combination thereof. According to one or more embodiments, at least one of the first capping layer and/or the second capping layer may (e.g., the first capping layer and the second capping layer may each independently) include an amine group-containing compound.

In one or more embodiments, at least one of the first capping layer and/or the second capping layer may (e.g., the first capping layer and the second capping layer may each independently) include a compound represented by Formula 201, a compound represented by Formula 202, or any combination thereof.

According to one or more embodiments, at least one of the first capping layer and/or the second capping layer may (e.g., the first capping layer and the second capping layer may each independently) include at least one of (e.g., selected from among) Compounds HT28 to HT33, at least one of (e.g., selected from among) Compounds CP1 to CP6, B—NPB, or any combination thereof:

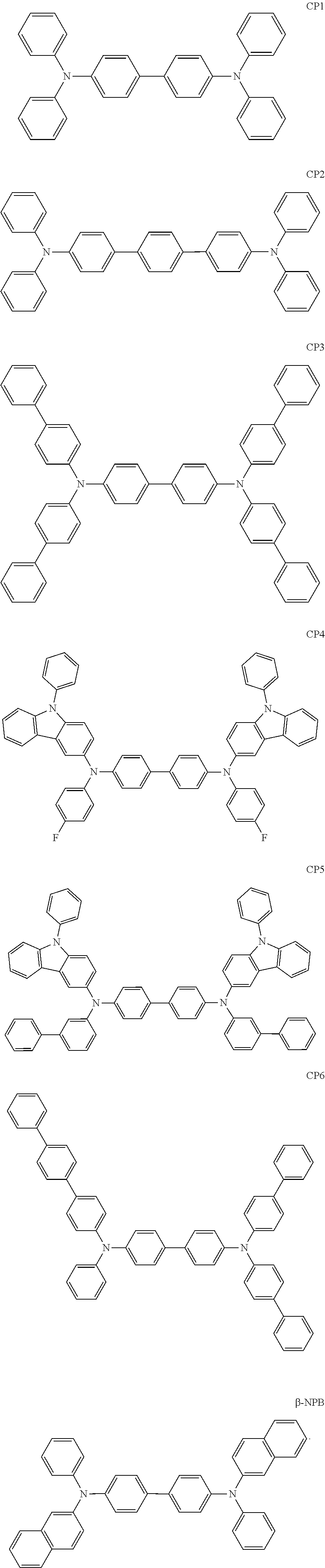

### Electronic Apparatus

The light-emitting device may be included in one or more suitable electronic apparatuses. For example, the electronic apparatus including the light-emitting device may be a light-emitting apparatus, an authentication apparatus, and/or the like.

In one or more embodiments, the electronic apparatus (for example, a light-emitting apparatus) may further include, in addition to the light-emitting device, i) a color filter, ii) a color conversion layer, or iii) a color filter and a color conversion layer. The color filter and/or the color conversion layer may be arranged in at least one direction in which light emitted from the light-emitting device travels. For example, in one or more embodiments, the light emitted from the light-emitting device may be blue light. Details on the light-emitting device may be the same as described herein. According to one or more embodiments, the color conversion layer may include a quantum dot. The quantum dot may be, for example, a quantum dot as described herein.

The electronic apparatus may include a first substrate. The first substrate may include a plurality of subpixel areas, the color filter may include a plurality of color filter areas respectively corresponding to the subpixel areas, and the color conversion layer may include a plurality of color conversion areas respectively corresponding to the subpixel areas.

A pixel-defining film may be arranged among the subpixel areas to define each of the subpixel areas.

In one or more embodiments, the color filter may further include a plurality of color filter areas and light-shielding patterns arranged among the color filter areas, and the color conversion layer may further include a plurality of color conversion areas and light-shielding patterns arranged among the color conversion areas.

The plurality of color filter areas (or the plurality of color conversion areas) may include: a first area configured to emit first color light; a second area configured to emit second color light; and/or a third area configured to emit third color light, wherein the first color light, the second color light, and/or the third color light may have different maximum emission wavelengths from one another. For example, in one or more embodiments, the first color light may be red light, the second color light may be green light, and the third color light may be blue light. For example, in one or more embodiments, the plurality of color filter areas (or the plurality of color conversion areas) may include quantum dots. For example, the first area may include a red quantum dot to emit red light, the second area may include a green quantum dot to emit green light, and the third area may not include (e.g., may exclude) a quantum dot. Details on the quantum dot may be the same as described herein. Each of the first area, the second area, and/or the third area may further include a scatter.

In one or more embodiments, the light-emitting device may be to emit first light, the first area may be to absorb the first light to emit first-first color light, the second area may be to absorb the first light to emit second-first color light, and the third area may be to absorb the first light to emit third-first color light. Here, the first-first color light, the second-first color light, and the third-first color light may have different maximum emission wavelengths from one another. For example, the first light may be blue light, the first-first color light may be red light, the second-first color light may be green light, and the third-first color light may be blue light.

In one or more embodiments, the electronic apparatus may further include a thin-film transistor, in addition to the light-emitting device as described above. The thin-film transistor may include a source electrode, a drain electrode, and an activation layer, wherein one selected from among the source electrode and the drain electrode may be electrically connected to the first electrode or the second electrode of the light-emitting device.

The thin-film transistor may further include a gate electrode, a gate insulating film, and/or the like.

The activation layer may include crystalline silicon, amorphous silicon, an organic semiconductor, an oxide semiconductor, and/or the like.

In one or more embodiments, the electronic apparatus may further include a sealing portion for sealing the light-emitting device. The sealing portion may be arranged between the color filter and/or the color conversion layer and the light-emitting device. The sealing portion allows light from the light-emitting device to be extracted to the outside, and concurrently (e.g., simultaneously) prevents ambient air and moisture from penetrating into the light-emitting device. The sealing portion may be a sealing substrate including a transparent glass substrate or a plastic substrate. The sealing portion may be a thin-film encapsulation layer including at least one layer of an organic layer and/or an inorganic layer. When the sealing portion is a thin-film encapsulation layer, the electronic apparatus may be flexible.

In one or more embodiments, various functional layers may be additionally arranged on the sealing portion, in addition to the color filter and/or the color conversion layer, according to the use of the electronic apparatus. Non-limiting examples of the functional layers may include a touch screen layer, a polarizing layer, and/or the like. The touch screen layer may be a pressure-sensitive touch screen layer, a capacitive touch screen layer, or an infrared touch screen layer.

The authentication apparatus may be, for example, a biometric authentication apparatus that authenticates an individual by using biometric information of a living body (for example, fingertips, pupils, and/or the like). The authentication apparatus may further include, in addition to the light-emitting device as described above, a biometric information collector.

The electronic apparatus may be applied to one or more of displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, one or more suitable measuring instruments, meters (for example, meters for a vehicle, an aircraft, and a vessel), projectors, and/or the like.

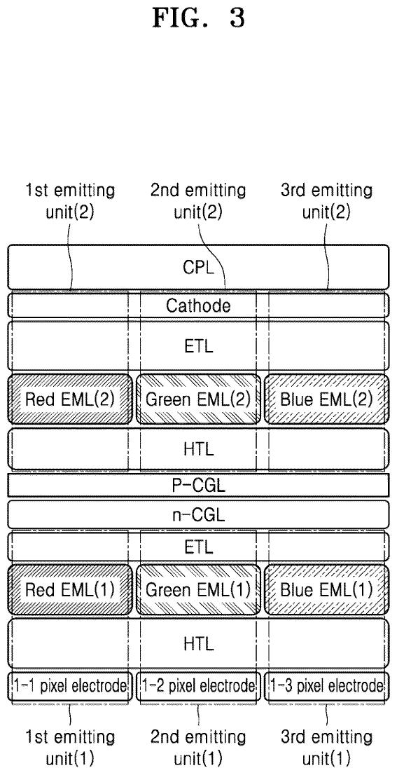

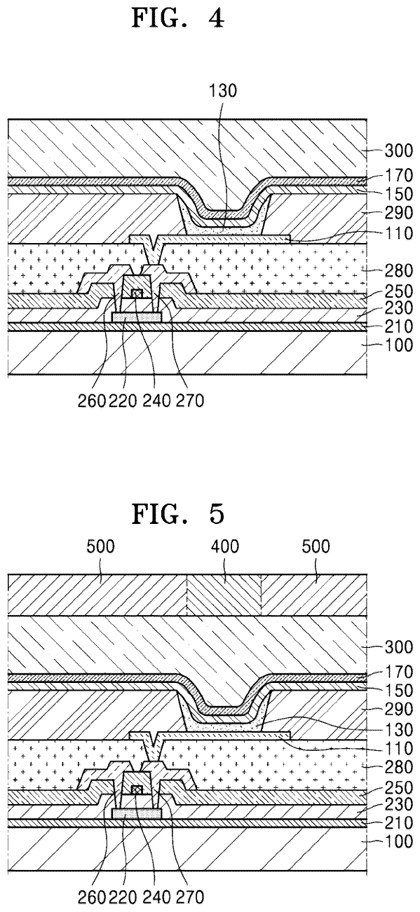

### Descriptions of FIGS. 4 and 5

FIG. 4 is a cross-sectional view of an electronic apparatus according to one or more embodiments of the present disclosure.

The electronic apparatus of FIG. 4 includes a substrate 100, a thin-film transistor (TFT), a light-emitting device, and an encapsulation portion 300 that seals the light-emitting device.

The substrate 100 may be a flexible substrate, a glass substrate, or a metal substrate. A buffer layer 210 may be on the substrate 100. The buffer layer 210 may prevent or reduce penetration of impurities through the substrate 100 and may provide a flat surface on the substrate 100.

The TFT may be on the buffer layer 210. The TFT may include an activation layer 220, a gate electrode 240, a source electrode 260, and a drain electrode 270.

The activation layer 220 may include an inorganic semiconductor such as silicon or polysilicon, an organic semiconductor, or an oxide semiconductor, and may include a source region, a drain region, and a channel region.

A gate insulating film 230 for insulating the activation layer 220 from the gate electrode 240 may be on the activation layer 220, and the gate electrode 240 may be on the gate insulating film 230.

An interlayer insulating film 250 may be on the gate electrode 240. The interlayer insulating film 250 may be arranged between the gate electrode 240 and the source electrode 260 and between the gate electrode 240 and the drain electrode 270, to insulate from one another.

The source electrode 260 and the drain electrode 270 may be on the interlayer insulating film 250. The interlayer insulating film 250 and the gate insulating film 230 may be formed to expose the source region and the drain region of the activation layer 220, and the source electrode 260 and the drain electrode 270 may be arranged in contact with the exposed portions of the source region and the drain region of the activation layer 220, respectively.

The TFT may be electrically connected to the light-emitting device to drive the light-emitting device, and may be covered and protected by a passivation layer 280. The passivation layer 280 may include an inorganic insulating film, an organic insulating film, or any combination thereof. The light-emitting device is provided on the passivation layer 280. The light-emitting device may include a first electrode 110, an interlayer 130, and a second electrode 150.

The first electrode 110 may be on the passivation layer 280. The passivation layer 280 may be arranged to expose a portion of the drain electrode 270, not fully covering the drain electrode 270, and the first electrode 110 may be arranged to be connected to the exposed portion of the drain electrode 270.

A pixel-defining film 290 including an insulating material may be on the first electrode 110. The pixel-defining film 290 may expose a certain region of the first electrode 110, and an interlayer 130 may be formed in the exposed region of the first electrode 110. The pixel-defining film 290 may be a polyimide or polyacrylic organic film. Although not shown in FIG. 4, in one or more embodiments, at least some layers of the interlayer 130 may extend beyond the upper portion of the pixel-defining film 290 and may thus be arranged in the form of a common layer. For example, at least some layers of the interlayer 130 may extend beyond the top of the pixel-defining film 290, forming a common layer.

The second electrode 150 may be on the interlayer 130, and a capping layer 170 may be additionally formed on the second electrode 150. The capping layer 170 may be formed to cover the second electrode 150.

The encapsulation portion 300 may be arranged on the capping layer 170. The encapsulation portion 300 may be arranged on the light-emitting device to protect the light-emitting device from moisture and/or oxygen. The encapsulation portion 300 may include: an inorganic film including silicon nitride (SiNₓ, e.g., Si₃N₄), silicon oxide (SiOₓ, e.g., SiO₂), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic-based resin (for example, polymethyl methacrylate, polyacrylic acid, and/or the like), an epoxy-based resin (for example, aliphatic glycidyl ether (AGE), and/or the like), or any combination thereof; or any combination of the inorganic films and the organic films.

FIG. 5 is a cross-sectional view of an electronic apparatus according to one or more embodiments of the present disclosure.

The electronic apparatus of FIG. 5 is substantially the same as the electronic apparatus of FIG. 4, except that a light-shielding pattern 500 and a functional region 400 are additionally arranged on the encapsulation portion 300. The functional region 400 may be i) a color filter area, ii) a color conversion area, or iii) a combination of the color filter area and the color conversion area. According to one or more embodiments, the light-emitting device included in the electronic apparatus of FIG. 5 may be a tandem light-emitting device.

### Manufacturing Method

Layers constituting the hole transport region, an emission layer, and layers constituting the electron transport region may be formed in a certain region by using one or more suitable methods such as vacuum deposition, spin coating, casting, Langmuir-Blodgett (LB) deposition, ink-jet printing, laser-printing, laser-induced thermal imaging (LITI), and/or the like.

When layers constituting the hole transport region, an emission layer, and layers constituting the electron transport region are each formed by vacuum deposition, the deposition may be performed at a deposition temperature of about 100° C. to about 500° C., a vacuum degree of about 10-8 torr to about 10-3 torr, and a deposition speed of about 0.01 Å/sec to about 100 Å/sec, depending on a material to be included in a layer to be formed and the structure of a layer to be formed.

When layers constituting the hole transport region, an emission layer, and layers constituting the electron transport region are formed by spin coating, the spin coating may be performed at a coating speed of about 2,000 rpm to about 5,000 rpm and at a heat treatment temperature of about 80° C. to about 200° C. by taking into account a material to be included in a layer to be formed and the structure of a layer to be formed.

### Definition of Terms

The term “C₃-C₆₀ carbocyclic group” as used herein refers to a cyclic group including (e.g., consisting of) carbon only as a ring-forming atom and having 3 to 60 carbon atoms, and the term “C₁-C₆₀ heterocyclic group” as used herein refers to a cyclic group having 1 to 60 carbon atoms and further having, in addition to carbon, a heteroatom as a ring-forming atom. The C₃-C₆₀ carbocyclic group and the C₁-C₆₀ heterocyclic group may each be a monocyclic group including (e.g., consisting of) one (e.g., exactly one) ring or a polycyclic group in which two or more rings are condensed with each other. For example, the C₁-C₆₀ heterocyclic group may have 3 to 61 ring-forming atoms.

The term “cyclic group” as used herein may include both (e.g., simultaneously) the C₃-C₆₀ carbocyclic group and the C₁-C₆₀ heterocyclic group.

The term “π electron-rich C₃-C₆₀ cyclic group” as used herein refers to a cyclic group that has 3 to 60 carbon atoms and does not include *—N═*′ as a ring-forming moiety, and the term “π electron-deficient nitrogen-containing C₁-C₆₀ cyclic group” as used herein refers to a heterocyclic group that has 1 to 60 carbon atoms and includes *—N═*′ as a ring-forming moiety.

For example,
the C₃-C₆₀ carbocyclic group may be i) Group T1 or ii) a condensed cyclic group in which two or more of Group T1 are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
the C₁-C₆₀ heterocyclic group may be i) Group T2, ii) a condensed cyclic group in which two or more of Group T2 are condensed with each other, or iii) a condensed cyclic group in which one or more of Group T2 and one or more of Group T₁ are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),
the π electron-rich C₃-C₆₀ cyclic group may be i) Group T1, ii) a condensed cyclic group in which two or more of Group T1 are condensed with each other, iii) Group T3, iv) a condensed cyclic group in which two or more of Group T3 are condensed with each other, or v) a condensed cyclic group in which one or more of Group T3 and one or more of Group T1 are condensed with each other (for example, the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, and/or the like),
the π electron-deficient nitrogen-containing C₁-C₆₀ cyclic group may be i) Group T4, ii) a condensed cyclic group in which two or more of Group T4 are condensed with each other, iii) a condensed cyclic group in which one or more of Group T4 and one or more of Group T1 are condensed with each other, iv) a condensed cyclic group in which one or more of Group T4 and one or more of Group T3 are condensed with each other, or v) a condensed cyclic group in which one or more of Group T4, one or more of Group T1, and one or more of Group T3 are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),
Group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,
Group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
Group T3 may be a furan group, a thiophene group, a 1H-pyrrole group, a silole group, or a borole group, and
Group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “cyclic group”, “C₃-C₆₀ carbocyclic group”, “C₁-C₆₀ heterocyclic group”, “π electron-rich C₃-C₆₀ cyclic group”, and “π electron-deficient nitrogen-containing C₁-C₆₀ cyclic group” as used herein may each refer to a group condensed to any cyclic group, a monovalent group, or a polyvalent group (for example, a divalent group, a trivalent group, a tetravalent group, and/or the like) according to the structure of a formula for which the corresponding term is used. For example, the “benzene group” may be a benzo group, a phenyl group, a phenylene group, and/or the like, which may be easily understood by those of ordinary skill in the art according to the structure of a formula including the “benzene group.”

For example, non-limiting examples of a monovalent C₃-C₆₀ carbocyclic group and a monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group, and non-limiting examples of a divalent C₃-C₆₀ carbocyclic group and a divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein refers to a linear or branched aliphatic hydrocarbon monovalent group that has 1 to 60 carbon atoms, and non-limiting examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, and/or the like. The term “C₁-C₆₀ alkylene group” as used herein refers to a divalent group having substantially the same structure as the C₁-C₆₀ alkyl group.

The term “C₂-C₆₀ alkenyl group” as used herein refers to a monovalent hydrocarbon group having at least one carbon-carbon double bond in the middle or at the terminus of a C₂-C₆₀ alkyl group, and non-limiting examples thereof may include an ethenyl group, a propenyl group, a butenyl group, and/or the like. The term “C₂-C₆₀ alkenylene group” as used herein refers to a divalent group having substantially the same structure as the C₂-C₆₀ alkenyl group.

The term “C₂-C₆₀ alkynyl group” as used herein refers to a monovalent hydrocarbon group having at least one carbon-carbon triple bond in the middle or at the terminus of a C₂-C₆₀ alkyl group, and non-limiting examples thereof may include an ethynyl group, a propynyl group, and/or the like. The term “C₂-C₆₀ alkynylene group” as used herein refers to a divalent group having substantially the same structure as the C₂-C₆₀ alkynyl group.

The term “C₁-C₆₀ alkoxy group” as used herein refers to a monovalent group represented by —OA₁₀₁ (wherein A₁₀₁ is a C₁-C₆₀ alkyl group), and non-limiting examples thereof may include a methoxy group, an ethoxy group, an isopropyloxy group, and/or the like.

The term “C₃-C₁₀ cycloalkyl group” as used herein refers to a monovalent saturated hydrocarbon cyclic group having 3 to 10 carbon atoms, and non-limiting examples thereof may include a cyclopropyl group, a cyclobutyl group, a cyclopentyl group, a cyclohexyl group, a cycloheptyl group, a cyclooctyl group, an adamantyl group, a norbornyl group (or bicyclo[2.2.1]heptyl group), a bicyclo[1.1.1]pentyl group, a bicyclo[2.1.1]hexyl group, a bicyclo[2.2.2]octyl group, and/or the like. The term “C₃-C₁₀ cycloalkylene group” as used herein refers to a divalent group having substantially the same structure as the C₃-C₁₀ cycloalkyl group.

The term “C₁-C₁₀ heterocycloalkyl group” as used herein refers to a monovalent cyclic group that has 1 to 10 carbon atoms and further includes, in addition to the carbon atoms, at least one heteroatom as a ring-forming atom, and non-limiting examples thereof may include a 1,2,3,4-oxatriazolidinyl group, a tetrahydrofuranyl group, a tetrahydrothiophenyl group, and/or the like. The term “C₁-C₁₀ heterocycloalkylene group” as used herein refers to a divalent group having substantially the same structure as the C₁-C₁₀ heterocycloalkyl group.

The term “C₃-C₁₀ cycloalkenyl group” as used herein refers to a monovalent cyclic group that has 3 to 10 carbon atoms and at least one carbon-carbon double bond in the ring thereof and no aromaticity, and non-limiting examples thereof may include a cyclopentenyl group, a cyclohexenyl group, a cycloheptenyl group, and/or the like. The term “C₃-C₁₀ cycloalkenylene group” as used herein refers to a divalent group having substantially the same structure as the C₃-C₁₀ cycloalkenyl group.

The term “C₁-C₁₀ heterocycloalkenyl group” as used herein refers to a monovalent cyclic group that has 1 to 10 carbon atoms, further includes, in addition to the carbon atoms, at least one heteroatom as a ring-forming atom, and has at least one double bond in the ring thereof. Non-limiting examples of the C₁-C₁₀ heterocycloalkenyl group may include a 4,5-dihydro-1,2,3,4-oxatriazolyl group, a 2,3-dihydrofuranyl group, a 2,3-dihydrothiophenyl group, and/or the like. The term “C₁-C₁₀ heterocycloalkenylene group” as used herein refers to a divalent group having substantially the same structure as the C₁-C₁₀ heterocycloalkenyl group.

The term “C₆-C₆₀ aryl group” as used herein refers to a monovalent group having a carbocyclic aromatic system of 6 to 60 carbon atoms, and the term “C₆-C₆₀ arylene group” as used herein refers to a divalent group having a carbocyclic aromatic system of 6 to 60 carbon atoms. Non-limiting examples of the C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and/or the like. When the C₆-C₆₀ aryl group and the C₆-C₆₀ arylene group each include two or more rings, the rings may be condensed with each other.

The term “C₁-C₆₀ heteroaryl group” as used herein refers to a monovalent group having a heterocyclic aromatic system that has 1 to 60 carbon atoms and further includes, in addition to the carbon atoms, at least one heteroatom as a ring-forming atom. The term “C₁-C₆₀ heteroarylene group” as used herein refers to a divalent group having a heterocyclic aromatic system that has 1 to 60 carbon atoms and further includes, in addition to the carbon atoms, at least one heteroatom as a ring-forming atom. Non-limiting examples of the C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and/or the like. When the C₁-C₆₀ heteroaryl group and the C₁-C₆₀ heteroarylene group each include two or more rings, the two or more rings may be condensed with each other.

The term “monovalent non-aromatic condensed polycyclic group” as used herein refers to a monovalent group (for example, having 8 to 60 carbon atoms) having two or more rings condensed to each other, only carbon atoms as ring-forming atoms, and no aromaticity in its entire molecular structure as a whole. Non-limiting examples of the monovalent non-aromatic condensed polycyclic group may include an indenyl group, a fluorenyl group, a spiro-bifluorenyl group, a benzofluorenyl group, an indenophenanthrenyl group, an indeno anthracenyl group, and/or the like. The term “divalent non-aromatic condensed polycyclic group” as used herein refers to a divalent group having substantially the same structure as the monovalent non-aromatic condensed polycyclic group described above.

The term “monovalent non-aromatic condensed heteropolycyclic group” as used herein refers to a monovalent group (for example, having 1 to 60 carbon atoms) having two or more rings condensed to each other, further including, in addition to carbon atoms, at least one heteroatom, as a ring-forming atom, and having non-aromaticity in its entire molecular structure as a whole. Non-limiting examples of the monovalent non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, a benzothienodibenzothiophenyl group, and/or the like. The term “divalent non-aromatic condensed heteropolycyclic group” as used herein refers to a divalent group having substantially the same structure as the monovalent non-aromatic condensed heteropolycyclic group described above.

The term “C₆-C₆₀ aryloxy group” as used herein refers to —OA₁₀₂ (wherein A₁₀₂ is a C₆-C₆₀ aryl group), and the term “C₆-C₆₀ arylthio group” as used herein refers to —SA₁₀₃ (wherein A₁₀₃ is a C₆-C₆₀ aryl group).

The term “C₇-C₆₀ arylalkyl group” as used herein refers to -A₁₀₄A₁₀₅ (wherein A₁₀₄ is a C₁-C₅₄ alkylene group, and A₁₀₅ is a C₆-C₅₉ aryl group), and the term “C₂-C₆₀ heteroarylalkyl group” as used herein refers to -A₁₀₆A₁₀₇ (wherein A₁₀₆ is a C₁-C₅₉ alkylene group, and A₁₀₇ is a C₁-C₅₉ heteroaryl group).

The term “R₁₀ₐ” as used herein may refer to:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₅-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or
a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

The term “heteroatom” as used herein refers to any atom other than a carbon atom. non-limiting examples of the heteroatom may include O, S, N, P, Si, B, Ge, Se, or any combinations thereof.

The term “transition metal” as used herein may include hafnium (Hf), tantalum (Ta), tungsten (W), rhenium (Re), osmium (Os), iridium (Ir), platinum (Pt), gold (Au), and/or the like.

The term “Ph” as used herein refers to a phenyl group, the term “Me” as used herein refers to a methyl group, the term “Et” as used herein refers to an ethyl group, the term “tert-Bu” or “But” as used herein refers to a tert-butyl group, and the term “OMe” as used herein refers to a methoxy group.

The term “biphenyl group” as used herein refers to “a phenyl group substituted with a phenyl group.” In one or more embodiments, the “biphenyl group” may be “a substituted phenyl group having a “C₆-C₆₀ aryl group” as a substituent.

The term “terphenyl group” as used herein refers to “a phenyl group substituted with a biphenyl group”. In one or more embodiments, the “terphenyl group” may be “a substituted phenyl group” having, as a substituent, “a C₆-C₆₀ aryl group that is substituted with a C₆-C₆₀ aryl group.”

The number of carbon atoms in the substituent definition is an example. For example, in the C₁-C₆₀ alkyl group, the number of carbon atoms, 60, is an example, and the definition for the alkyl group is equally applied to the C₁-C₂₀ alkyl group. The same applies to other cases.

Any hydrogen in the compound structures described herein may optionally be substituted with deuterium.

* and *′ as used herein, unless defined otherwise, each refer to a binding site to a neighboring atom in a corresponding formula.

Hereinafter, a light-emitting device according to one or more embodiments will be described in more detail with reference to the following Examples.

### EXAMPLES

### Synthesis Examples

### Synthesis of Compound 3

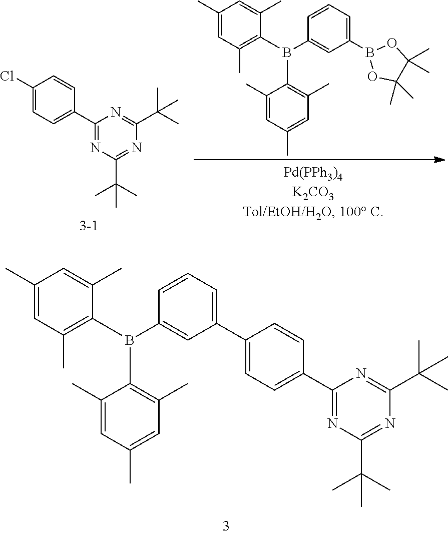

Intermediate 3-1 (3.03 g), tetrakis(triphenylphosphine)palladium(0) (Pd(PPh₃)₄) (0.56 g), K₂CO₃ (3.45 g), 2-(3-(dimesitylboranyl)phenyl)-4,4,5,5-tetramethyl-1,3,2-dioxaborolane (4.52 g) were dissolved in toluene(Tol)/ethanol(EtOH)/H₂O (80 mL/20 mL/20 mL) and stirred at 100° C. for 12 hours. The reaction temperature was lowered to room temperature, the reaction was terminated by using water, and then, an extraction process was performed thereon three times by using ethyl ether. The separated organic layer was dried over anhydrous magnesium sulfate and then distilled/dried under reduced pressure. The residue obtained was separated and purified by column chromatography to obtain Compound 3 (4.15 g, yield: 70%).

### Synthesis of Compound 13

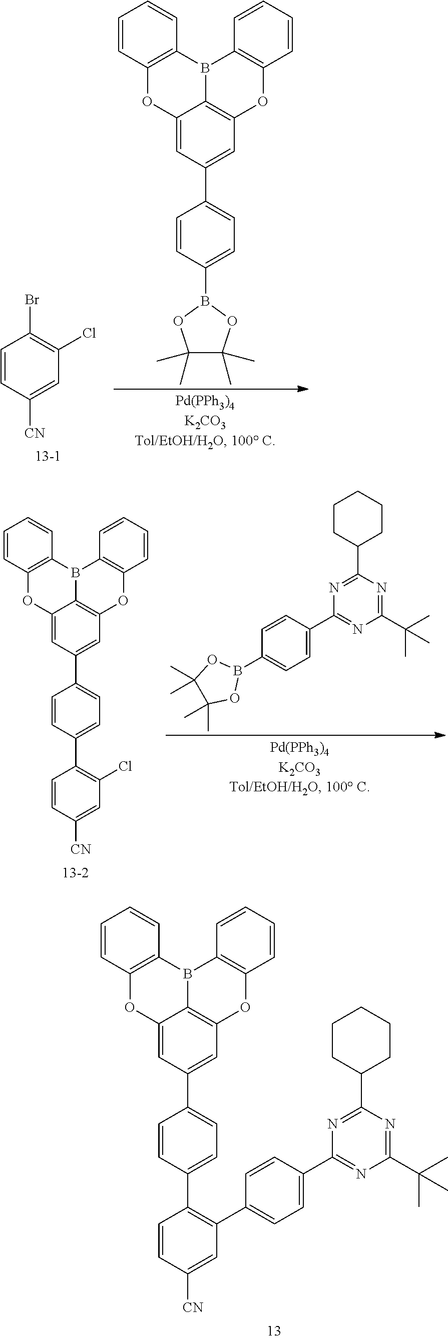 [SMILES: N#Cc1ccc(Br)c(Cl)c1 ; CC1(C)OB(c2ccc(-c3cc4c5c(c3)Oc3ccccc3B5c3ccccc3O4)cc2)OC1(C)C ; N#Cc1ccc(-c2ccc(-c3cc4c5c(c3)Oc3ccccc3B5c3ccccc3O4)cc2)c(Cl)c1 ; CC(C)(C)c1nc(-c2ccc(B3OC(C)(C)C(C)(C)O3)cc2)nc(C2CCCCC2)n1 ; CC(C)(C)c1nc(-c2ccc(-c3cc(C#N)ccc3-c3ccc(-c4cc5c6c(c4)Oc4ccccc4B6c4ccccc4O5)cc3)cc2)nc(C2CCCCC2)n1]

### Synthesis of Intermediate 13-2

Intermediate 13-1 (2.16 g), Pd(PPh₃)₄ (0.56 g), K₂CO₃ (3.45 g), 7-(4-(4,4,5,5-tetramethyl-1,3,2-dioxaborolan-2-yl)phenyl)-5,9-dioxa-13b-boranaphtho[3,2,1-de]anthracene (4.72 g) were dissolved in Tol/EtOH/H₂O (80 mL/20 mL/20 mL) and stirred at 100° C. for 12 hours. The reaction temperature was lowered to room temperature, the reaction was terminated by using water, and then, an extraction process was performed thereon three times by using ethyl ether. The separated organic layer was dried over anhydrous magnesium sulfate and then distilled/dried under reduced pressure. The residue obtained was separated and purified by column chromatography to obtain Intermediate 13-2 (3.60 g, yield: 75%).

### Synthesis of Compound 13

Intermediate 13-2 (4.81 g), Pd(PPh₃)₄ (0.56 g), K₂CO₃ (3.45 g), 2-(tert-butyl)-4-cyclohexyl-6-(4-(4,4,5,5-tetramethyl-1,3,2-dioxaborolan-2-yl)phenyl)-1,3,5-triazine (4.21 g) were dissolved in Tol/EtOH/H₂O (80 mL/20 mL/20 mL) and stirred at 100° C. for 12 hours. The reaction temperature was lowered to room temperature, the reaction was terminated by using water, and then, an extraction process was performed thereon three times by using ethyl ether. The separated organic layer was dried over anhydrous magnesium sulfate and then distilled/dried under reduced pressure. The residue obtained was separated and purified by column chromatography to obtain Compound 13 (4.44 g, yield: 60%).

### Synthesis of Compound 30

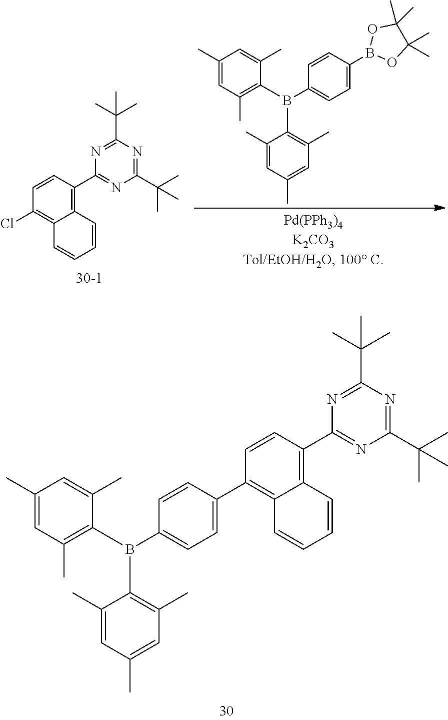

Intermediate 30-1 (3.53 g), Pd(PPh₃)₄ (0.56 g), K₂CO₃ (3.45 g), 2-(4-(dimesitylboranyl)phenyl)-4,4,5,5-tetramethyl-1,3,2-dioxaborolane (4.52 g) were dissolved in Tol/EtOH/H₂O (80 mL/20 mL/20 mL) and stirred at 100° C. for 12 hours. The reaction temperature was lowered to room temperature, the reaction was terminated by using water, and then, an extraction process was performed thereon three times by using ethyl ether. The separated organic layer was dried over anhydrous magnesium sulfate and then distilled/dried under reduced pressure. The residue obtained was separated and purified by column chromatography to obtain Compound 30 (4.37 g, yield: 68%).

### Synthesis of Compound 81

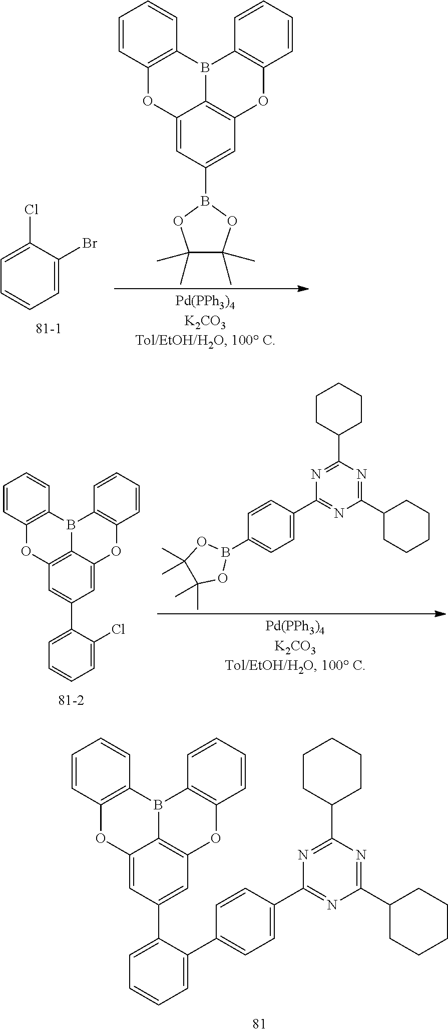

### Synthesis of Intermediate 81-2

Intermediate 81-1 (1.91 g), Pd(PPh₃)₄ (0.56 g), K₂CO₃ (3.45 g), 7-(4,4,5,5-tetramethyl-1,3,2-dioxaborolan-2-yl)-5,9-dioxa-13b-boranaphtho[3,2,1-de]anthracene (3.96 g) were dissolved in Tol/EtOH/H₂O (80 mL/20 mL/20 mL) and stirred at 100° C. for 12 hours. The reaction temperature was lowered to room temperature, the reaction was terminated by using water, and then, an extraction process was performed thereon three times by using ethyl ether. The separated organic layer was dried over anhydrous magnesium sulfate and then distilled/dried under reduced pressure. The residue obtained was separated and purified by column chromatography to obtain Intermediate 81-2 (2.35 g, yield: 62%).

### Synthesis of Compound 81

Intermediate 81-2 (3.80 g), Pd(PPh₃)₄ (0.56 g), K₂CO₃ (3.45 g), 2,4-dicyclohexyl-6-(4-(4,4,5,5-tetramethyl-1,3,2-dioxaborolan-2-yl)phenyl)-1,3,5-triazine (4.47 g) were dissolved in Tol/EtOH/H₂O (80 mL/20 mL/20 mL) and stirred at 100° C. for 12 hours. The reaction temperature was lowered to room temperature, the reaction was terminated by using water, and then, an extraction process was performed thereon three times by using ethyl ether. The separated organic layer was dried over anhydrous magnesium sulfate and then distilled/dried under reduced pressure. The residue obtained was separated and purified by column chromatography to obtain Compound 81 (5.12 g, yield: 77%).

### Synthesis of Compound 111

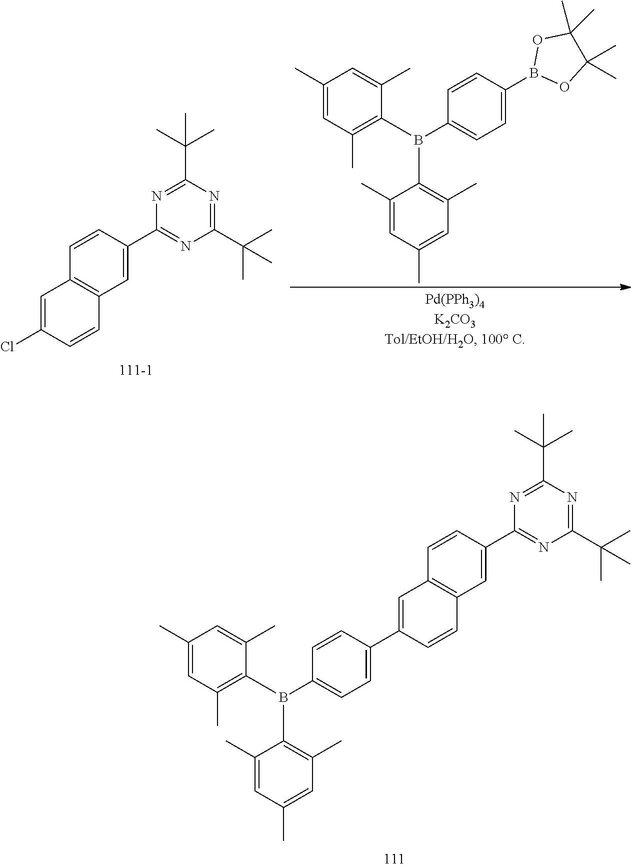

Intermediate 111-1 (3.53 g), Pd(PPh₃)₄ (0.56 g), K₂CO₃ (3.45 g), 2-(4-(dimesitylboranyl)phenyl)-4,4,5,5-tetramethyl-1,3,2-dioxaborolane (4.52 g) were dissolved in Tol/EtOH/H₂O (80 mL/20 mL/20 mL) and stirred at 100° C. for 12 hours. The reaction temperature was lowered to room temperature, the reaction was terminated by using water, and then, an extraction process was performed thereon three times by using ethyl ether. The separated organic layer was dried over anhydrous magnesium sulfate and then distilled/dried under reduced pressure. The residue obtained was separated and purified by column chromatography to obtain Compound 111 (4.11 g, yield: 64%).

### Synthesis of Compound 154

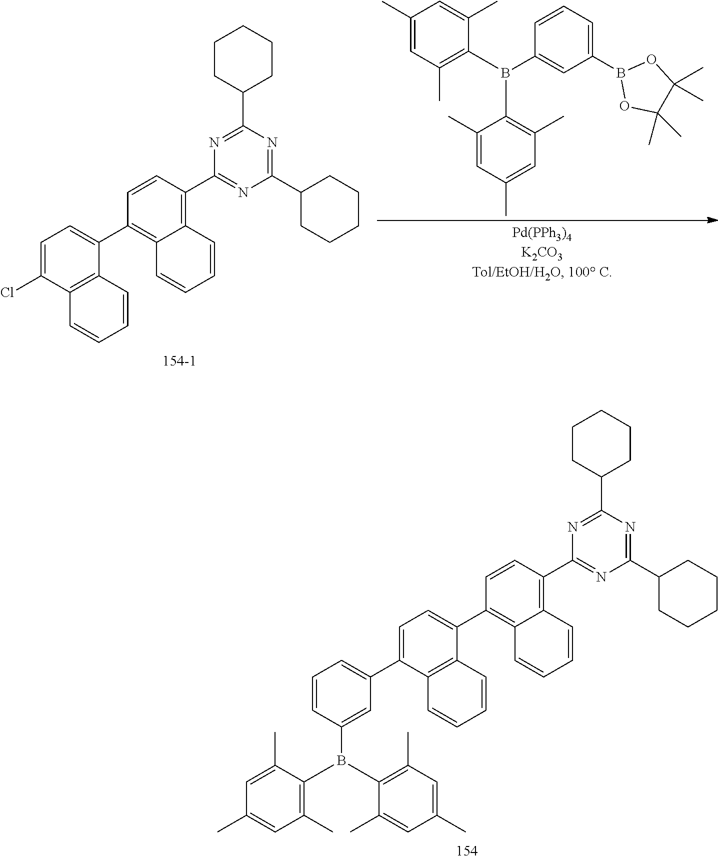

Intermediate 154-1 (5.76 g), Pd(PPh₃)₄ (0.56 g), K₂CO₃ (3.45 g), 2-(3-(dimesitylboranyl)phenyl)-4,4,5,5-tetramethyl-1,3,2-dioxaborolane (4.52 g) were dissolved in Tol/EtOH/H₂O (80 mL/20 mL/20 mL) and stirred at 100° C. for 12 hours. The reaction temperature was lowered to room temperature, the reaction was terminated by using water, and then, an extraction process was performed thereon three times by using ethyl ether. The separated organic layer was dried over anhydrous magnesium sulfate and the distilled/dried under reduced pressure. The residue obtained was separated and purified by column chromatography to obtain Compound 154 (4.92 g, yield: 60%).

### Synthesis of Compound 204

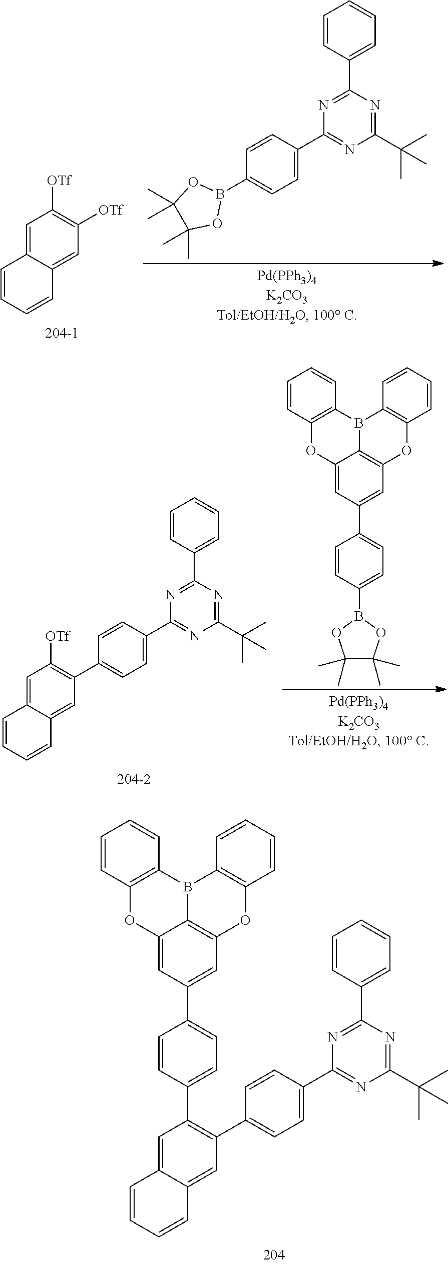 [SMILES: O=S(=O)(Oc1cc2ccccc2cc1OS(=O)(=O)C(F)(F)F)C(F)(F)F ; CC(C)(C)c1nc(-c2ccccc2)nc(-c2ccc(B3OC(C)(C)C(C)(C)O3)cc2)n1 ; CC(C)(C)c1nc(-c2ccccc2)nc(-c2ccc(-c3cc4ccccc4cc3OS(=O)(=O)C(F)(F)F)cc2)n1 ; CC1(C)OB(c2ccc(-c3cc4c5c(c3)Oc3ccccc3B5c3ccccc3O4)cc2)OC1(C)C ; CC(C)(C)c1nc(-c2ccccc2)nc(-c2ccc(-c3cc4ccccc4cc3-c3ccc(-c4cc5c6c(c4)Oc4ccccc4B6c4ccccc4O5)cc3)cc2)n1]

### Synthesis of Intermediate 204-2

Intermediate 204-1 (4.24 g), Pd(PPh₃)₄ (0.56 g), K₂CO₃ (3.45 g), 2-(tert-butyl)-4-phenyl-6-(4-(4,4,5,5-tetramethyl-1,3,2-dioxaborolan-2-yl)phenyl)-1,3,5-triazine (4.15 g) were dissolved in Tol/EtOH/H₂O (80 mL/20 mL/20 mL) and stirred at 100° C. for 12 hours. The reaction temperature was lowered to room temperature, the reaction was terminated by using water, and then, an extraction process was performed thereon three times by using ethyl ether. The separated organic layer was dried over anhydrous magnesium sulfate and then distilled/dried under reduced pressure. The residue obtained was separated and purified by column chromatography to obtain Intermediate 204-2 (4.51 g, yield: 80%).

### Synthesis of Compound 204

Intermediate 204-2 (5.64 g), Pd(PPh₃)₄ (0.56 g), K₂CO₃ (3.45 g), 7-(4-(4,4,5,5-tetramethyl-1,3,2-dioxaborolan-2-yl)phenyl)-5,9-dioxa-13b-boranaphtho[3,2,1-de]anthracene (4.72 g) were dissolved in Tol/EtOH/H₂O (80 mL/20 mL/20 mL) and stirred at 100° C. for 12 hours. The reaction temperature was lowered to room temperature, the reaction was terminated by using water, and then, an extraction process was performed thereon three times by using ethyl ether. The separated organic layer was dried over anhydrous magnesium sulfate and then distilled/dried under reduced pressure. The residue obtained was separated and purified by column chromatography to obtain Compound 204 (5.16 g, yield: 68%).

### Synthesis of Compound 224

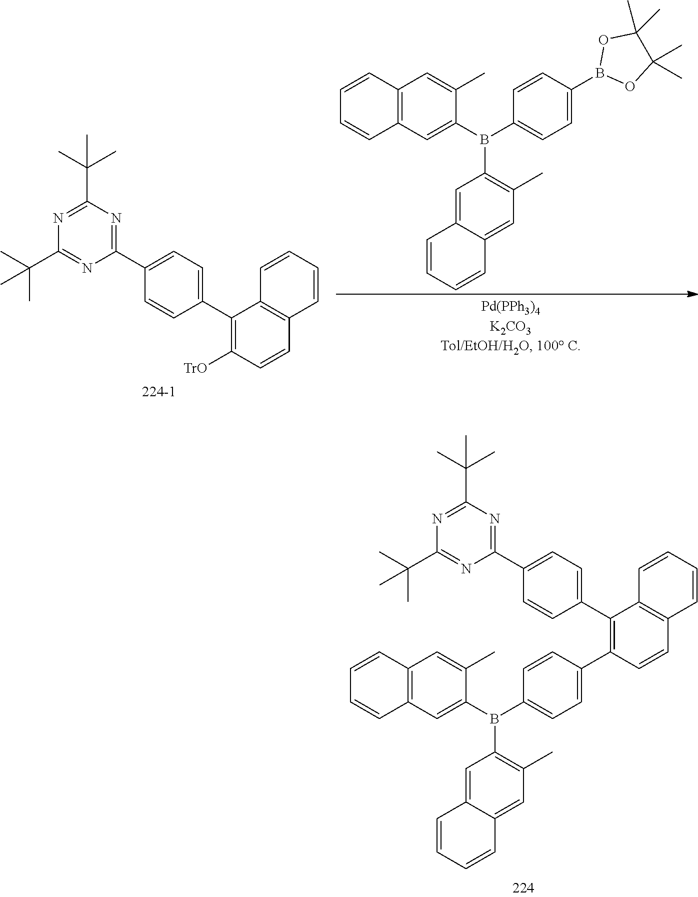

Intermediate 224-1 (5.43 g), Pd(PPh₃)₄ (0.56 g), K₂CO₃ (3.45 g), 2-(4-(bis(3-methylnaphthalen-2-yl) boranyl)phenyl)-4,4,5,5-tetramethyl-1,3,2-dioxaborolane (4.96 g) were dissolved in Tol/EtOH/H₂O (80 mL/20 mL/20 mL) and stirred at 100° C. for 12 hours. The reaction temperature was lowered to room temperature, the reaction was terminated by using water, and then, an extraction process was performed thereon three times by using ethyl ether. The separated organic layer was dried over anhydrous magnesium sulfate and then distilled/dried under reduced pressure. The residue obtained was separated and purified by column chromatography to obtain Compound 224 (5.03 g, yield: 66%).

### Synthesis of Compound 250

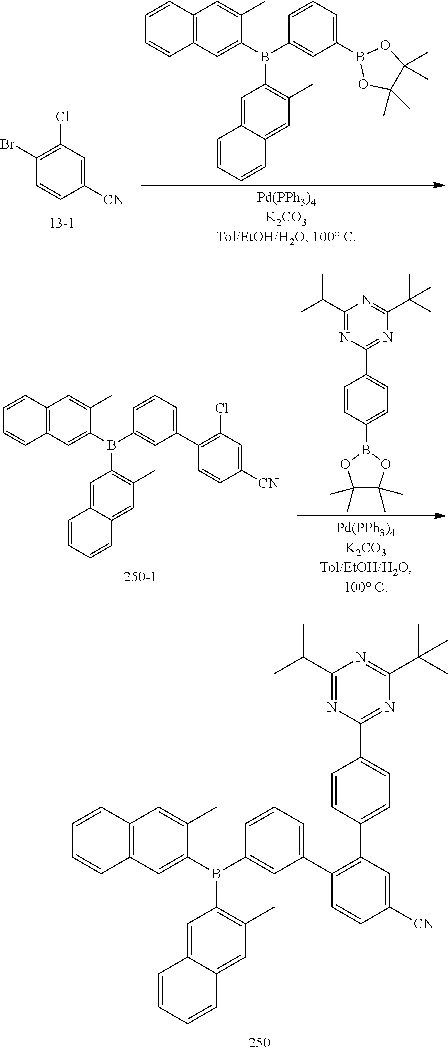

### Synthesis of Intermediate 250-1

Intermediate 13-1 (2.16 g), Pd(PPh₃)₄ (0.56 g), K₂CO₃ (3.45 g), 2-(3-(bis(3-methylnaphthalen-2-yl) boranyl)phenyl)-4,4,5,5-tetramethyl-1,3,2-dioxaborolane (4.96 g) were dissolved in Tol/EtOH/H₂O (80 mL/20 mL/20 mL) and stirred at 100° C. for 12 hours. The reaction temperature was lowered to room temperature, the reaction was terminated by using water, and then, an extraction process was performed thereon three times by using ethyl ether. The separated organic layer was dried over anhydrous magnesium sulfate and then distilled/dried under reduced pressure. The residue obtained was separated and purified by column chromatography to obtain Intermediate 250-1 (3.48 g, yield: 69%).

### Synthesis of Compound 250

Intermediate 250-1 (5.05 g), Pd(PPh₃)₄ (0.56 g), K₂CO₃ (3.45 g), 2-(tert-butyl)-4-isopropyl-6-(4-(4,4,5,5-tetramethyl-1,3,2-dioxaborolan-2-yl)phenyl)-1,3,5-triazine (3.81 g) were dissolved in Tol/EtOH/H₂O (80 mL/20 mL/20 mL) and stirred at 100° C. for 12 hours. The reaction temperature was lowered to room temperature, the reaction was terminated by using water, and then, an extraction process was performed thereon three times by using ethyl ether. The separated organic layer was dried over anhydrous magnesium sulfate and then distilled/dried under reduced pressure. The residue obtained was separated and purified by column chromatography to obtain Compound 250 (5.14 g, yield: 71%).

The compounds separated by chromatography were each confirmed by proton nuclear magnetic resonance spectroscopy (1H-NMR).

### Manufacture of Light-Emitting Device

### Comparative Example 1

As an anode, a glass substrate (product of Corning Inc.) with a 15 Ω/cm² (1,200 Å) ITO electrode formed thereon was cut to a size of 50 mm×50 mm×0.7 mm, sonicated with isopropyl alcohol and (then with) pure water each for 5 minutes, cleaned by irradiation of ultraviolet rays and exposure of ozone thereto for 30 minutes, and then mounted on a vacuum deposition apparatus.

NPD was deposited on the anode to form a hole injection layer having a thickness of 300 Å, HT3 was deposited on the hole injection layer to form a hole transport layer having a thickness of 200 Å, and then, CzSi was deposited on the hole transport layer to form an emission auxiliary layer having a thickness of 100 Å.

Referring to Table 1, a first host, a second host, a first dopant, and a second dopant were co-deposited on the emission auxiliary layer at a weight ratio of 42:42:15:1 to form an emission layer having a thickness of 200 Å.

Subsequently, TSPO1 was deposited on the emission layer to form a hole blocking layer having a thickness of 200 Å, TPBI was deposited on the hole blocking layer to form an electron transport layer having a thickness of 300 Å, LiF was deposited on the electron transport layer to form an electron injection layer having a thickness of 10 Å, and then, Al was deposited on the electron injection layer to form a cathode having a thickness of 3000 Å, thereby completing the manufacture of a light-emitting device.

### Comparative Examples 2 to 4

A light-emitting device was manufactured in substantially the same manner as in Comparative Example 1, except that each of the compounds in Table 1 was respectively used when forming the electron transport layer.

### Examples 1 to 9

A light-emitting device was manufactured in substantially the same manner as in Comparative Example 1, except that each of the compounds in Table 1 was respectively used when forming the electron transport layer.

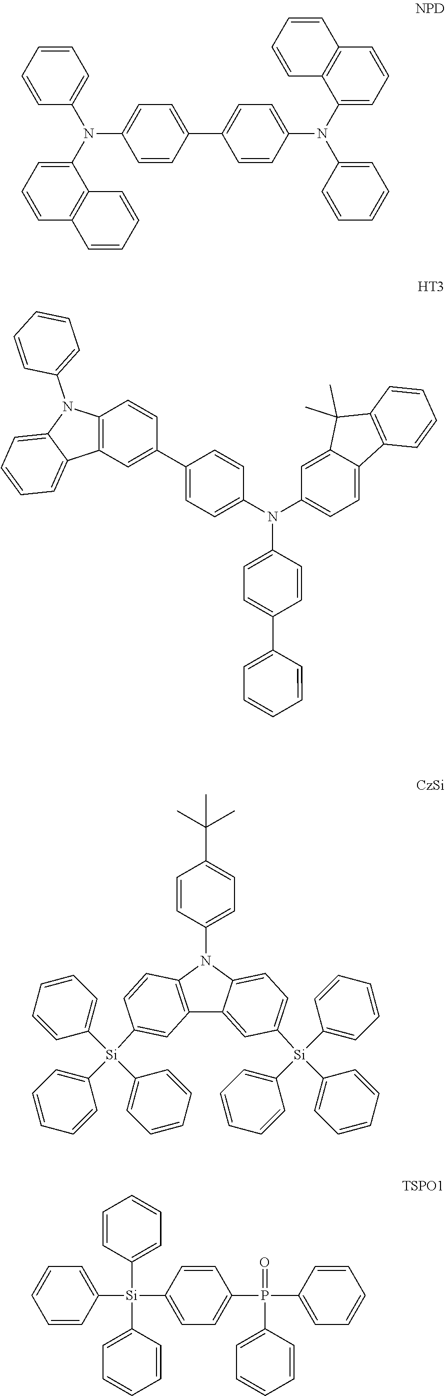 [SMILES: c1ccc(N(c2ccc(-c3ccc(N(c4ccccc4)c4cccc5ccccc45)cc3)cc2)c2cccc3ccccc23)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1 ; O=P(c1ccccc1)(c1ccccc1)c1ccc([Si](c2ccccc2)(c2ccccc2)c2ccccc2)cc1]

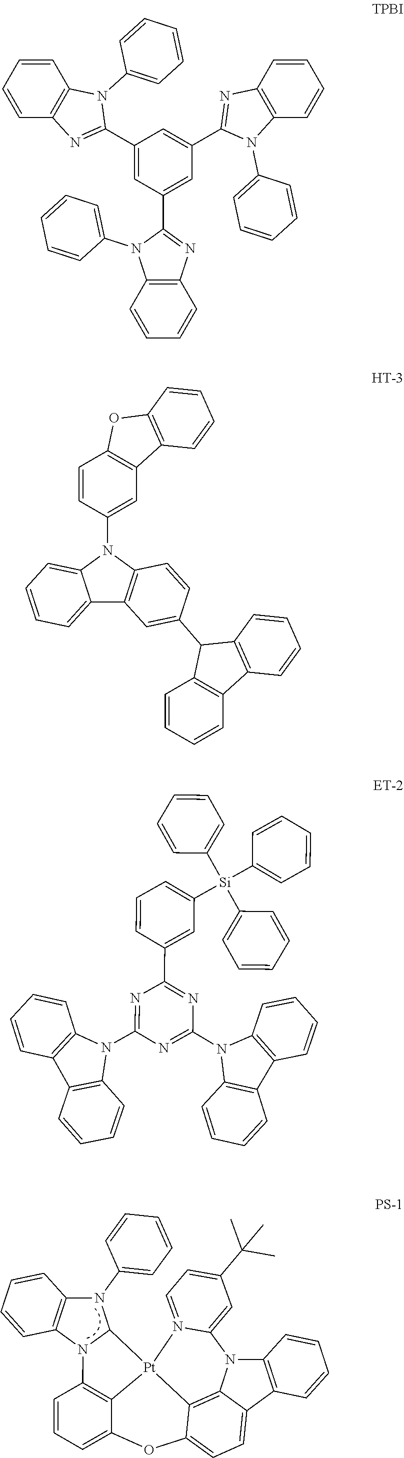

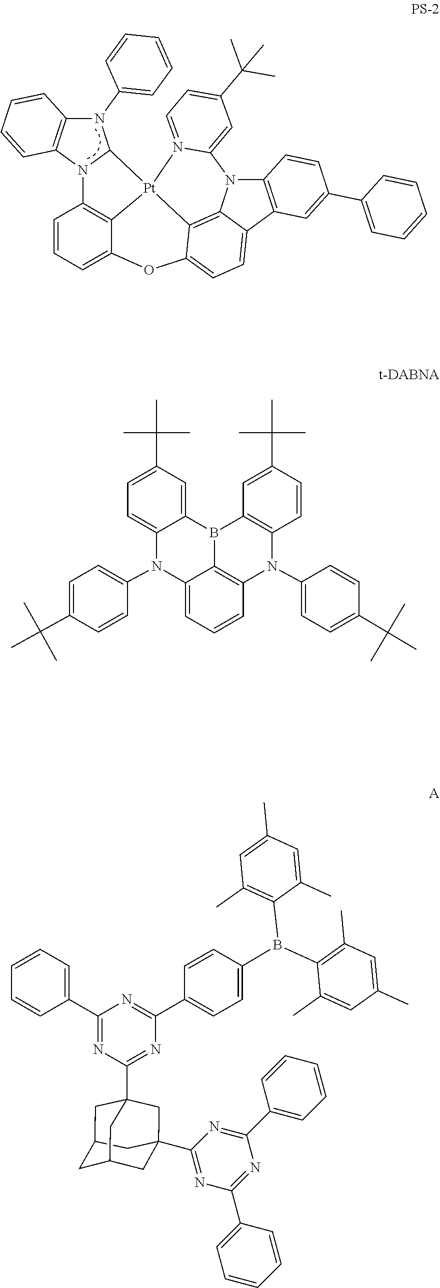

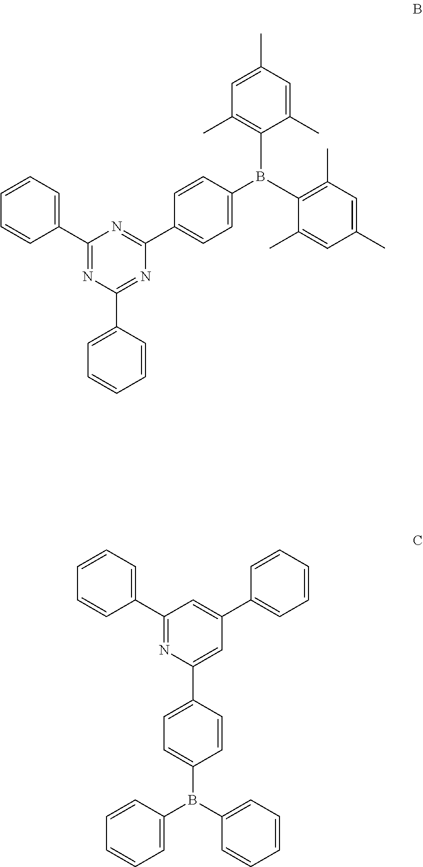 [SMILES: Cc1cc(C)c(B(c2ccc(-c3nc(-c4ccccc4)nc(-c4ccccc4)n3)cc2)c2c(C)cc(C)cc2C)c(C)c1 ; c1ccc(B(c2ccccc2)c2ccc(-c3cc(-c4ccccc4)cc(-c4ccccc4)n3)cc2)cc1]

The results of the light-emitting devices are shown in Table 1.

The driving voltage of each of the light-emitting devices was measured by using a source meter (Keithley Instrument Inc., 2400 series), and the efficiency and lifespan (T95) thereof were measured by using a measurement apparatus C9920-2-12 of Hamamatsu Photonics Inc. The lifespan (T95) is time taken for the luminance of a light-emitting device to decrease to 95% of the initial luminance thereof, the lifespan ratio (T95) shown in Table 1 is a ratio of the lifespan (T95) of each light-emitting device to the lifespan (T95) of Comparative Example 1.

TABLE 1

| | Hole | | | | Electron | Driving | | Lifespan |
|---|---|---|---|---|---|---|---|---|
| | transport | | First | Second | transport | voltage | Efficiency | ratio |
| | layer | HT/ET¹⁾ | dopant | dopant | layer | (V) | (cd/A) | (T95) |
| Comparative | HT3 | HT-3/ET-2 | PS-2 | t-DABNA | TPBI | 5.6 | 18.8 | 1 |
| Example 1 | | | | | | | | |
| Comparative | HT3 | HT-3/ET-2 | PS-2 | t-DABNA | A | 4.7 | 22.8 | 4.7 |
| Example 2 | | | | | | | | |
| Comparative | HT3 | HT-3/ET-2 | PS-2 | t-DABNA | B | 4.5 | 23.8 | 5.1 |
| Example 3 | | | | | | | | |
| Comparative | HT3 | HT-3/ET-2 | PS-2 | t-DABNA | C | 5.1 | 20.8 | 2.5 |
| Example 4 | | | | | | | | |
| Example 1 | HT3 | HT-3/ET-2 | PS-2 | t-DABNA | Compound 3 | 3.94 | 26.8 | 6.3 |
| Example 2 | HT3 | HT-3/ET-2 | PS-2 | t-DABNA | Compound 13 | 4.09 | 25.3 | 6.1 |
| Example 3 | HT3 | HT-3/ET-2 | PS-2 | t-DABNA | Compound 30 | 3.96 | 25.3 | 5.8 |
| Example 4 | HT3 | HT-3/ET-2 | PS-2 | t-DABNA | Compound 81 | 4.11 | 25.2 | 5.9 |
| Example 5 | HT3 | HT-3/ET-2 | PS-2 | t-DABNA | Compound 111 | 4.23 | 25.9 | 5.7 |
| Example 6 | HT3 | HT-3/ET-2 | PS-2 | t-DABNA | Compound 154 | 4.34 | 26.7 | 6.3 |
| Example 7 | HT3 | HT-3/ET-2 | PS-2 | t-DABNA | Compound 204 | 4.21 | 26.9 | 6.4 |
| Example 8 | HT3 | HT-3/ET-2 | PS-1 | t-DABNA | Compound 224 | 4.03 | 27.4 | 6.5 |
| Example 9 | HT3 | HT-3/ET-2 | PS-1 | t-DABNA | Compound 250 | 4.19 | 25.0 | 6.7 |

¹⁾HT: hole-transporting host
ET: electron-transporting host
HT:ET = 5:5 (weight ratio)

Referring to Table 1, it can be seen that the light-emitting devices in the Examples outperform those in the Comparative Examples with respect to efficiency, driving voltage, and lifespan.

A light-emitting device according to one or more embodiments by including the compound of Formula 1 has better driving voltage, efficiency, and lifespan than a comparable light-emitting device in the art. For example, the light-emitting device including a compound of the present disclosure as an electron transporting material may have low driving voltage, high efficiency, and long lifespan.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof.

In the context of the present application and unless otherwise defined, the terms “use,” “using,” and “used” may be considered synonymous with the terms “utilize,” “utilizing,” and “utilized,” respectively.

Throughout the present disclosure, when a component such as a layer, a film, a region, or a plate is mentioned to be placed “on” another component, it will be understood that it may be directly on another component or that another component may be interposed therebetween. In some embodiments, “directly on” may refer to that there are no additional layers, films, regions, plates, etc., between a layer, a film, a region, a plate, etc. and the other part. For example, “directly on” may refer to two layers or two members are disposed without utilizing an additional member such as an adhesive member therebetween.

In the present disclosure, although the terms “first,” “second,” etc., may be utilized herein to describe one or more elements, components, regions, and/or layers, these elements, components, regions, and/or layers should not be limited by these terms. These terms are only utilized to distinguish one component from another component.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

The light-emitting device, the electronic apparatus, the manufacturing apparatus thereof, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It should be understood that embodiments described herein should be considered in a descriptive sense only and not for purposes of limitation. Descriptions of features or aspects within each embodiment should typically be considered as available for other similar features or aspects in one or more embodiments. While one or more embodiments have been described with reference to the drawings, it will be understood by those of ordinary skill in the art that one or more suitable changes in form and details may be made therein without departing from the spirit and scope as defined by the appended claims and equivalents thereof.

What is claimed is:

1. A light-emitting device comprising:
a first electrode;
a second electrode opposite to the first electrode; and
an interlayer between the first electrode and the second electrode and comprising an emission layer,
wherein the interlayer comprises a compound represented by Formula 1: 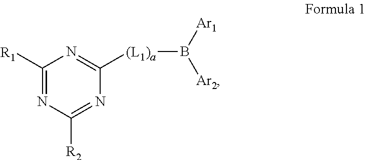
and
wherein, in Formula 1,
R₁ and R₂ are each independently a C₁-C₆₀ alkyl group unsubstituted or substituted with at least one R₁₀ₐ, a C₃-C₁₀ cycloalkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₁-C₆₀ alkylthio group unsubstituted or substituted with at least one R₁₀ₐ, a C₆-C₆₀ aryl group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₁-C₆₀ heteroaryl group unsubstituted or substituted with at least one R₁₀ₐ, a C₈-C₆₀ non-aromatic condensed polycyclic group unsubstituted or substituted with at least one R₁₀ₐ, a C₁-C₆₀ non-aromatic condensed heteropolycyclic group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
provided that at least of R₁ or R₂ is a C₁-C₆₀ alkyl group unsubstituted or substituted with at least one R₁₀ₐ, or a C₃-C₁₀ cycloalkyl group unsubstituted or substituted with at least one R₁₀ₐ, with exclusion of an adamantyl group from the C₃-C₁₀ cycloalkyl group,
Ar₁ and Ar₂ are each independently hydrogen, deuterium, —F, —Cl, —Br, —I, a hydroxyl group, a cyano group, a nitro group, a C₆-C₆₀ aryl group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₁-C₆₀ heteroaryl group unsubstituted or substituted with at least one R₁₀ₐ, a C₈-C₆₀ non-aromatic condensed polycyclic group unsubstituted or substituted with at least one R₁₀ₐ, or a C₁-C₆₀ non-aromatic condensed heteropolycyclic group unsubstituted or substituted with at least one R₁₀ₐ,
a is an integer from 1 to 5,
L₁, at each occurrence, is independently a C₃-C₃₀ carbocyclic group unsubstituted or substituted with at least one R₁₀ₐ or a C₁-C₃₀ heterocyclic group unsubstituted or substituted with at least one R₁₀ₐ,
provided that when L₁ directly bonded to a triazine moiety is phenylene, then the other substitution position of the phenylene is not meta,
when a is 2 or more, then each L₁ is identical to or different from the others,
optionally, adjacent substituents among substituents bonded to B are linked to each other via a direct bond, —O—, —C(Q₁)(Q₂)-, —Si(Q₁)(Q₂)-, —N(Q₁)-, —C(═O)—, —S(═O)₂—, or —P(═O)—, to form a ring,
R₁₀ₐ is:
hydrogen, deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

2. The light-emitting device of claim 1, wherein,
the first electrode is an anode,
the second electrode is a cathode, and
the interlayer further comprises: a hole transport region between the first electrode and the emission layer, and comprising a hole injection layer, a hole transport layer, an electron blocking layer, an emission auxiliary layer, or any combination thereof; and/or
an electron transport region between the second electrode and the emission layer, and comprising a hole blocking layer, an electron transport layer, an electron injection layer, or any combination thereof.

3. The light-emitting device of claim 2,
wherein the electron transport region comprises the compound represented by Formula 1.

4. The light-emitting device of claim 1,
wherein the emission layer comprises a first host, a second host, a first dopant, and a second dopant,
the first dopant being a compound comprising a metal and a ligand comprising an imidazole moiety, and
the second dopant being a compound comprising boron.

5. The light-emitting device of claim 4,
wherein the first host is a hole-transporting host.

6. The light-emitting device of claim 4,
the second host is an electron-transporting host.

7. The light-emitting device of claim 1,
wherein the emission layer is to emit blue light.

8. The light-emitting device of claim 1,
wherein the emission layer comprises m emission layers,
the interlayer further comprises m−1 charge generation layers each respectively arranged between two adjacent emission layers among the m emission layers, and
m is an integer of 2 or more.

9. The light-emitting device of claim 8,
wherein the interlayer comprises a red emission layer, a blue emission layer, and a green emission layer.

10. An electronic apparatus comprising the light-emitting device of claim 1.

11. The electronic apparatus of claim 10, further comprising
a thin-film transistor,
wherein the thin-film transistor comprises a source electrode and a drain electrode, and
the first electrode of the light-emitting device is electrically connected to the source electrode or the drain electrode of the thin-film transistor.

12. The electronic apparatus of claim 10,
wherein the electronic apparatus comprises at least one of a display, a light source, lighting, a personal computer, a mobile phone, a digital camera, an electronic organizer, an electronic dictionary, an electronic game machine, a medical instrument, a fish finder, a measuring instrument, a meter, or a projector.

13. A compound represented by Formula 1:
Formula 1 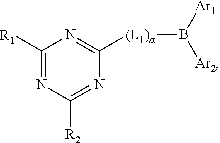
wherein, in Formula 1,
R₁ and R₂ are each independently a C₁-C₆₀ alkyl group unsubstituted or substituted with at least one R₁₀ₐ, a C₃-C₁₀ cycloalkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₁-C₆₀ alkylthio group unsubstituted or substituted with at least one R₁₀ₐ, a C₆-C₆₀ aryl group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₁-C₆₀ heteroaryl group unsubstituted or substituted with at least one R₁₀ₐ, a C₈-C₆₀ non-aromatic condensed polycyclic group unsubstituted or substituted with at least one R₁₀ₐ, a C₁-C₆₀ non-aromatic condensed heteropolycyclic group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
provided that at least one of R₁ or R₂ is a C₁-C₆₀ alkyl group unsubstituted or substituted with at least one R₁₀ₐ, or a C₅-C₁₀ cycloalkyl group unsubstituted or substituted with at least one R₁₀ₐ, with exclusion of an adamantyl group from the C₃-C₁₀ cycloalkyl group,
Ar₁ and Ar₂ are each independently hydrogen, deuterium, —F, —Cl, —Br, —I, a hydroxyl group, a cyano group, a nitro group, a C₆-C₆₀ aryl group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₁-C₆₀ heteroaryl group unsubstituted or substituted with at least one R₁₀ₐ, a C₈-C₆₀ non-aromatic condensed polycyclic group unsubstituted or substituted with at least one R₁₀ₐ, or a C₁-C₆₀ non-aromatic condensed heteropolycyclic group unsubstituted or substituted with at least one R₁₀ₐ,
a is an integer from 1 to 5,
L₁, at each occurrence, is independently a C₃-C₃₀ carbocyclic group unsubstituted or substituted with at least one R₁₀ₐ or a C₁-C₃₀ heterocyclic group unsubstituted or substituted with at least one R₁₀ₐ,
provided that when L₁ directly bonded to a triazine moiety is phenylene, then the other substitution position of the phenylene is not meta,
when a is 2 or more, then each L₁ is identical to or different from the others,
optionally, adjacent substituents among substituents bonded to B are linked to each other via a direct bond, —O—, —C(Q₁)(Q₂)-, —Si(Q₁)(Q₂)-, —N(Q₁)-, —C(═O)—, —S(═O)₂—, or —P(═O)—, to form a ring,
R₁₀ₐ is:
hydrogen, deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₈-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

14. The compound of claim 13,
wherein, in Formula 1, L₁ and Ar₁ are linked to each other via a direct bond, —O—, —C(Q₁)(Q₂)-, —Si(Q₁)(Q₂)-, —N(Q₁)-, —C(═O)—, —S(═O)₂—, or —P(═O)—, to form a ring.

15. The compound of claim 13,
wherein, in Formula 1, L₁ and Ar₂ are linked to each other via a direct bond, —O—, —C(Q₁)(Q₂)-, —Si(Q₁)(Q₂)-, —N(Q₁)-, —C(═O)—, —S(═O)₂—, or —P(═O)—, to form a ring.

16. The compound of claim 13,
wherein, in Formula 1, Ar₁ and Ar₂ are linked to each other via a direct bond, —O—, —C(Q₁)(Q₂)-, —Si(Q₁)(Q₂)-, —N(Q₁)-, —C(═O)—, —S(═O)₂—, or —P(═O)—, to form a ring.

17. The compound of claim 13,
wherein, in Formula 1, when L₁ directly bonded to a triazine moiety is phenylene, then the other substitution position of the phenylene is para.

18. The compound of claim 13,
wherein, in Formula 1, at least one of R₁ or R₂ is a C₁-C₂₀ alkyl group, a cyclopentyl group, a cyclohexyl group, a cycloheptyl group, a cyclooctyl group, or a norbornyl group.

19. The compound of claim 13,
wherein, in Formula 1, when a is 2 or more, then L₁ directly bonded to a boron atom is phenylene.

20. The compound of claim 13,
wherein the compound represented by Formula 1 is any one selected from among Compounds 1 to 262: 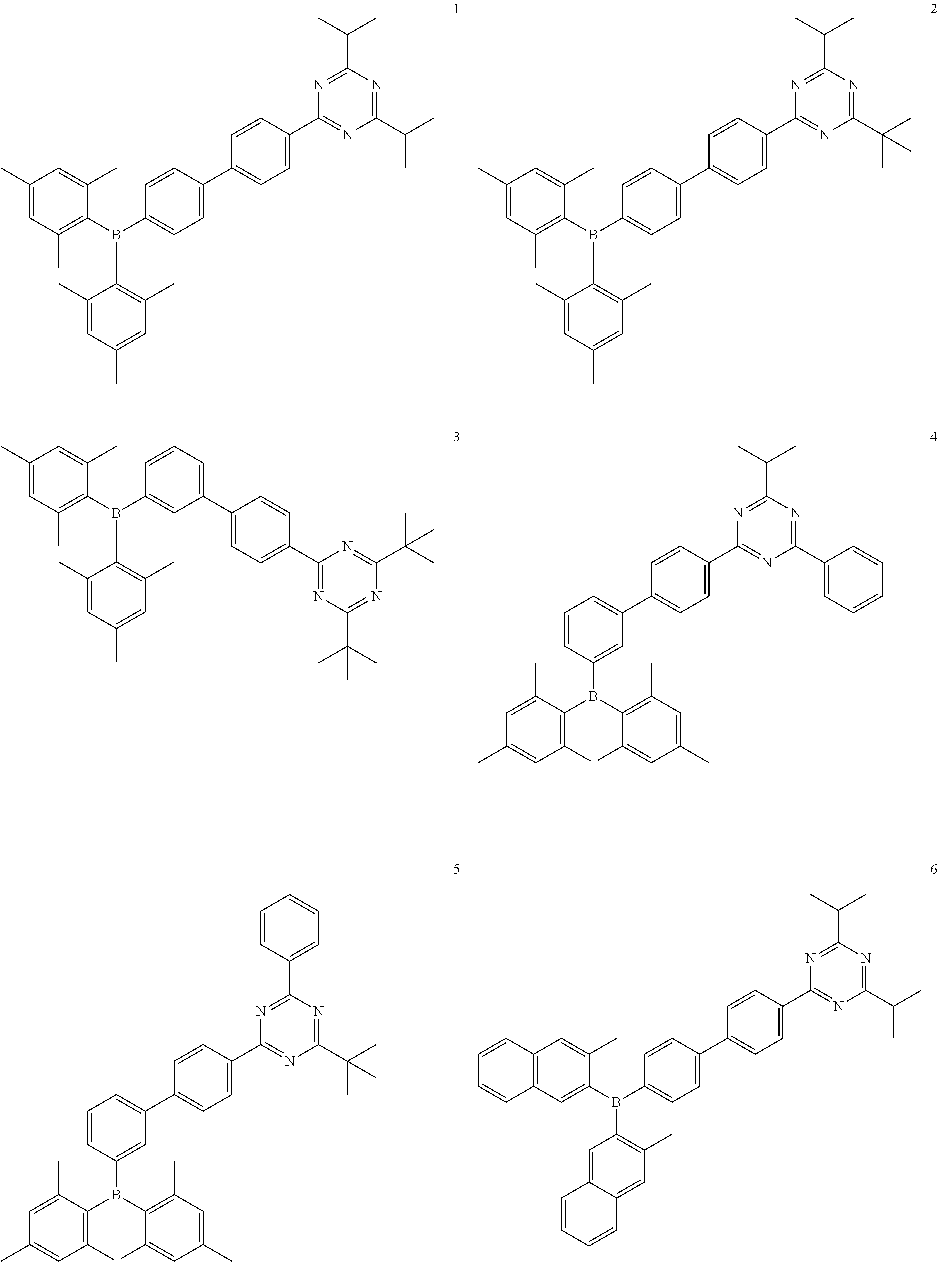 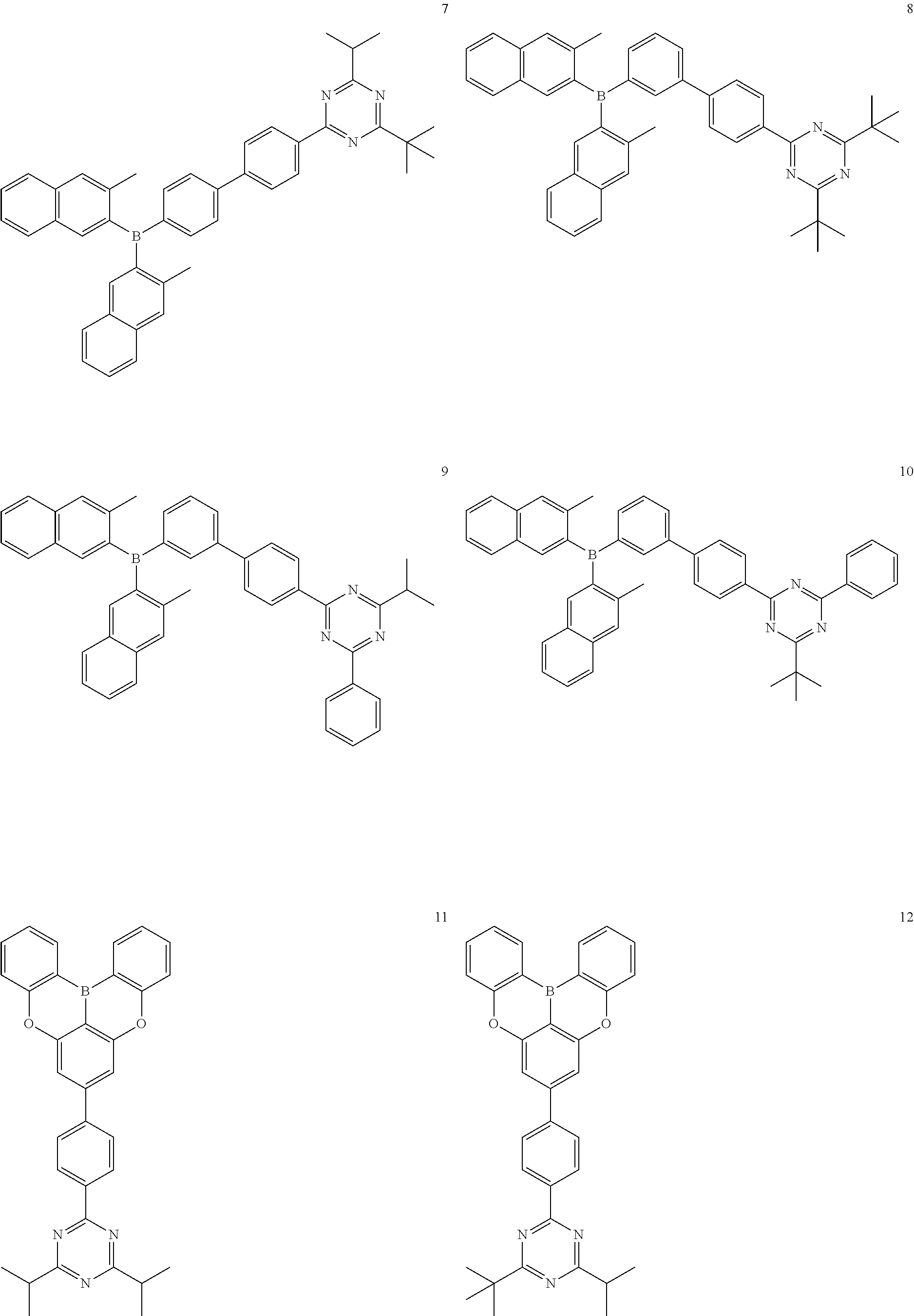 [SMILES: Cc1cc2ccccc2cc1B(c1ccc(-c2ccc(-c3nc(C(C)C)nc(C(C)(C)C)n3)cc2)cc1)c1cc2ccccc2cc1C ; Cc1cc2ccccc2cc1B(c1cccc(-c2ccc(-c3nc(C(C)(C)C)nc(C(C)(C)C)n3)cc2)c1)c1cc2ccccc2cc1C ; Cc1cc2ccccc2cc1B(c1cccc(-c2ccc(-c3nc(-c4ccccc4)nc(C(C)C)n3)cc2)c1)c1cc2ccccc2cc1C ; Cc1cc2ccccc2cc1B(c1cccc(-c2ccc(-c3nc(-c4ccccc4)nc(C(C)(C)C)n3)cc2)c1)c1cc2ccccc2cc1C ; CC(C)c1nc(-c2ccc(-c3cc4c5c(c3)Oc3ccccc3B5c3ccccc3O4)cc2)nc(C(C)C)n1 ; CC(C)c1nc(-c2ccc(-c3cc4c5c(c3)Oc3ccccc3B5c3ccccc3O4)cc2)nc(C(C)(C)C)n1] 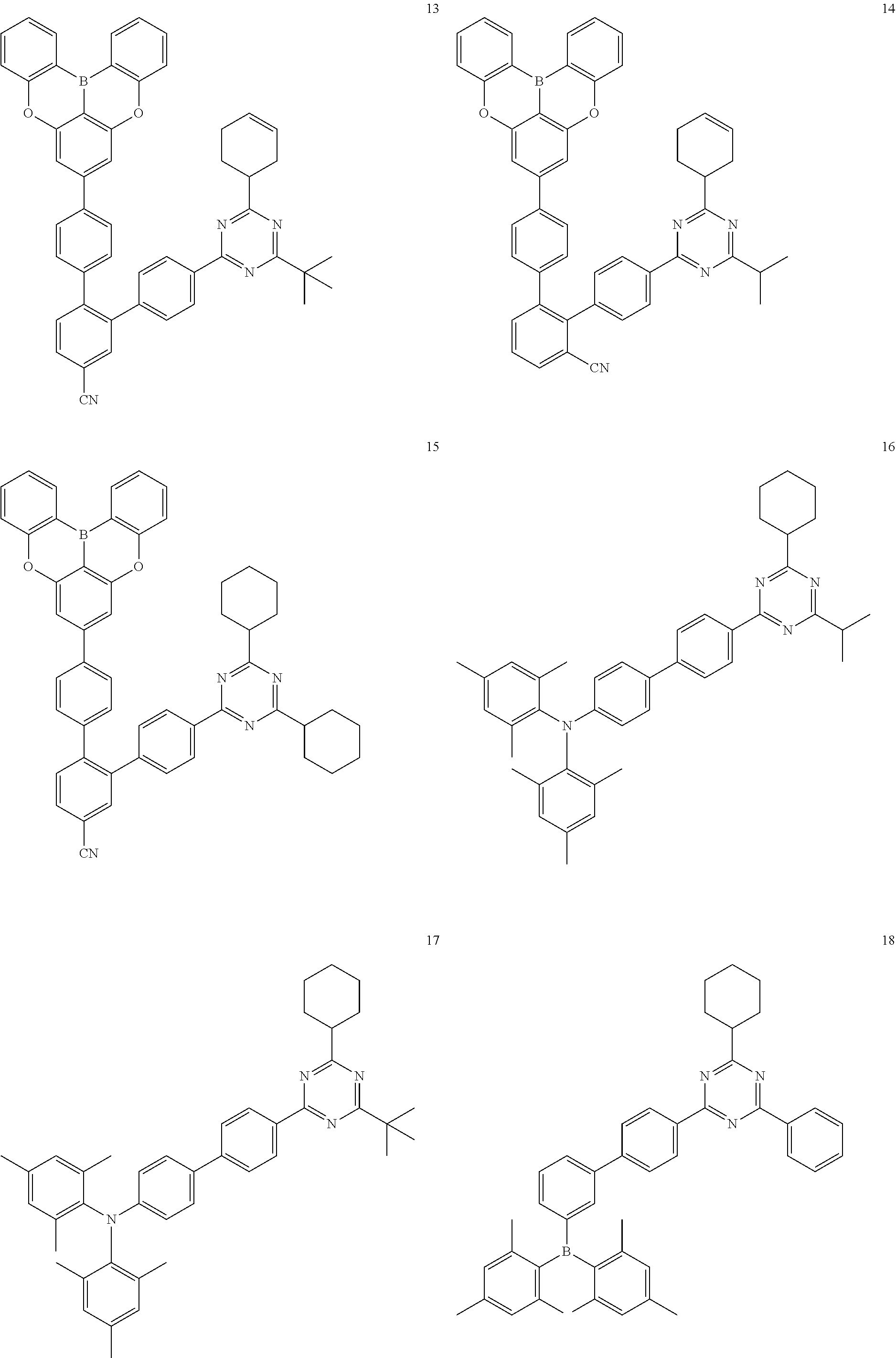 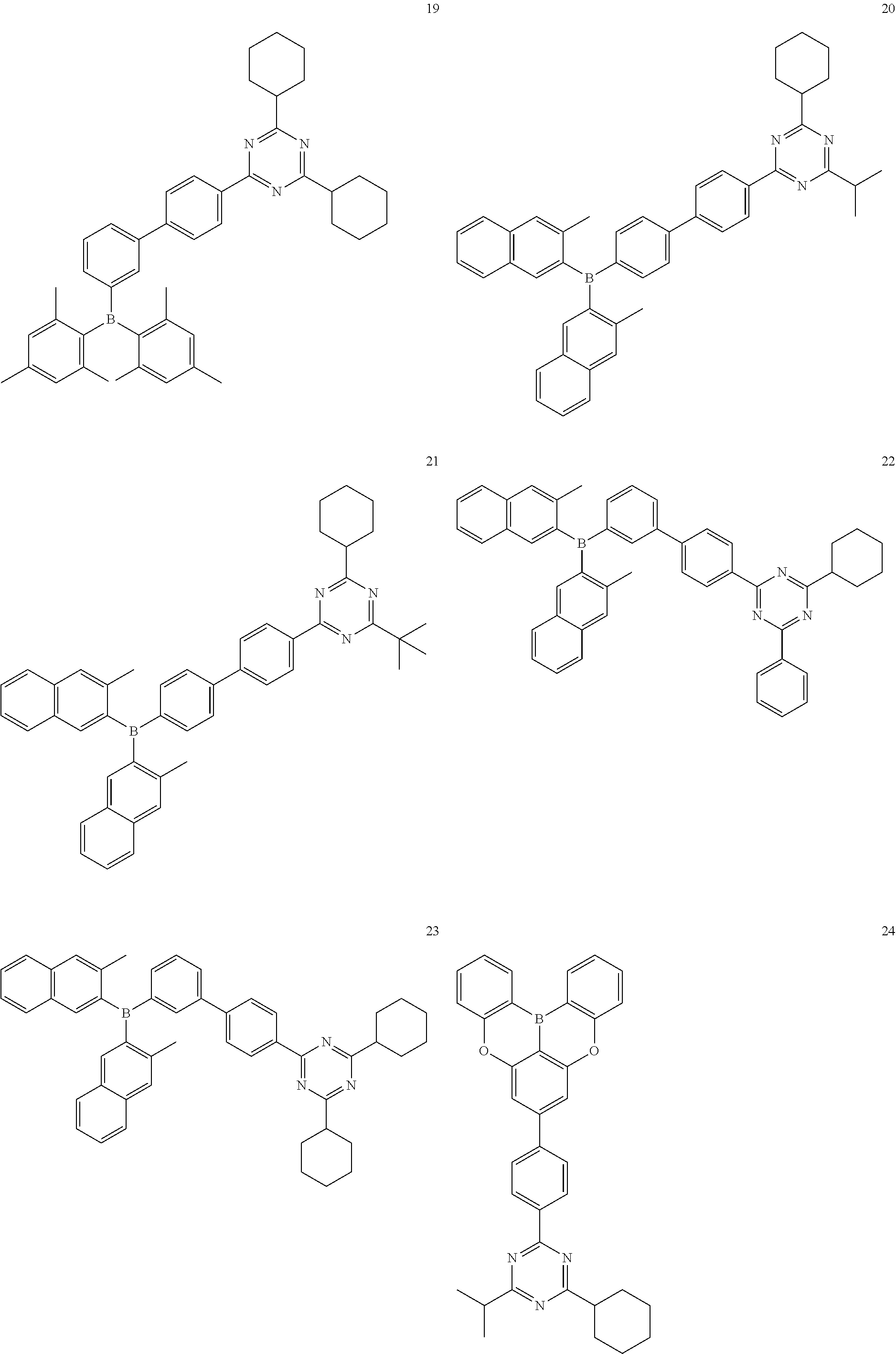 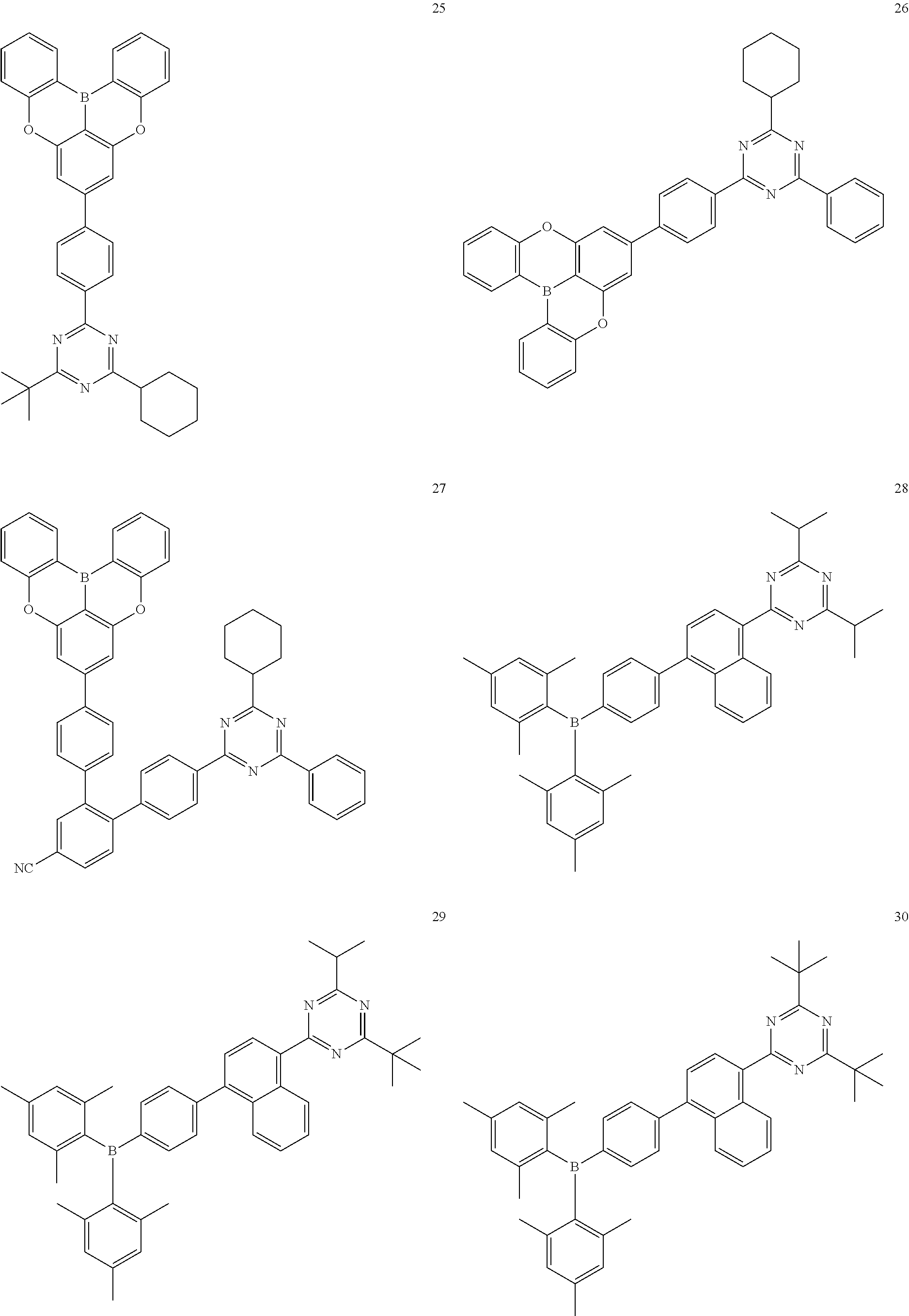 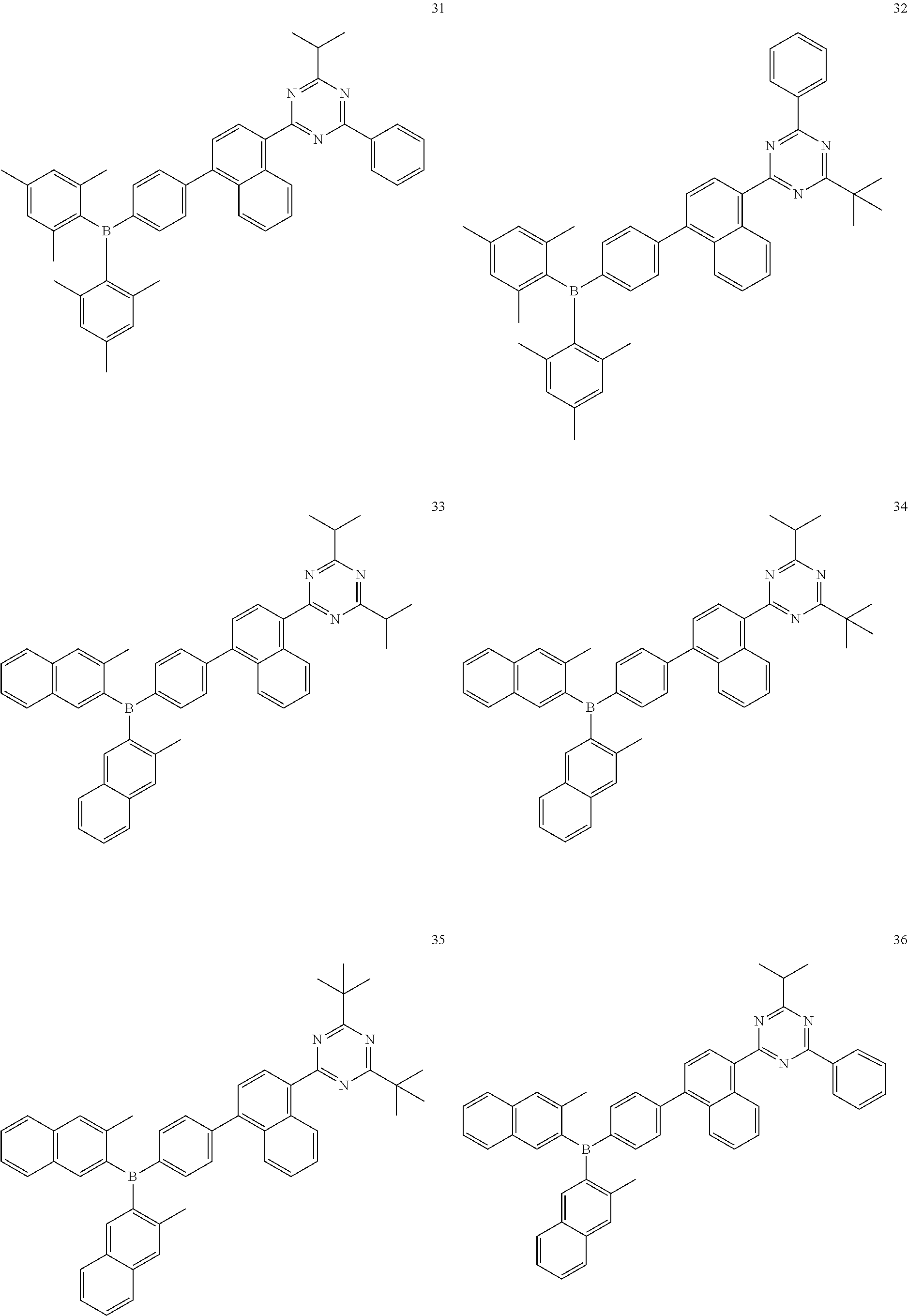 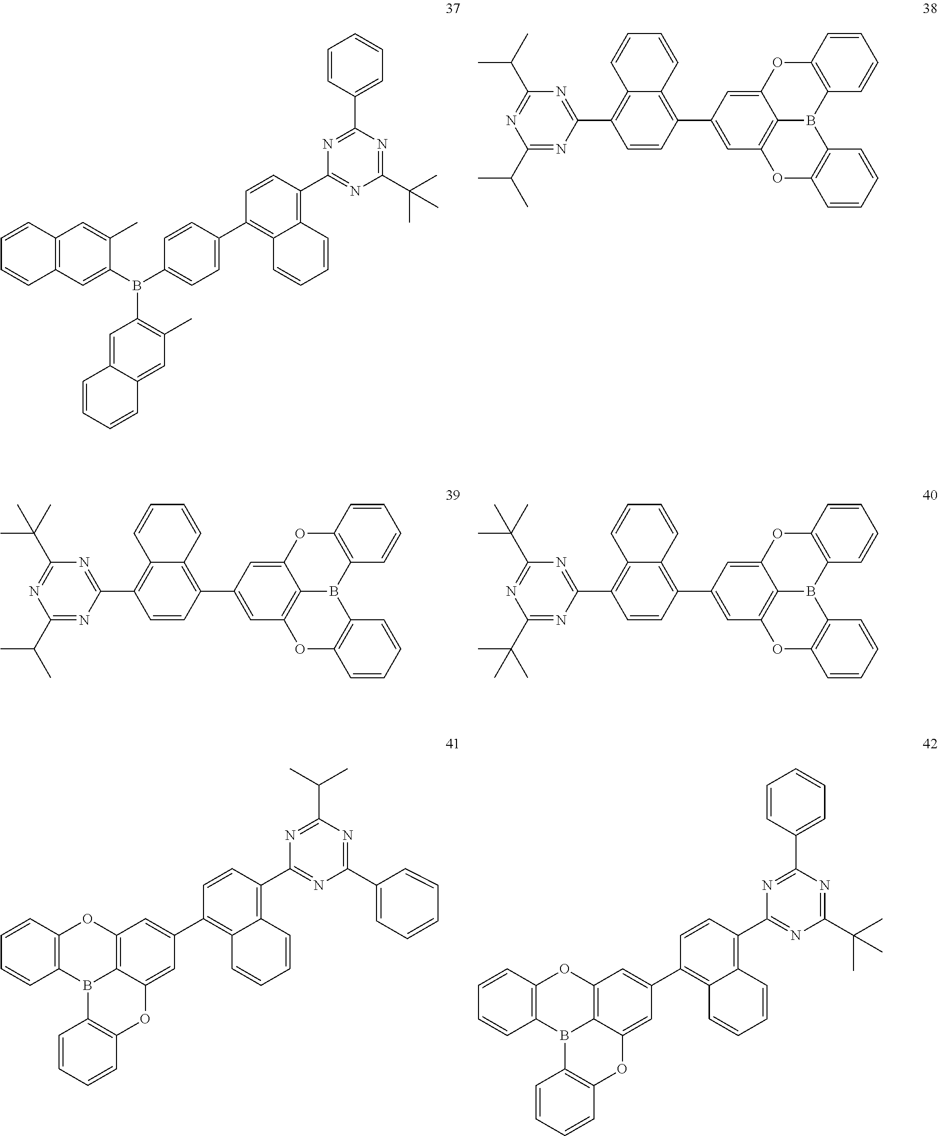 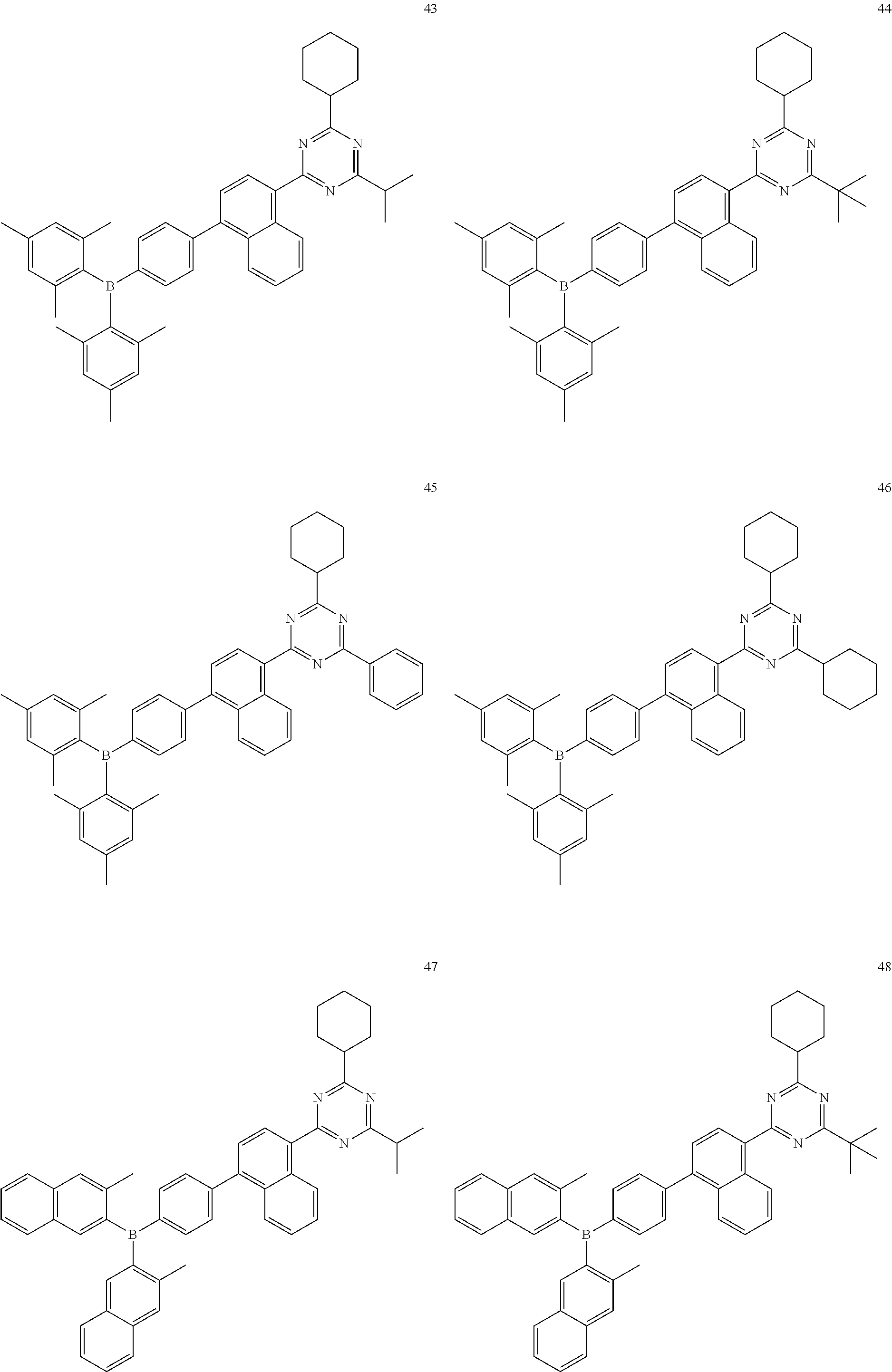 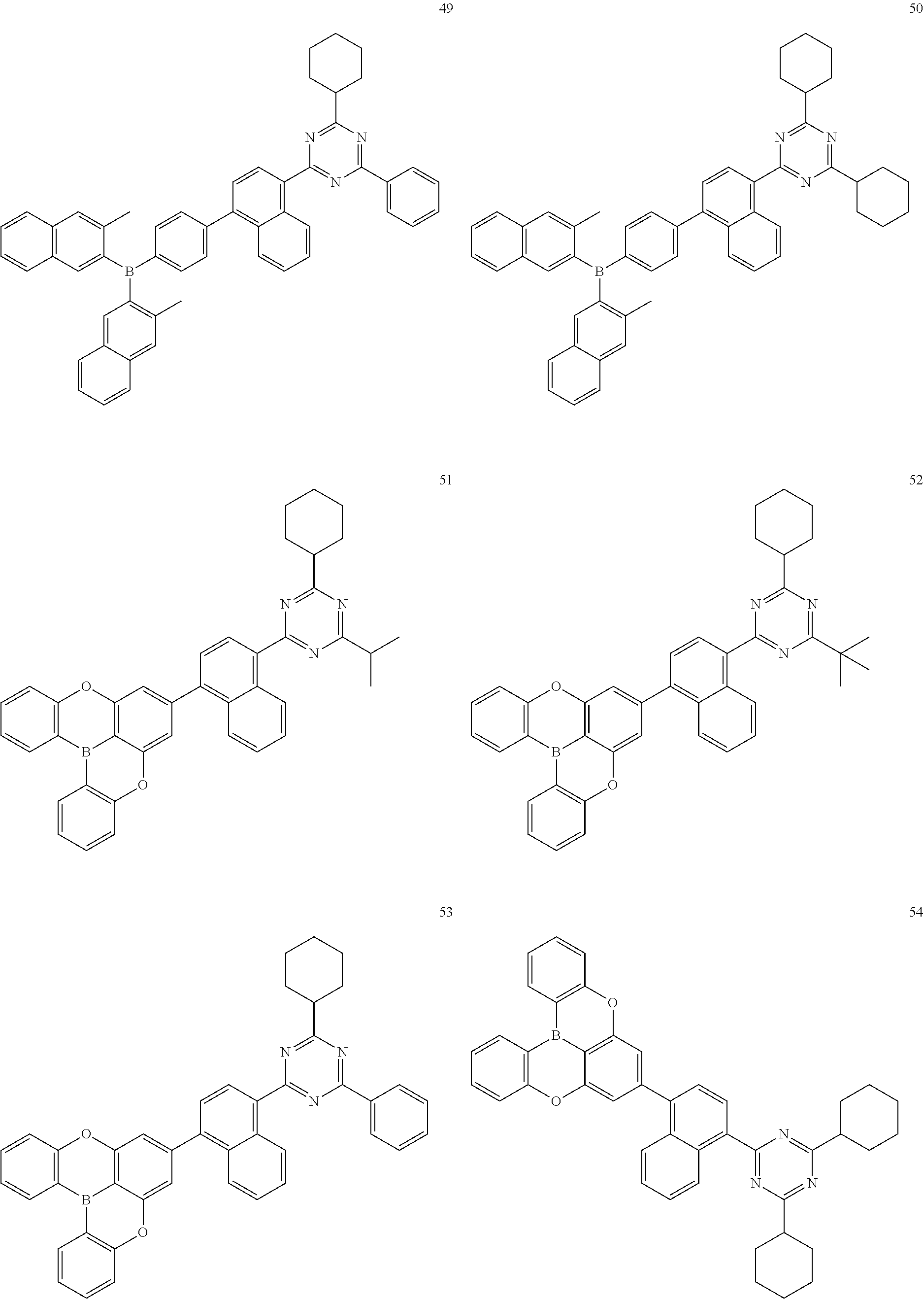 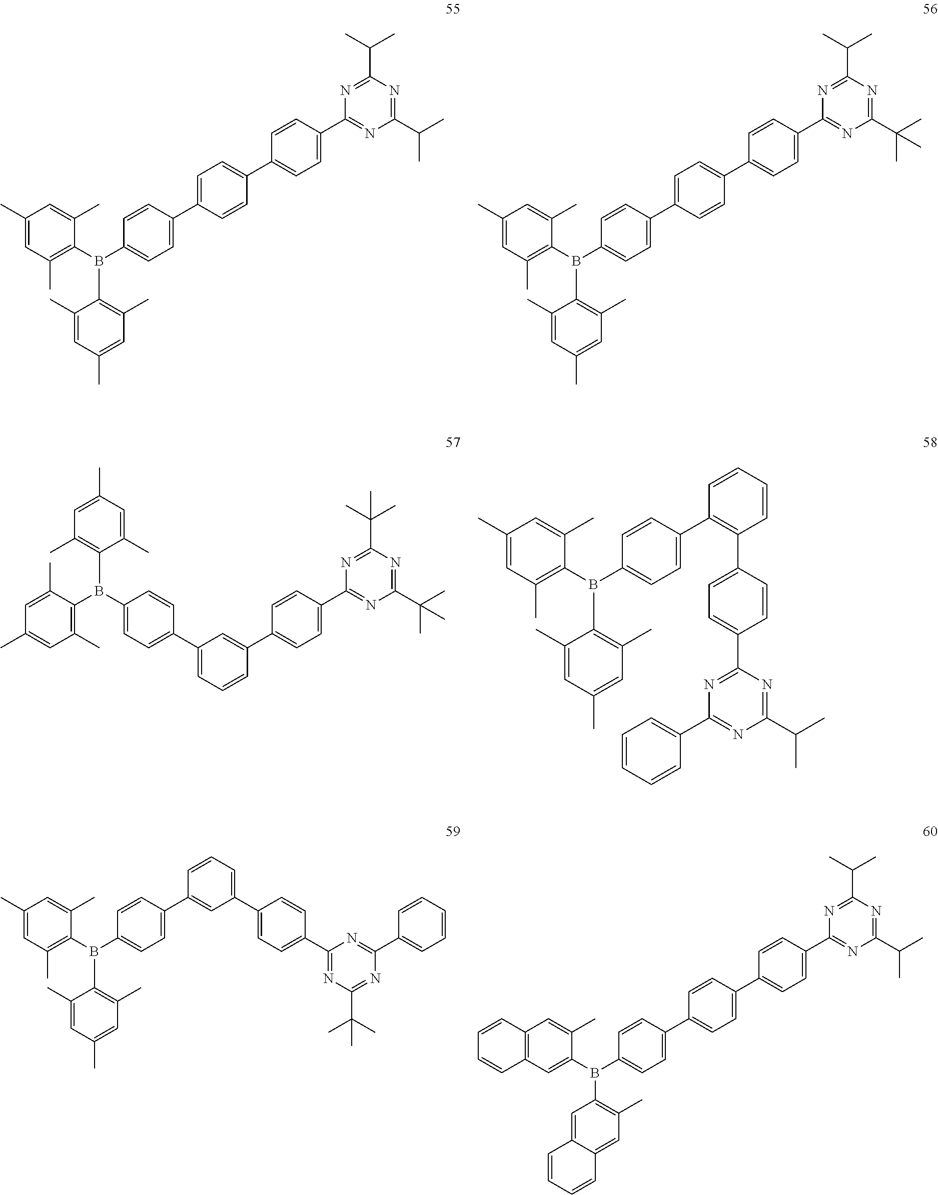 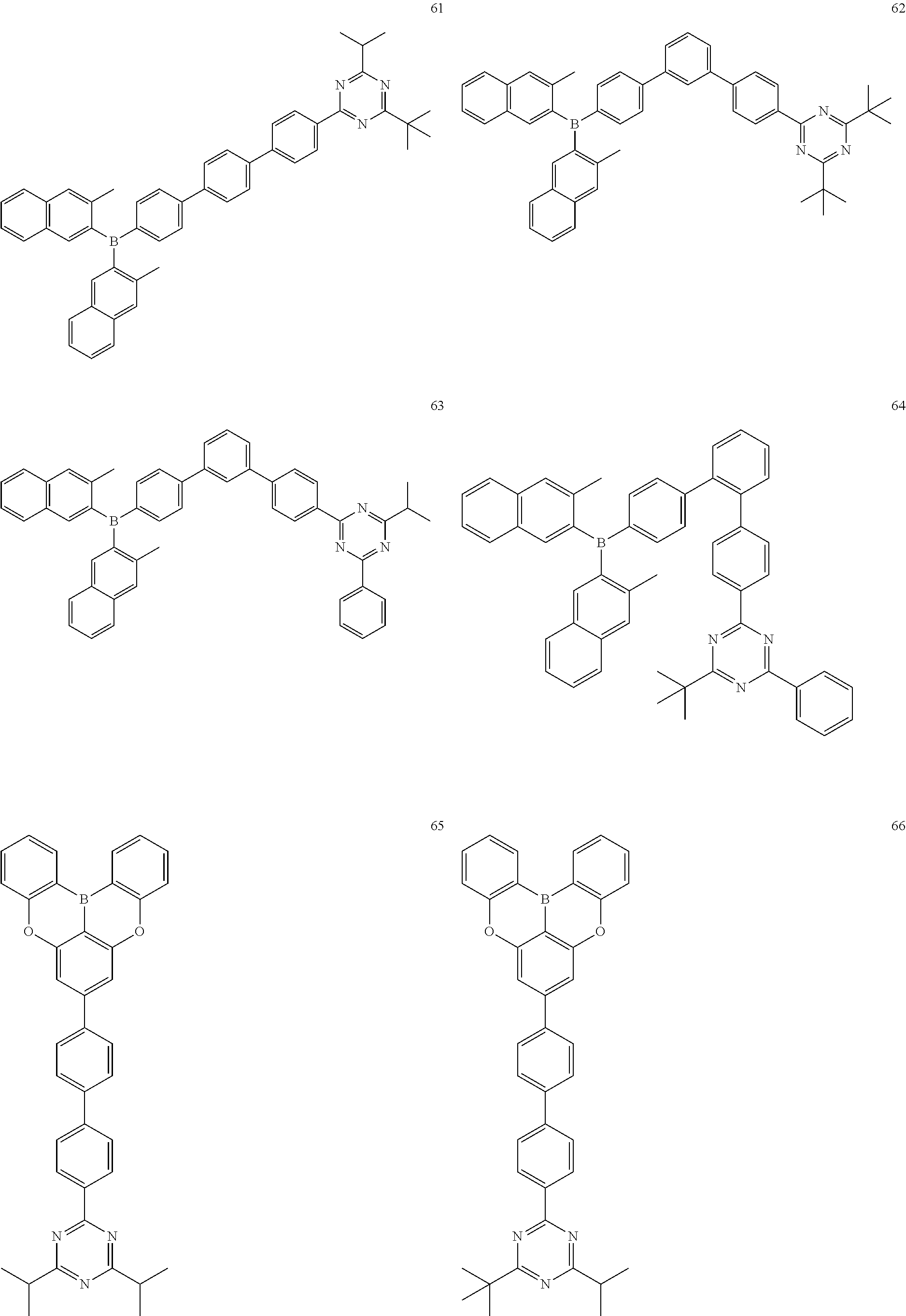 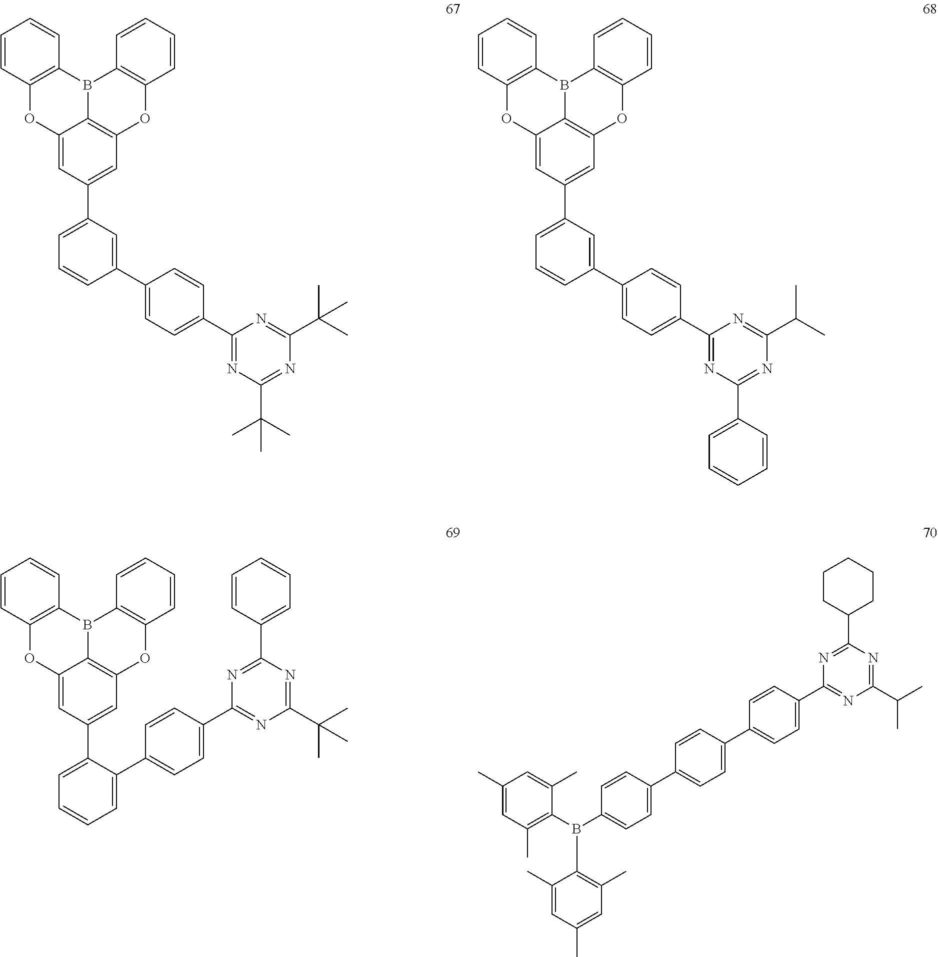 [SMILES: CC(C)(C)c1nc(-c2ccc(-c3cccc(-c4cc5c6c(c4)Oc4ccccc4B6c4ccccc4O5)c3)cc2)nc(C(C)(C)C)n1 ; CC(C)c1nc(-c2ccccc2)nc(-c2ccc(-c3cccc(-c4cc5c6c(c4)Oc4ccccc4B6c4ccccc4O5)c3)cc2)n1 ; CC(C)(C)c1nc(-c2ccccc2)nc(-c2ccc(-c3ccccc3-c3cc4c5c(c3)Oc3ccccc3B5c3ccccc3O4)cc2)n1 ; Cc1cc(C)c(B(c2ccc(-c3ccc(-c4ccc(-c5nc(C(C)C)nc(C6CCCCC6)n5)cc4)cc3)cc2)c2c(C)cc(C)cc2C)c(C)c1] 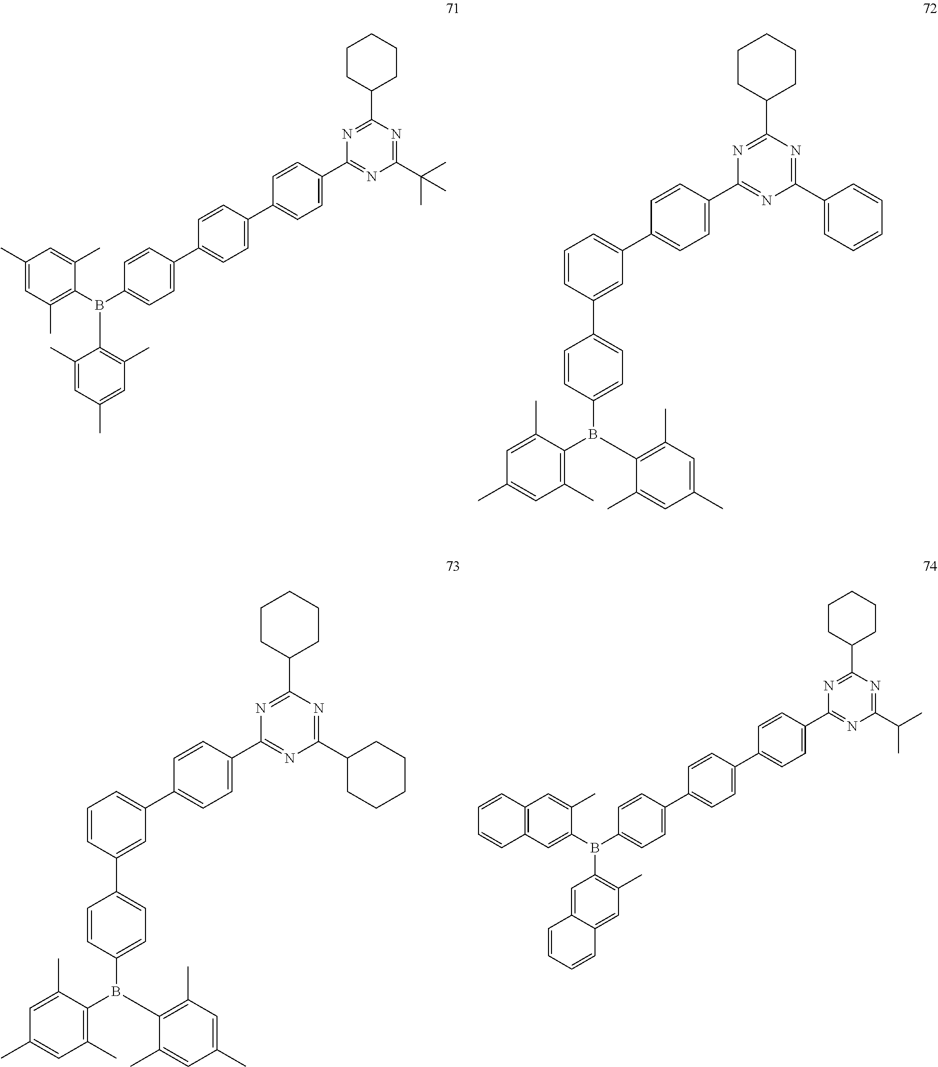 [SMILES: Cc1cc(C)c(B(c2ccc(-c3ccc(-c4ccc(-c5nc(C6CCCCC6)nc(C(C)(C)C)n5)cc4)cc3)cc2)c2c(C)cc(C)cc2C)c(C)c1 ; Cc1cc(C)c(B(c2ccc(-c3cccc(-c4ccc(-c5nc(-c6ccccc6)nc(C6CCCCC6)n5)cc4)c3)cc2)c2c(C)cc(C)cc2C)c(C)c1 ; Cc1cc(C)c(B(c2ccc(-c3cccc(-c4ccc(-c5nc(C6CCCCC6)nc(C6CCCCC6)n5)cc4)c3)cc2)c2c(C)cc(C)cc2C)c(C)c1 ; Cc1cc2ccccc2cc1B(c1ccc(-c2ccc(-c3ccc(-c4nc(C(C)C)nc(C5CCCCC5)n4)cc3)cc2)cc1)c1cc2ccccc2cc1C] 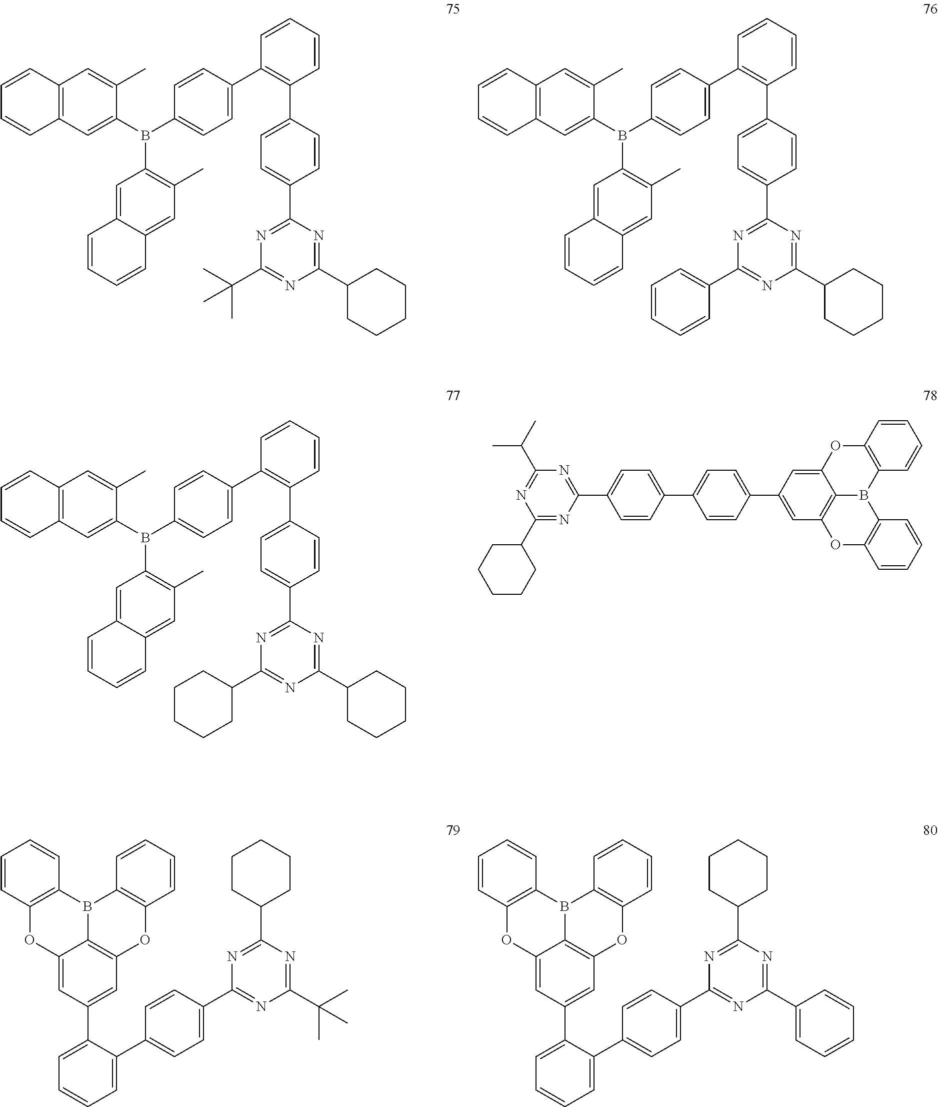 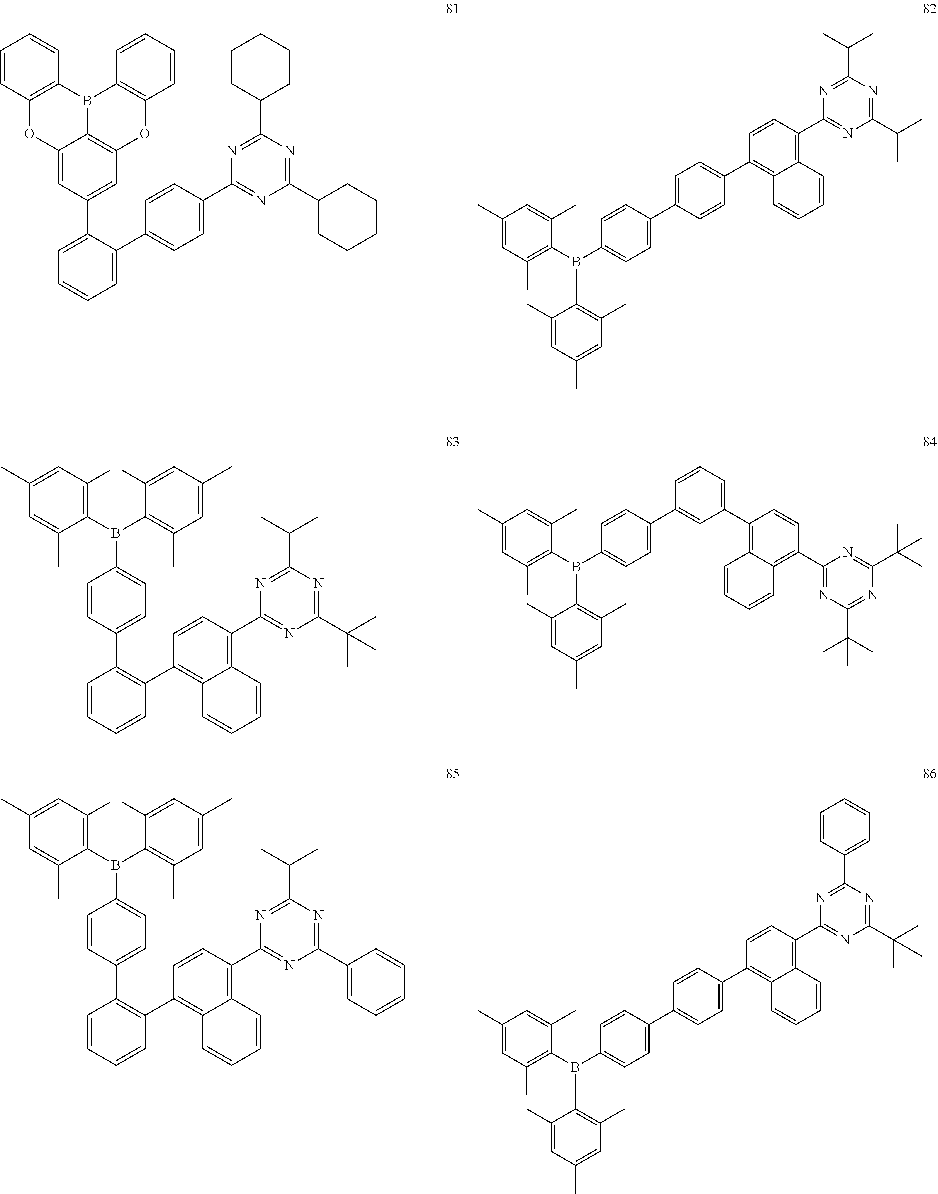 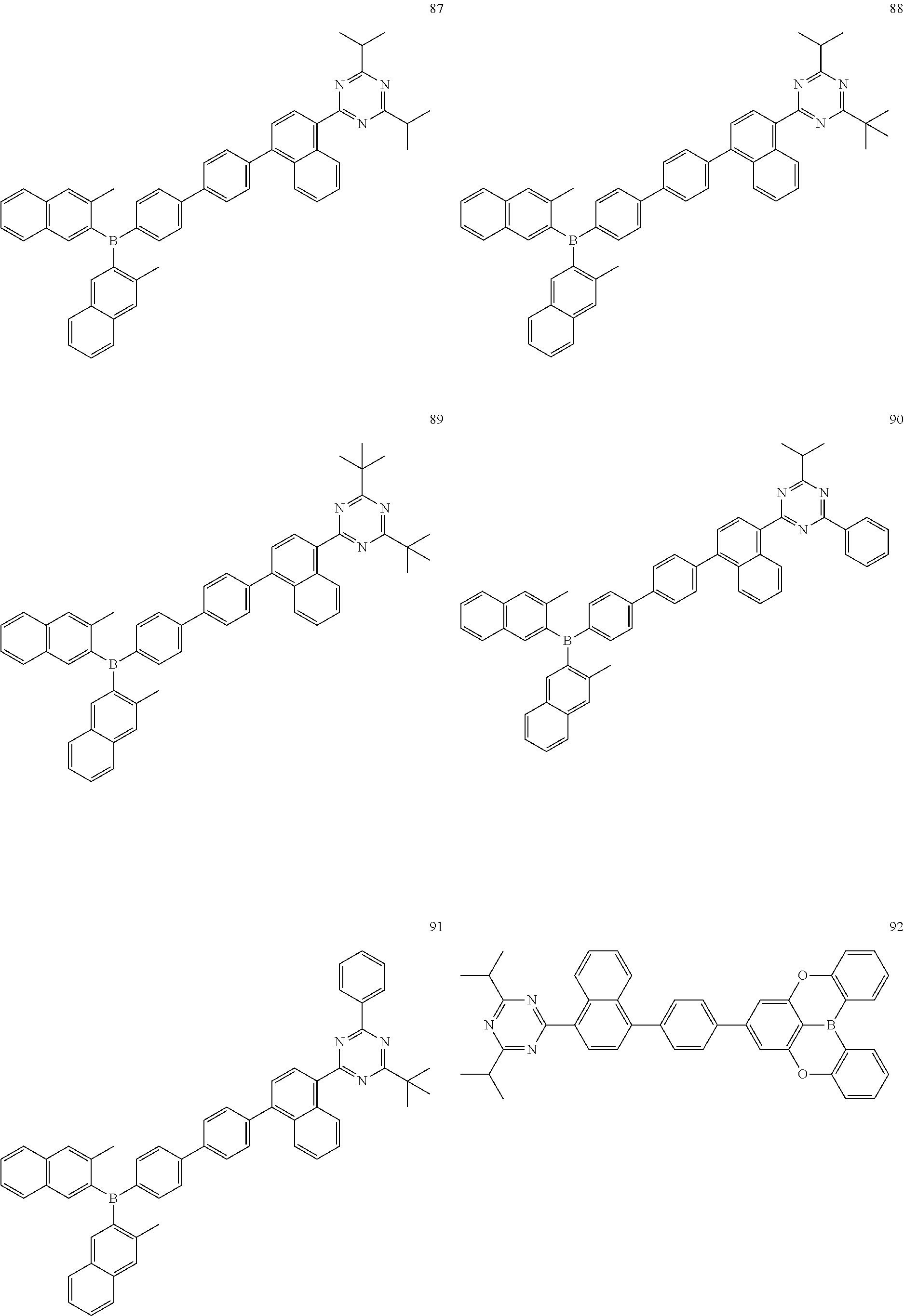 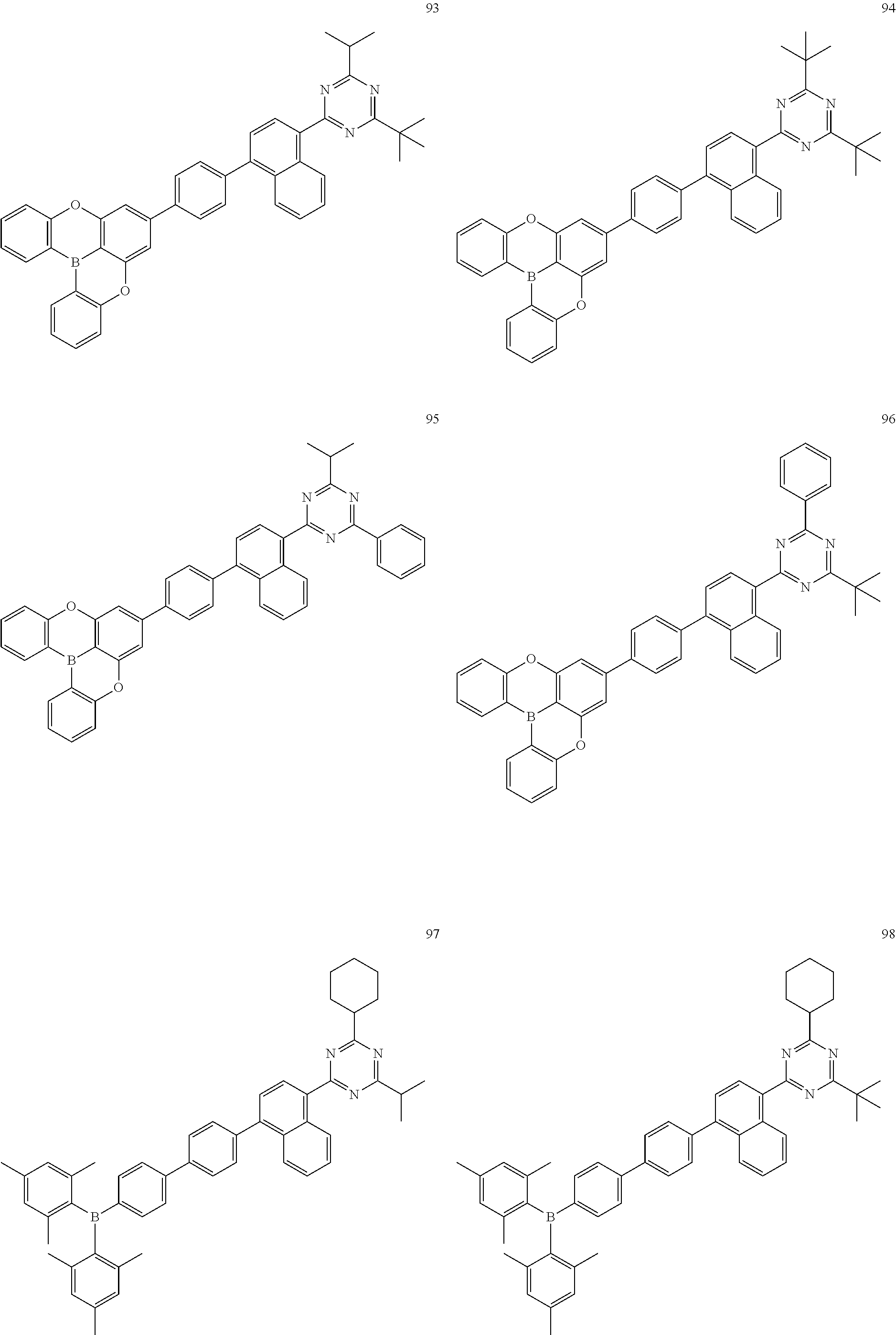 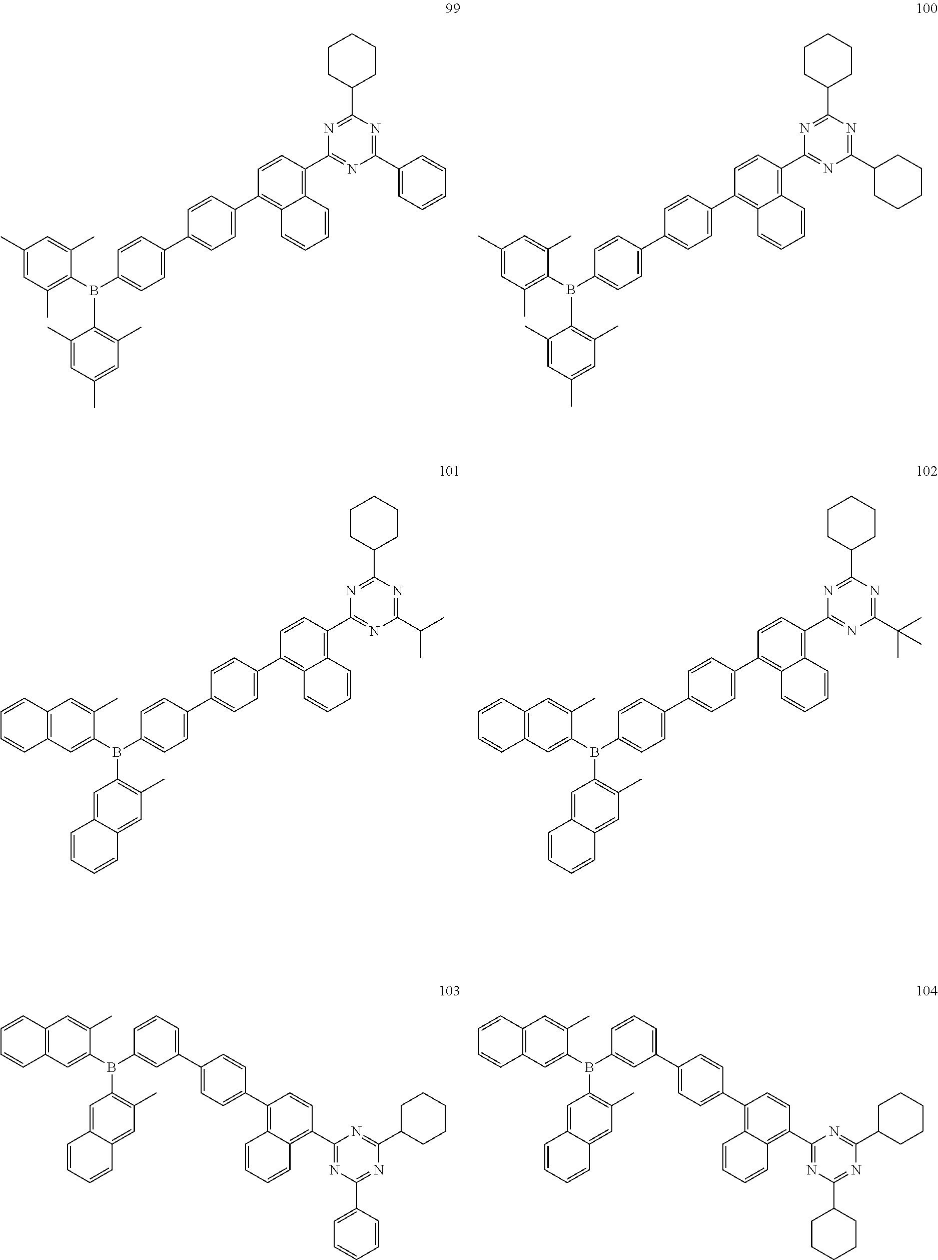 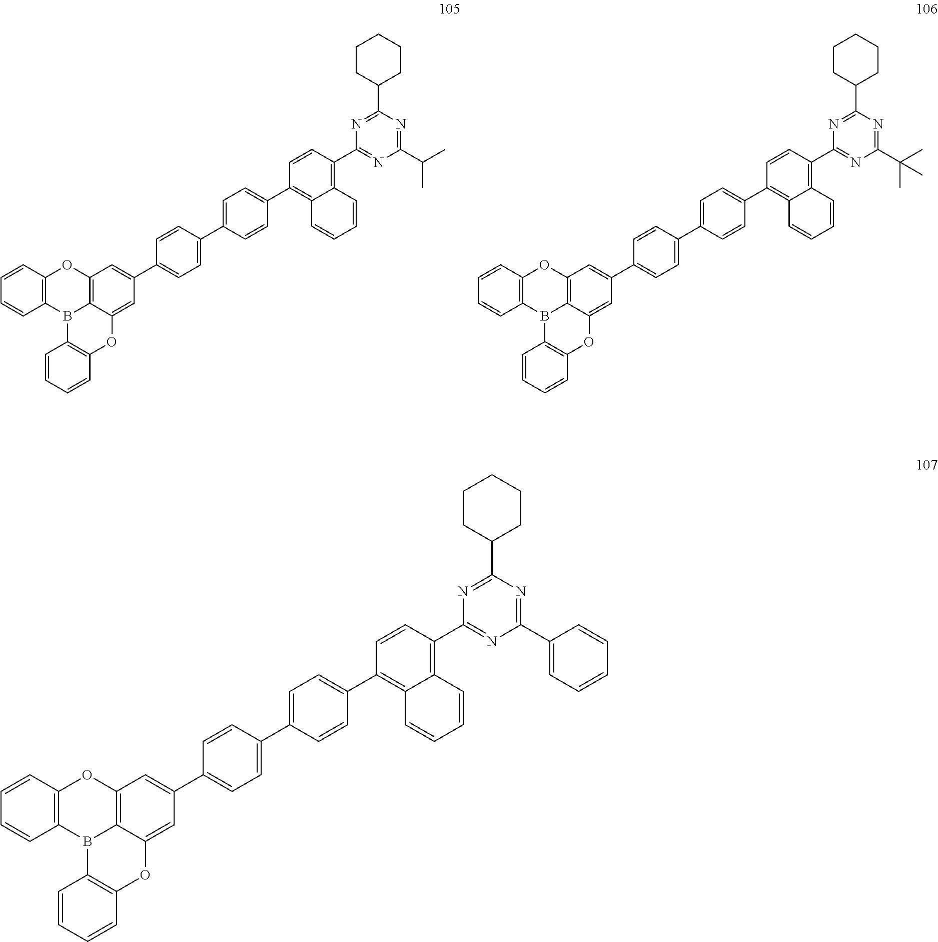 [SMILES: CC(C)c1nc(-c2ccc(-c3ccc(-c4ccc(-c5cc6c7c(c5)Oc5ccccc5B7c5ccccc5O6)cc4)cc3)c3ccccc23)nc(C2CCCCC2)n1 ; CC(C)(C)c1nc(-c2ccc(-c3ccc(-c4ccc(-c5cc6c7c(c5)Oc5ccccc5B7c5ccccc5O6)cc4)cc3)c3ccccc23)nc(C2CCCCC2)n1 ; c1ccc(-c2nc(-c3ccc(-c4ccc(-c5ccc(-c6cc7c8c(c6)Oc6ccccc6B8c6ccccc6O7)cc5)cc4)c4ccccc34)nc(C3CCCCC3)n2)cc1] 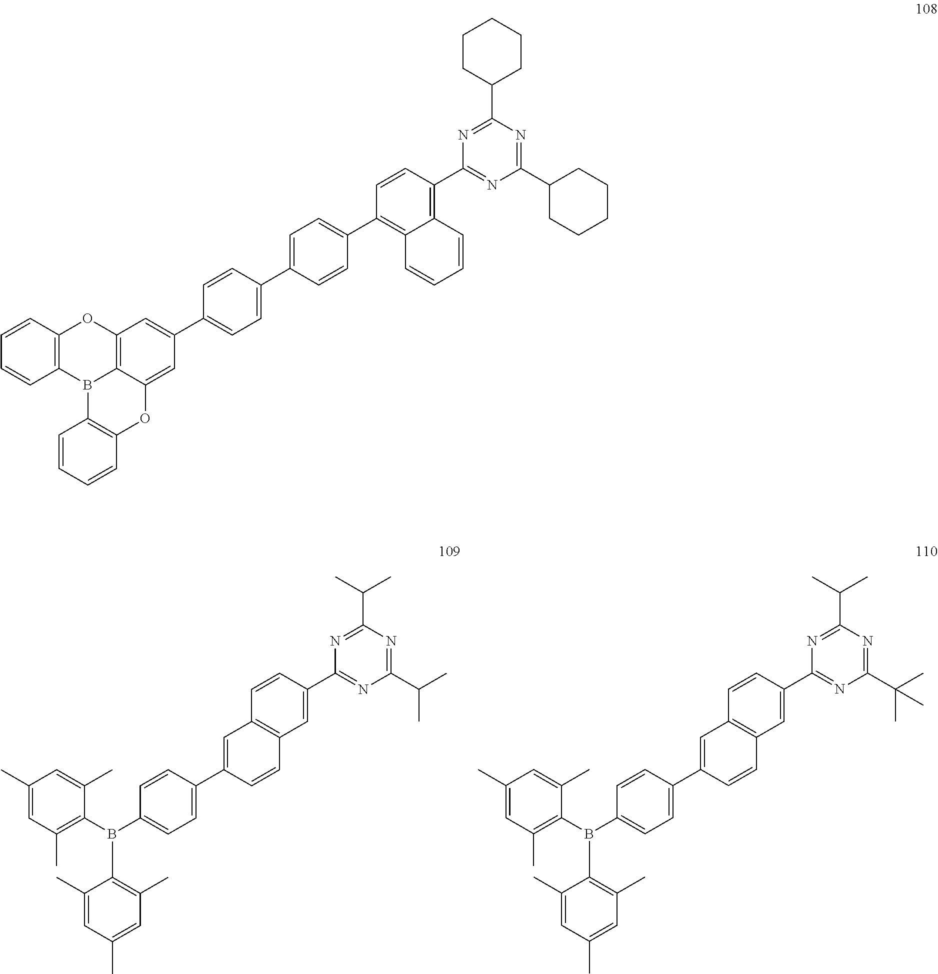 [SMILES: c1ccc2c(c1)Oc1cc(-c3ccc(-c4ccc(-c5ccc(-c6nc(C7CCCCC7)nc(C7CCCCC7)n6)c6ccccc56)cc4)cc3)cc3c1B2c1ccccc1O3 ; Cc1cc(C)c(B(c2ccc(-c3ccc4cc(-c5nc(C(C)C)nc(C(C)C)n5)ccc4c3)cc2)c2c(C)cc(C)cc2C)c(C)c1 ; Cc1cc(C)c(B(c2ccc(-c3ccc4cc(-c5nc(C(C)C)nc(C(C)(C)C)n5)ccc4c3)cc2)c2c(C)cc(C)cc2C)c(C)c1] 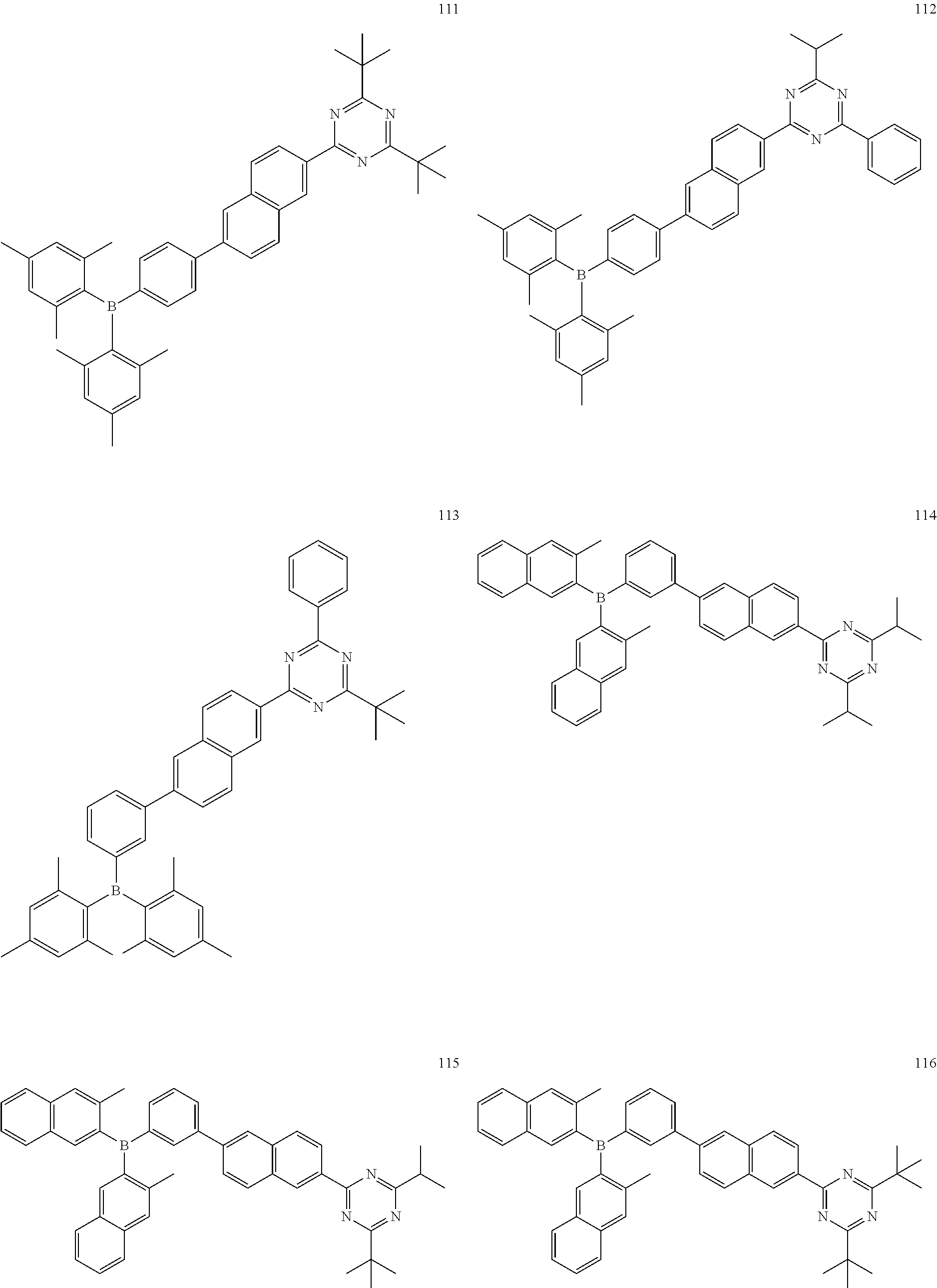 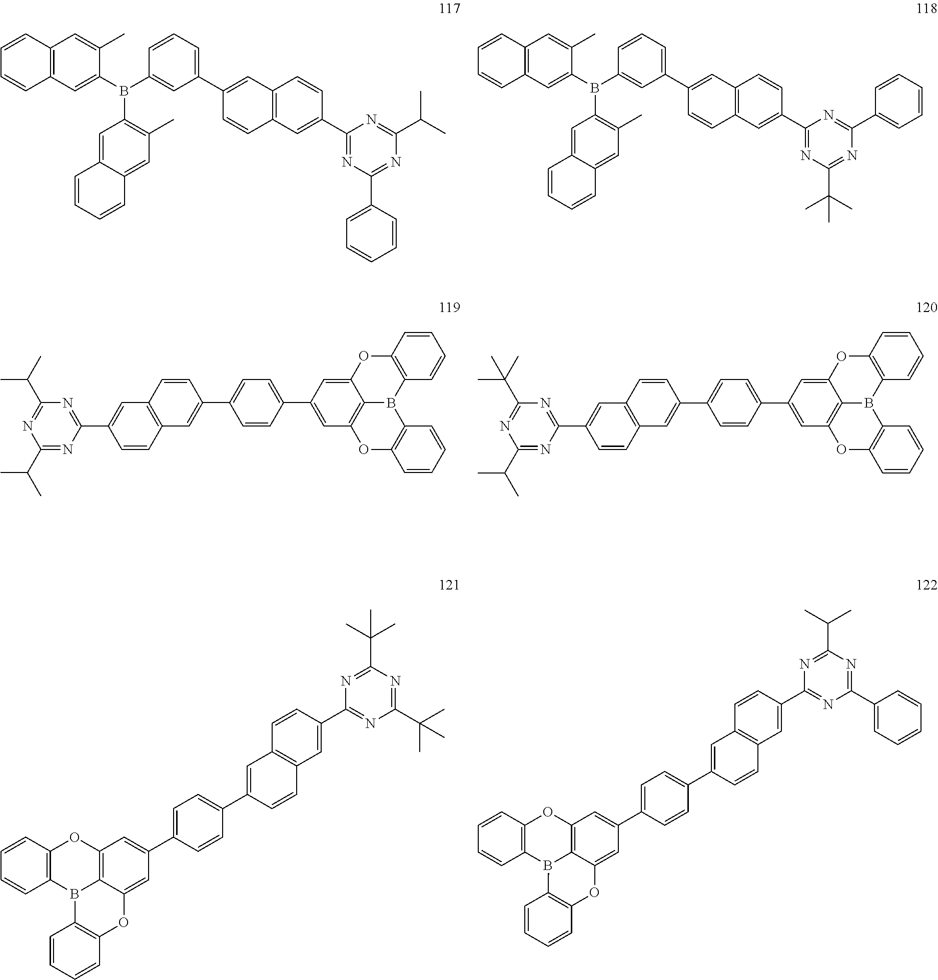 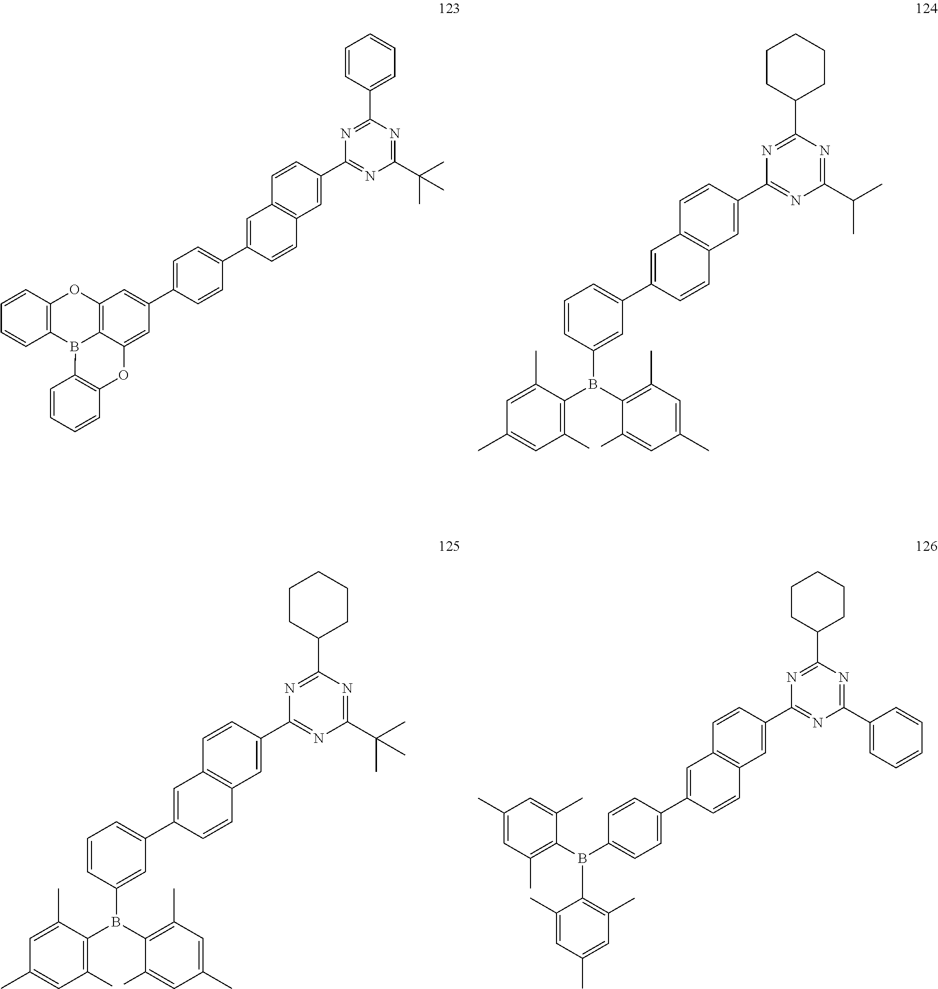 [SMILES: CC(C)(C)c1nc(-c2ccccc2)nc(-c2ccc3cc(-c4ccc(-c5cc6c7c(c5)Oc5ccccc5B7c5ccccc5O6)cc4)ccc3c2)n1 ; Cc1cc(C)c(B(c2cccc(-c3ccc4cc(-c5nc(C(C)C)nc(C6CCCCC6)n5)ccc4c3)c2)c2c(C)cc(C)cc2C)c(C)c1 ; Cc1cc(C)c(B(c2cccc(-c3ccc4cc(-c5nc(C6CCCCC6)nc(C(C)(C)C)n5)ccc4c3)c2)c2c(C)cc(C)cc2C)c(C)c1 ; Cc1cc(C)c(B(c2ccc(-c3ccc4cc(-c5nc(-c6ccccc6)nc(C6CCCCC6)n5)ccc4c3)cc2)c2c(C)cc(C)cc2C)c(C)c1] 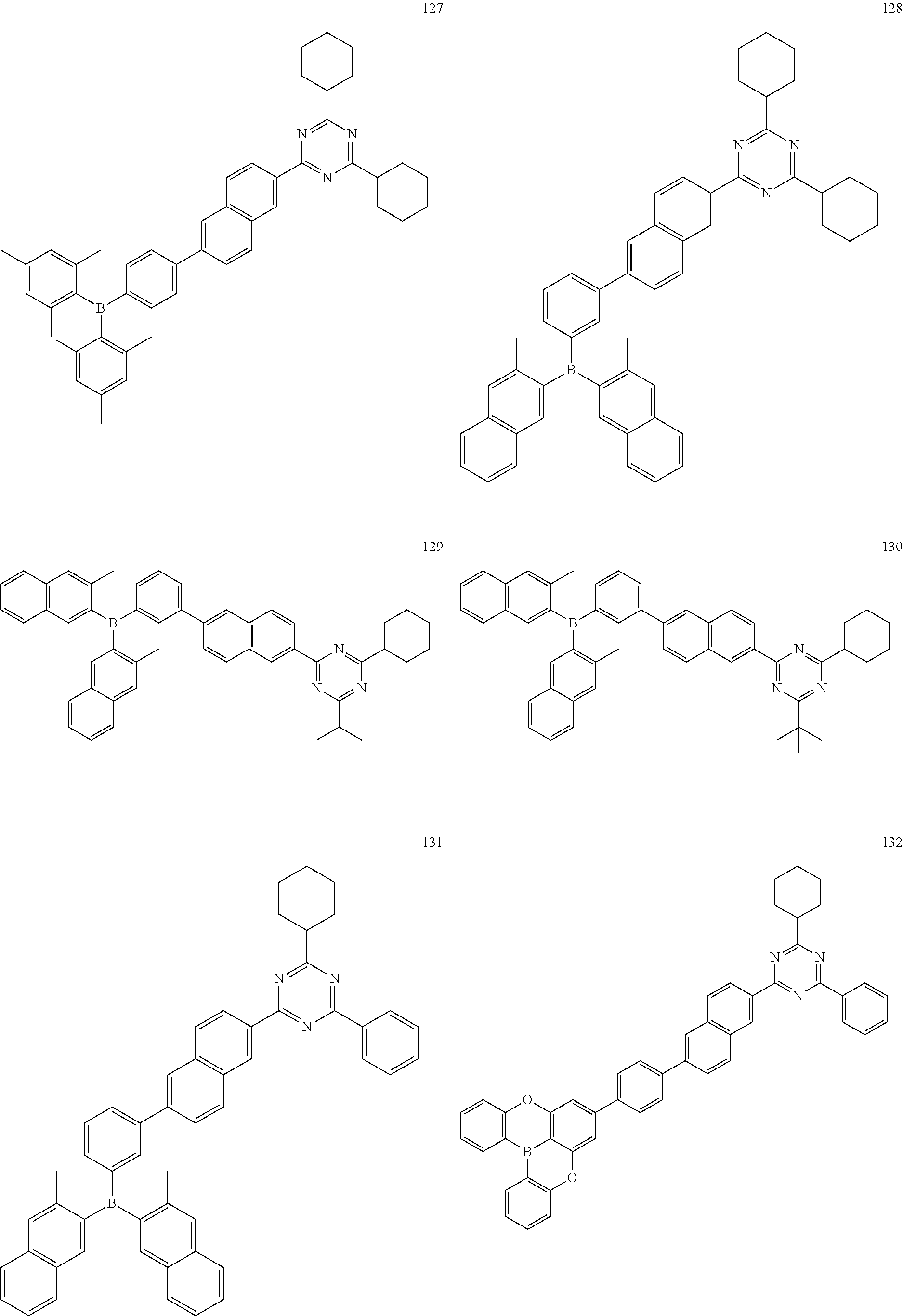 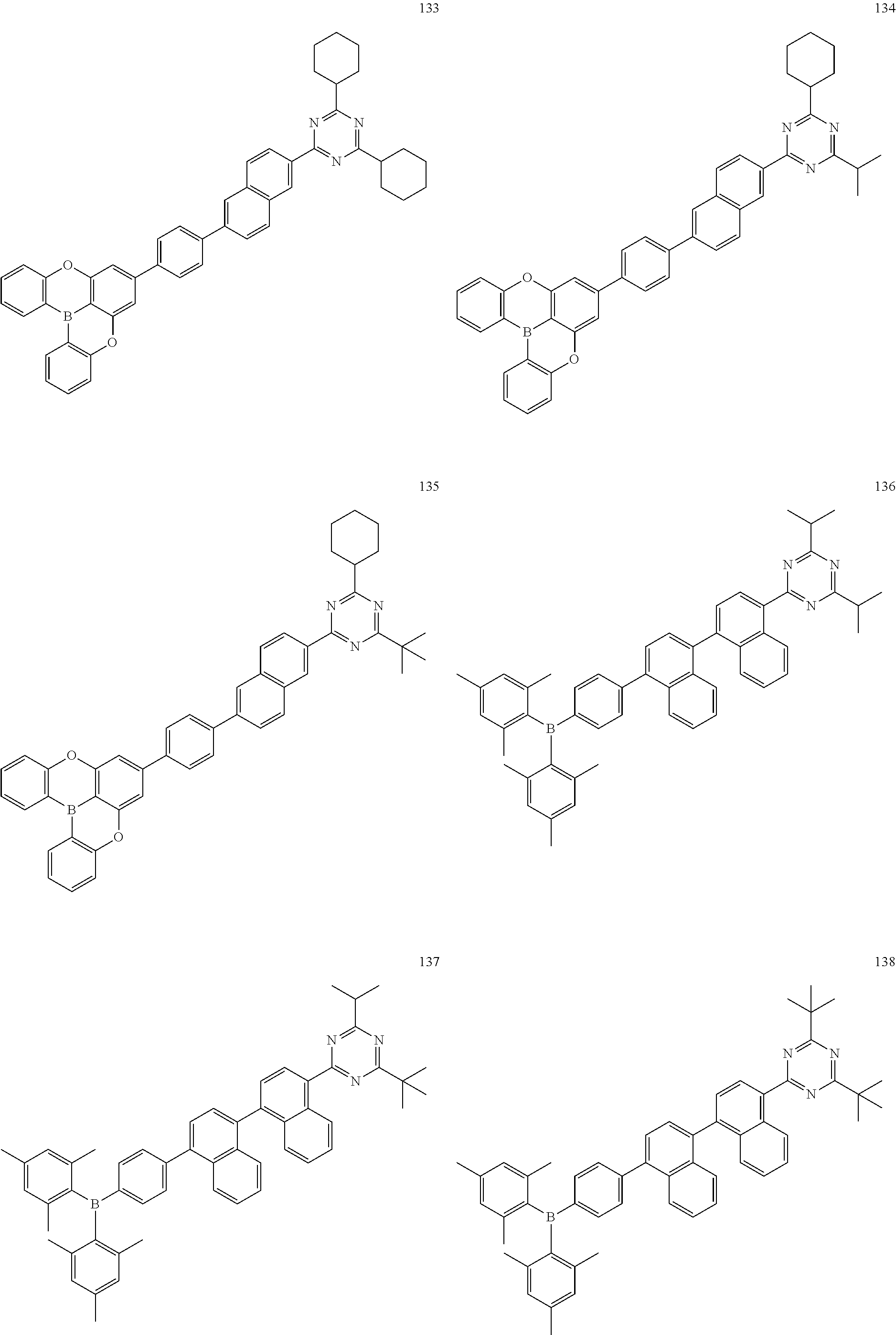 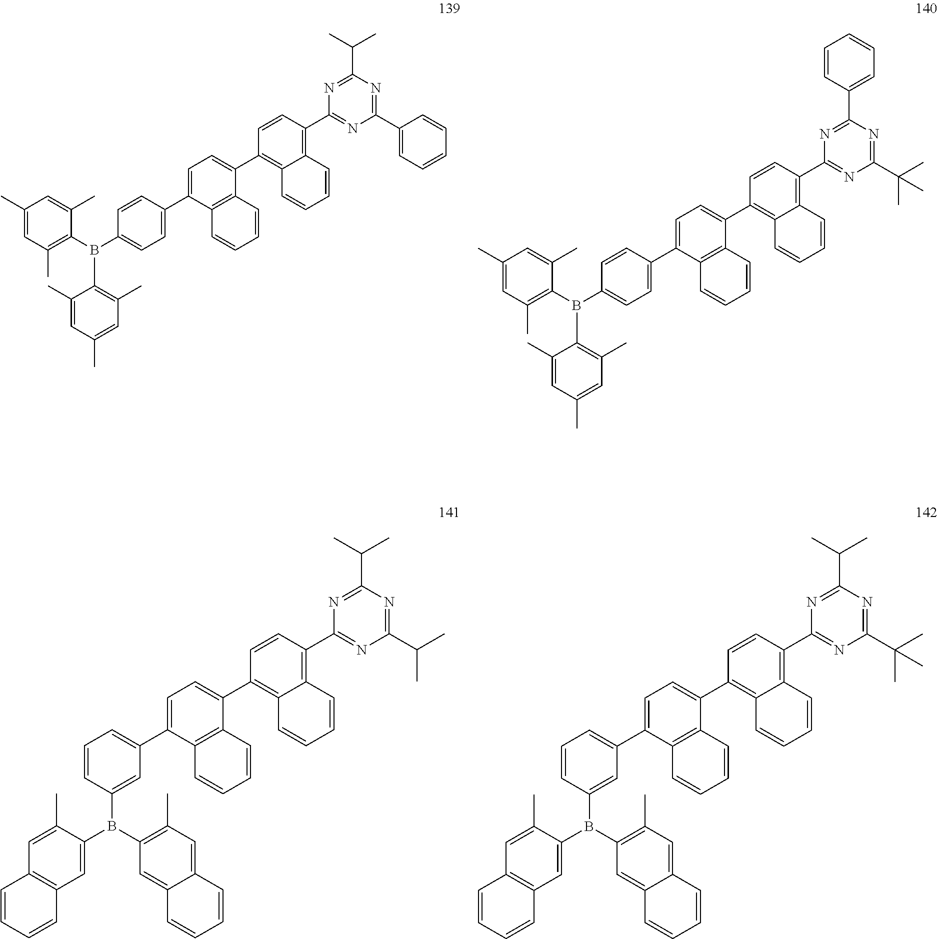 [SMILES: Cc1cc(C)c(B(c2ccc(-c3ccc(-c4ccc(-c5nc(-c6ccccc6)nc(C(C)C)n5)c5ccccc45)c4ccccc34)cc2)c2c(C)cc(C)cc2C)c(C)c1 ; Cc1cc(C)c(B(c2ccc(-c3ccc(-c4ccc(-c5nc(-c6ccccc6)nc(C(C)(C)C)n5)c5ccccc45)c4ccccc34)cc2)c2c(C)cc(C)cc2C)c(C)c1 ; Cc1cc2ccccc2cc1B(c1cccc(-c2ccc(-c3ccc(-c4nc(C(C)C)nc(C(C)C)n4)c4ccccc34)c3ccccc23)c1)c1cc2ccccc2cc1C ; Cc1cc2ccccc2cc1B(c1cccc(-c2ccc(-c3ccc(-c4nc(C(C)C)nc(C(C)(C)C)n4)c4ccccc34)c3ccccc23)c1)c1cc2ccccc2cc1C] 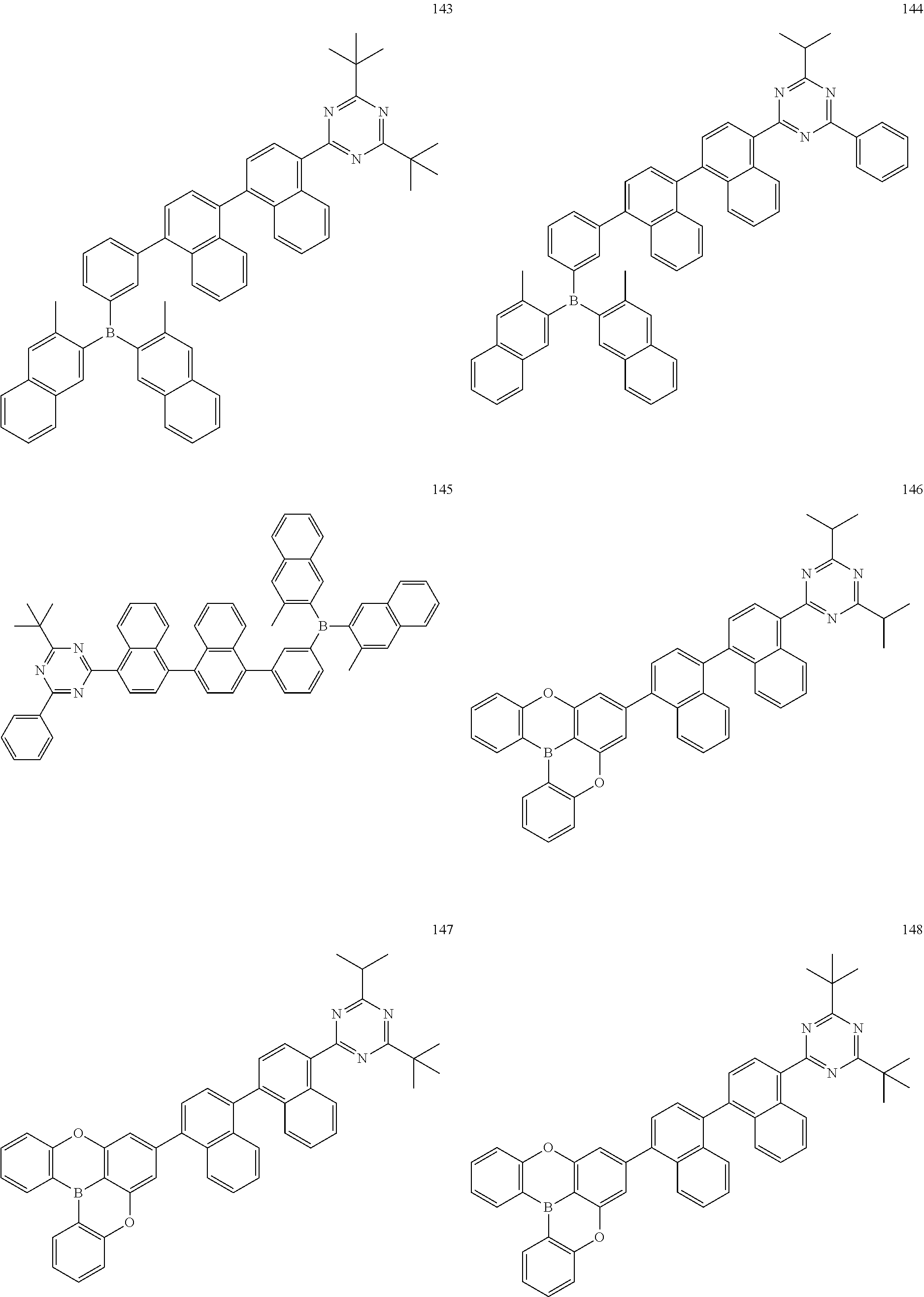 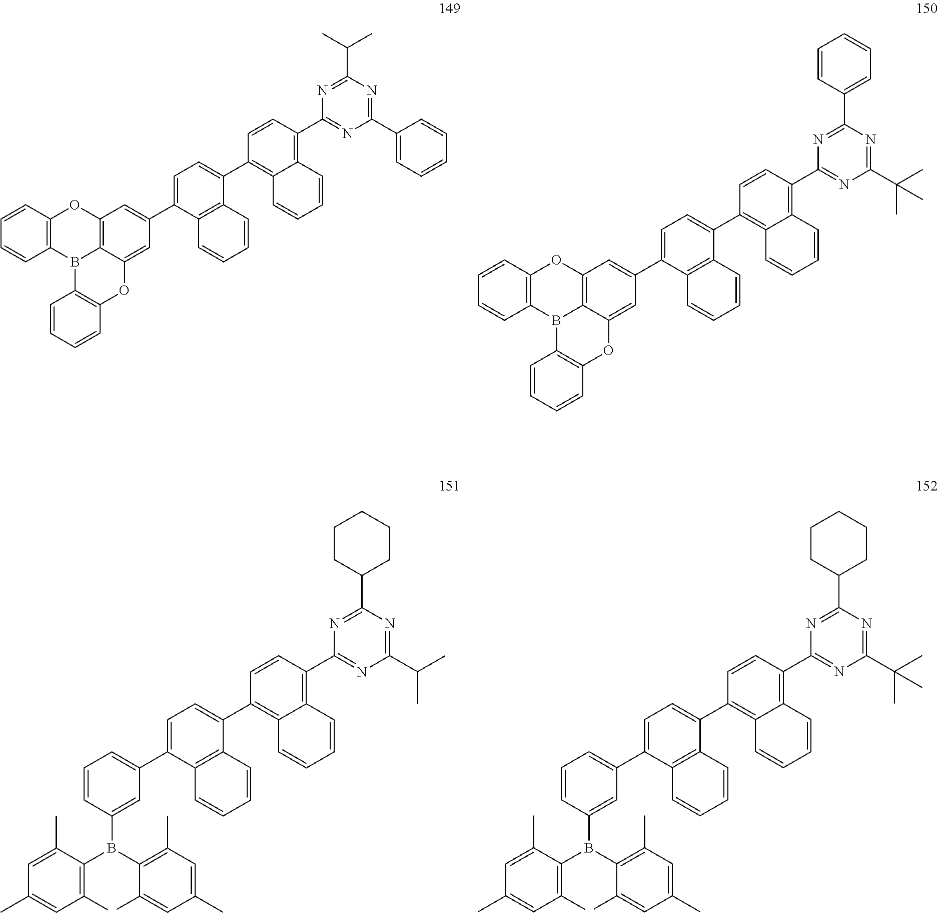 [SMILES: CC(C)c1nc(-c2ccccc2)nc(-c2ccc(-c3ccc(-c4cc5c6c(c4)Oc4ccccc4B6c4ccccc4O5)c4ccccc34)c3ccccc23)n1 ; CC(C)(C)c1nc(-c2ccccc2)nc(-c2ccc(-c3ccc(-c4cc5c6c(c4)Oc4ccccc4B6c4ccccc4O5)c4ccccc34)c3ccccc23)n1 ; Cc1cc(C)c(B(c2cccc(-c3ccc(-c4ccc(-c5nc(C(C)C)nc(C6CCCCC6)n5)c5ccccc45)c4ccccc34)c2)c2c(C)cc(C)cc2C)c(C)c1 ; Cc1cc(C)c(B(c2cccc(-c3ccc(-c4ccc(-c5nc(C6CCCCC6)nc(C(C)(C)C)n5)c5ccccc45)c4ccccc34)c2)c2c(C)cc(C)cc2C)c(C)c1] 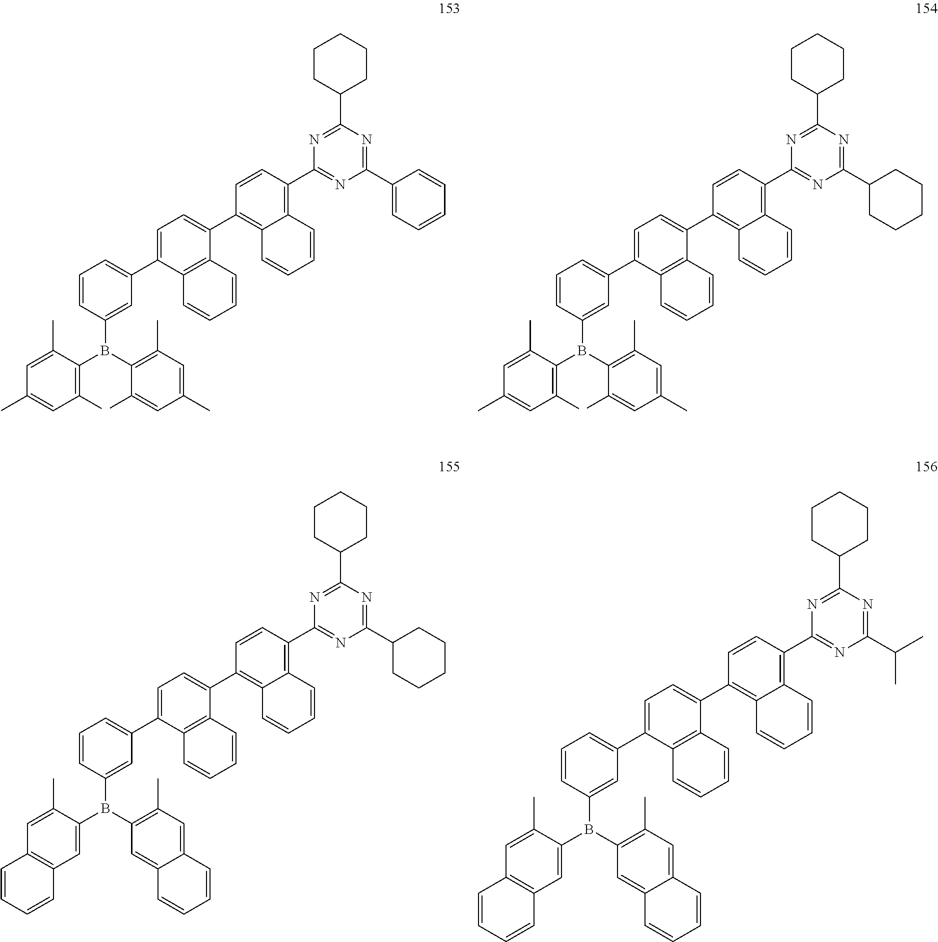 [SMILES: Cc1cc(C)c(B(c2cccc(-c3ccc(-c4ccc(-c5nc(-c6ccccc6)nc(C6CCCCC6)n5)c5ccccc45)c4ccccc34)c2)c2c(C)cc(C)cc2C)c(C)c1 ; Cc1cc(C)c(B(c2cccc(-c3ccc(-c4ccc(-c5nc(C6CCCCC6)nc(C6CCCCC6)n5)c5ccccc45)c4ccccc34)c2)c2c(C)cc(C)cc2C)c(C)c1 ; Cc1cc2ccccc2cc1B(c1cccc(-c2ccc(-c3ccc(-c4nc(C5CCCCC5)nc(C5CCCCC5)n4)c4ccccc34)c3ccccc23)c1)c1cc2ccccc2cc1C ; Cc1cc2ccccc2cc1B(c1cccc(-c2ccc(-c3ccc(-c4nc(C(C)C)nc(C5CCCCC5)n4)c4ccccc34)c3ccccc23)c1)c1cc2ccccc2cc1C] 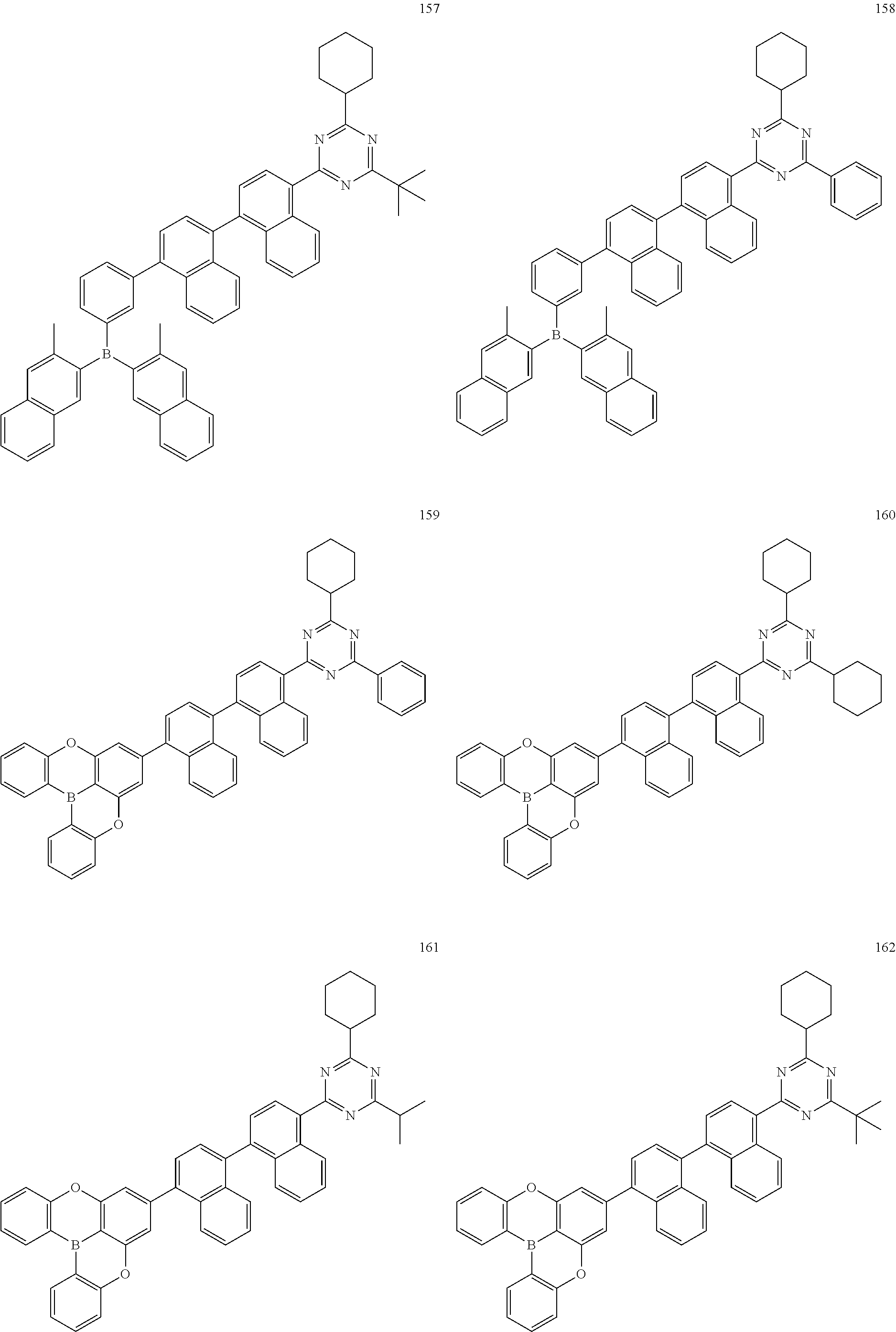 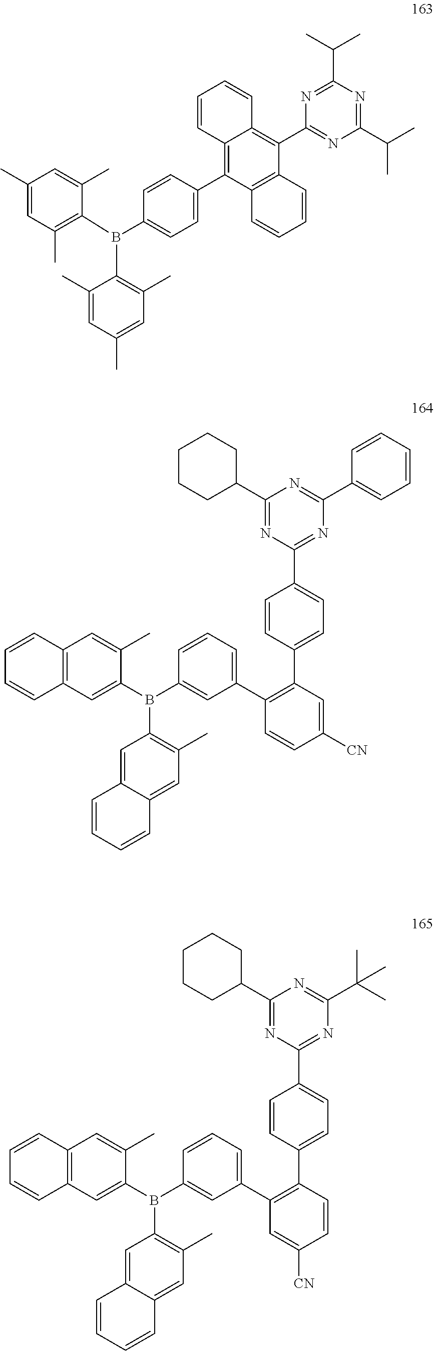 [SMILES: Cc1cc(C)c(B(c2ccc(-c3c4ccccc4c(-c4nc(C(C)C)nc(C(C)C)n4)c4ccccc34)cc2)c2c(C)cc(C)cc2C)c(C)c1 ; Cc1cc2ccccc2cc1B(c1cccc(-c2ccc(C#N)cc2-c2ccc(-c3nc(-c4ccccc4)nc(C4CCCCC4)n3)cc2)c1)c1cc2ccccc2cc1C ; Cc1cc2ccccc2cc1B(c1cccc(-c2cc(C#N)ccc2-c2ccc(-c3nc(C4CCCCC4)nc(C(C)(C)C)n3)cc2)c1)c1cc2ccccc2cc1C] 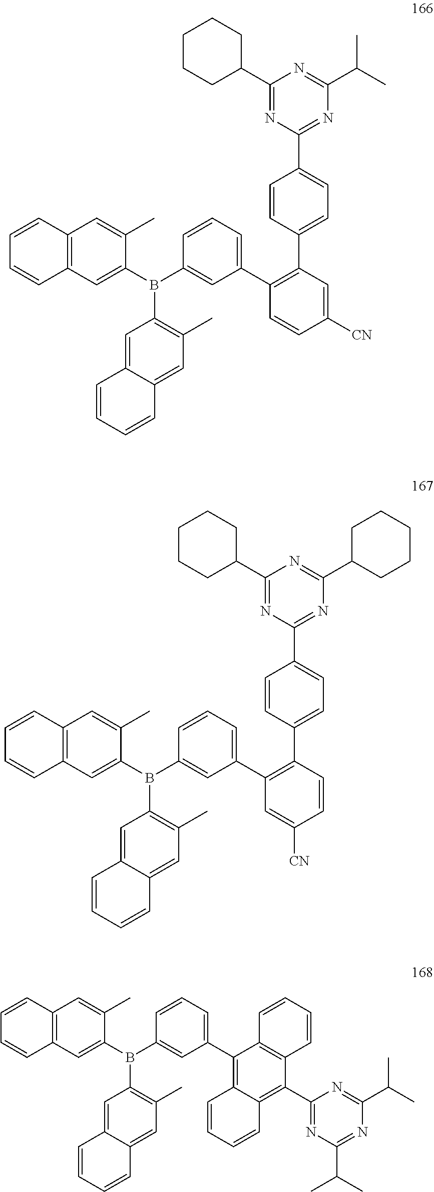 [SMILES: Cc1cc2ccccc2cc1B(c1cccc(-c2ccc(C#N)cc2-c2ccc(-c3nc(C(C)C)nc(C4CCCCC4)n3)cc2)c1)c1cc2ccccc2cc1C ; Cc1cc2ccccc2cc1B(c1cccc(-c2cc(C#N)ccc2-c2ccc(-c3nc(C4CCCCC4)nc(C4CCCCC4)n3)cc2)c1)c1cc2ccccc2cc1C ; Cc1cc2ccccc2cc1B(c1cccc(-c2c3ccccc3c(-c3nc(C(C)C)nc(C(C)C)n3)c3ccccc23)c1)c1cc2ccccc2cc1C] 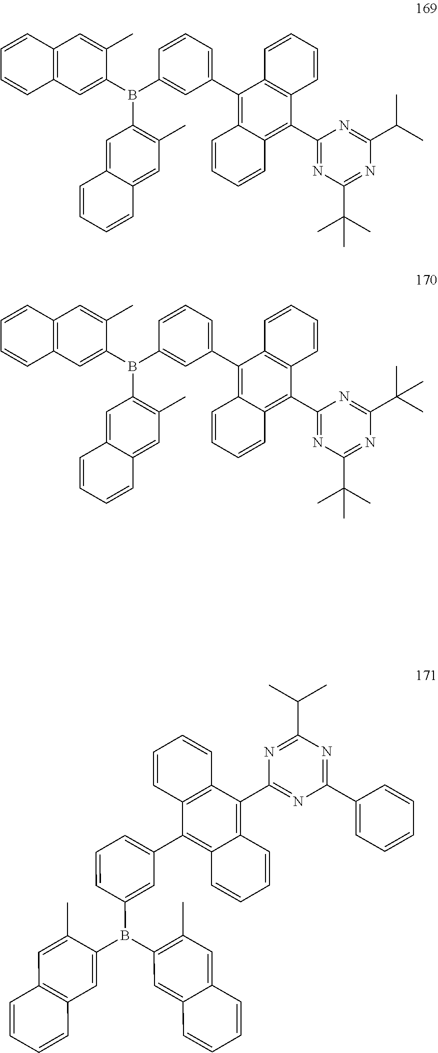 [SMILES: Cc1cc2ccccc2cc1B(c1cccc(-c2c3ccccc3c(-c3nc(C(C)C)nc(C(C)(C)C)n3)c3ccccc23)c1)c1cc2ccccc2cc1C ; Cc1cc2ccccc2cc1B(c1cccc(-c2c3ccccc3c(-c3nc(C(C)(C)C)nc(C(C)(C)C)n3)c3ccccc23)c1)c1cc2ccccc2cc1C ; Cc1cc2ccccc2cc1B(c1cccc(-c2c3ccccc3c(-c3nc(-c4ccccc4)nc(C(C)C)n3)c3ccccc23)c1)c1cc2ccccc2cc1C] 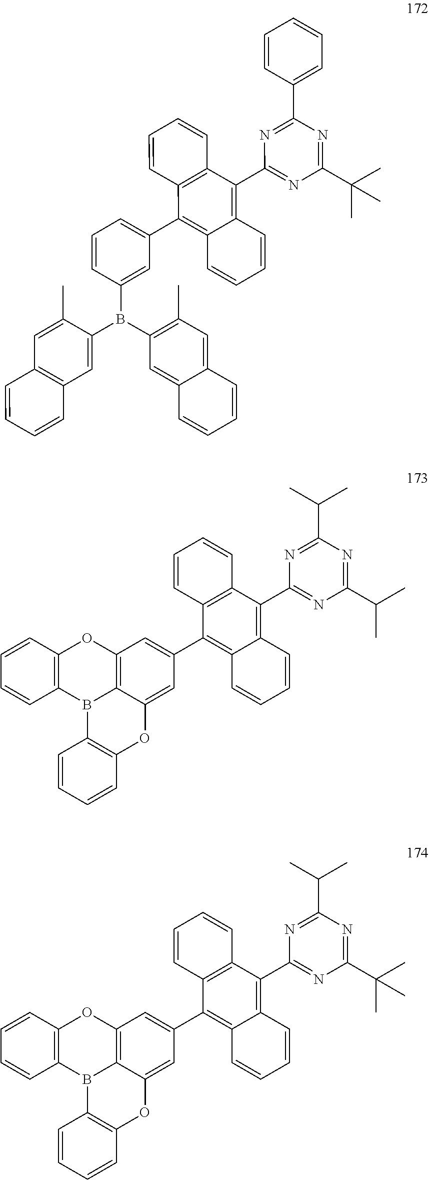 [SMILES: Cc1cc2ccccc2cc1B(c1cccc(-c2c3ccccc3c(-c3nc(-c4ccccc4)nc(C(C)(C)C)n3)c3ccccc23)c1)c1cc2ccccc2cc1C ; CC(C)c1nc(-c2c3ccccc3c(-c3cc4c5c(c3)Oc3ccccc3B5c3ccccc3O4)c3ccccc23)nc(C(C)C)n1 ; CC(C)c1nc(-c2c3ccccc3c(-c3cc4c5c(c3)Oc3ccccc3B5c3ccccc3O4)c3ccccc23)nc(C(C)(C)C)n1] 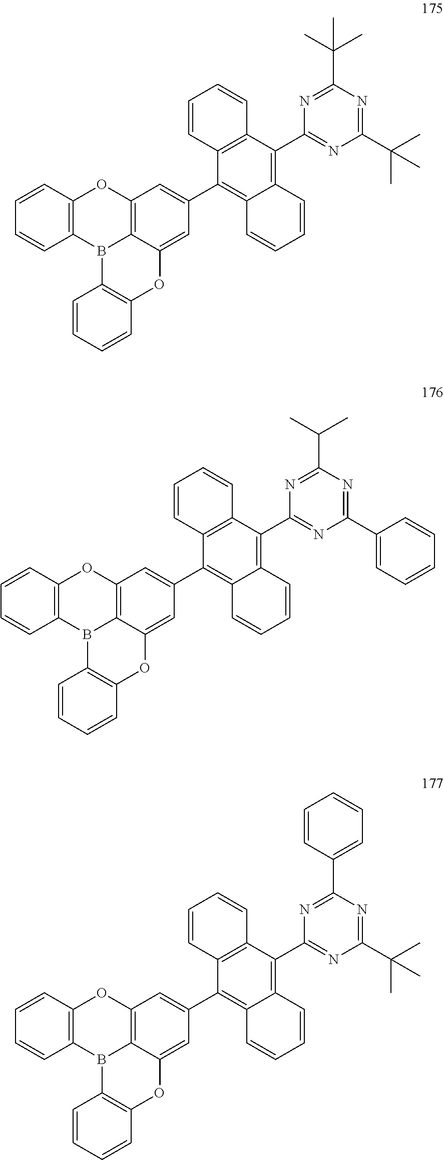 [SMILES: CC(C)(C)c1nc(-c2c3ccccc3c(-c3cc4c5c(c3)Oc3ccccc3B5c3ccccc3O4)c3ccccc23)nc(C(C)(C)C)n1 ; CC(C)c1nc(-c2ccccc2)nc(-c2c3ccccc3c(-c3cc4c5c(c3)Oc3ccccc3B5c3ccccc3O4)c3ccccc23)n1 ; CC(C)(C)c1nc(-c2ccccc2)nc(-c2c3ccccc3c(-c3cc4c5c(c3)Oc3ccccc3B5c3ccccc3O4)c3ccccc23)n1] 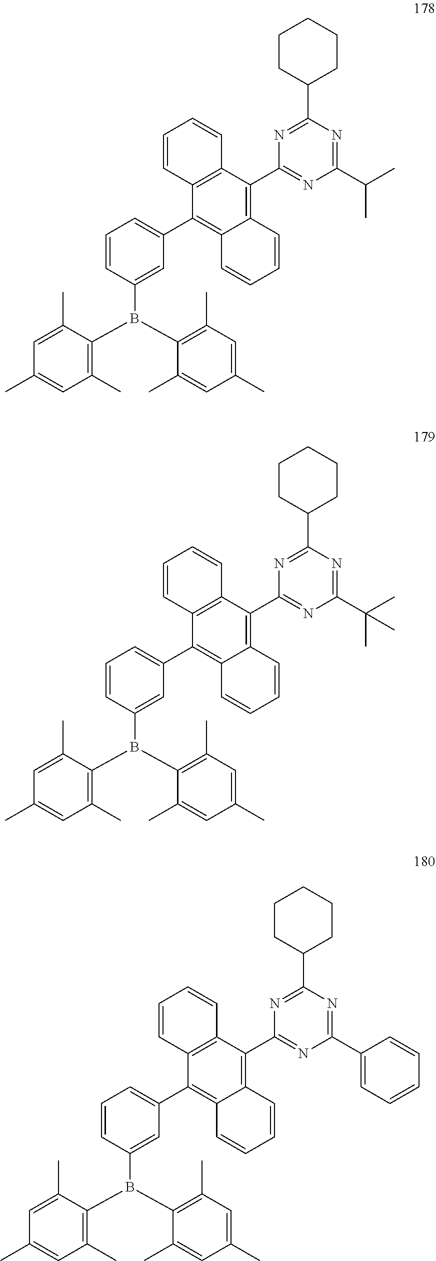 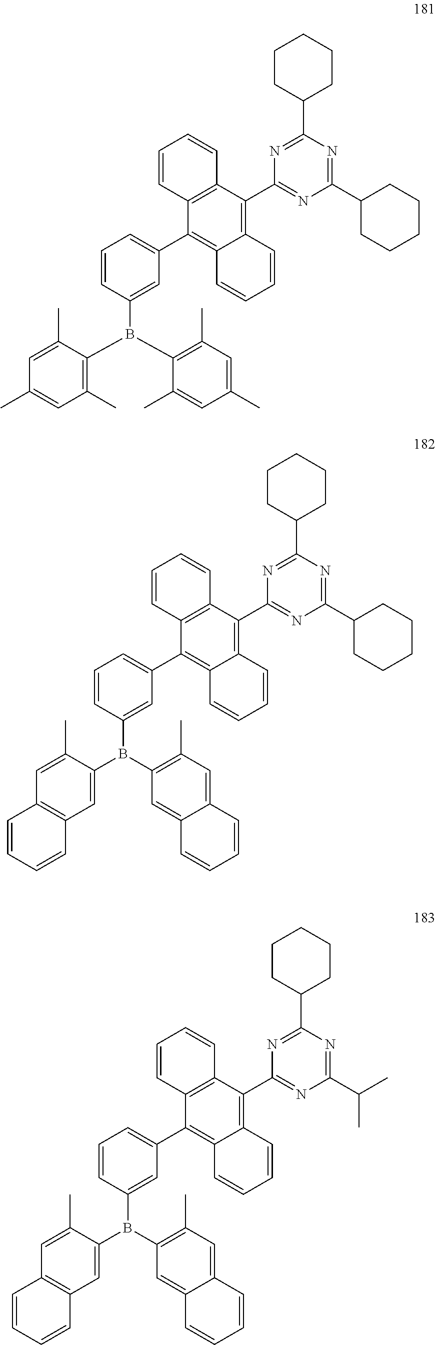 [SMILES: Cc1cc(C)c(B(c2cccc(-c3c4ccccc4c(-c4nc(C5CCCCC5)nc(C5CCCCC5)n4)c4ccccc34)c2)c2c(C)cc(C)cc2C)c(C)c1 ; Cc1cc2ccccc2cc1B(c1cccc(-c2c3ccccc3c(-c3nc(C4CCCCC4)nc(C4CCCCC4)n3)c3ccccc23)c1)c1cc2ccccc2cc1C ; Cc1cc2ccccc2cc1B(c1cccc(-c2c3ccccc3c(-c3nc(C(C)C)nc(C4CCCCC4)n3)c3ccccc23)c1)c1cc2ccccc2cc1C] 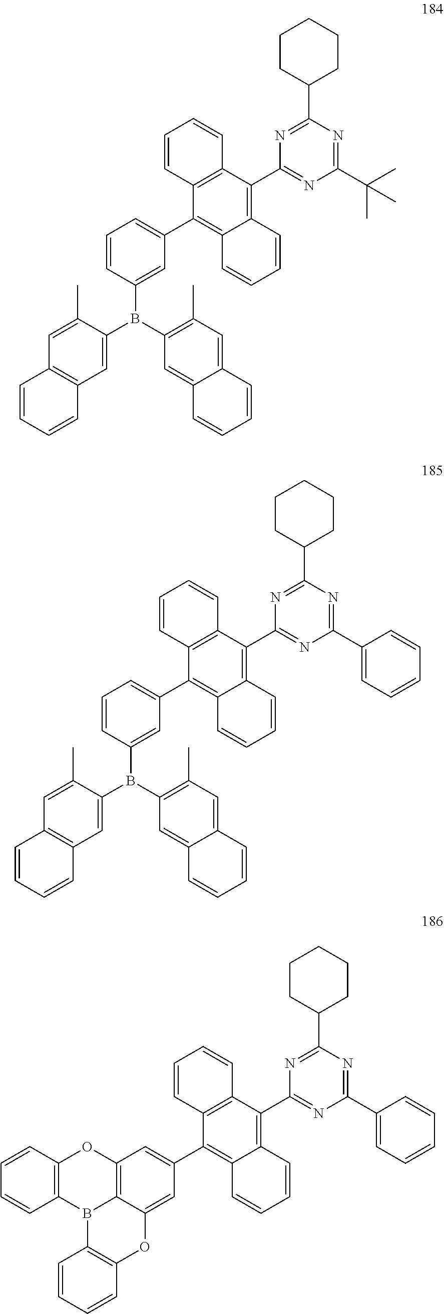 [SMILES: Cc1cc2ccccc2cc1B(c1cccc(-c2c3ccccc3c(-c3nc(C4CCCCC4)nc(C(C)(C)C)n3)c3ccccc23)c1)c1cc2ccccc2cc1C ; Cc1cc2ccccc2cc1B(c1cccc(-c2c3ccccc3c(-c3nc(-c4ccccc4)nc(C4CCCCC4)n3)c3ccccc23)c1)c1cc2ccccc2cc1C ; c1ccc(-c2nc(-c3c4ccccc4c(-c4cc5c6c(c4)Oc4ccccc4B6c4ccccc4O5)c4ccccc34)nc(C3CCCCC3)n2)cc1] 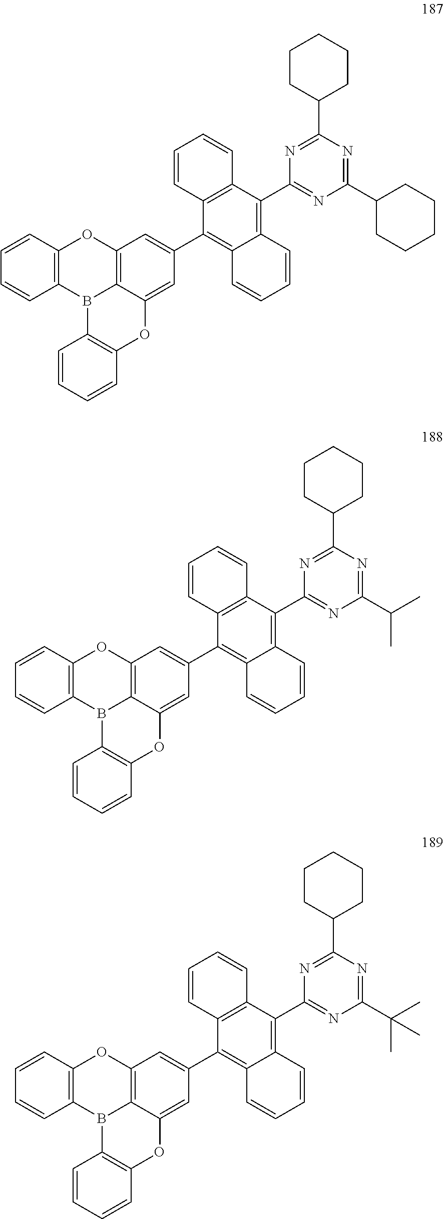 [SMILES: c1ccc2c(c1)Oc1cc(-c3c4ccccc4c(-c4nc(C5CCCCC5)nc(C5CCCCC5)n4)c4ccccc34)cc3c1B2c1ccccc1O3 ; CC(C)c1nc(-c2c3ccccc3c(-c3cc4c5c(c3)Oc3ccccc3B5c3ccccc3O4)c3ccccc23)nc(C2CCCCC2)n1 ; CC(C)(C)c1nc(-c2c3ccccc3c(-c3cc4c5c(c3)Oc3ccccc3B5c3ccccc3O4)c3ccccc23)nc(C2CCCCC2)n1] 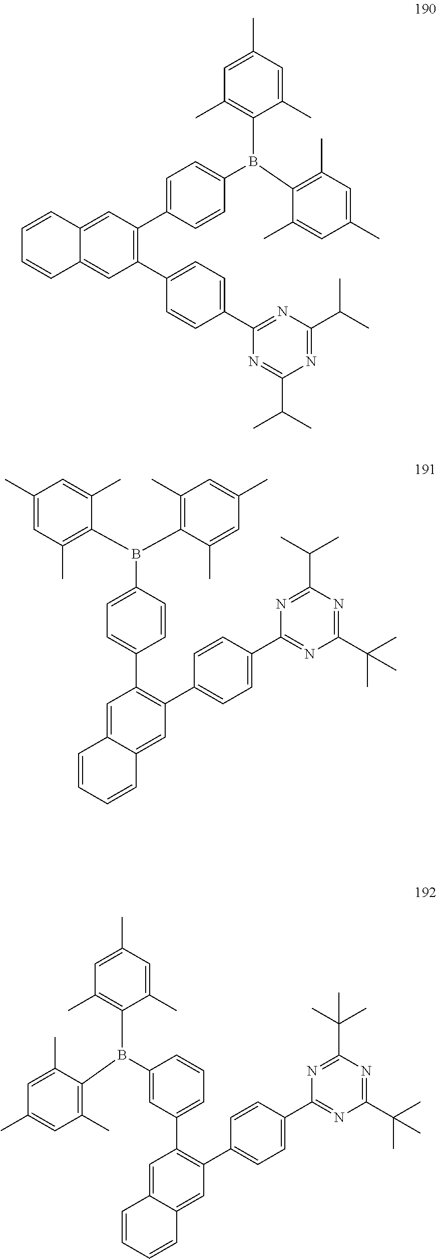 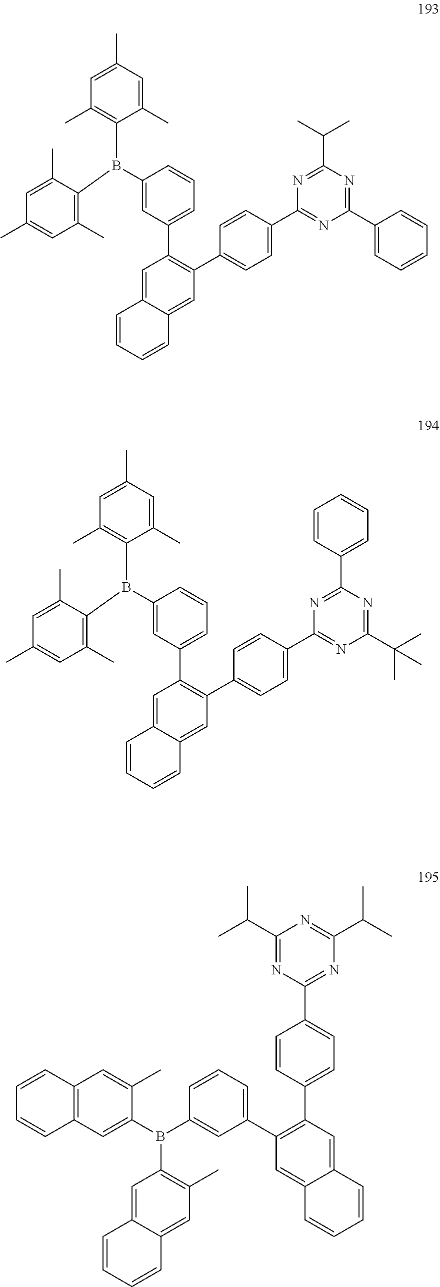 [SMILES: Cc1cc(C)c(B(c2cccc(-c3cc4ccccc4cc3-c3ccc(-c4nc(-c5ccccc5)nc(C(C)C)n4)cc3)c2)c2c(C)cc(C)cc2C)c(C)c1 ; Cc1cc(C)c(B(c2cccc(-c3cc4ccccc4cc3-c3ccc(-c4nc(-c5ccccc5)nc(C(C)(C)C)n4)cc3)c2)c2c(C)cc(C)cc2C)c(C)c1 ; Cc1cc2ccccc2cc1B(c1cccc(-c2cc3ccccc3cc2-c2ccc(-c3nc(C(C)C)nc(C(C)C)n3)cc2)c1)c1cc2ccccc2cc1C] 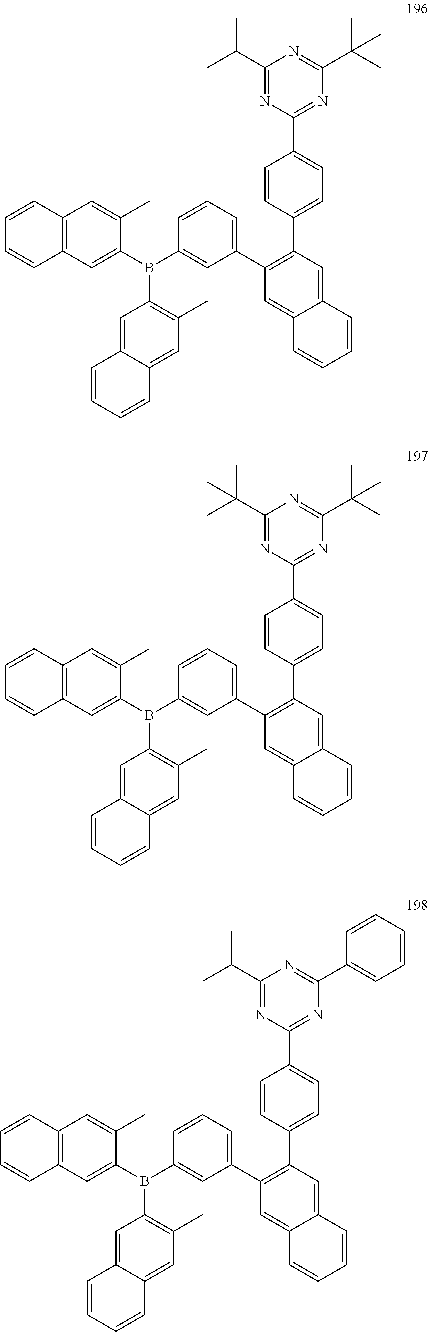 [SMILES: Cc1cc2ccccc2cc1B(c1cccc(-c2cc3ccccc3cc2-c2ccc(-c3nc(C(C)C)nc(C(C)(C)C)n3)cc2)c1)c1cc2ccccc2cc1C ; Cc1cc2ccccc2cc1B(c1cccc(-c2cc3ccccc3cc2-c2ccc(-c3nc(C(C)(C)C)nc(C(C)(C)C)n3)cc2)c1)c1cc2ccccc2cc1C ; Cc1cc2ccccc2cc1B(c1cccc(-c2cc3ccccc3cc2-c2ccc(-c3nc(-c4ccccc4)nc(C(C)C)n3)cc2)c1)c1cc2ccccc2cc1C] 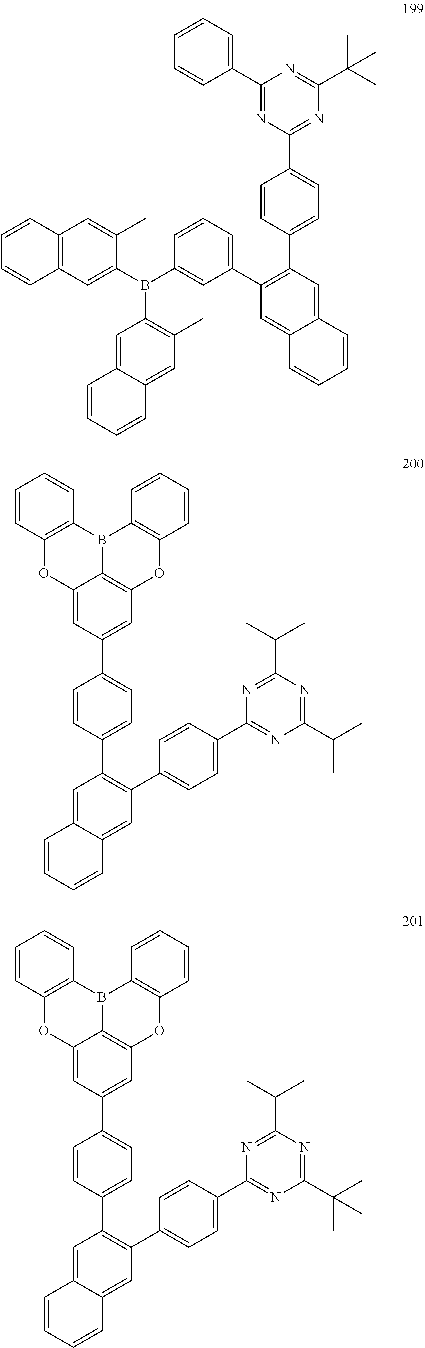 [SMILES: Cc1cc2ccccc2cc1B(c1cccc(-c2cc3ccccc3cc2-c2ccc(-c3nc(-c4ccccc4)nc(C(C)(C)C)n3)cc2)c1)c1cc2ccccc2cc1C ; CC(C)c1nc(-c2ccc(-c3cc4ccccc4cc3-c3ccc(-c4cc5c6c(c4)Oc4ccccc4B6c4ccccc4O5)cc3)cc2)nc(C(C)C)n1 ; CC(C)c1nc(-c2ccc(-c3cc4ccccc4cc3-c3ccc(-c4cc5c6c(c4)Oc4ccccc4B6c4ccccc4O5)cc3)cc2)nc(C(C)(C)C)n1] 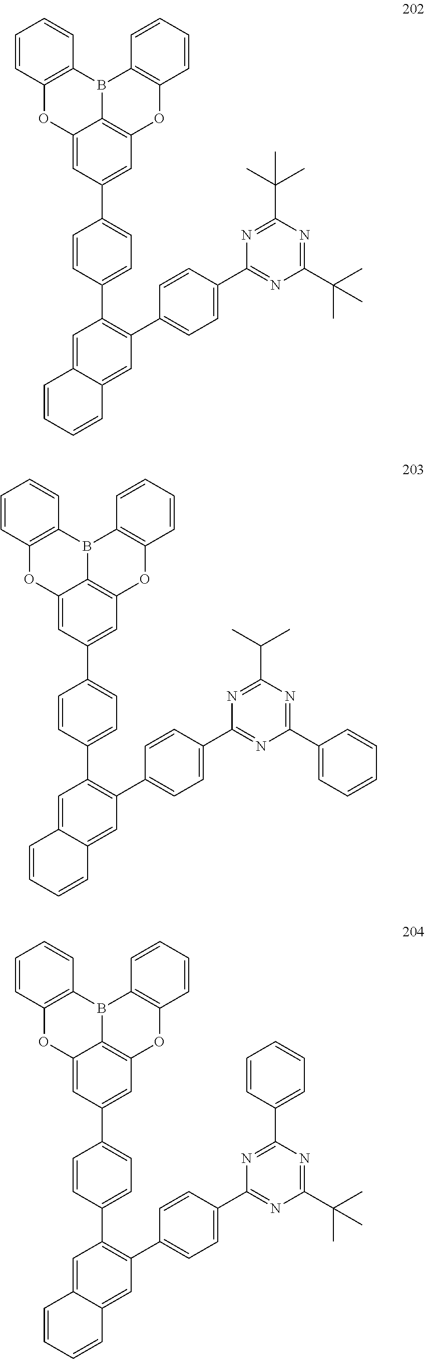 [SMILES: CC(C)(C)c1nc(-c2ccc(-c3cc4ccccc4cc3-c3ccc(-c4cc5c6c(c4)Oc4ccccc4B6c4ccccc4O5)cc3)cc2)nc(C(C)(C)C)n1 ; CC(C)c1nc(-c2ccccc2)nc(-c2ccc(-c3cc4ccccc4cc3-c3ccc(-c4cc5c6c(c4)Oc4ccccc4B6c4ccccc4O5)cc3)cc2)n1 ; CC(C)(C)c1nc(-c2ccccc2)nc(-c2ccc(-c3cc4ccccc4cc3-c3ccc(-c4cc5c6c(c4)Oc4ccccc4B6c4ccccc4O5)cc3)cc2)n1] 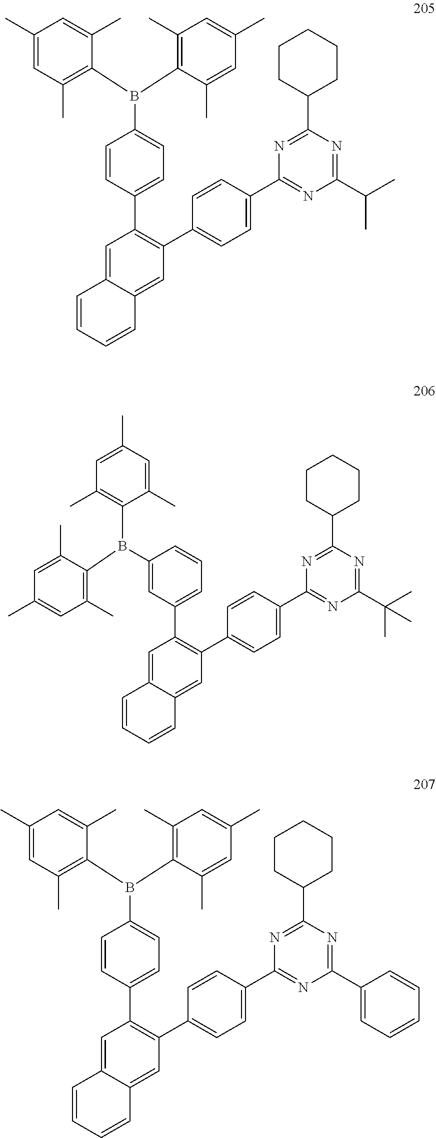 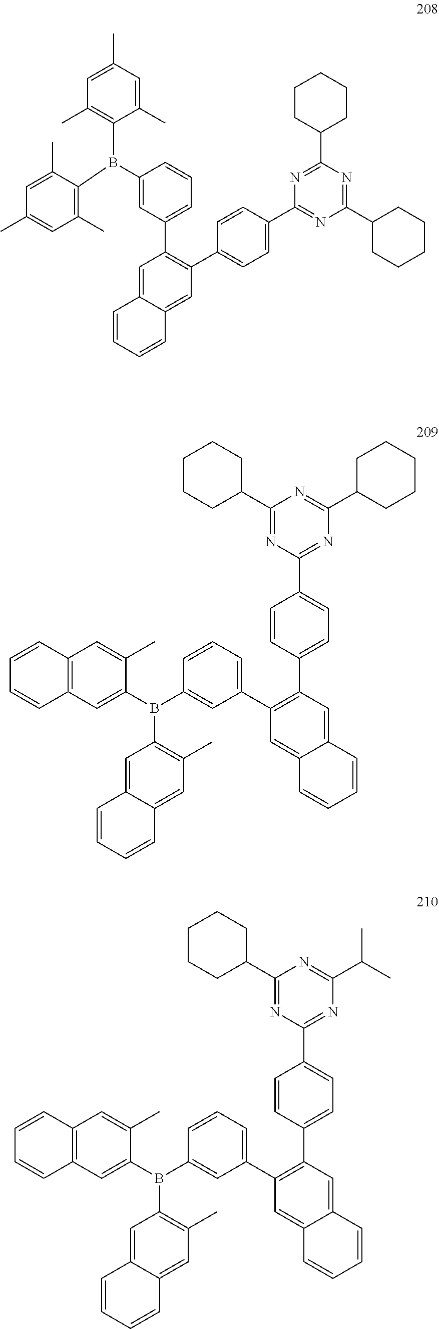 [SMILES: Cc1cc(C)c(B(c2cccc(-c3cc4ccccc4cc3-c3ccc(-c4nc(C5CCCCC5)nc(C5CCCCC5)n4)cc3)c2)c2c(C)cc(C)cc2C)c(C)c1 ; Cc1cc2ccccc2cc1B(c1cccc(-c2cc3ccccc3cc2-c2ccc(-c3nc(C4CCCCC4)nc(C4CCCCC4)n3)cc2)c1)c1cc2ccccc2cc1C ; Cc1cc2ccccc2cc1B(c1cccc(-c2cc3ccccc3cc2-c2ccc(-c3nc(C(C)C)nc(C4CCCCC4)n3)cc2)c1)c1cc2ccccc2cc1C] 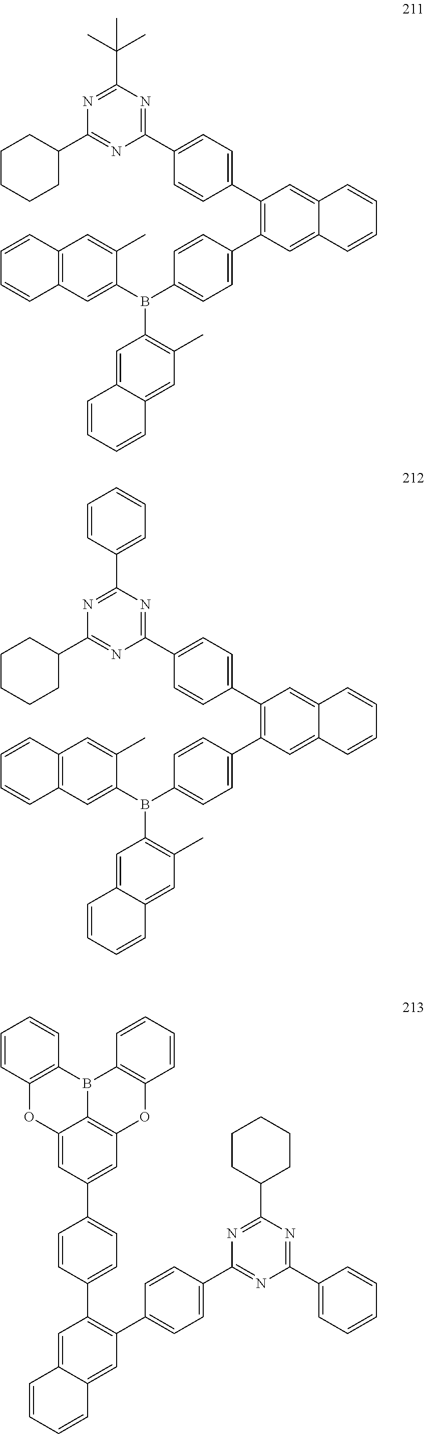 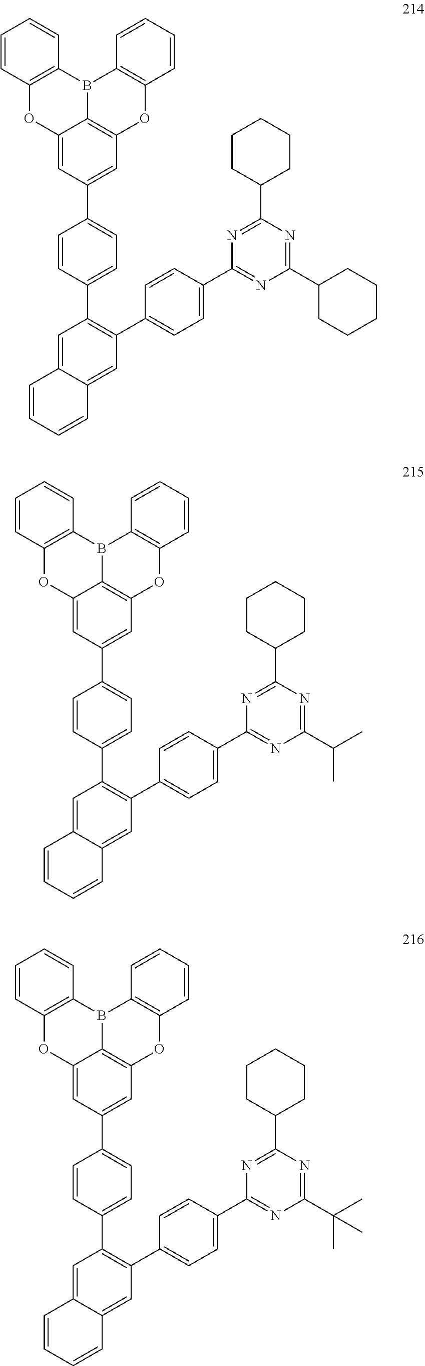 [SMILES: c1ccc2c(c1)Oc1cc(-c3ccc(-c4cc5ccccc5cc4-c4ccc(-c5nc(C6CCCCC6)nc(C6CCCCC6)n5)cc4)cc3)cc3c1B2c1ccccc1O3 ; CC(C)c1nc(-c2ccc(-c3cc4ccccc4cc3-c3ccc(-c4cc5c6c(c4)Oc4ccccc4B6c4ccccc4O5)cc3)cc2)nc(C2CCCCC2)n1 ; CC(C)(C)c1nc(-c2ccc(-c3cc4ccccc4cc3-c3ccc(-c4cc5c6c(c4)Oc4ccccc4B6c4ccccc4O5)cc3)cc2)nc(C2CCCCC2)n1] 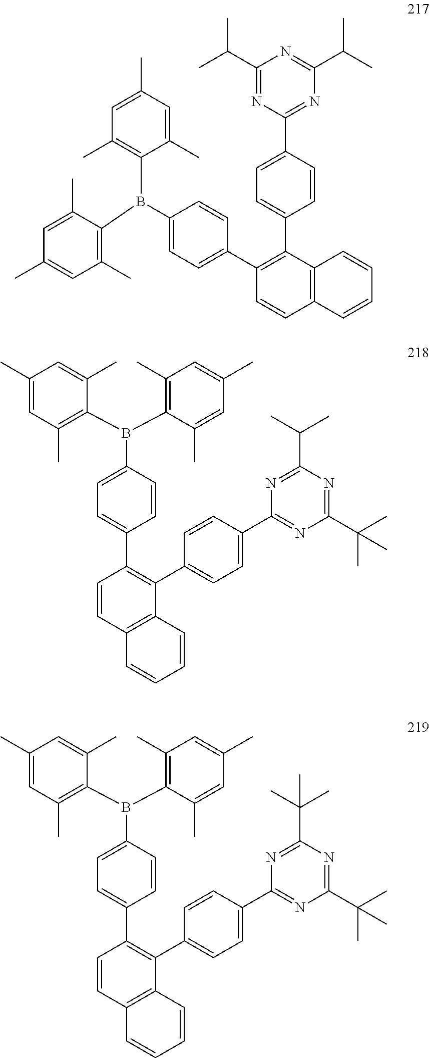 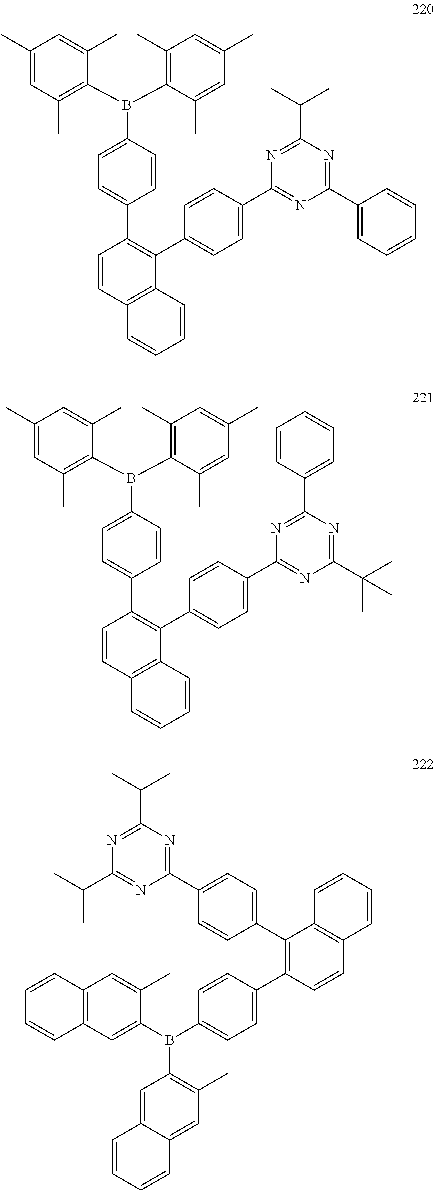 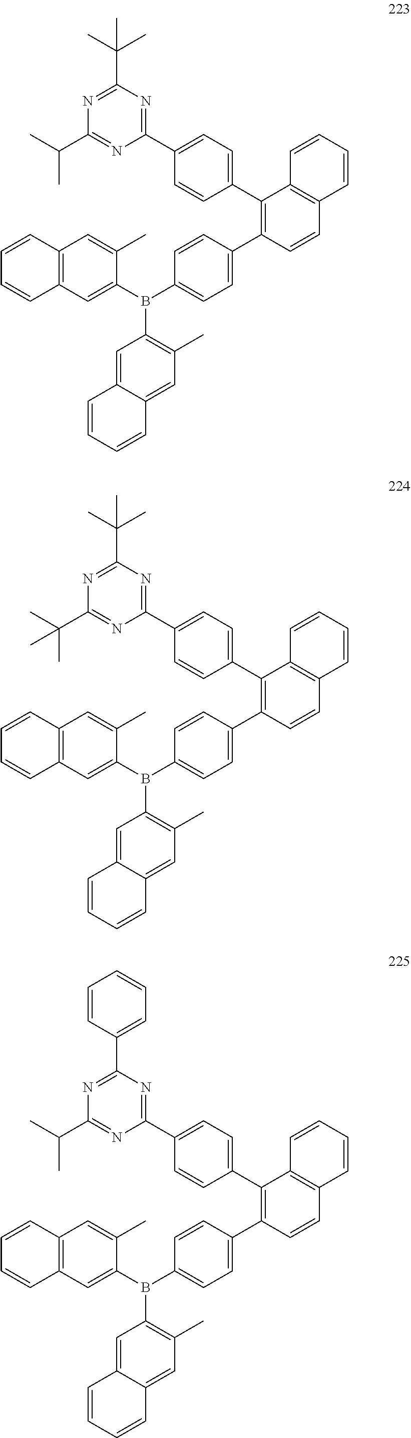 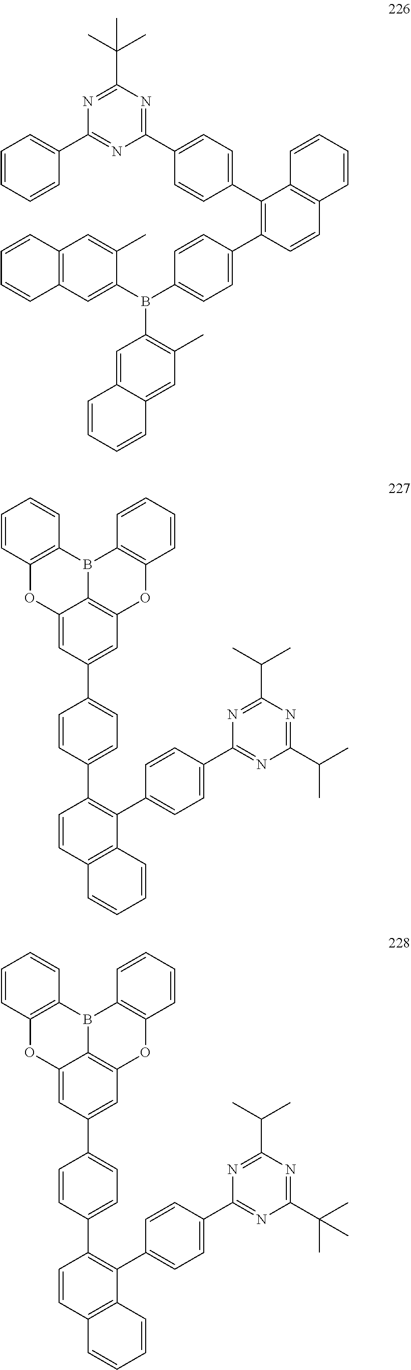 [SMILES: Cc1cc2ccccc2cc1B(c1ccc(-c2ccc3ccccc3c2-c2ccc(-c3nc(-c4ccccc4)nc(C(C)(C)C)n3)cc2)cc1)c1cc2ccccc2cc1C ; CC(C)c1nc(-c2ccc(-c3c(-c4ccc(-c5cc6c7c(c5)Oc5ccccc5B7c5ccccc5O6)cc4)ccc4ccccc34)cc2)nc(C(C)C)n1 ; CC(C)c1nc(-c2ccc(-c3c(-c4ccc(-c5cc6c7c(c5)Oc5ccccc5B7c5ccccc5O6)cc4)ccc4ccccc34)cc2)nc(C(C)(C)C)n1] 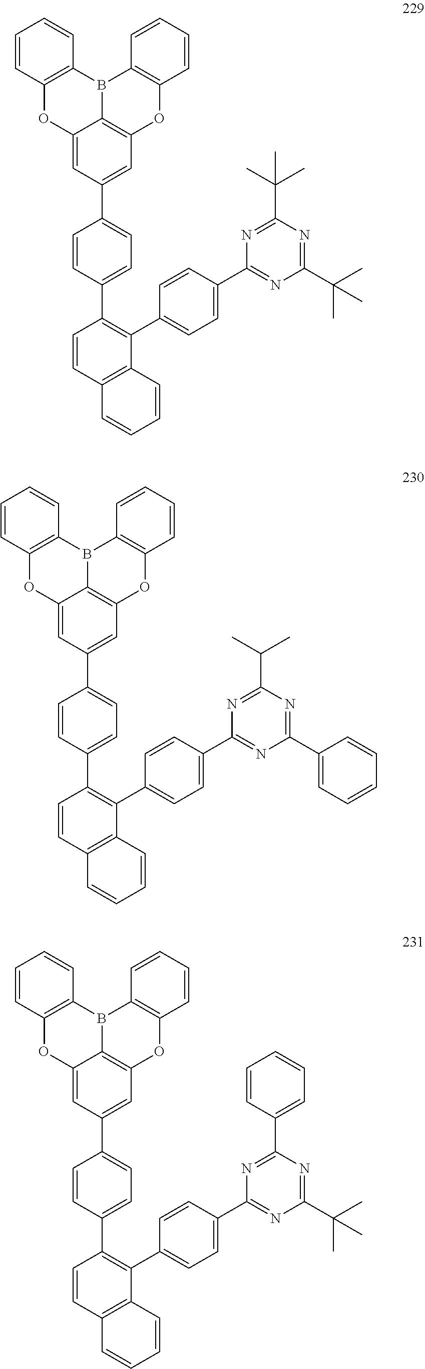 [SMILES: CC(C)(C)c1nc(-c2ccc(-c3c(-c4ccc(-c5cc6c7c(c5)Oc5ccccc5B7c5ccccc5O6)cc4)ccc4ccccc34)cc2)nc(C(C)(C)C)n1 ; CC(C)c1nc(-c2ccccc2)nc(-c2ccc(-c3c(-c4ccc(-c5cc6c7c(c5)Oc5ccccc5B7c5ccccc5O6)cc4)ccc4ccccc34)cc2)n1 ; CC(C)(C)c1nc(-c2ccccc2)nc(-c2ccc(-c3c(-c4ccc(-c5cc6c7c(c5)Oc5ccccc5B7c5ccccc5O6)cc4)ccc4ccccc34)cc2)n1] 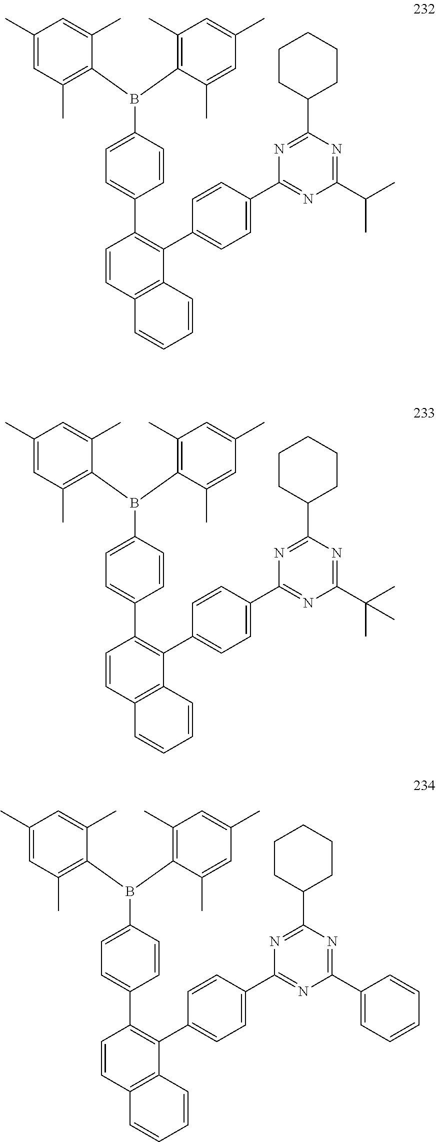 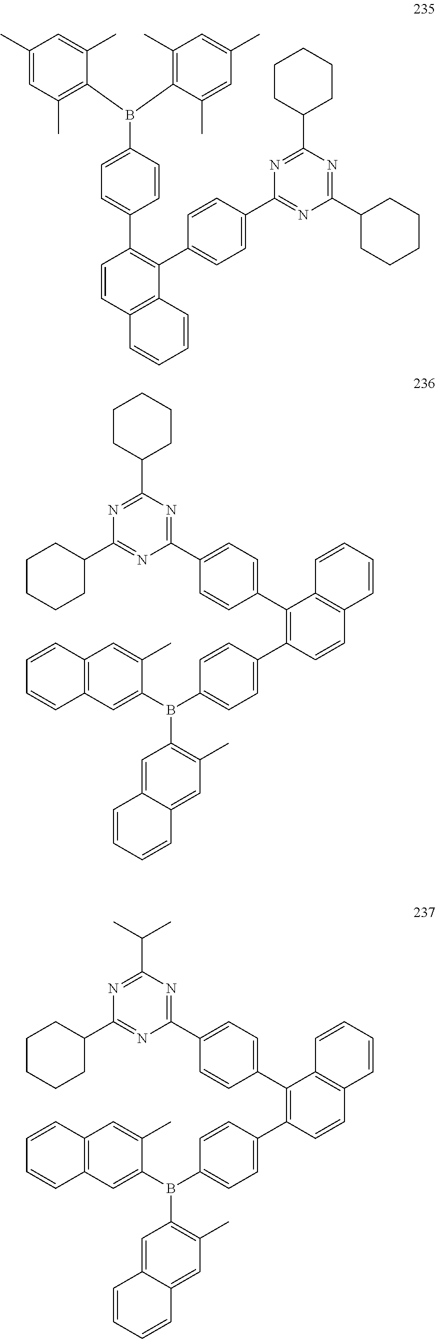 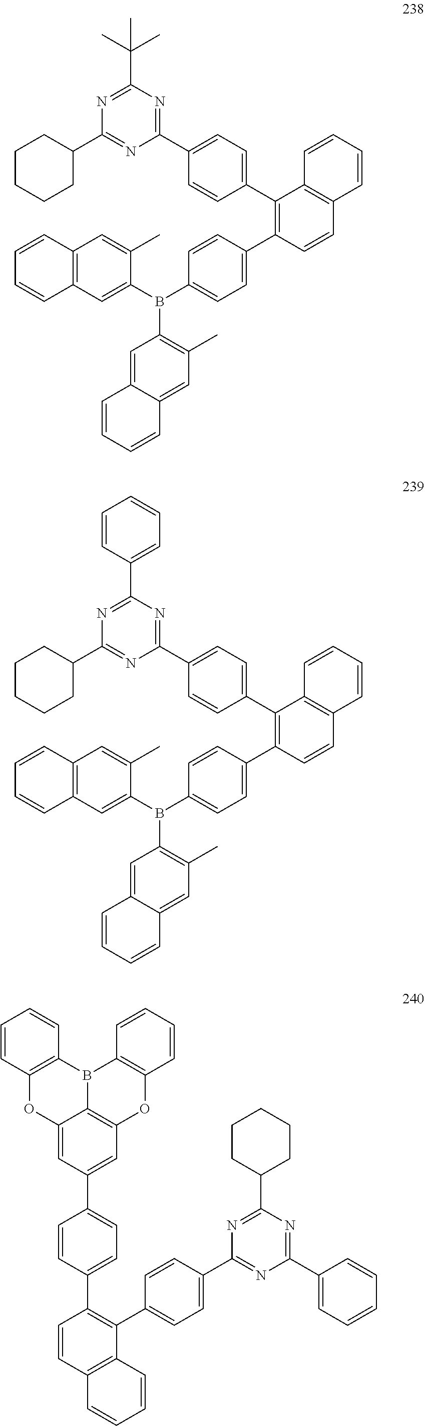 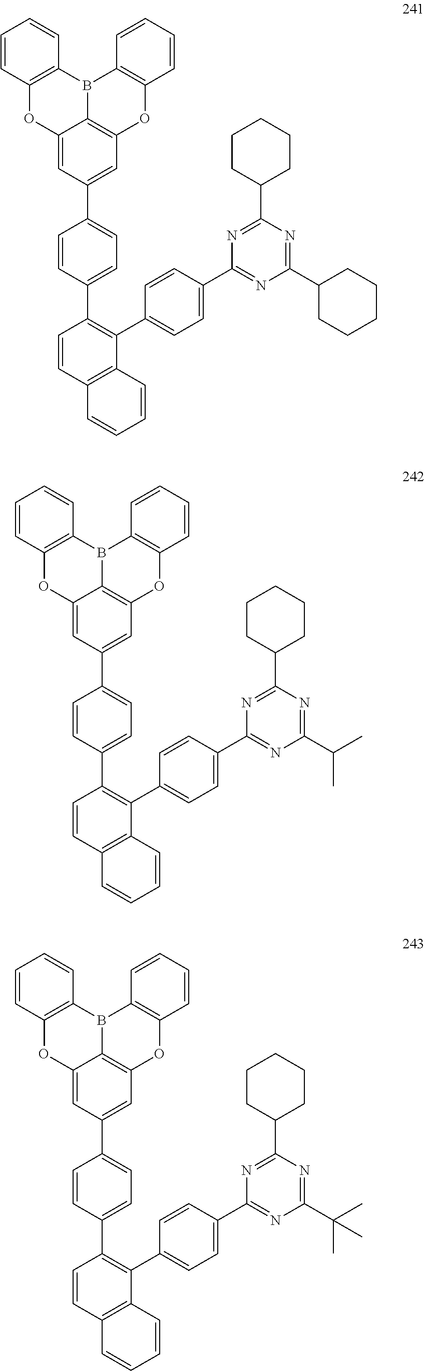 [SMILES: c1ccc2c(c1)Oc1cc(-c3ccc(-c4ccc5ccccc5c4-c4ccc(-c5nc(C6CCCCC6)nc(C6CCCCC6)n5)cc4)cc3)cc3c1B2c1ccccc1O3 ; CC(C)c1nc(-c2ccc(-c3c(-c4ccc(-c5cc6c7c(c5)Oc5ccccc5B7c5ccccc5O6)cc4)ccc4ccccc34)cc2)nc(C2CCCCC2)n1 ; CC(C)(C)c1nc(-c2ccc(-c3c(-c4ccc(-c5cc6c7c(c5)Oc5ccccc5B7c5ccccc5O6)cc4)ccc4ccccc34)cc2)nc(C2CCCCC2)n1] 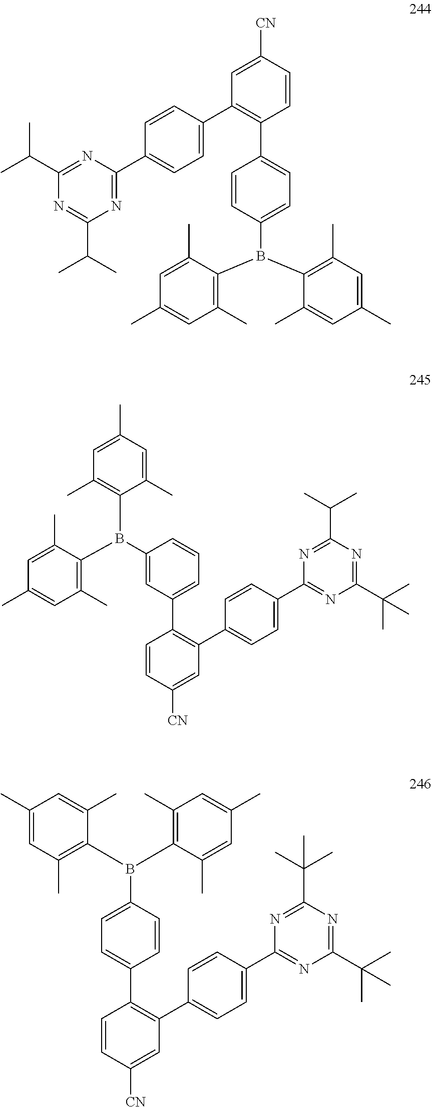 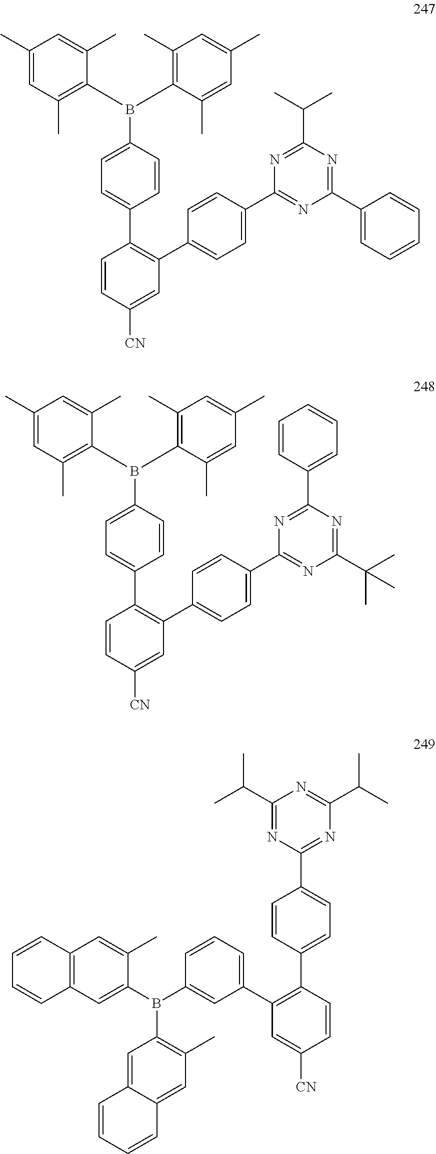 [SMILES: Cc1cc(C)c(B(c2ccc(-c3ccc(C#N)cc3-c3ccc(-c4nc(-c5ccccc5)nc(C(C)C)n4)cc3)cc2)c2c(C)cc(C)cc2C)c(C)c1 ; Cc1cc(C)c(B(c2ccc(-c3ccc(C#N)cc3-c3ccc(-c4nc(-c5ccccc5)nc(C(C)(C)C)n4)cc3)cc2)c2c(C)cc(C)cc2C)c(C)c1 ; Cc1cc2ccccc2cc1B(c1cccc(-c2cc(C#N)ccc2-c2ccc(-c3nc(C(C)C)nc(C(C)C)n3)cc2)c1)c1cc2ccccc2cc1C] 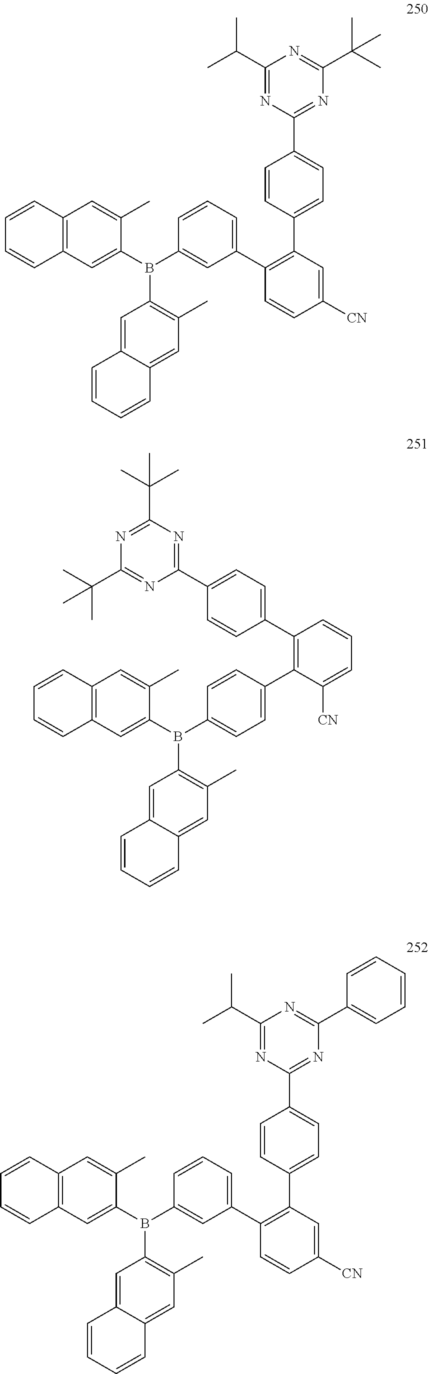 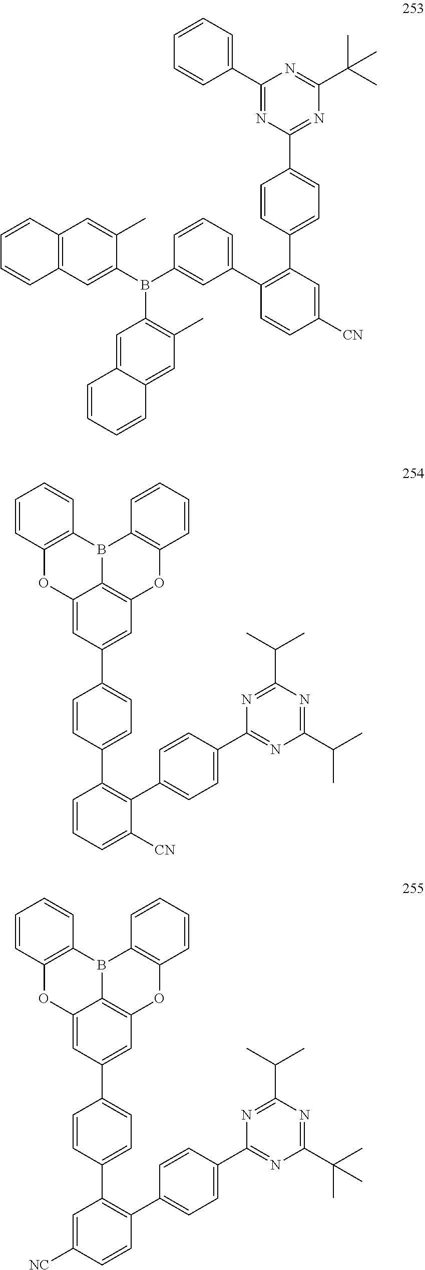 [SMILES: Cc1cc2ccccc2cc1B(c1cccc(-c2ccc(C#N)cc2-c2ccc(-c3nc(-c4ccccc4)nc(C(C)(C)C)n3)cc2)c1)c1cc2ccccc2cc1C ; CC(C)c1nc(-c2ccc(-c3c(C#N)cccc3-c3ccc(-c4cc5c6c(c4)Oc4ccccc4B6c4ccccc4O5)cc3)cc2)nc(C(C)C)n1 ; CC(C)c1nc(-c2ccc(-c3ccc(C#N)cc3-c3ccc(-c4cc5c6c(c4)Oc4ccccc4B6c4ccccc4O5)cc3)cc2)nc(C(C)(C)C)n1] 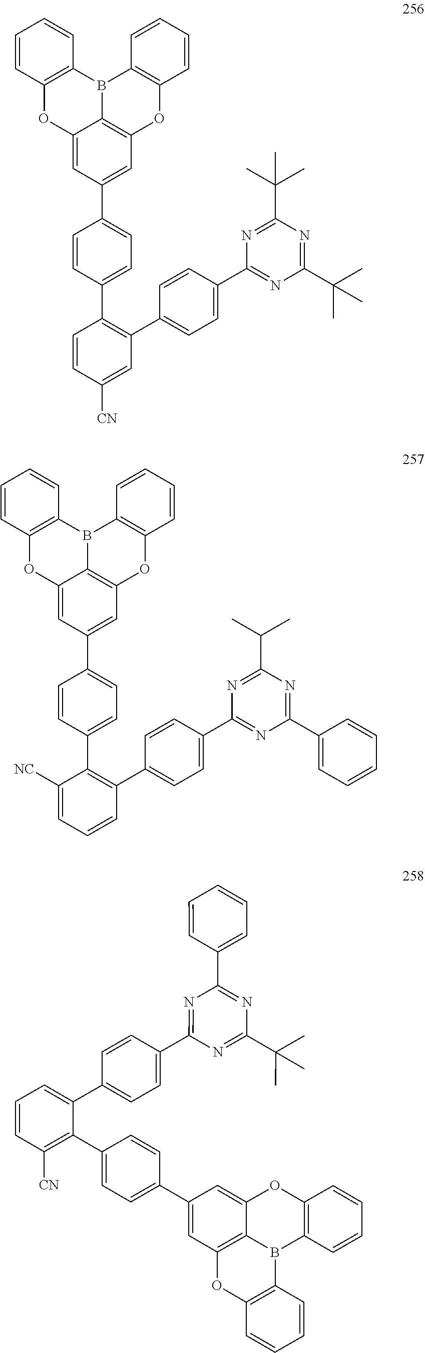 [SMILES: CC(C)(C)c1nc(-c2ccc(-c3cc(C#N)ccc3-c3ccc(-c4cc5c6c(c4)Oc4ccccc4B6c4ccccc4O5)cc3)cc2)nc(C(C)(C)C)n1 ; CC(C)c1nc(-c2ccccc2)nc(-c2ccc(-c3cccc(C#N)c3-c3ccc(-c4cc5c6c(c4)Oc4ccccc4B6c4ccccc4O5)cc3)cc2)n1 ; CC(C)(C)c1nc(-c2ccccc2)nc(-c2ccc(-c3cccc(C#N)c3-c3ccc(-c4cc5c6c(c4)Oc4ccccc4B6c4ccccc4O5)cc3)cc2)n1] 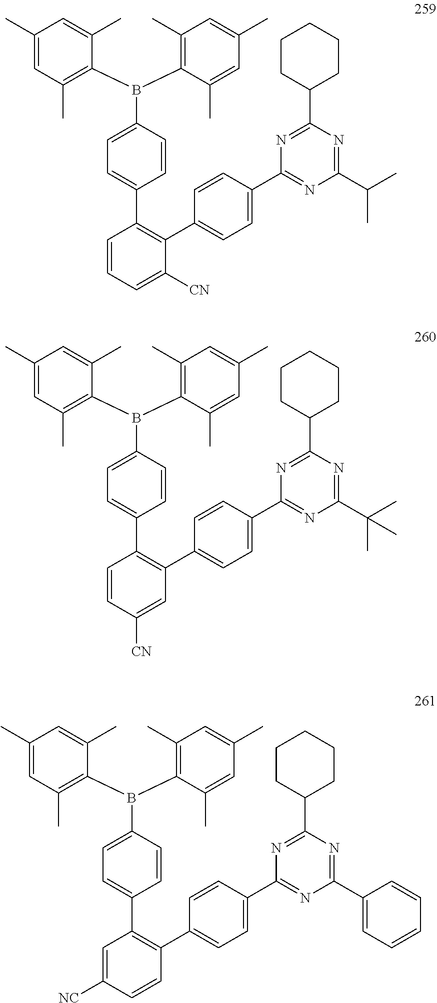 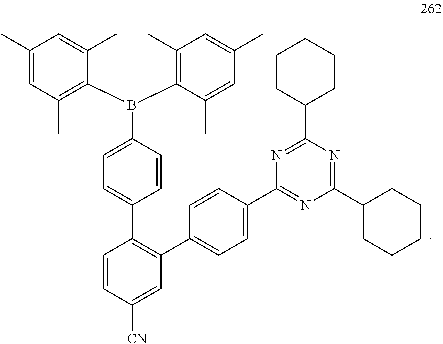 [SMILES: Cc1cc(C)c(B(c2ccc(-c3ccc(C#N)cc3-c3ccc(-c4nc(C5CCCCC5)nc(C5CCCCC5)n4)cc3)cc2)c2c(C)cc(C)cc2C)c(C)c1]
